(19) United States
(12) Patent Application Publication
(10) Pub. No.: US 2019/0355911 A1
(43) Pub. Date: Nov. 21, 2019

(54) ORGANIC MIXTURE, ORGANIC COMPOSITION, ORGANIC ELECTRONIC COMPONENT AND PREPARATION METHOD THEREFOR

(71) Applicant: GUANGZHOU CHINARAY OPTOELECTRONIC MATERIALS LTD., Guangzhou, Guangdong (CN)

(72) Inventors: Junyou PAN, Guangzhou, Guangdong (CN); Ruifeng HE, Guangzhou, Guangdong (CN); Jiahui TAN, Guangzhou, Guangdong (CN); Yini LI, Guangzhou, Guangdong (CN)

(73) Assignee: GUANGZHOU CHINARAY OPTOELECTRONIC MATERIALS LTD., Guangzhou, Guangdong (CN)

(21) Appl. No.: 16/463,349

(22) PCT Filed: Nov. 23, 2017
(86) PCT No.: PCT/CN2017/112712

§ 371 Date: May 22, 2019

(30) Foreign Application Priority Data
Nov. 23, 2016 (CN) 201611046922.1

(51) Int. Cl. H01L 51/00

(52) U.S. Cl. CPC H01L 51/0072; H01L 51/5056; H01L 2251/552; H01L 51/0054

(57) ABSTRACT

An organic mixture, an organic composition, an organic electronic component, and a preparation method therefor. The organic mixture comprises two organic compounds H1 and H2, the organic compound H1 being a spiro compound, the organic compound H1 being a compound comprising rich electrons, min((LUMO(H1)−HOMO(H2)), (LUMO(H2)−HOMO(H1)))≤min (ET(H1), ET(H2))+0.1 eV, the LUMO(H1), HOMO(H1) and ET(H1) respectively indicating a lowest unoccupied molecular orbital, a highest occupied molecular orbital and a triplet-state energy level of the organic compound H1, and the LUMO(H2), HOMO(H2) and ET(H2) respectively indicating a lowest unoccupied molecular orbital, a highest occupied molecular orbital and a triplet-state energy level of the organic compound H2.

### CROSS-REFERENCE TO RELATED APPLICATIONS

The present application is the national phase of International Application PCT/CN2017/112712, filed on Nov. 23, 2017, which claims priority to Chinese Application No. 201611046922.1, filed on Nov. 23, 2016, both of which are incorporated herein by reference in their entireties.

### TECHNICAL FIELD

The present disclosure relates to the technical field of organic optoelectronic materials, and in particular to an organic mixture and an application thereof, an organic electronic device and a preparation method thereof.

### BACKGROUND

With the properties of light weight, active emitting, wide viewing angle, high contrast, high emitting efficiency, low energy consumption, easy preparation for flexible and large-sized panels, etc., organic light-emitting diodes (OLEDs) are regarded as the most promising next-generation display technology in the industry.

In order to promote the large-scale industrialization of the organic light-emitting diodes, further improving the luminescence properties and lifetime of the organic light-emitting diodes is a key issue that need to be solved urgently, and high-performance organic optoelectronic material systems with still need to be further developed.

The host material is the key element for efficient and long-lifetime light-emitting diodes. Since the organic light-emitting diodes using phosphorescent materials can achieve nearly 100% internal electroluminescence quantum efficiency, the phosphorescent materials, especially, red and green phosphorescent materials, have become the mainstream material system in the industry. However, the phosphorescent OLEDs have the roll-off effect, i.e., the phenomenon that the emitting efficiency decreases rapidly with the increase of current or voltage, due to the charge imbalance in the device, which is particularly disadvantageous for high brightness applications. In order to solve the above problem, Kim et al. (see Kim et al. Adv. Func. Mater. 2013 DOI: 10.1002/adfm.201300547, and Kim et al. Adv. Func. Mater. 2013, DOI: 10.1002/adfm.201300187) obtained the OLEDs with low roll-off and high efficiency by using a co-host that can form an exciplex together with another metal complex as the phosphorescent emitter. However, the lifetime of such OLED devices still needs to be greatly improved.

### SUMMARY

According to various embodiments of the present disclosure, an organic mixture, an organic formulation, an organic electronic device and a preparation method thereof are provided, and one or more of the problems involved in the background have been solved.

An organic mixture comprising two organic compounds H1 and H2 is provided, the organic compound H1 is a spiro compound, and the organic compound H2 is a compound containing electron-donating groups, wherein, min((LUMO(H1)−HOMO(H2)), (LUMO(H2)−HOMO(H1)))≤min (E_{T}(H1), E_{T}(H2))+0.1 eV; wherein, the LUMO(H1), HOMO(H1) and E_{T}(H1) respectively represent the lowest unoccupied molecular orbital energy level, highest occupied molecular orbital energy level and triplet excited state energy level of the organic compound H1, and the LUMO(H2), HOMO(H2) and E_{T}(H2) respectively represent the lowest unoccupied molecular orbital energy level, highest occupied molecular orbital energy level and triplet energy level of the organic compound H2.

A formulation comprising an organic solvent and the above organic mixture is also provided.

An organic electronic device comprising a cathode, an anode and a functional layer located between the cathode and the anode is further provided, the functional layer comprises the above organic mixture or the above formulation.

A method of preparing the above organic electronic device is further provided, comprising the following steps:

grinding and mixing the organic compound H1 and the organic compound H2; and

placing the ground and mixed organic compound H1 and organic compound H2 in an organic source for evaporation, to form the functional layer.

A method of preparing the above organic electronic device is further provided, comprising the following steps:

placing the organic compound H1 and the organic compound H2 in two sources under vacuum for evaporation, respectively, to form the functional layer.

The details of one or more embodiments of the present disclosure are set forth in the accompanying drawings and the description below. Other features, objects and advantages of the present disclosure will become apparent from the description, the accompanying drawings, and the claims.

### DETAILED DESCRIPTION OF THE EMBODIMENTS

In order to make the purpose, technical solution and advantages of the present disclosure clearer, the embodiments of the present disclosure will be further described in detail below with reference to the accompanying drawings. It should be noted that, the specific embodiment illustrated herein is merely for the purpose of explanation, and should not be deemed to limit the disclosure.

Formulation, printing ink and ink herein, have the same meaning and may be used interchangeably. Host material, matrix material, Host or Matrix material have the same meaning and may be used interchangeably. Metal organic complex, metal organic complex, and organometallic complex have the same meaning and may be used interchangeably. In the present disclosure, (HOMO−1) is defined as the second highest occupied molecular orbital energy level, and (HOMO−2) is defined as the third highest occupied molecular orbital energy level, and so on. (LUMO+1) is defined as the second lowest unoccupied molecular orbital energy level, and (LUMO+2) is defined as the third lowest occupied molecular orbital energy level, and so on.

The organic mixture of an embodiment comprises two organic compounds H1 and H2. The organic compound H1 is a spiro compound, and the organic compound H2 is a compound containing electron-donating groups, wherein, min((LUMO(H1)−HOMO(H2)), (LUMO(H2)−HOMO(H1)))≤min (E_{T}(H1), E_{T}(H2))+0.1 eV; wherein, the LUMO(H1), HOMO(H1) and E_{T}(H1) respectively represent the lowest unoccupied molecular orbital energy level, highest occupied molecular orbital energy level and triplet excited state energy level of the organic compound H1, and the LUMO(H2), HOMO(H2) and E_{T}(H2) respectively represent the lowest unoccupied molecular orbital energy level, highest occupied molecular orbital energy level and triplet excited state energy level of the organic compound H2. Wherein, the energy of the combined excited state formed between the organic compound H1 and the organic compound H2 depends on min((LUMO(H1)−HOMO(H2)), (LUMO(H2)−HOMO(H1))).

Since the above organic mixture comprises the spiro compound and the compound containing electron-donating groups, both of which have excellent optoelectronic properties and intrinsic stability and the energy levels of both satisfies (min (LUMO(H1)−HOMO(H2)), (LUMO(H2)−HOMO(H1)))≤min(E_{T}(H1), E_{T}(H2))+0.1 eV, thus, both of the spiro compound and the compound containing electron-donating groups may have suitable HOMO and LUMO energy levels, which is beneficial to reduce the barrier of electron and hole injection, and easy to achieve the balance of charge carrier transport, thereby the working voltage and roll-off effect of the device can be reduced. Meanwhile, the energy transfer intermediate state of exciplex with smaller difference between singlet and triplet energy levels is formed between the organic compound H1 and the organic compound H2, so that the energy of the exciton can be more fully utilized, thereby the efficiency and lifetime of the device can be effectively improved.

In the present embodiment, the excited state of the organic mixture will preferentially occupy the exciplex state with the lowest energy or facilitate the energy transfer of the triplet excited state of the organic compound H1 or H2 to the exciplex state, so as to improve the concentration of the exciplex state.

The HOMO and LUMO energy levels can be measured by optoelectronic effects, such as XPS (X-ray Photoelectron Spectroscopy) and UPS (Ultroviolet Photoelectron Spectroscopy) or by Cyclic Voltammetry (hereinafter referred to as CV). In addition, the molecular orbital energy level may also be calculated by a quantum chemistry method such as density functional theory (hereinafter referred to as DFT).

The triplet energy level E_{T} of organic materials can be measured by low temperature time-resolved luminescence spectroscopy, or by quantum simulation calculation (e.g., by Time-dependent DFT), such as by the commercial software Gaussian 03W (Gaussian Inc.), and the specific simulation method may refer to WO2011141110 or may be as described below.

It should be noted that, the absolute values of HOMO, LUMO and E_{T} depend on the measurement or calculation methods used, even for the same method, different HOMO/LUMO value may be obtained by different evaluation methods, such as starting point and peak point on the CV curve. Therefore, reasonable and meaningful comparisons should be made by using same measurement method and same evaluation method. In the embodiments of the present disclosure, the values of HOMO, LUMO and E_{T} are based on the simulations of Time-dependent DFT, but this does not affect the application of other measurement or calculation methods, and the HOMO, LUMO and E_{T} can also be obtained by other measurement or calculation methods.

In an embodiment, min((LUMO(H1)−HOMO(H2), LUMO(H2)−HOMO(H1))≤min(E_{T}(H1), E_{T}(H2)). Further, min((LUMO(H1)−HOMO(H2), LUMO(H2)−HOMO(H1))≤min(E_{T}(H1), E_{T}(H2))−0.05 eV. Still further, min((LUMO(H1)−HOMO(H2), LUMO(H2)−HOMO(H1))≤min(E_{T}(H1), E_{T}(H2))−0.1 eV Even further, min((LUMO(H1)−HOMO(H2), LUMO(H2)−HOMO(H1))≤min(E_{T}(H1), E_{T}(H2))−0.15 eV In an embodiment, min ((LUMO(H1)−HOMO(H2), LUMO(H2)−HOMO(H1))≤min(E_{T}(H1), E_{T}(H2))−0.2 eV.

In an embodiment, min((LUMO(H1)−HOMO(H2)), (LUMO(H2)−HOMO(H1))) is no larger than the energy level of the triplet excited state of the organic compound H1, and min((LUMO(H1)−HOMO(H2)), (LUMO (H2)−HOMO (H1))) is no larger than the energy level of the triplet excited state of the organic compound H2.

In an embodiment, the organic compound H1 and/or the organic compound H2 satisfies (HOMO−(HOMO−1))≥0.2 eV, wherein, the HOMO refers to the highest occupied molecular orbital energy level of the organic compound H1 or the organic compound H2, the (HOMO−1) refers to the occupied molecular orbital energy level of the organic compound H1 or the organic compound H2, which is one level lower than the highest occupied molecular orbital, that is, the second highest occupied molecular orbital energy level. Further, the organic compound H1 and/or the organic compound H2 satisfies (HOMO−(HOMO−1))≥0.25 eV. Further, the organic compound H1 and/or the organic compound H2 satisfies (HOMO−(HOMO−1))≥0.3 eV Still further, the organic compound H1 and/or the organic compound H2 satisfies (HOMO−(HOMO−1))≥0.35 eV. Further, the organic compound H1 and/or the organic compound H2 satisfies (HOMO−(HOMO−1))≥0.4 eV The organic compound H1 and/or the organic compound H2 may also satisfies (HOMO−(HOMO−1))≥0.45 eV.

In an embodiment, the organic compound H2 satisfies (HOMO−(HOMO−1))≥0.2 eV, wherein, the HOMO refers to the highest occupied molecular orbital energy level of the organic compound H2, and the (HOMO−1) refers to the occupied molecular orbital energy level of the organic compound H2, which is one level lower than the highest occupied molecular orbital energy level of the organic compound H2, that is, the second highest occupied molecular orbital energy level. Further, the organic compound H2 satisfies (HOMO−(HOMO−1))≥0.25 eV. Further, the organic compound H2 satisfies (HOMO−(HOMO−1))≥0.3 eV Still further, the organic compound H2 satisfies (HOMO−(HOMO−1))≥0.35 eV Further, the organic compound H2 satisfies (HOMO−(HOMO−1))≥0.4 eV Still further, the organic compound H2 may also satisfies (HOMO−(HOMO−1))≥0.45 eV.

In an embodiment, the organic compound H1 has a structure represented by the general formula (1):

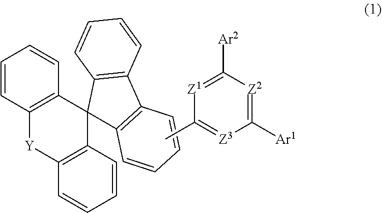

wherein, Z¹, Z² and Z³ are independently selected from N or C atoms, and at least one of Z¹, Z² and Z³ is a N atom;

Y is selected from a signal bond, N(R), C(R)₂, Si(R)₂, O, C═N(R), C═C(R)₂, P(R), P(═O)R, S, S═O or SO₂;

Ar¹ and Ar² are independently selected from an aromatic group with a ring atom number of 5 to 60 or a heteroaromatic group with a ring atom number of 5 to 60;

R is selected from the group consisting of H, D, F, CN, carbonyl, sulfonyl, alkoxy, alkyl with a carbon atom number of 1 to 30, cycloalkyl with a carbon atom number of 3 to 30, an aromatic group with a ring atom number of 5 to 60 and a heteroaromatic group with a ring atom number of 5 to 60.

In an embodiment, at least two of Z¹, Z² and Z³ as shown in the general formula (1) are N atoms, and particularly, all of Z¹, Z² and Z³ are N atoms.

In an embodiment, Y as shown in the general formula (1) is a single bond, N(R), C(R)², O or S. Further, Y as shown in the general formula (1) is a single bond or N(R). Particularly, Y as shown in the general formula (1) is a single bond.

In an embodiment, Ar¹ and Ar² as shown in the general formula (1) are aromatic groups with a ring atom number of 5 to 50 or heteroaromatic groups with a ring atom number of 5 to 50. Further, Ar¹ and Ar² are aromatic groups with a ring atom number of 5 to 40 or heteroaromatic groups with a ring atom number of 5 to 40. Still further, Ar¹ and Ar² are aromatic groups with a ring atom number of 5 to 30 or heteroaromatic groups with a ring atom number of 5 to 30.

The aromatic group refers to a hydrocarbyl comprising at least one aromatic ring. The aromatic group may also be an aromatic ring system which refers to the ring system including monocyclic and polycyclic groups. The heteroaromatic group refers to a hydrocarbyl comprising at least one heteroaromatic ring (containing heteroatoms). The heteroaromatic group may also be a heteroaromatic ring system which refers to the ring system including monocyclic and polycyclic groups. Such polycyclic rings may have two or more rings, wherein two carbon atoms are shared by two adjacent rings, i.e., fused ring. At least one of such polycyclic rings is aromatic or heteroaromatic. In the present embodiment, the aromatic or heteroaromatic ring systems not only include aromatic or heteroaromatic systems, but also a plurality of aryl or heteroaryl groups interrupted by short non-aromatic units (<10% of non-H atoms, especially less than 5% of non-H atoms, such as C, N or O atoms) in the system. Therefore, systems such as 9,9′-spirobifluorene, 9,9-diarylfluorene, triarylamine, diaryl ether and the like may also be considered to be aromatic ring systems.

In an embodiment, the aromatic group is selected from the group consisting of benzene, naphthalene, anthracene, phenanthrene, perylene, tetracene, pyrene, benzopyrene, triphenylene, acenaphthene, fluorene and derivatives thereof.

The heteroaromatic group is selected from the group consisting of furan, benzofuran, thiophene, benzothiophene, pyrrole, pyrazole, triazole, imidazole, oxazole, oxadiazole, thiazole, tetrazole, indole, carbazole, pyrroloimidazole, pyrrolopyrrole, thienopyrrole, thienothiophene, furopyrrole, furofuran, thienofuran, benzisoxazole, benzisothiazole, benzimidazole, pyridine, pyrazine, pyridazine, pyrimidine, triazine, quinoline, isoquinoline, cinnoline, quinoxaline, phenanthridine, perimidine, quinazoline, quinazolinone and derivatives thereof.

In an embodiment, Ar¹ and Ar² as shown in the general formula (1) are independently selected from one of the following groups:

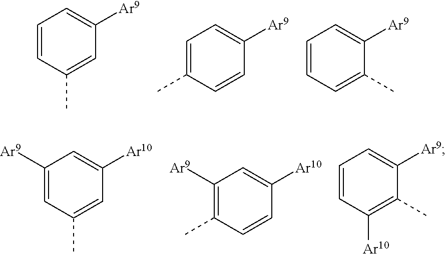

wherein, Ar⁹ and Ar¹⁰ are aromatic groups with a ring atom number of 5 to 48 or heteroaromatic groups with a ring atom number of 5 to 48.

In an embodiment, the organic compound H1 is selected from one of the following structural formulas:

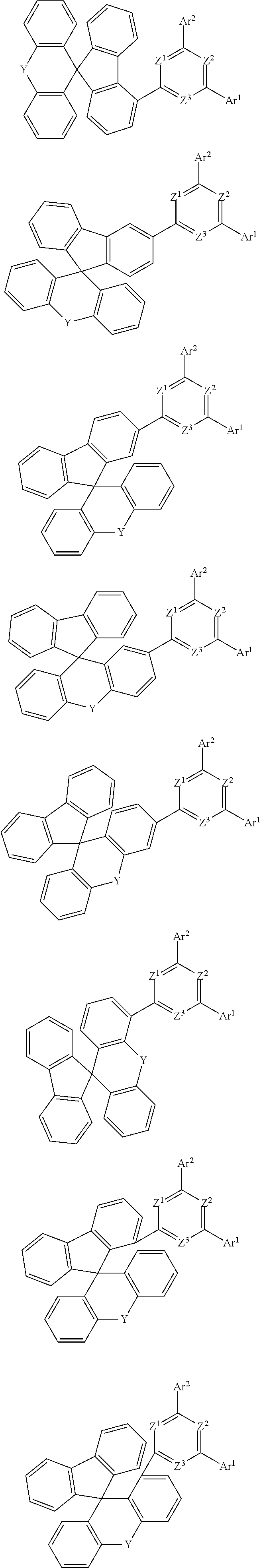

wherein, Z¹, Z² and Z³ are independently selected from N or C atoms, and at least one of Z¹, Z² and Z³ is a N atom;

Y is selected from a signal bond, N(R), C(R)₂, Si(R)₂, O, C═N(R), C═C(R)₂, P(R), P(═O)R, S, S═O or SO₂;

Ar¹ and Ar² are independently selected from an aromatic group with a ring atom number of 5 to 60 or a heteroaromatic group with a ring atom number of 5 to 60;

R is selected from the group consisting of H, D, F, CN, carbonyl, sulfonyl, alkoxy, alkyl with a carbon atom number of 1 to 30, cycloalkyl with a carbon atom number of 3 to 30, an aromatic group with a ring atom number of 5 to 60 and a heteroaromatic group with a ring atom number of 5 to 60.

In an embodiment, Ar¹ and Ar² as shown in the general formula (1) are independently selected from one of the following structural groups:

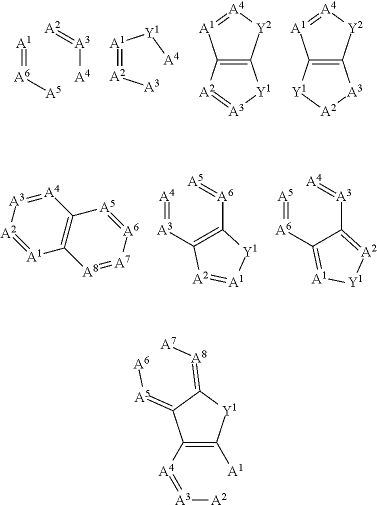

wherein, A¹, A², A³, A⁴, A⁵, A⁶, A⁷ and A⁸ are independently selected from CR³ or N;

Y¹ and Y² are independently selected from CR⁴R⁵, SiR⁴R⁵, NR³, C(═O), S or O;

R³, R⁴ and R⁵ are independently selected from the group consisting of H, D, a linear alkyl containing 1 to 20 C atoms, an linear alkoxy containing 1 to 20 C atoms, a linear thioalkoxy containing 1 to 20 C atoms, a branched or cyclic alkyl group containing 3 to 20 C atoms, a branched or cyclic alkoxy group containing 3 to 20 C atoms, a branched or cyclic thioalkoxy group containing 3 to 20 C atoms, a branched or cyclic silyl group containing 3 to 20 C atoms, a substituted ketone group containing 1 to 20 C atoms, an alkoxycarbonyl group containing 2 to 20 C atoms, an aryloxycarbonyl group containing 7 to 20 C atoms, cyano group, carbamoyl group, haloformyl group, formyl group, isocyano group, isocyanate group, thiocyanate group, isothiocyanate group, hydroxyl group, nitro group, CF₃ group, Cl, Br, F, a crosslinkable group, a substituted or unsubstituted aromatic ring system containing 5 to 40 ring atoms or substituted or unsubstituted heteroaromatic ring system containing 5 to 40 ring atoms, and a aryloxy group containing 5 to 40 ring atoms or heteroaryloxy group containing 5 to 40 ring atoms; wherein, at least one of R³, R⁴ and R⁵ may form a monocyclic or polycyclic aliphatic or aromatic ring with the ring bonded to the groups, or at least two of R³, R⁴ and R⁵ form a monocyclic or polycyclic aliphatic or aromatic ring with each other.

In an embodiment, Ar¹ and Ar² are independently selected from one of the following structural groups:

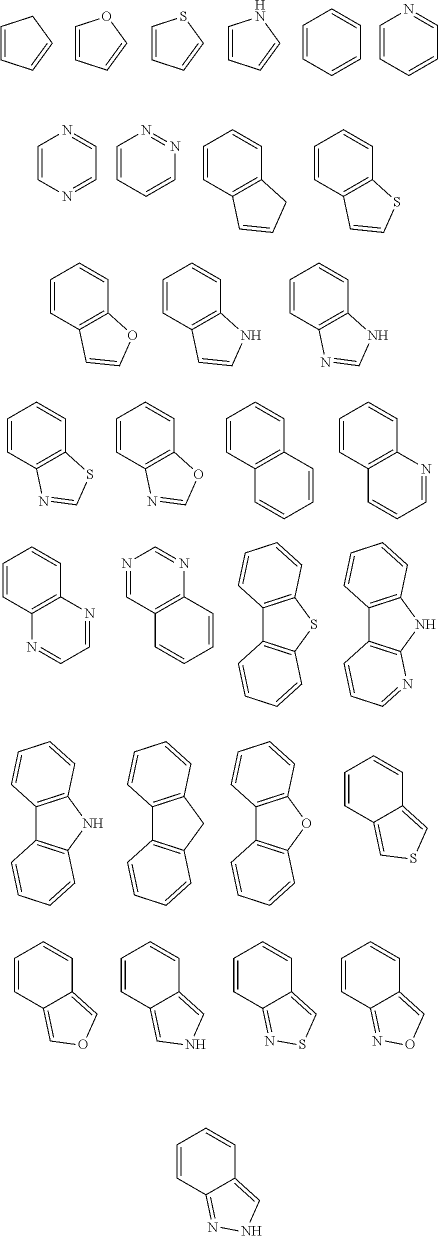

wherein, H on any ring of the above groups may be arbitrarily substituted.

Specific examples of the compound represented by the general formula (1) are exemplified below, but not limited to:

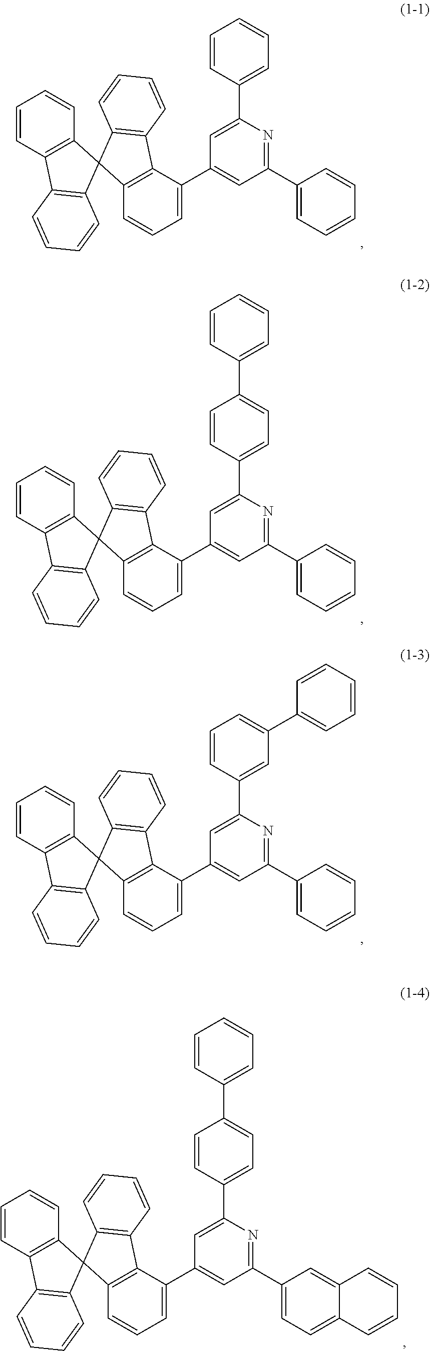

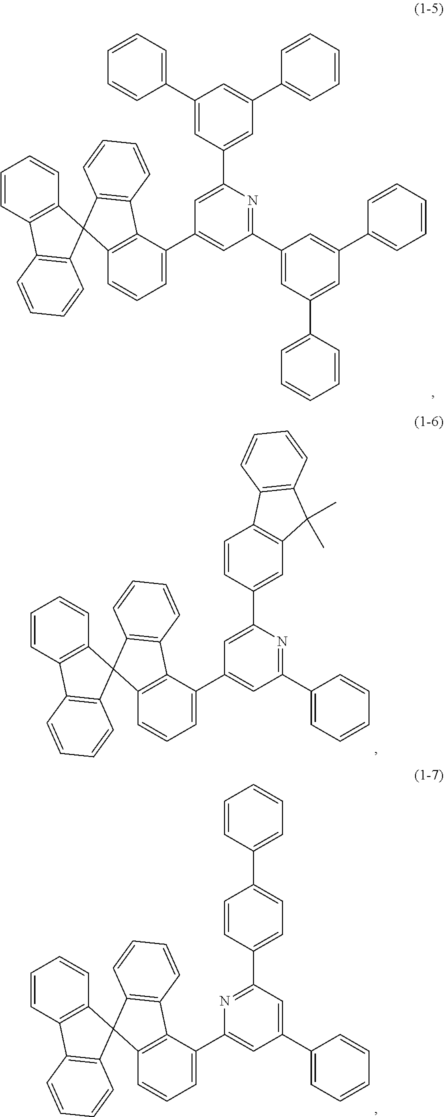

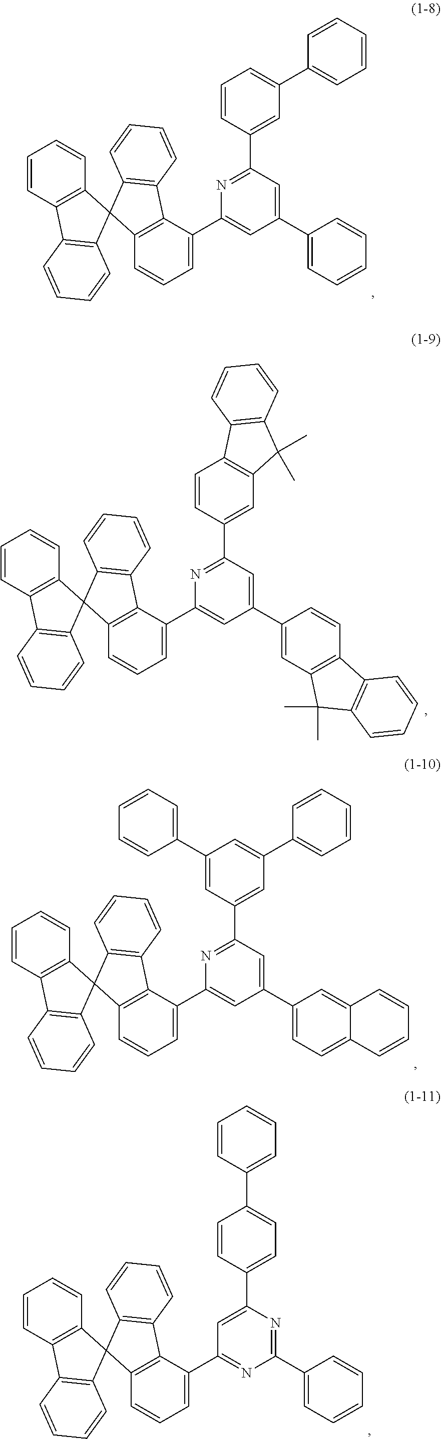

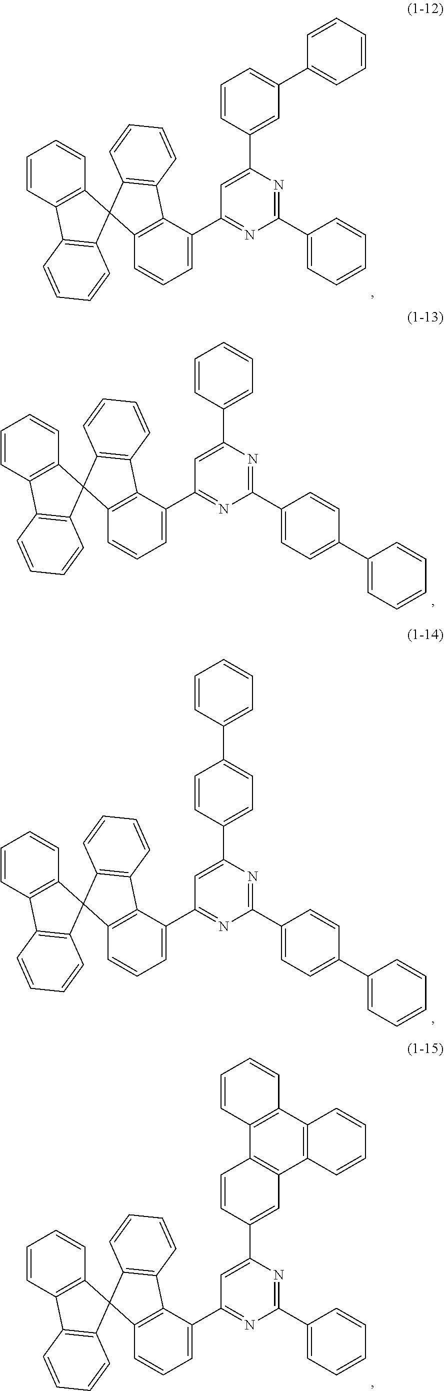

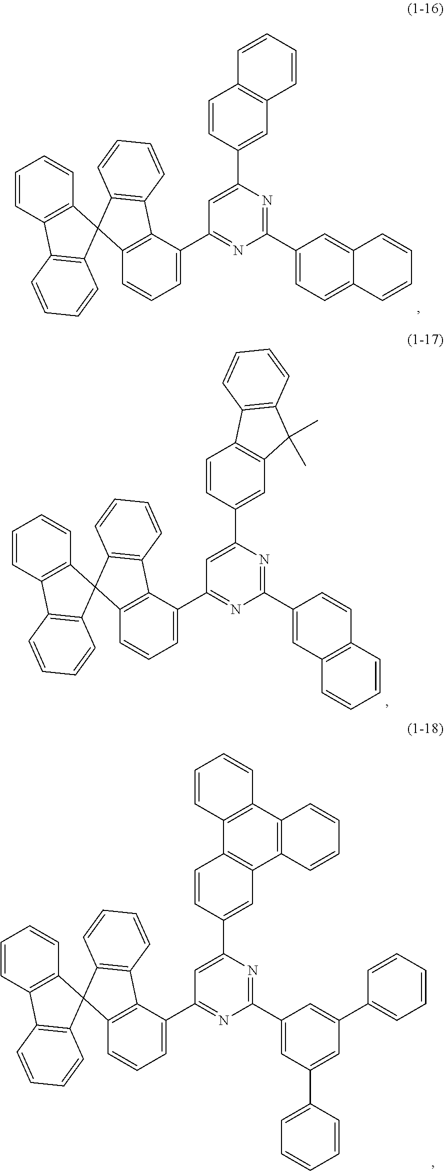

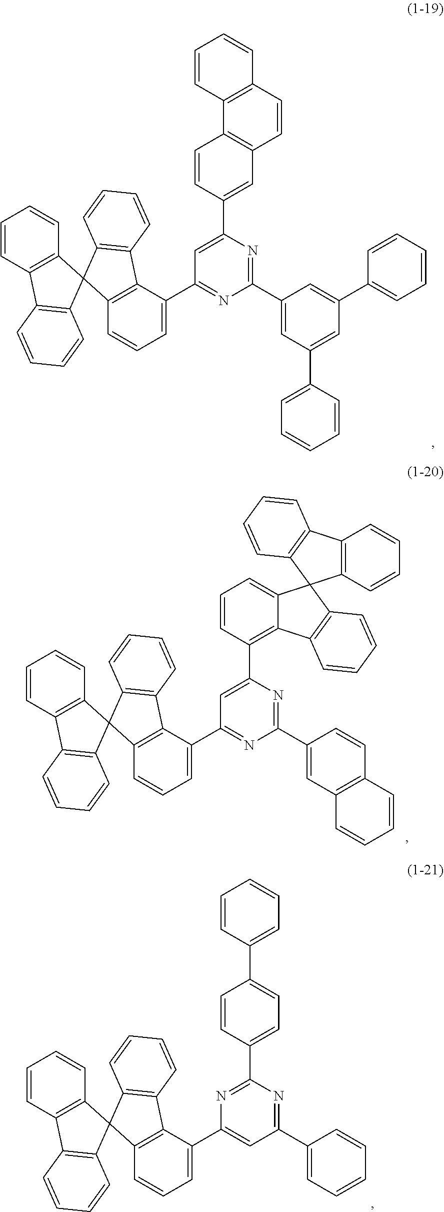

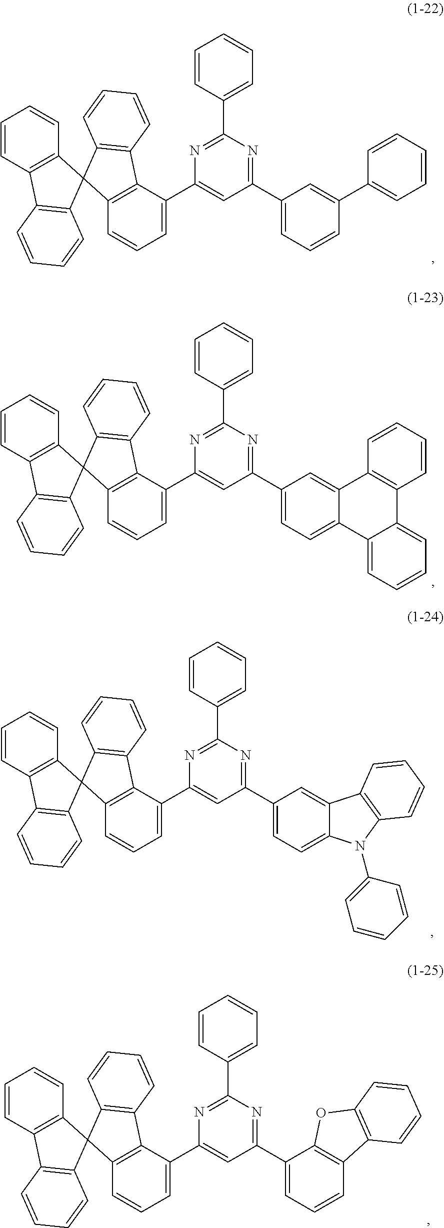

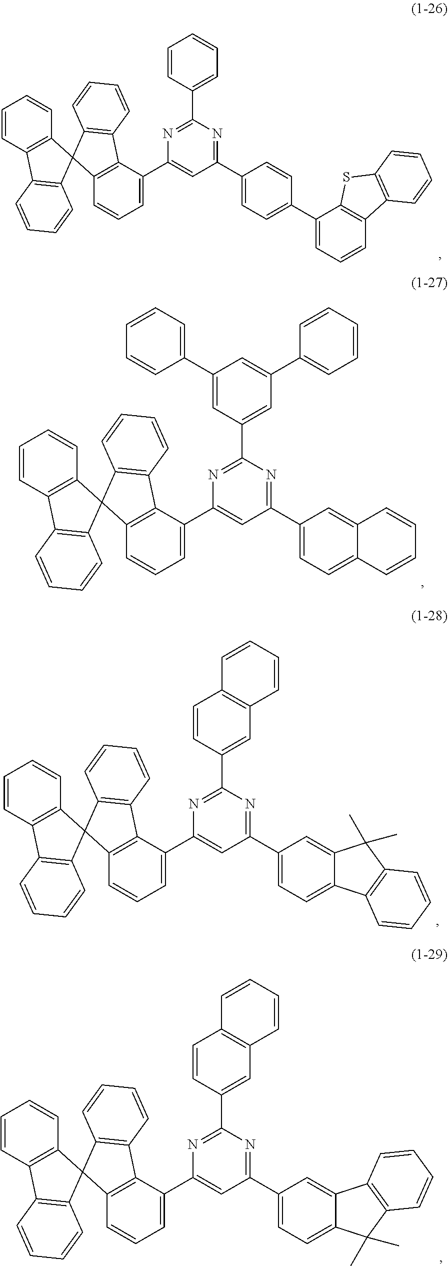

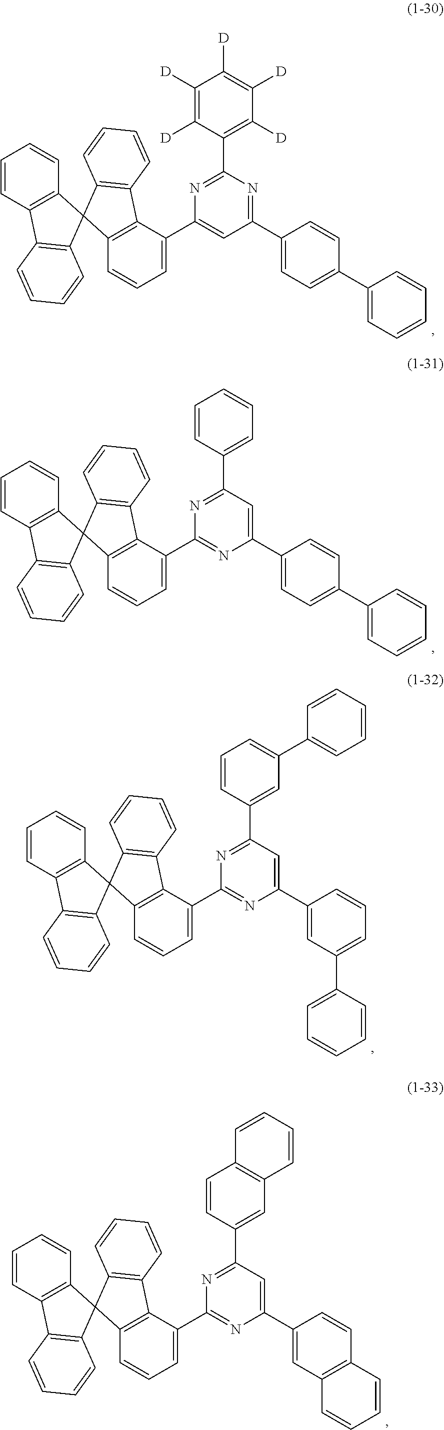

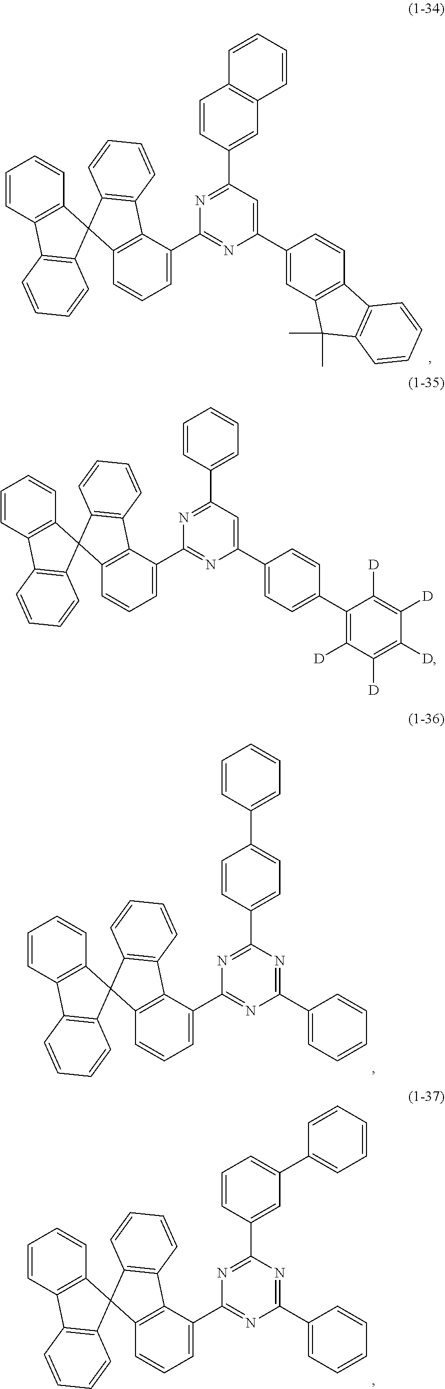

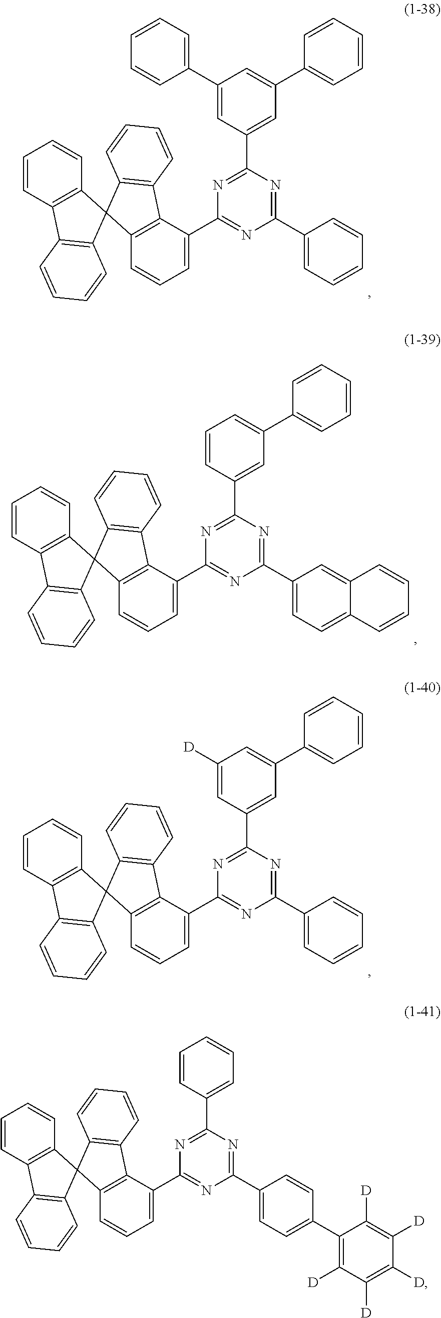

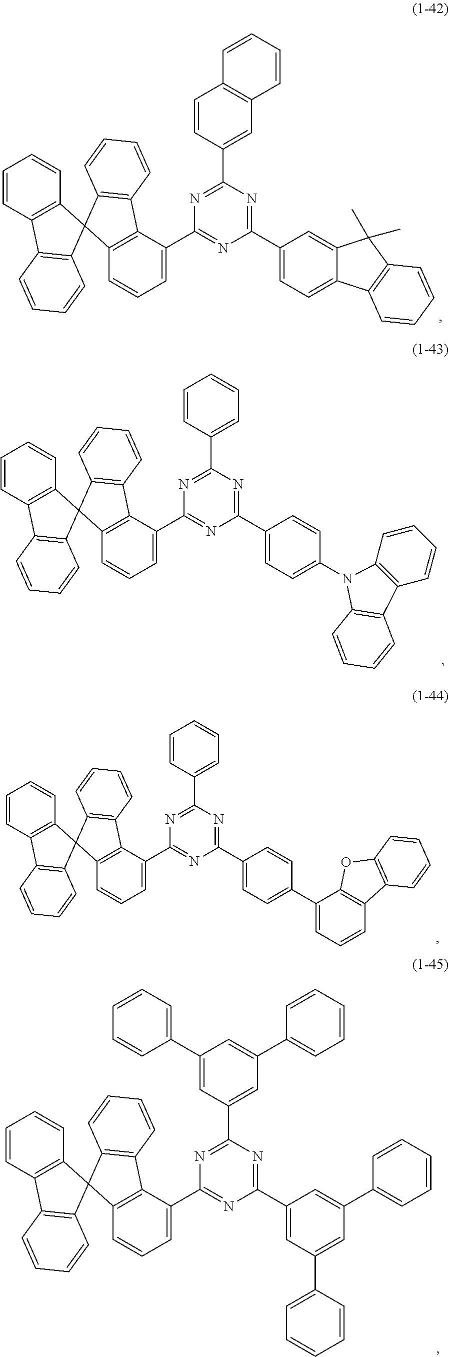

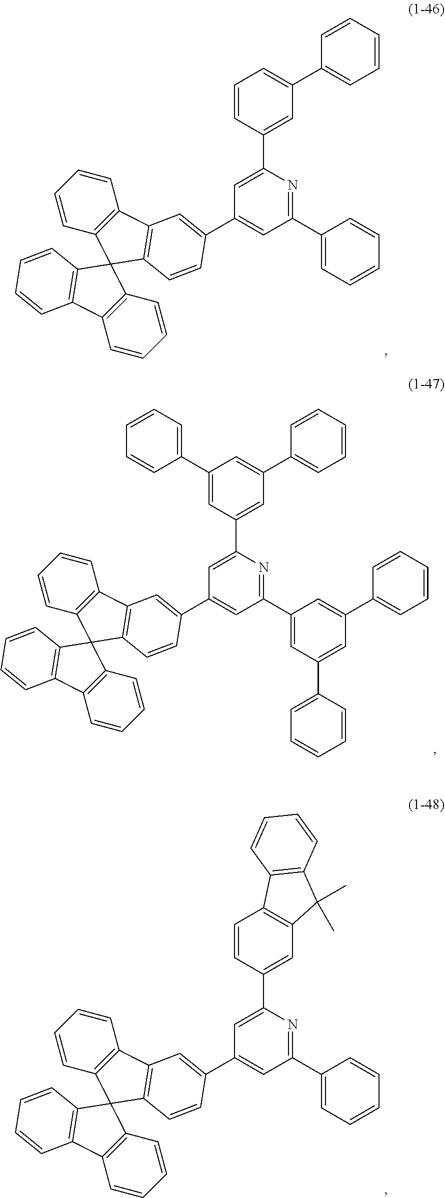

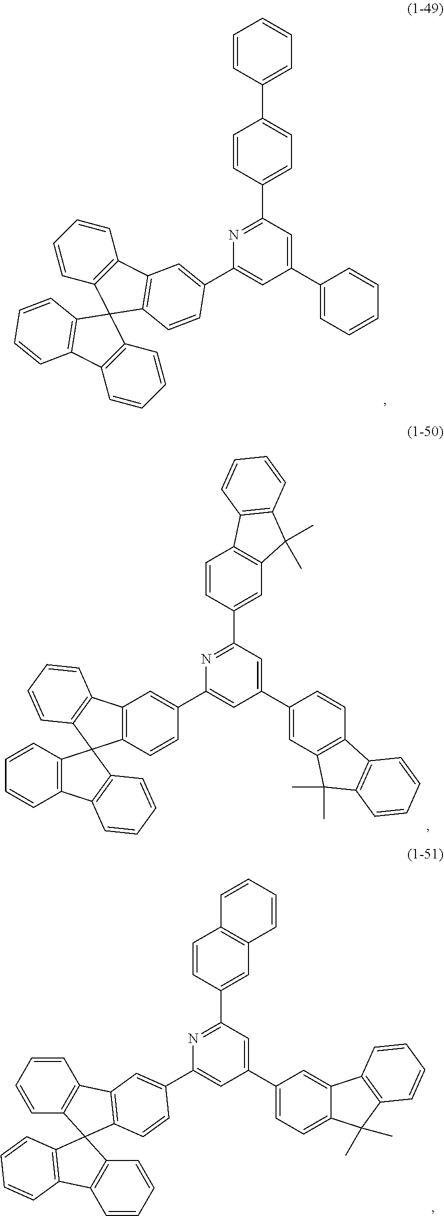

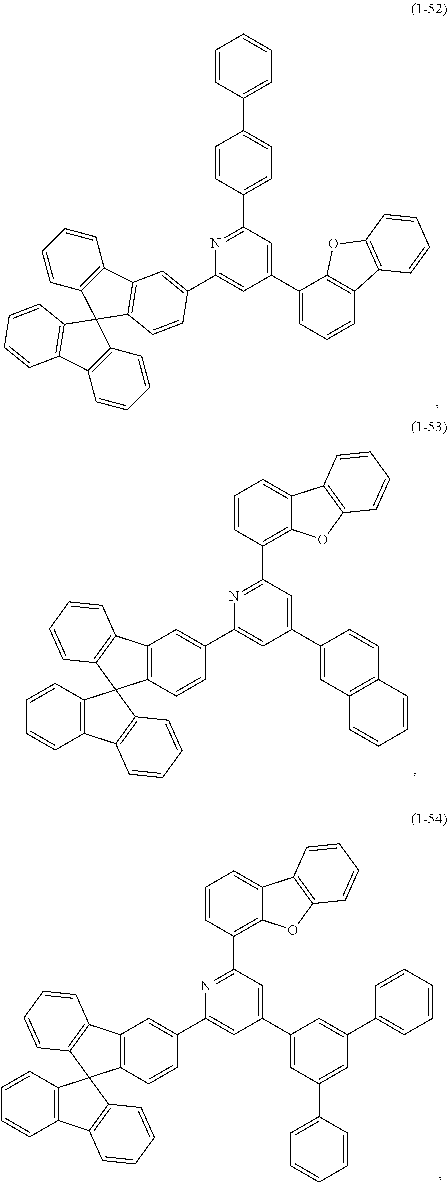

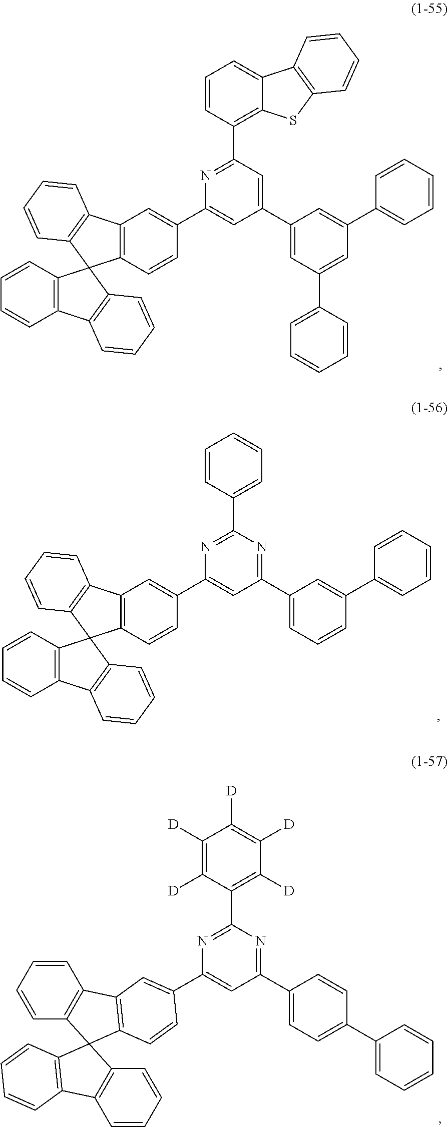

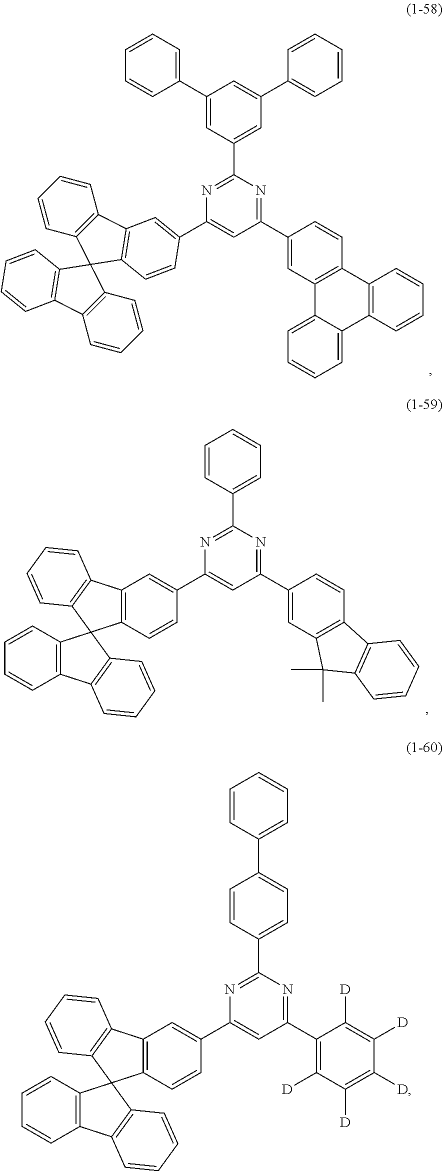

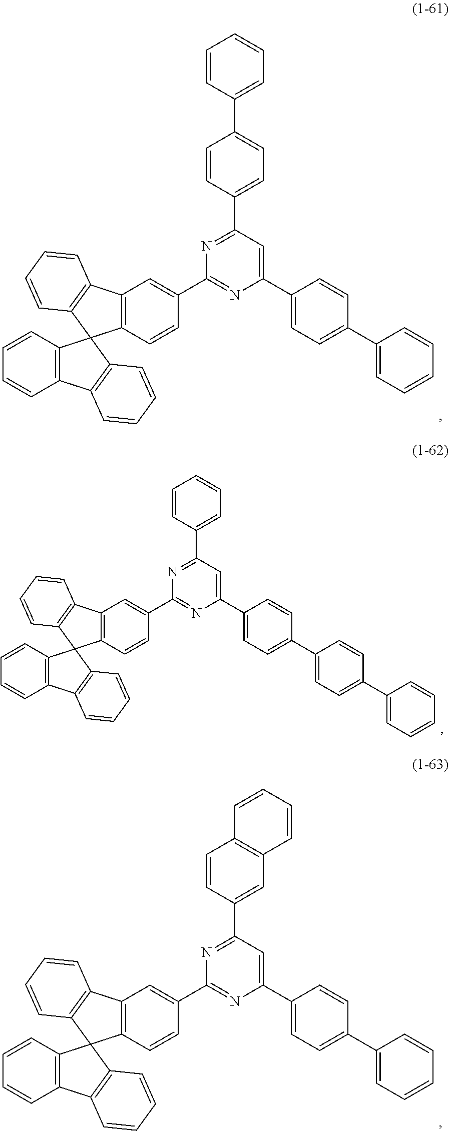

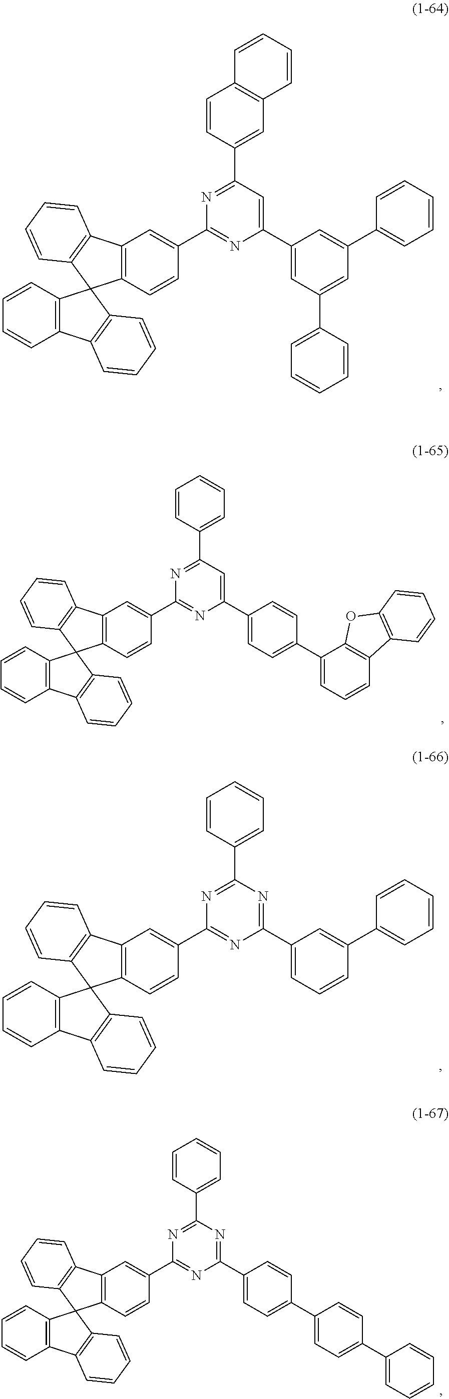

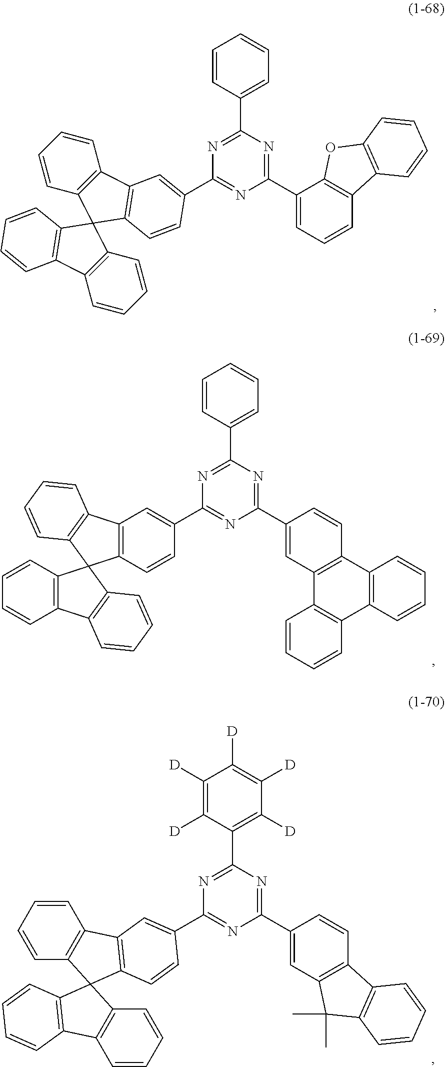

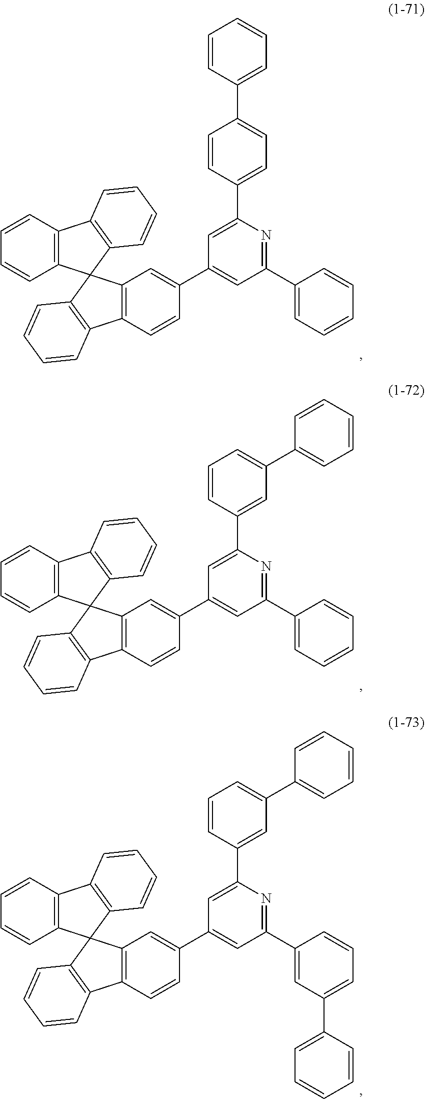

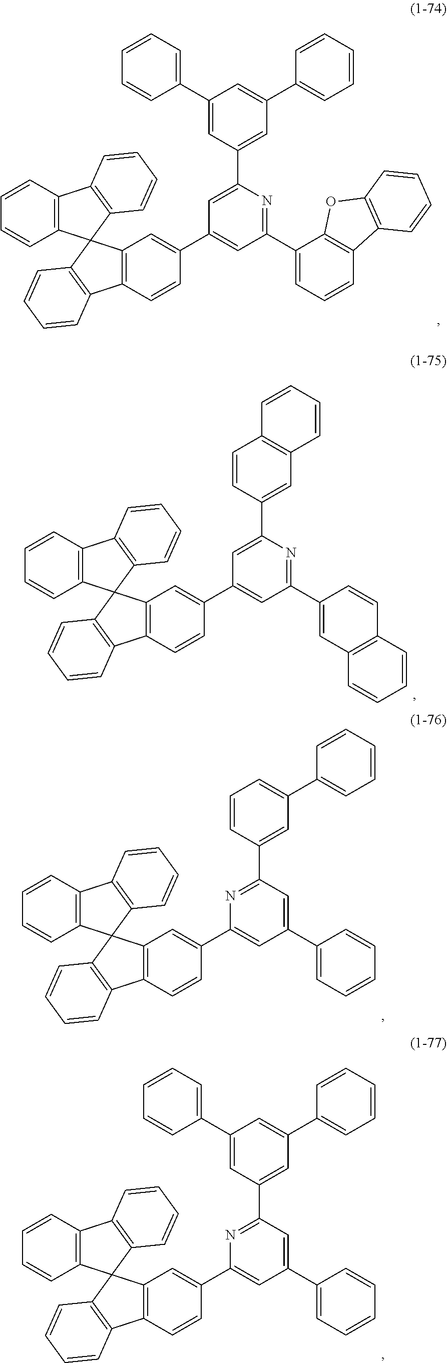

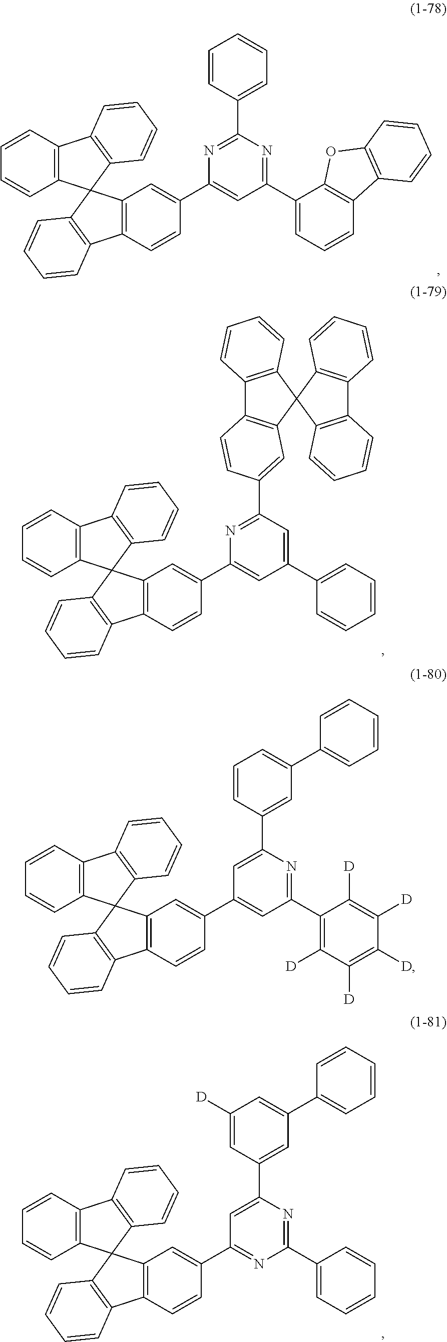

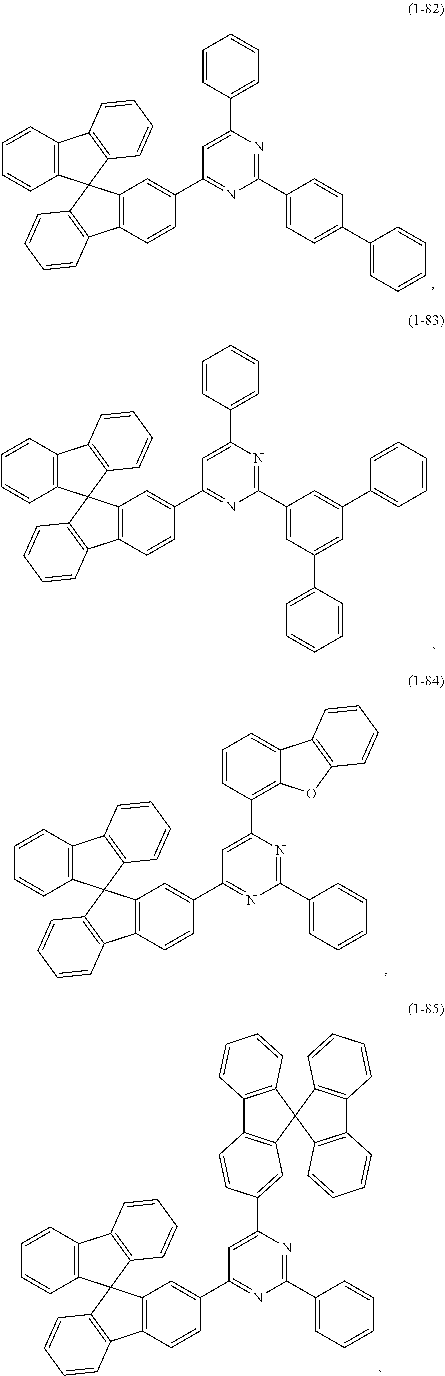

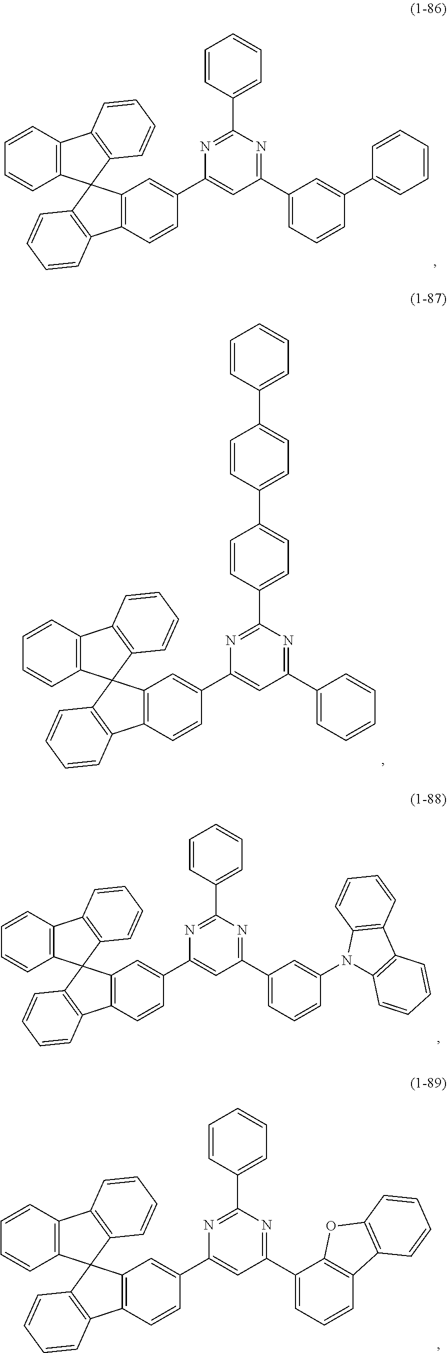

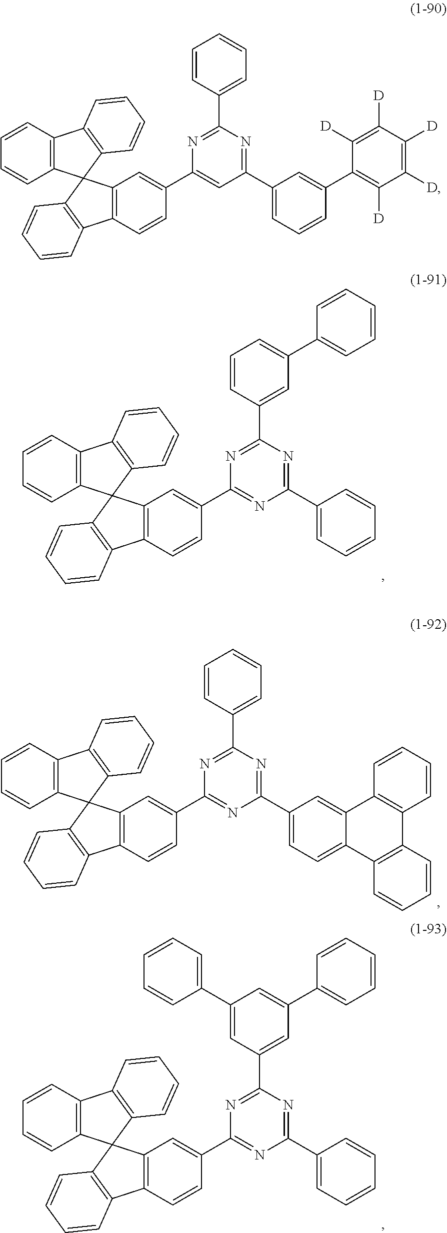

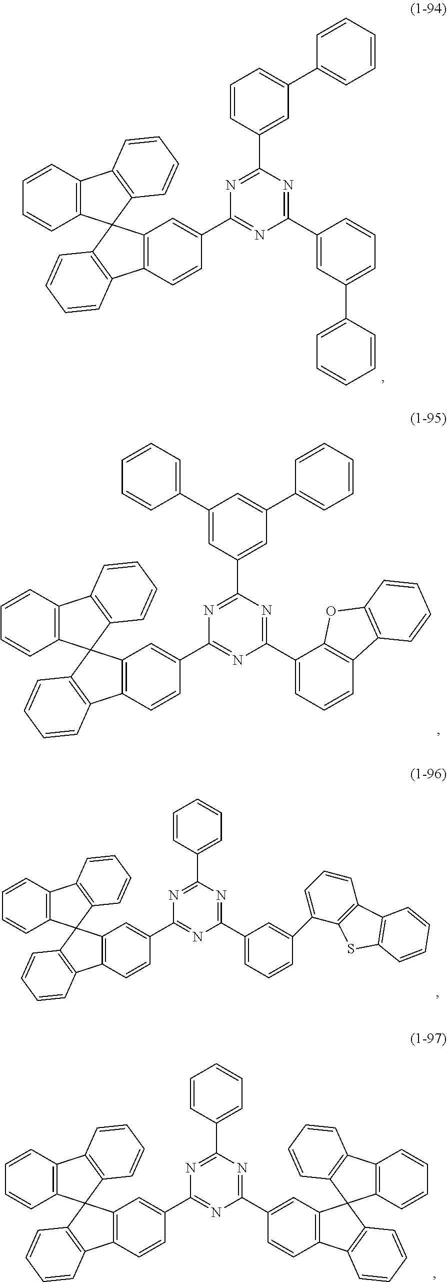

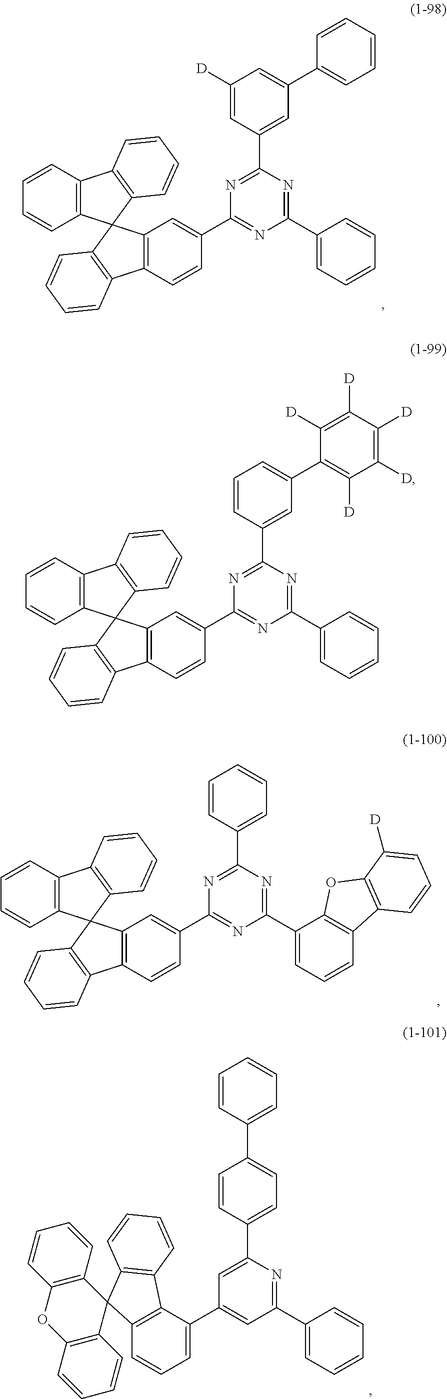

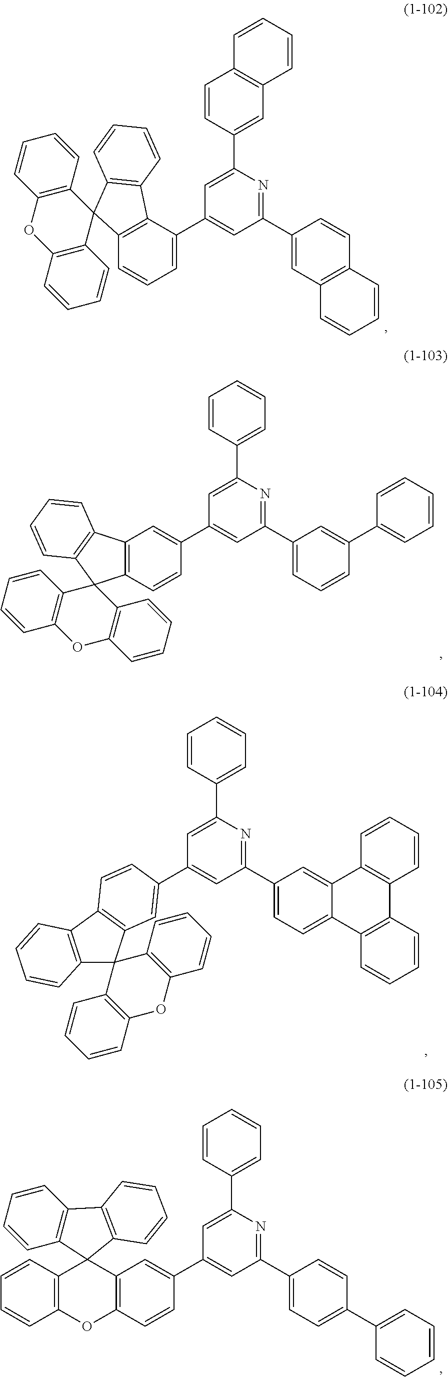

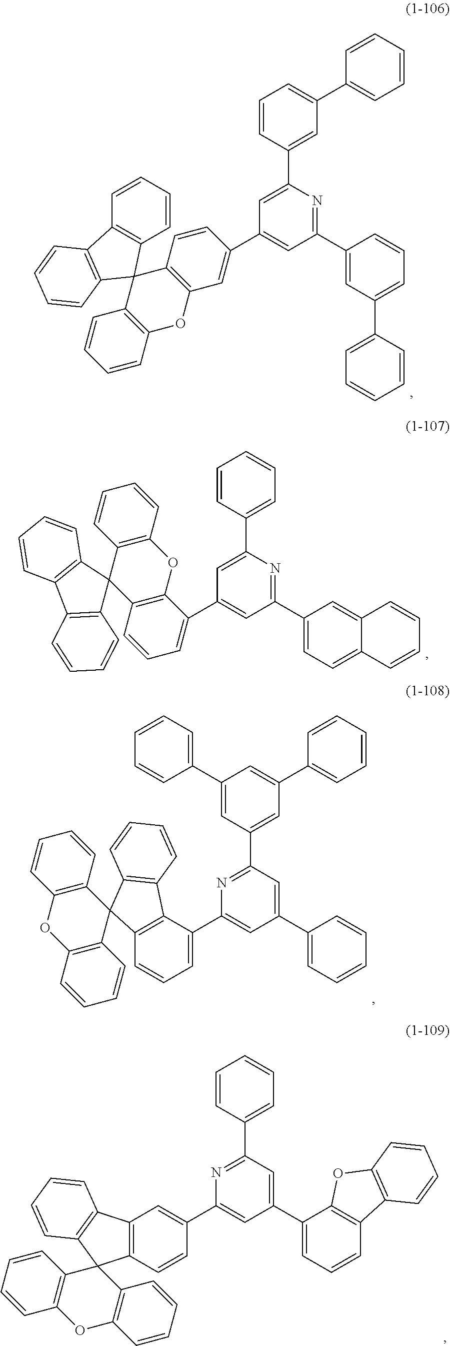

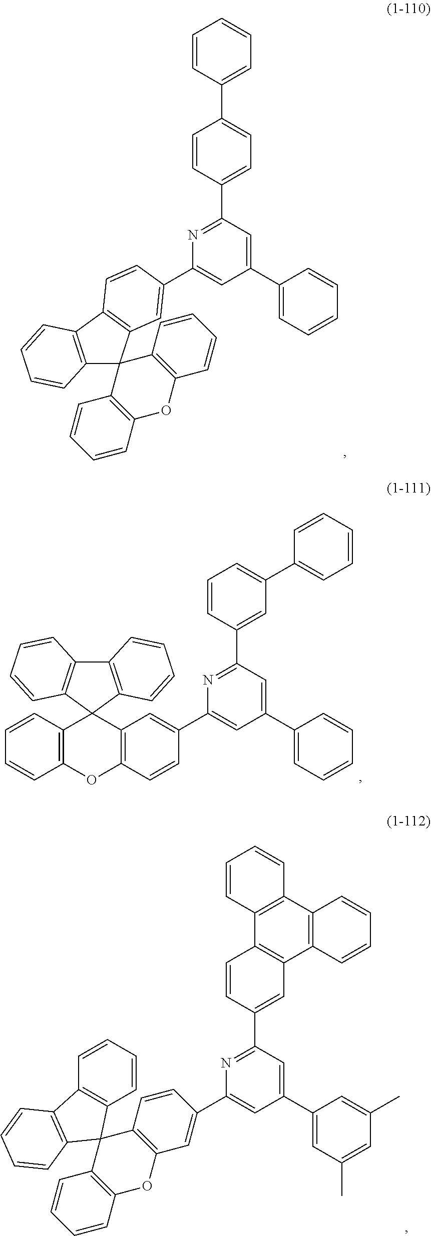

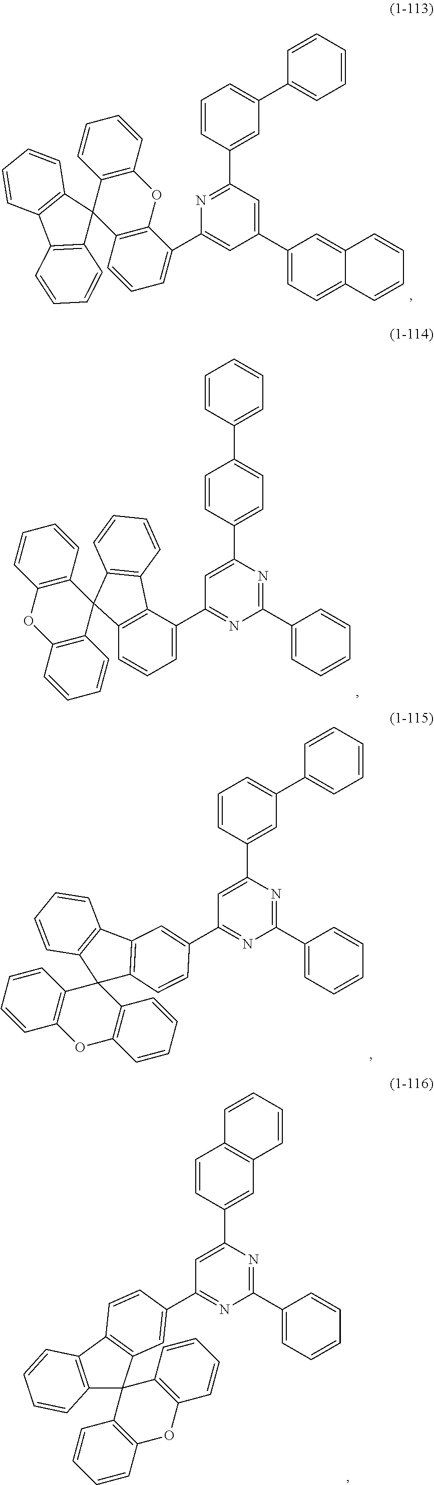

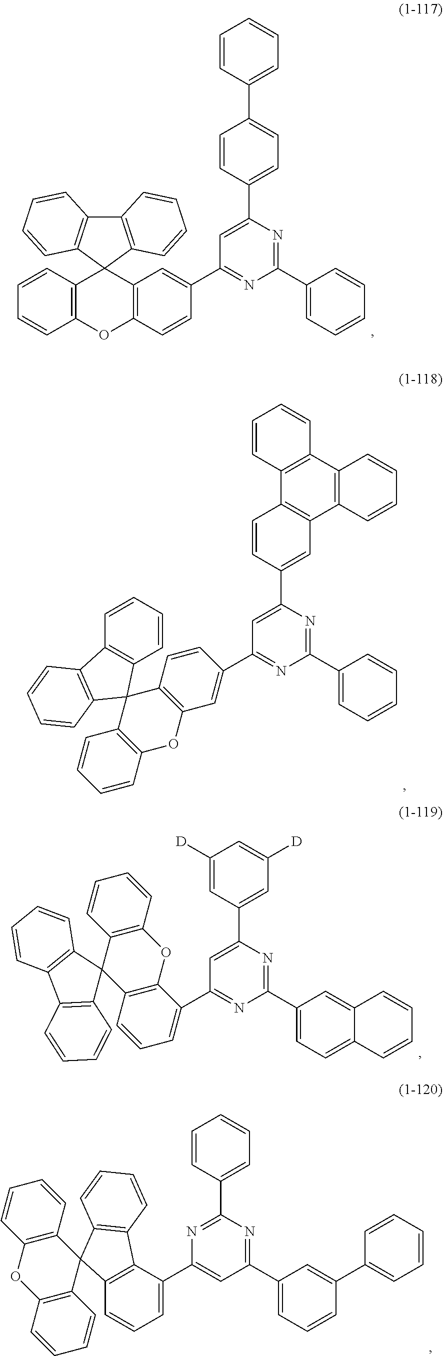

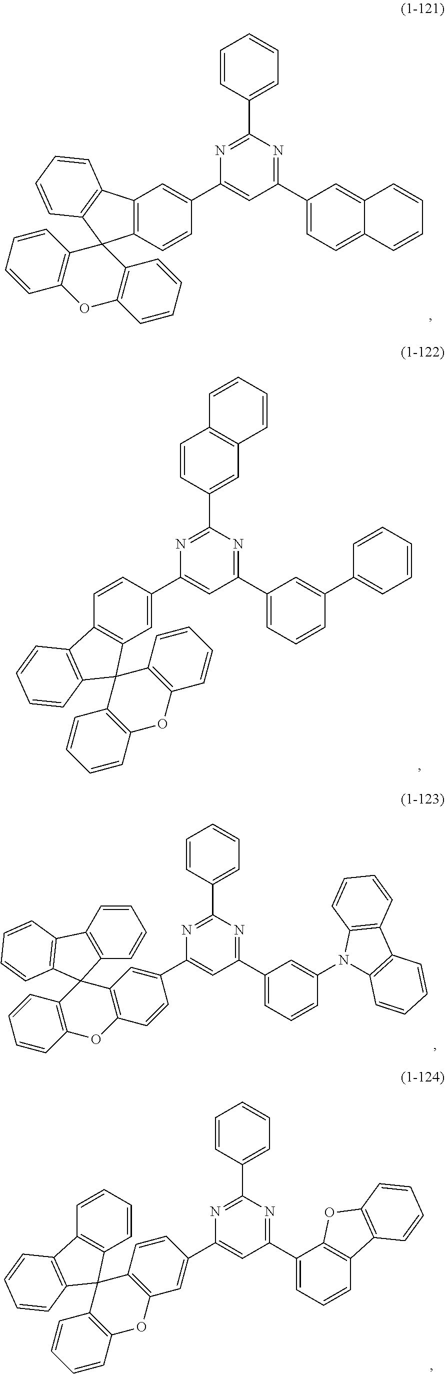

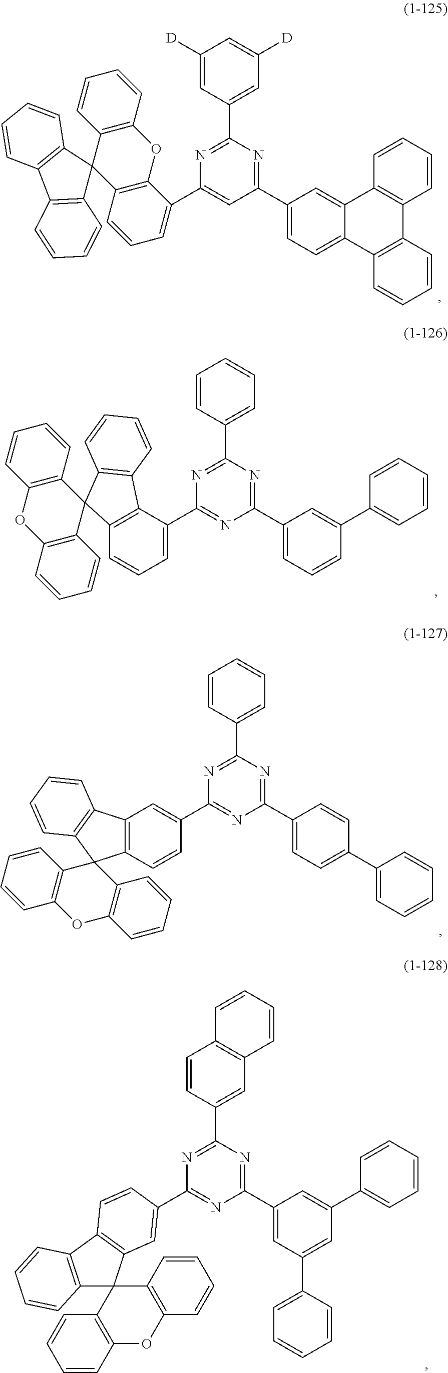

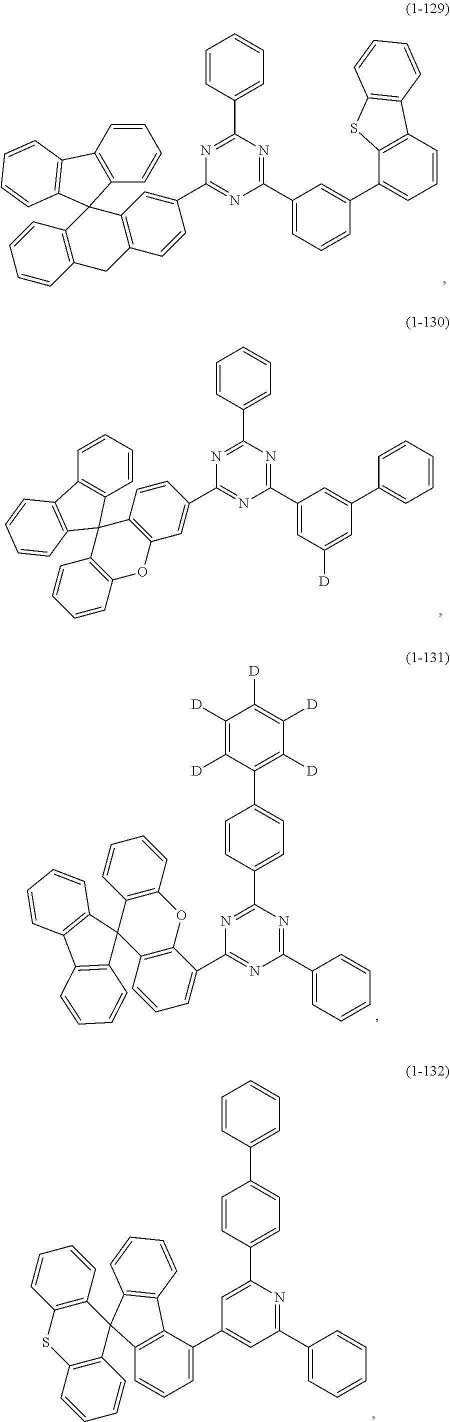

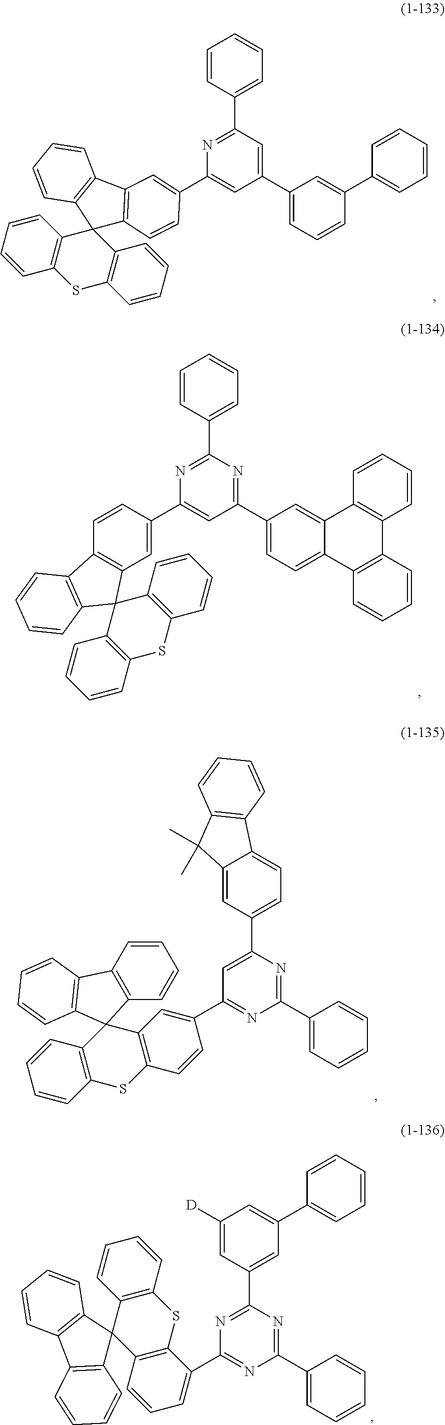

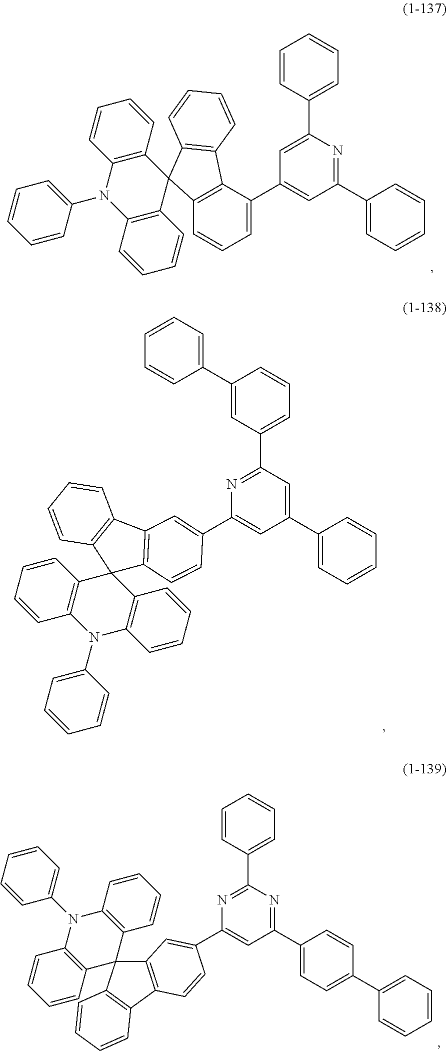

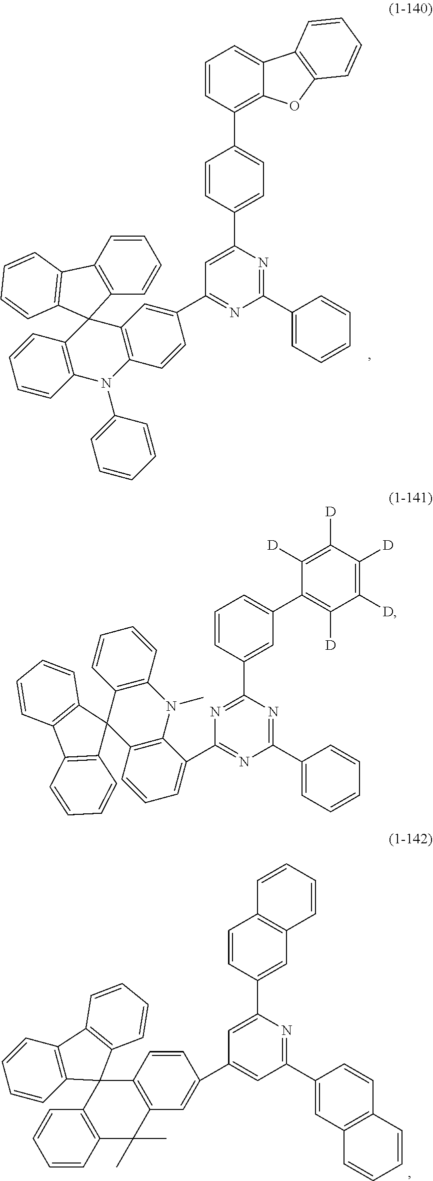

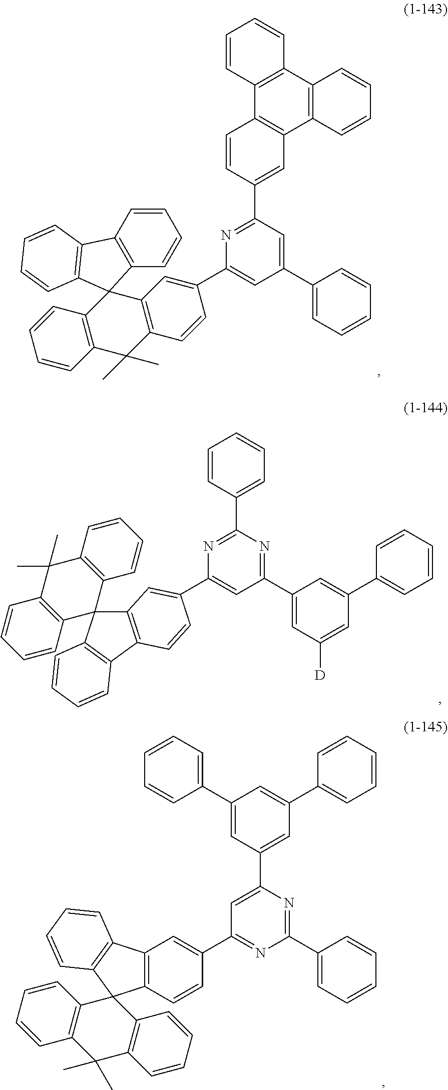

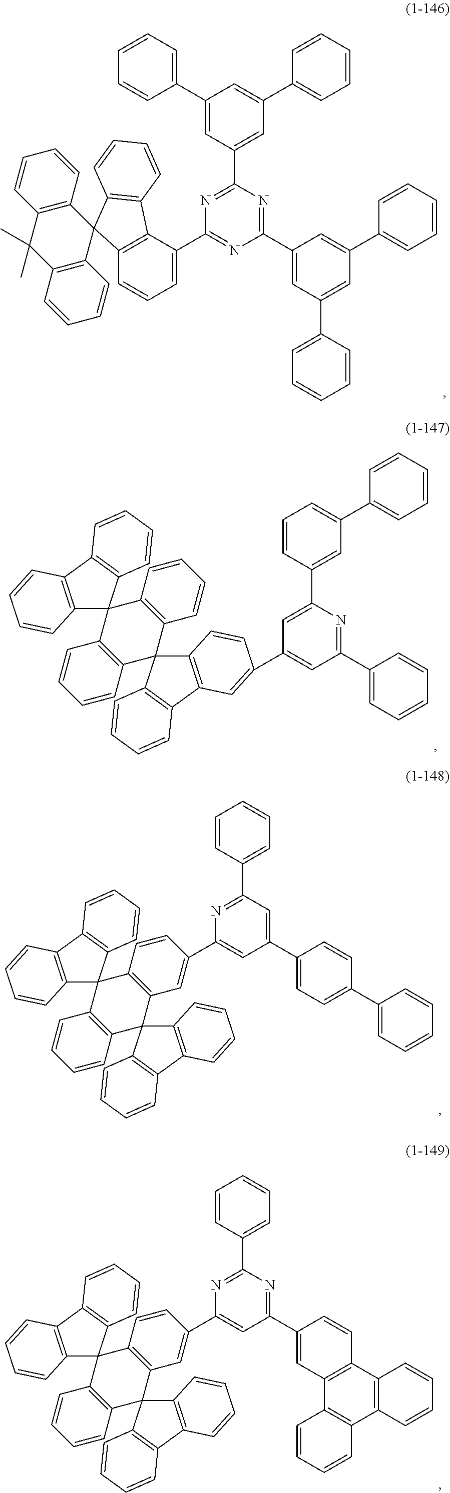

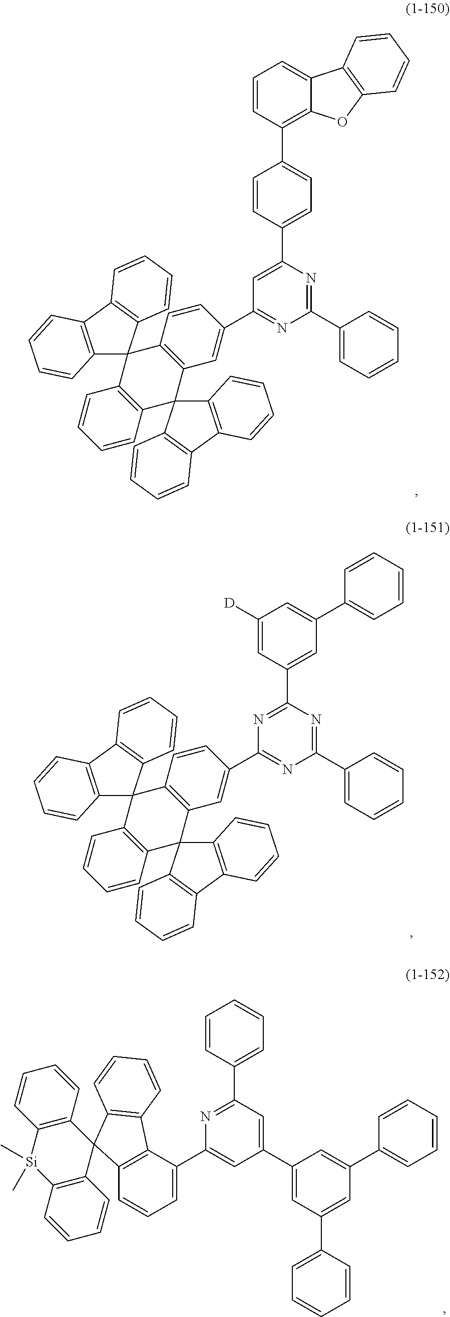

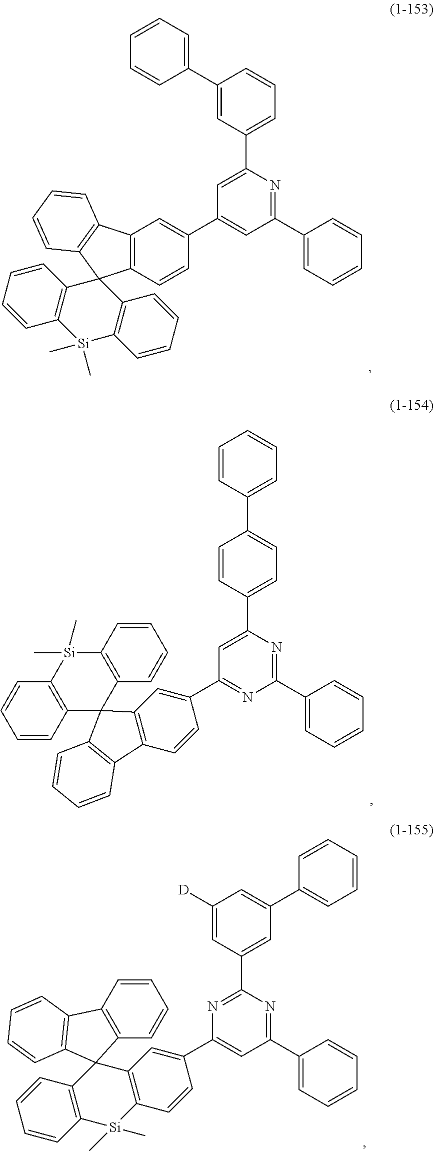

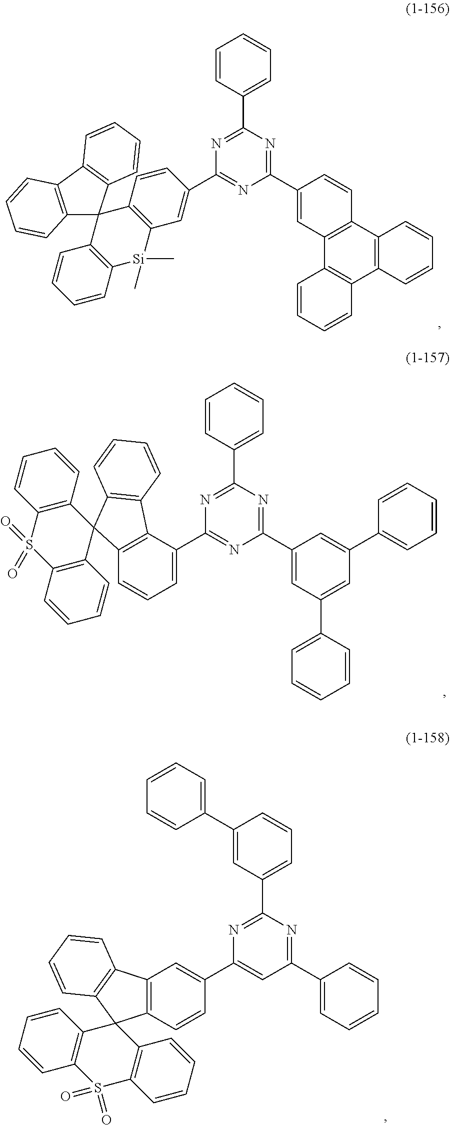

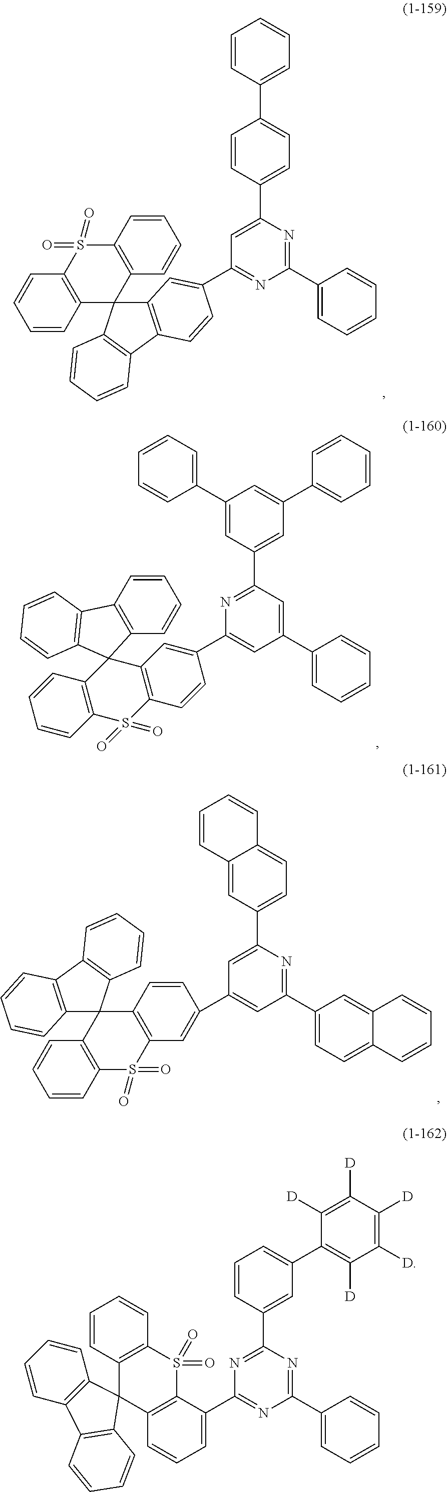

In an embodiment, the organic compound H2 is a compound represented by one of the following general formulas (2) to (5):

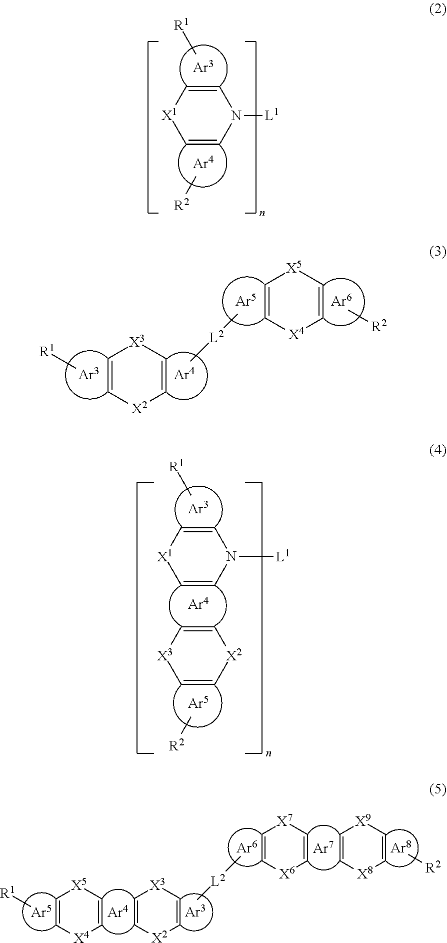

wherein, L¹ is selected from an aromatic group with a ring atom number of 5 to 60 or a heteroaromatic group with a ring atom number of 5 to 60;

L² is selected from a single bond, or an aromatic group with a ring atom number of 5 to 30 or a heteroaromatic group with a ring atom number of 5 to 30, and L² is coupled to any one of the carbon atoms on the ring;

Ar³, Ar⁴, Ar⁵, Ar⁶, Ar⁷ and Ar⁸ are independently selected from an aromatic group with a ring atom number of 5 to 30 or a heteroaromatic group with a ring atom number of 5 to 30;

X¹ is selected from a signal bond, N(R), C(R)₂, Si(R)₂, O, C═N(R), C═C(R)₂, P(R), P(═O)R, S, S═O or SO₂;

X², X³, X⁴, X⁵, X⁶, X⁷, X⁸ and X⁹ are independently selected from a signal bond, N(R), C(R)₂, Si(R)₂, O, C═N(R), C═C(R)₂, P(R), P(═O)R, S, S═O or SO₂, but X² and X³ are not single bonds simultaneously, X⁴ and X⁵ are not single bonds simultaneously, X⁶ and X⁷ are not single bonds simultaneously, and X⁸ and X⁹ are not single bonds simultaneously;

R¹, R², and R are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring;

n is selected from 1, 2, 3 or 4.

It should be noted that the aromatic group or the heteroaromatic group is as described above and will not be described herein.

In an embodiment, L¹ is selected from an aromatic group with a ring atom number of 5 to 50 or a heteroaromatic group with a ring atom number of 5 to 50. Further, L¹ is selected from an aromatic group with a ring atom number of 5 to 40 or a heteroaromatic group with a ring atom number of 5 to 40. Still further, L¹ is selected from an aromatic group with a ring atom number of 6 to 30 or a heteroaromatic group with a ring atom number of 6 to 30.

In an embodiment, L² is selected from a single bond, an aromatic group with a ring atom number of 5 to 25 or a heteroaromatic group with a ring atom number of 5 to 25. Further, L² is selected from a single bond, an aromatic group with a ring atom number of 5 to 20 or a heteroaromatic group with a ring atom number of 5 to 20. Still further, L² is selected from a single bond, an aromatic group with a ring atom number of 5 to 15 or a heteroaromatic group with a ring atom number of 5 to 15.

In an embodiment, Ar³, Ar⁴, Ar⁵, Ar⁶, Ar⁷ and Ar⁸ are independently selected from an aromatic group with a ring atom number of 5 to 25 or a heteroaromatic group with a ring atom number of 5 to 25. Further, Ar³, Ar⁴, Ar⁵, Ar⁶, Ar⁷ and Ar⁸ are independently selected from an aromatic group with a ring atom number of 5 to 20 or a heteroaromatic group with a ring atom number of 5 to 20. Still further, Ar³, Ar⁴, Ar⁵, Ar⁶, Ar⁷ and Ar⁸ are independently selected from an aromatic group with a ring atom number of 5 to 15 or a heteroaromatic group with a ring atom number of 5 to 15.

In an embodiment, X¹ is selected from a single bond, N(R), C(R)₂, O or S.

In an embodiment, X², X³, X⁴, X⁵, X⁶, X⁷, X⁸ and X⁹ are independently selected from a signal bond, N(R), C(R)₂, O or S.

In an embodiment, n is selected from 1, 2 or 3, and further, n is selected from 1 or 2.

In an embodiment, the electron-donating group contained in the organic compound H2 is selected from one or more of the following:

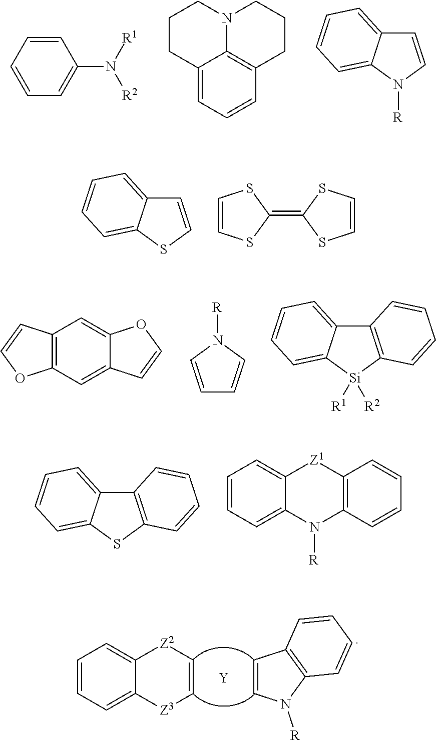

In an embodiment, Ar³, Ar⁴, Ar⁵, Ar⁶, Ar⁷ and Ar⁸ independently comprise one or more of the following structural groups:

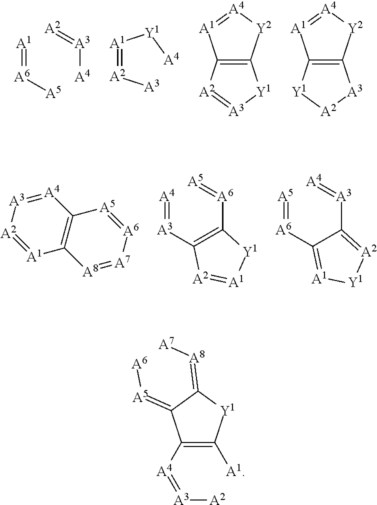

wherein, A¹, A², A³, A⁴, A⁵, A⁶, A⁷ and A⁸ are independently selected from CR³ or N;

Y¹ and Y² are independently selected from CR⁴R⁵, SiR⁴R⁵, NR³, C(═O), S or O;

R³, R⁴ and R⁵ are independently selected from the group consisting of H, D, a linear alkyl containing 1 to 20 C atoms, an linear alkoxy containing 1 to 20 C atoms, a linear thioalkoxy containing 1 to 20 C atoms, a branched or cyclic alkyl group containing 3 to 20 C atoms, a branched or cyclic alkoxy group containing 3 to 20 C atoms, a branched or cyclic thioalkoxy group containing 3 to 20 C atoms, a branched or cyclic silyl group containing 3 to 20 C atoms, a substituted ketone group containing 1 to 20 C atoms, an alkoxycarbonyl group containing 2 to 20 C atoms, an aryloxycarbonyl group containing 7 to 20 C atoms, cyano group, carbamoyl group, haloformyl group, formyl group, isocyano group, isocyanate group, thiocyanate group, isothiocyanate group, hydroxyl group, nitro group, CF₃ group, Cl, Br, F, a crosslinkable group, a substituted or unsubstituted aromatic containing 5 to 40 ring atoms or heteroaromatic ring system containing 5 to 40 ring atoms, and a aryloxy containing 5 to 40 ring atoms or heteroaryloxy group containing 5 to 40 ring atoms; wherein, at least one of R³, R⁴ and R⁵ may form a monocyclic or polycyclic aliphatic or aromatic ring with the ring bonded to the groups, or at least two of R³, R⁴ and R⁵ form a monocyclic or polycyclic aliphatic or aromatic ring with each other.

In an embodiment, Ar³, Ar⁴, Ar⁵, Ar⁶, Ar⁷, Ar⁸, A¹ and A² independently comprise one of the following structural groups:

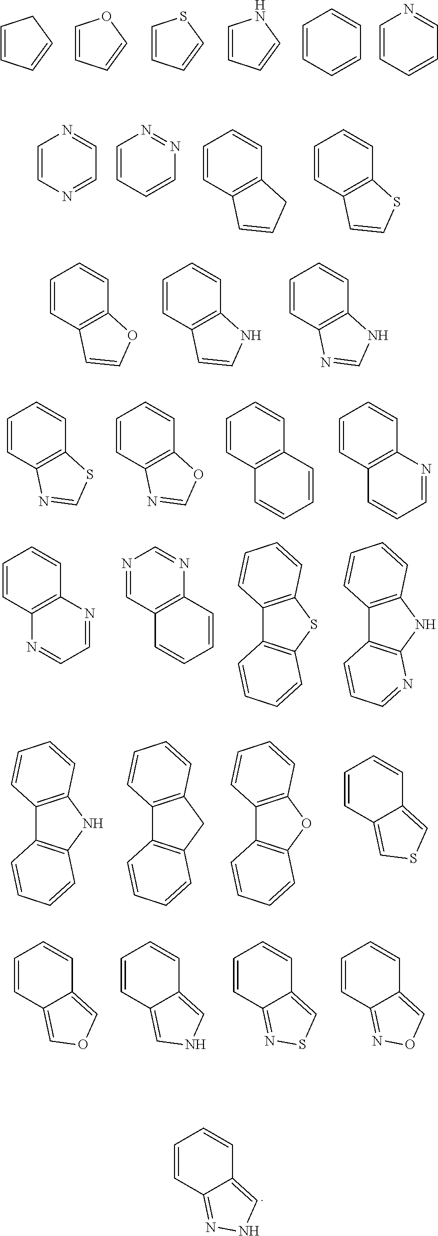

wherein, H on any ring of the above groups may be arbitrarily substituted.

In an embodiment, the compound represented by the general formula (2) is selected from one of the following structural formulas:

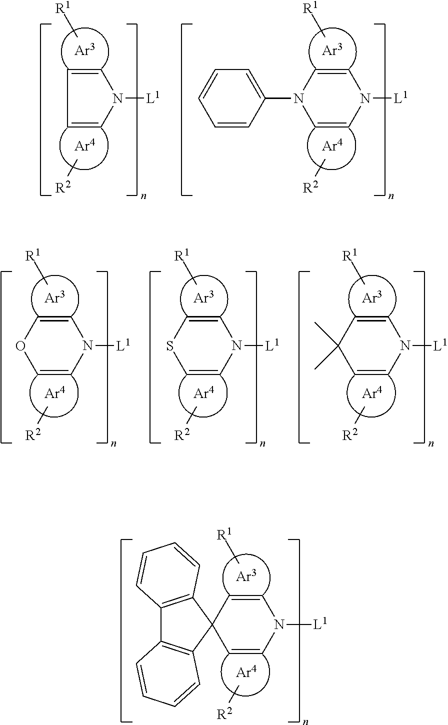

wherein, Ar³ and Ar⁴ are independently selected from an aromatic group with a ring atom number of 5 to 30 or a heteroaromatic group with a ring atom number of 5 to 30;

R¹ and R² are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring;

n is selected from 1, 2, 3 or 4;

L¹ is selected from an aromatic group with a ring atom number of 5 to 60 or a heteroaromatic group with a ring atom number of 5 to 60.

In an embodiment, the organic compound H2 has a structure represented by the general formula (6):

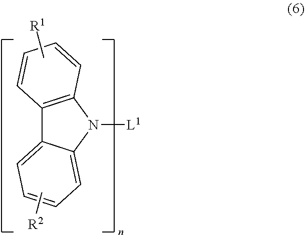

wherein, R¹ and R² are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring; n is selected from 1, 2, 3 or 4; L¹ is selected from an aromatic group with a ring atom number of 5 to 60 or a heteroaromatic group with a ring atom number of 5 to 60.

Specific examples of the compound represented by the general formula (2) are exemplified below, but not limited to:

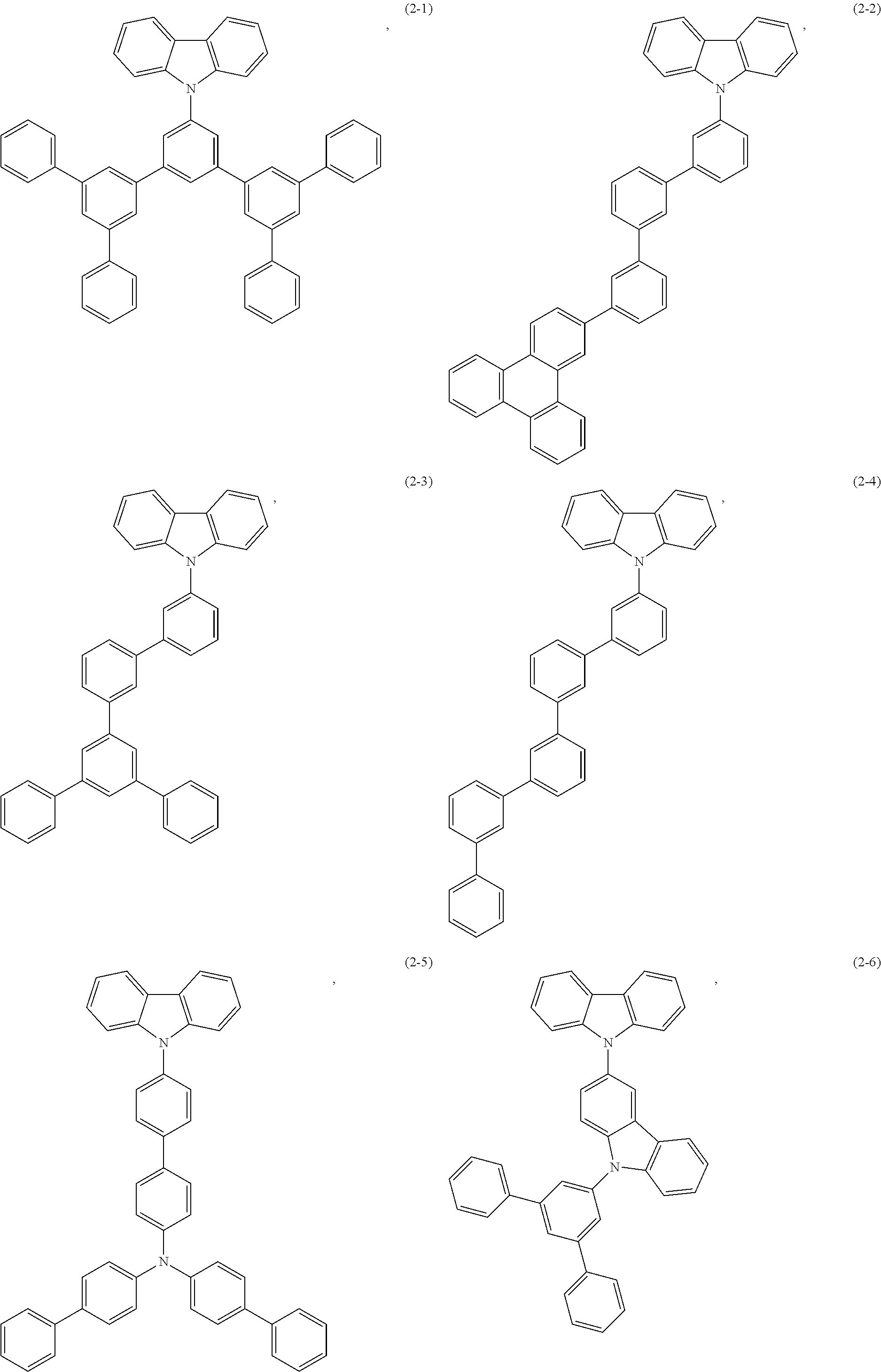

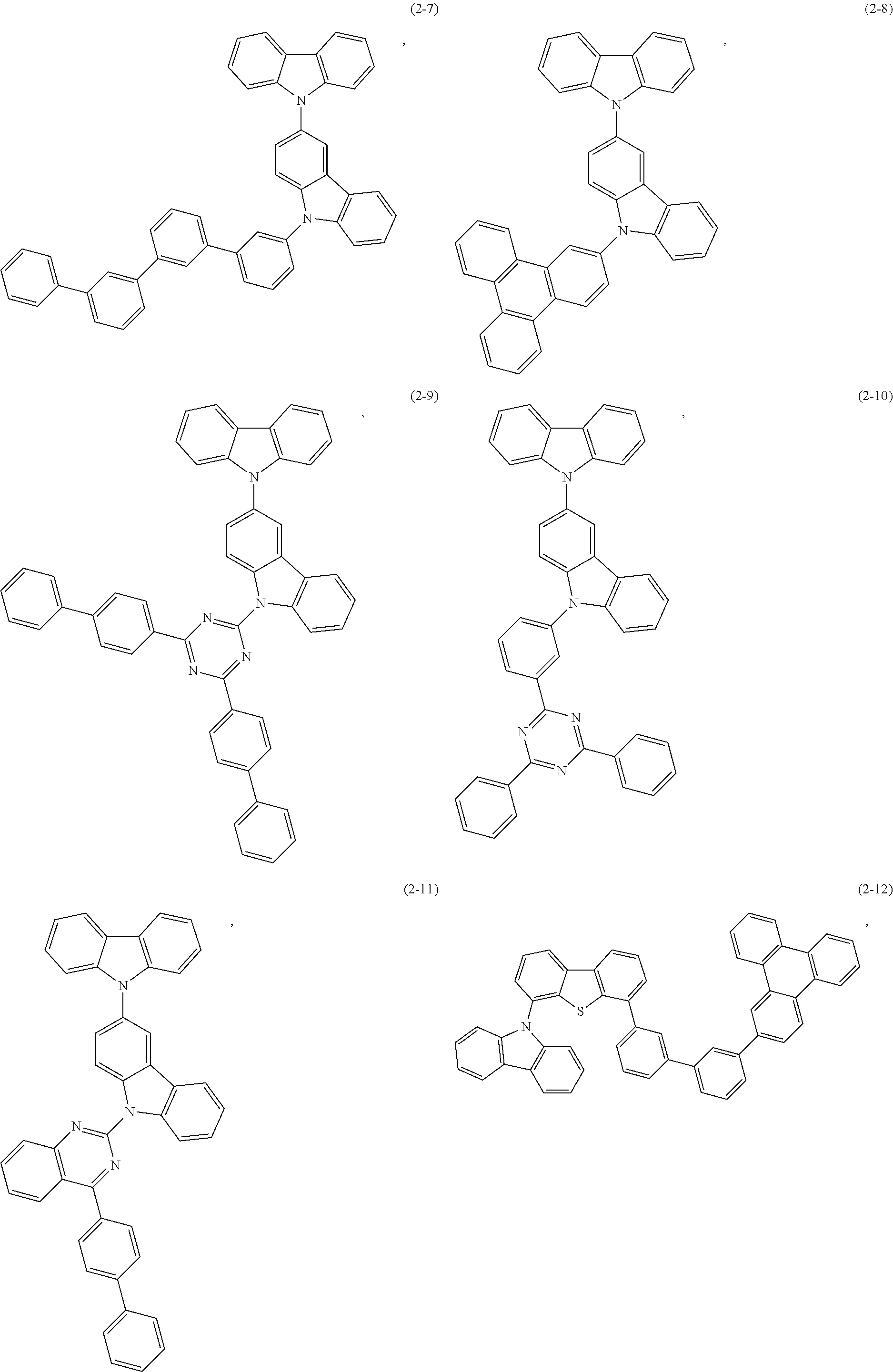

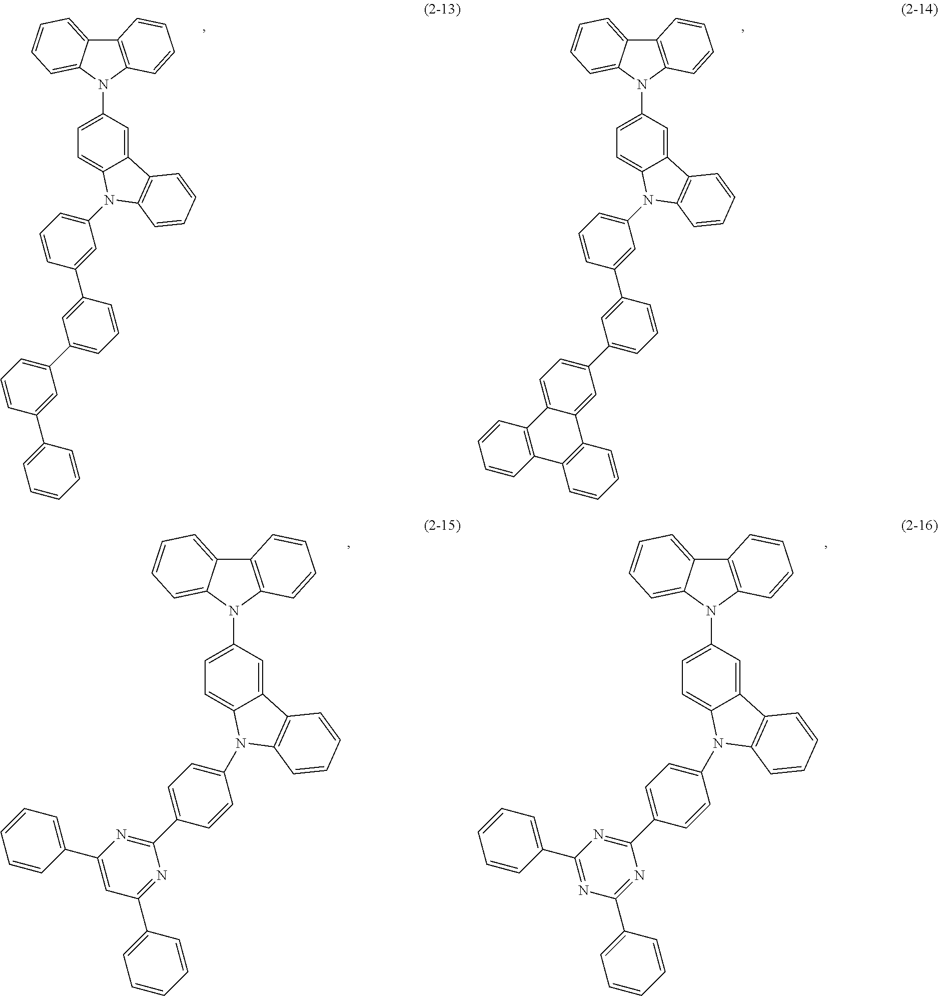

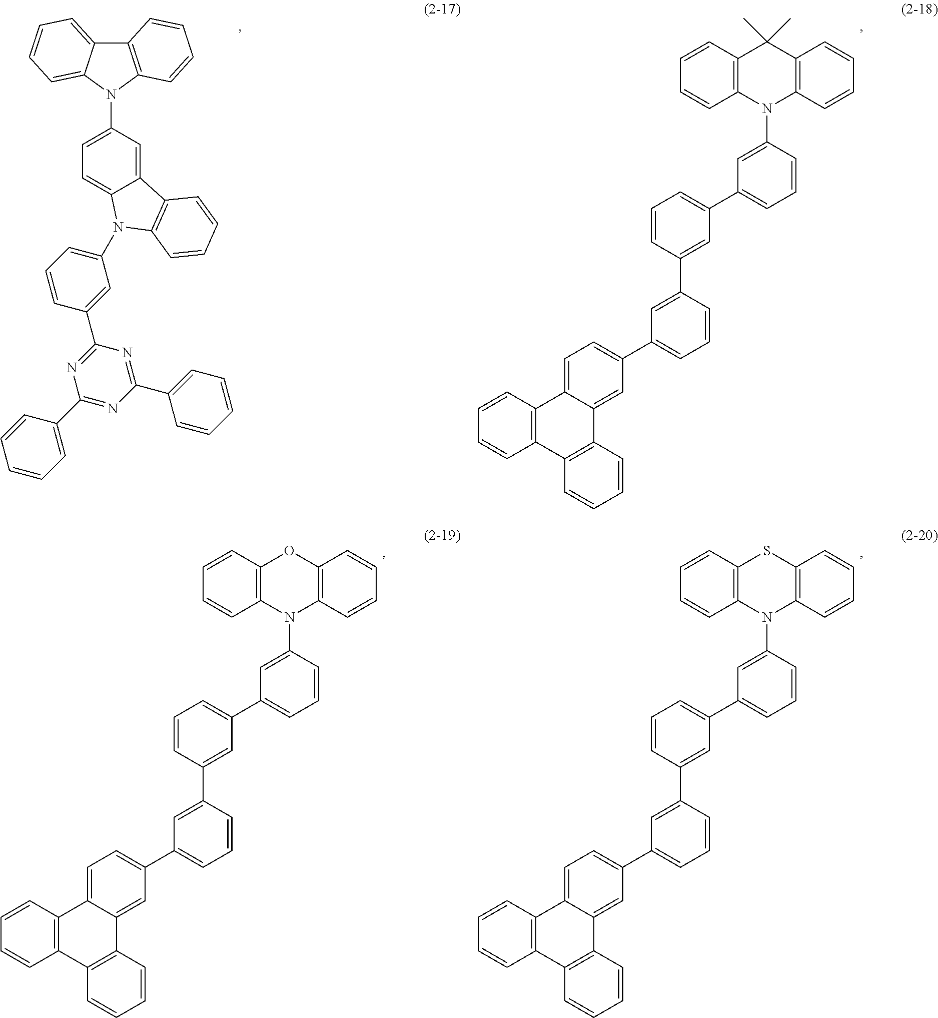

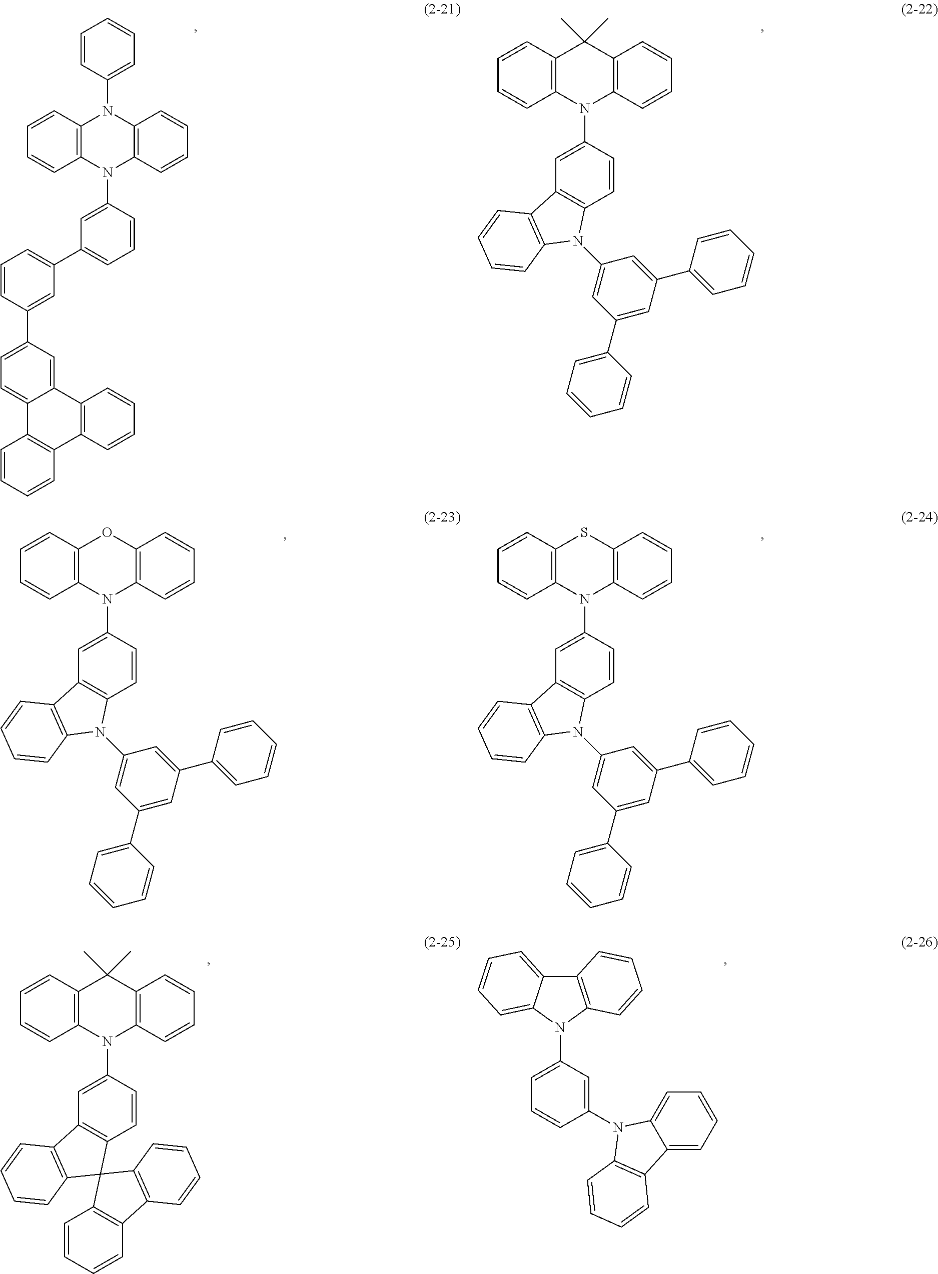

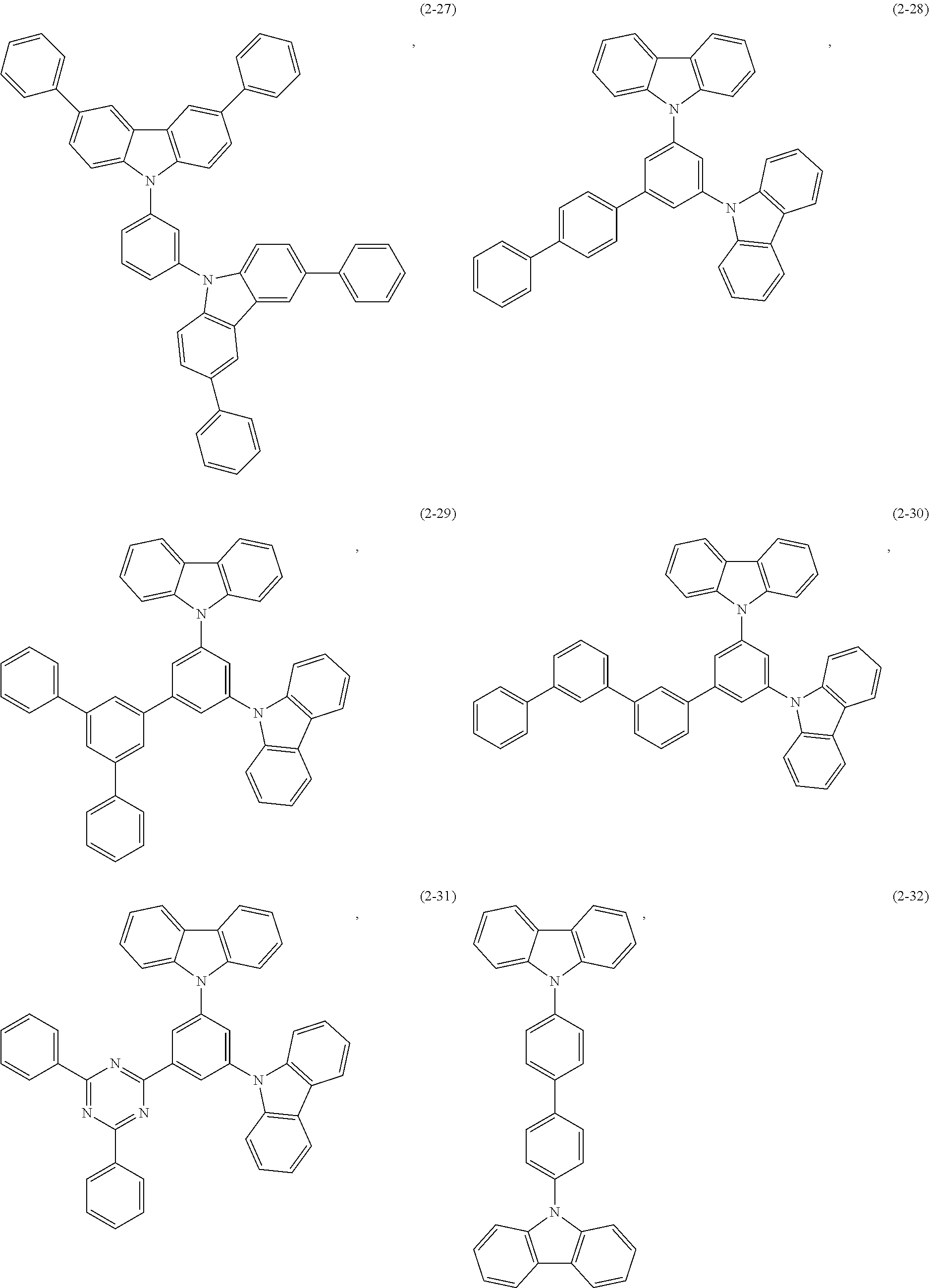

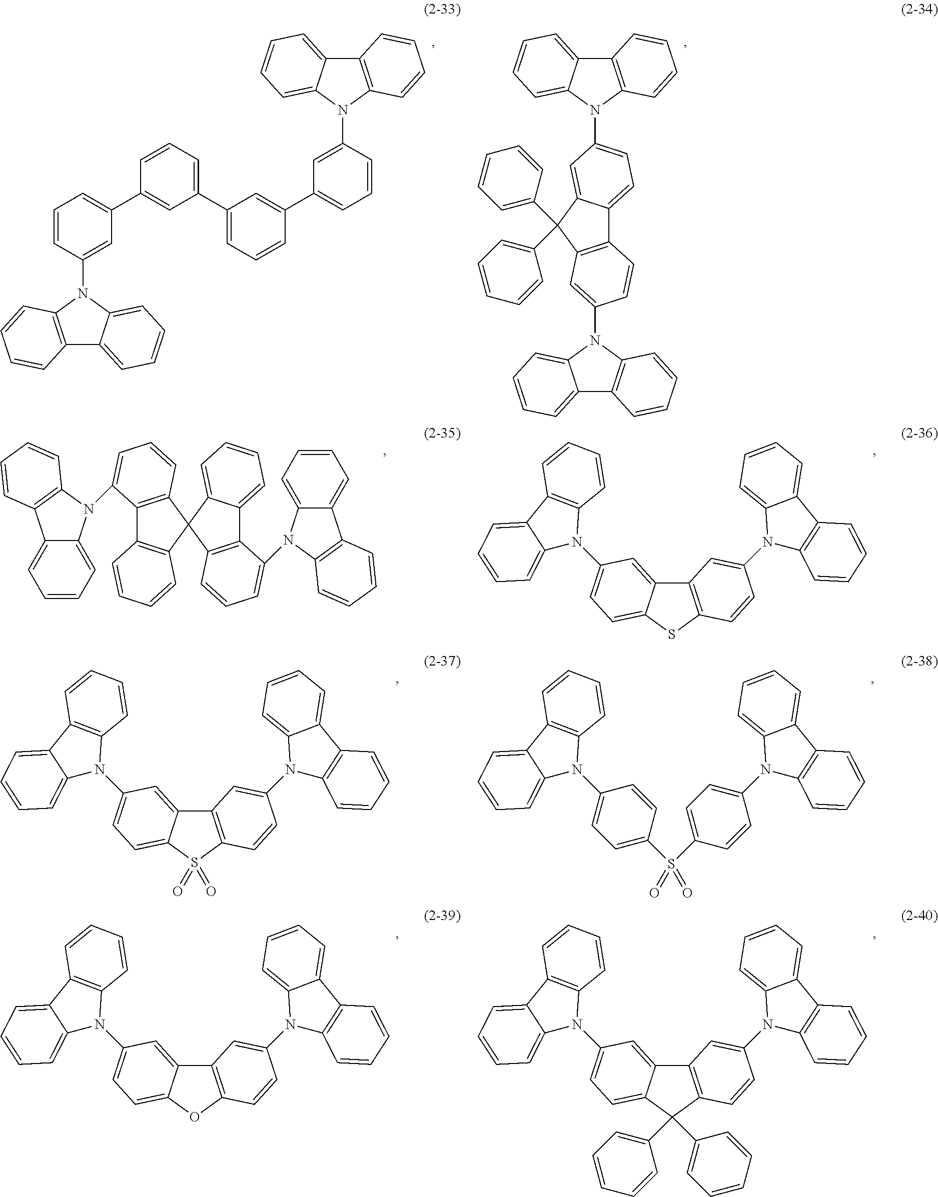

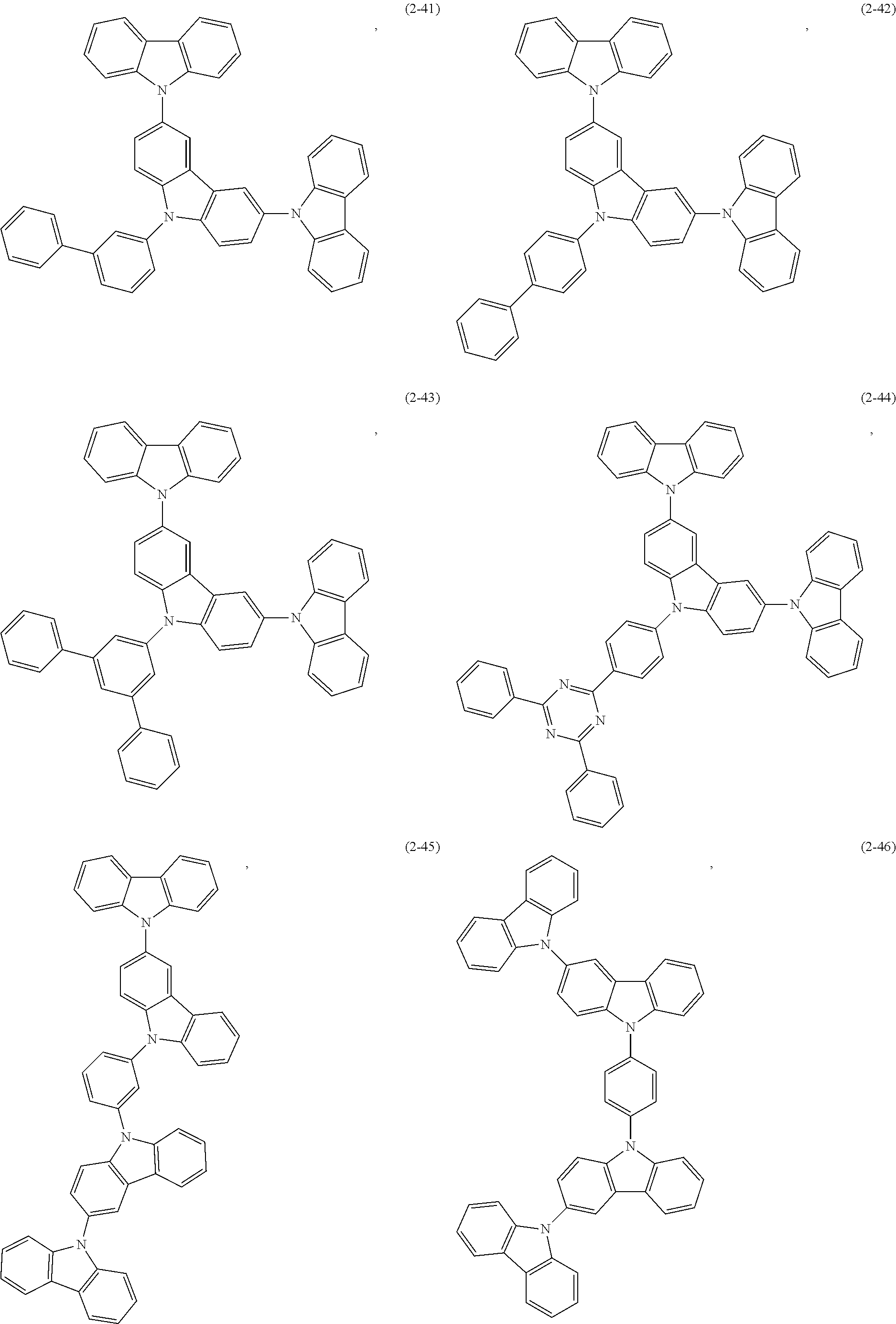

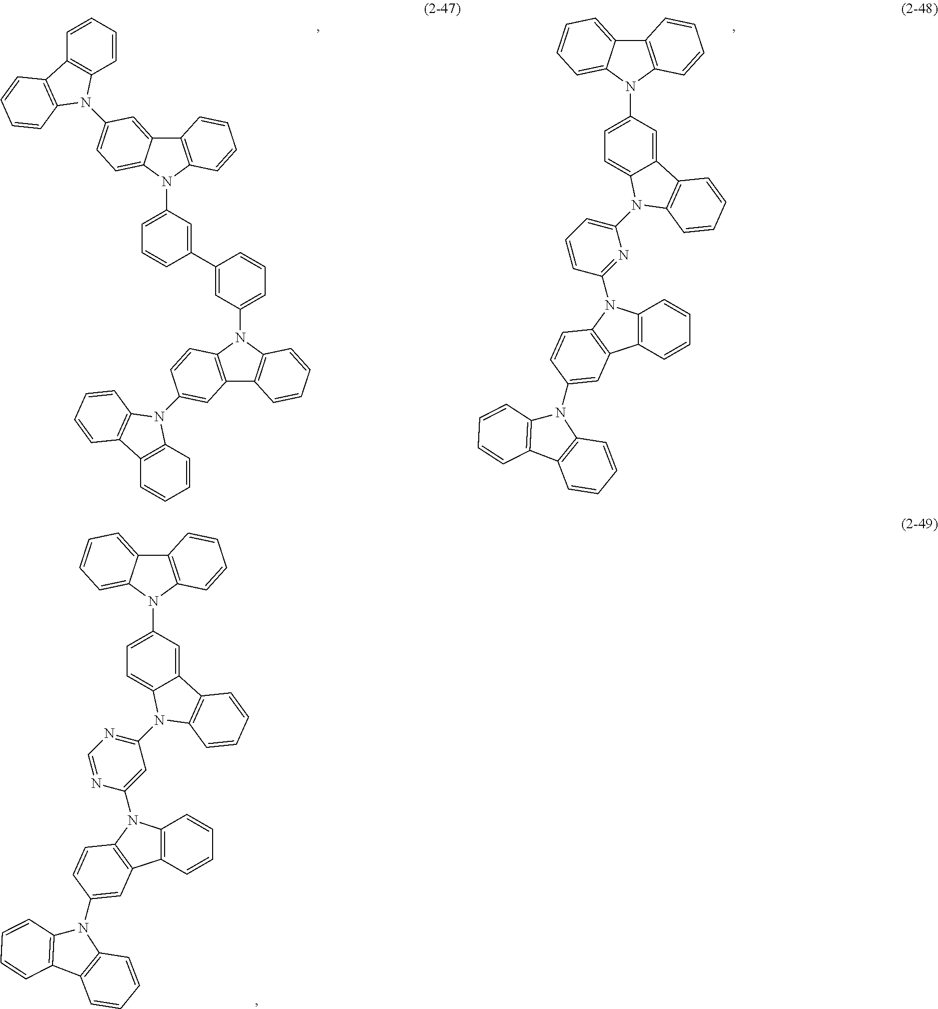

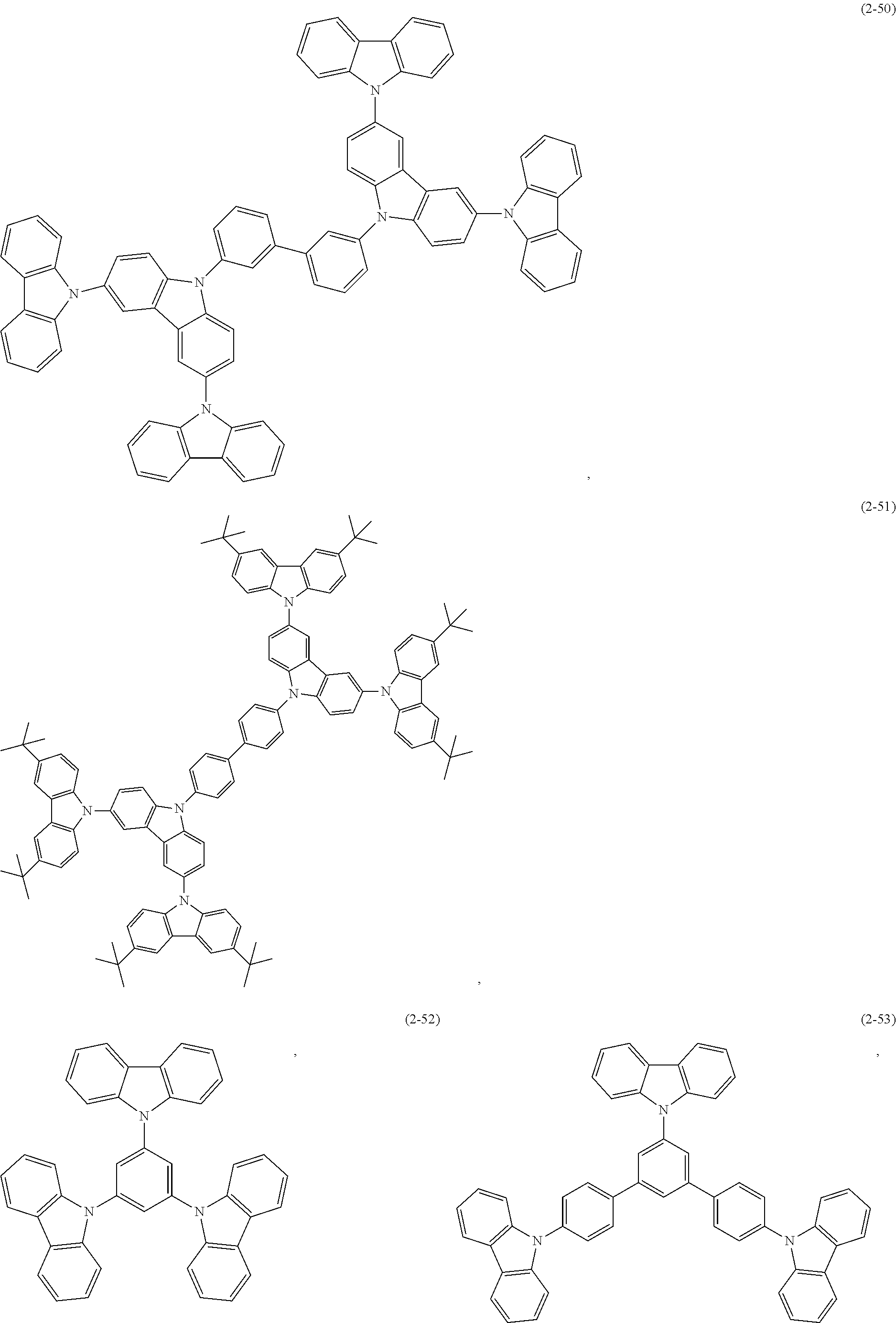

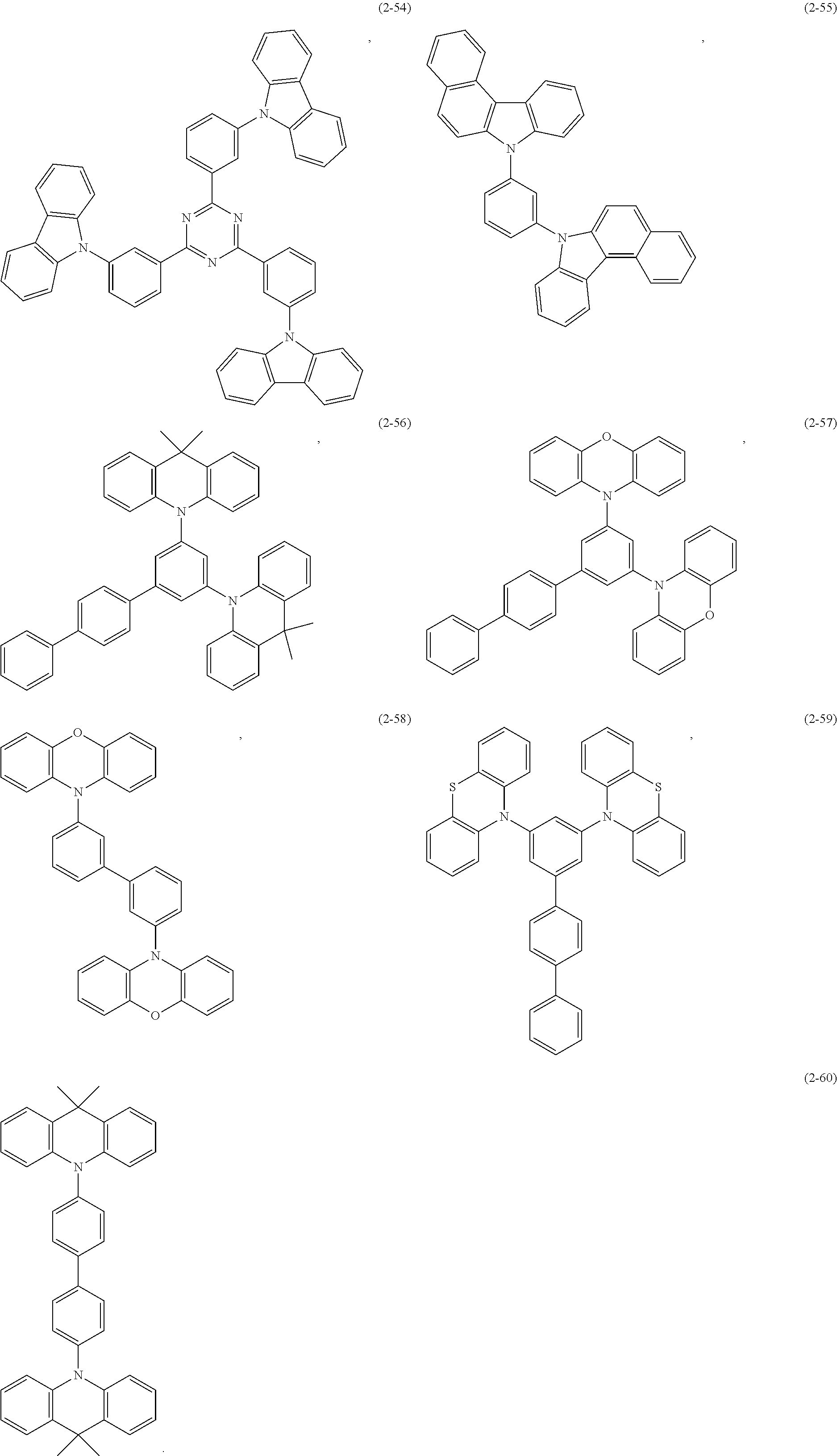

In an embodiment, the organic compound H2 is selected from:

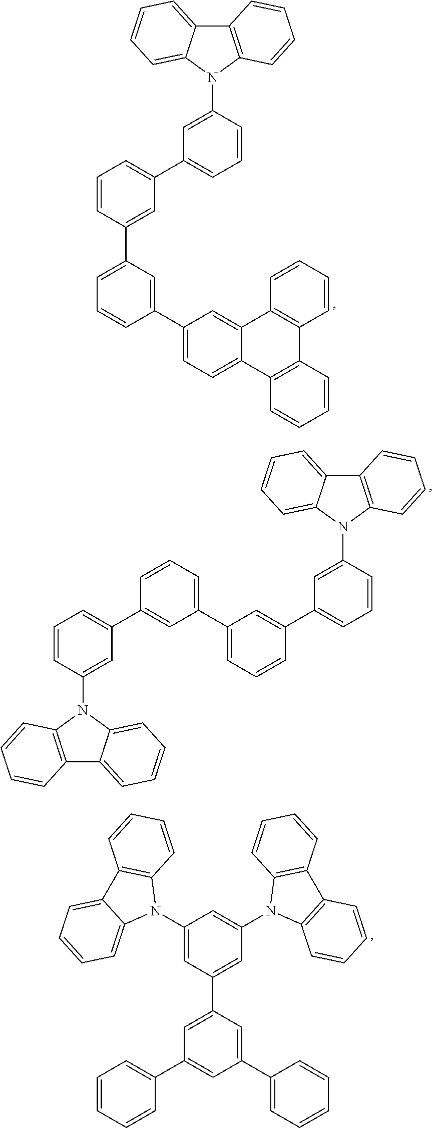

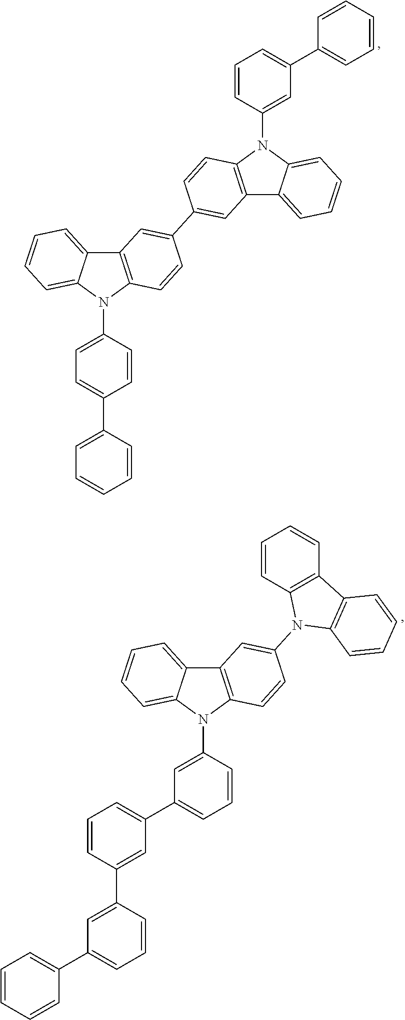 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-c3cccc(-c4cccc(-n5c6ccccc6c6cc(-n7c8ccccc8c8ccccc87)ccc65)c4)c3)c2)cc1]

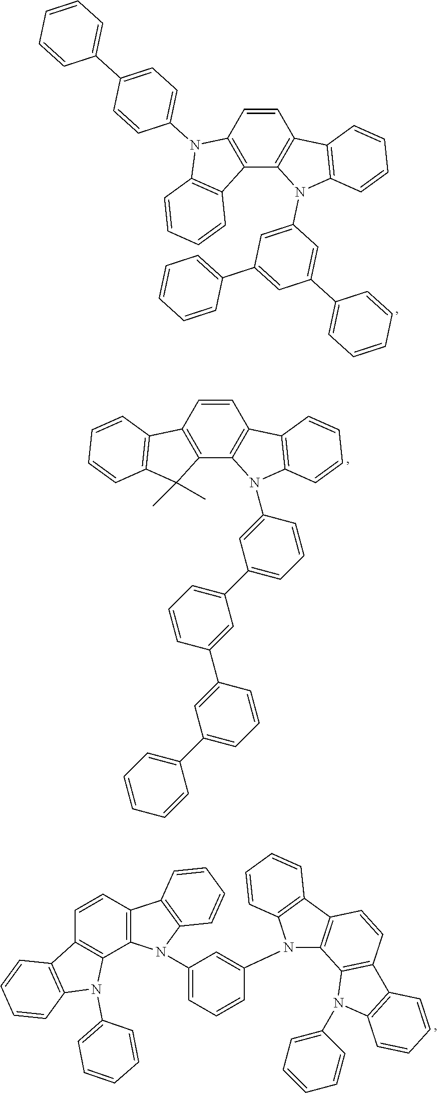 [SMILES: c1ccc(-c2ccc(-n3c4ccccc4c4c3ccc3c5ccccc5n(-c5cc(-c6ccccc6)cc(-c6ccccc6)c5)c34)cc2)cc1 ; CC1(C)c2ccccc2-c2ccc3c4ccccc4n(-c4cccc(-c5cccc(-c6cccc(-c7ccccc7)c6)c5)c4)c3c21 ; c1ccc(-n2c3ccccc3c3ccc4c5ccccc5n(-c5cccc(-n6c7ccccc7c7ccc8c9ccccc9n(-c9ccccc9)c8c76)c5)c4c32)cc1]

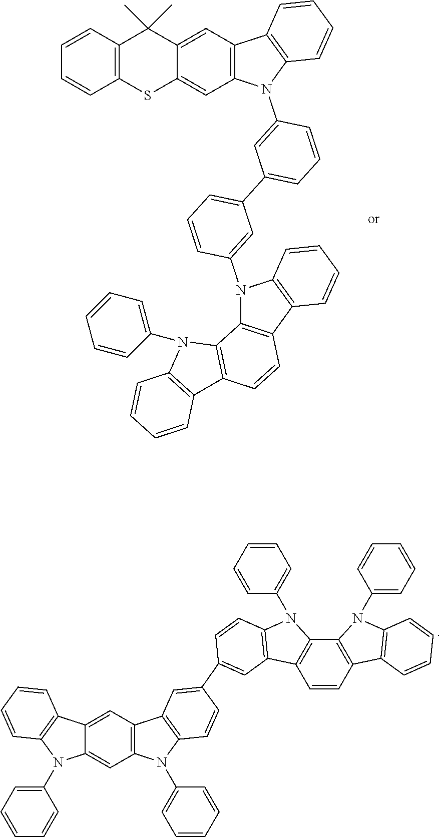 [SMILES: CC1(C)c2ccccc2Sc2cc3c(cc21)c1ccccc1n3-c1cccc(-c2cccc(-n3c4ccccc4c4ccc5c6ccccc6n(-c6ccccc6)c5c43)c2)c1 ; c1ccc(-n2c3ccccc3c3cc4c5cc(-c6ccc7c(c6)c6ccc8c9ccccc9n(-c9ccccc9)c8c6n7-c6ccccc6)ccc5n(-c5ccccc5)c4cc32)cc1]

In an embodiment, the organic compound H2 is selected from one of the following structural formulas:

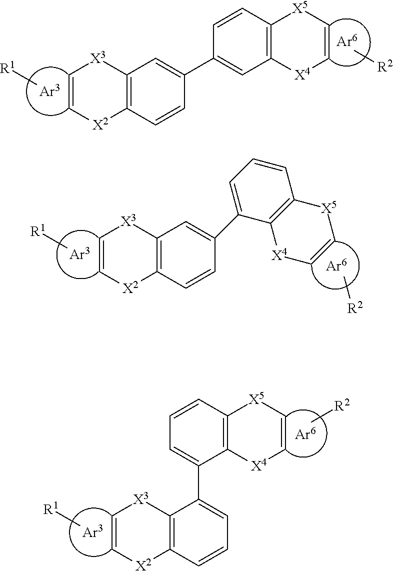

wherein, Ar³ and Ar⁶ are independently selected from an aromatic group with a ring atom number of 5 to 30 or a heteroaromatic group with a ring atom number of 5 to 30;

X², X³, X⁴, X⁵, X⁶, X⁷, X⁸ and X⁹ are independently selected from a single bond, N(R), C(R)₂, Si(R)₂, O, C═N(R), C═C(R)₂, P(R), P(═O)R, S, S═O or SO₂, and X² and X³ are not single bonds simultaneously, X⁴ and X⁵ are not both single bonds simultaneously, X⁶ and X⁷ are not both single bonds simultaneously, and X⁸ and X⁹ are not both single bonds simultaneously;

R¹, R² and R are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring.

In an embodiment, the organic compound H2 has a structure represented by the general formula (7):

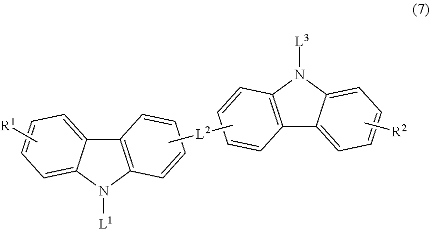

wherein, R¹, R² and R are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring; L¹ is selected from an aromatic group or a heteroaromatic group with a ring atom number of 5 to 60; L² is selected from a single bond, or an aromatic group with a ring atom number of 5 to 30 or a heteroaromatic group with a ring atom number of 5 to 30, and L² is coupled to any one of the carbon atoms on the ring; L³ is selected from an aromatic group with a ring atom number of 5 to 60 or a heteroaromatic group with a ring atom number of 5 to 60.

Specific examples of the compound represented by the general formula (3) are exemplified below, but not limited to:

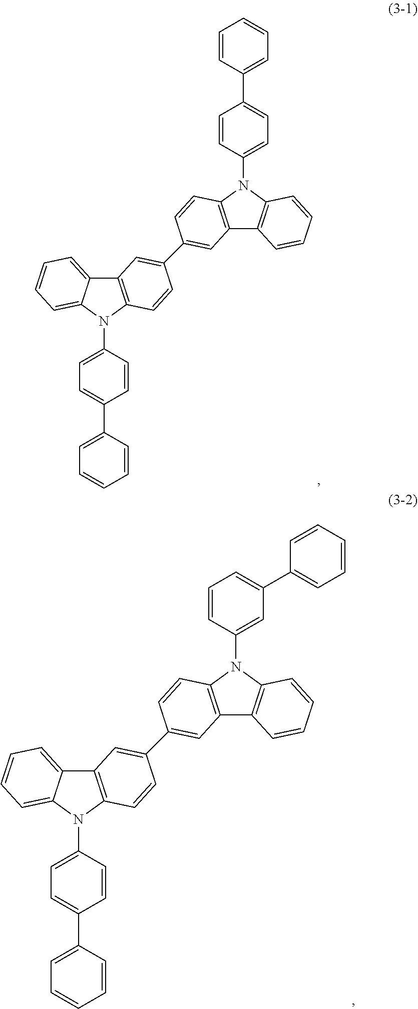

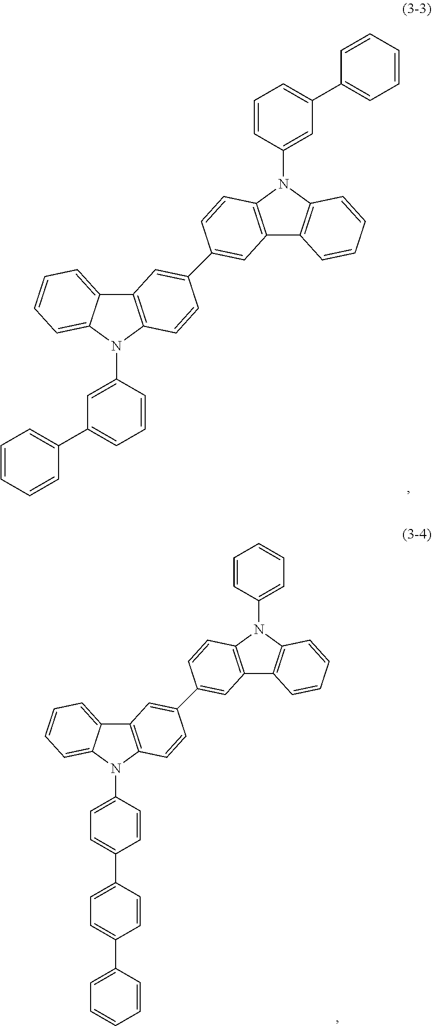

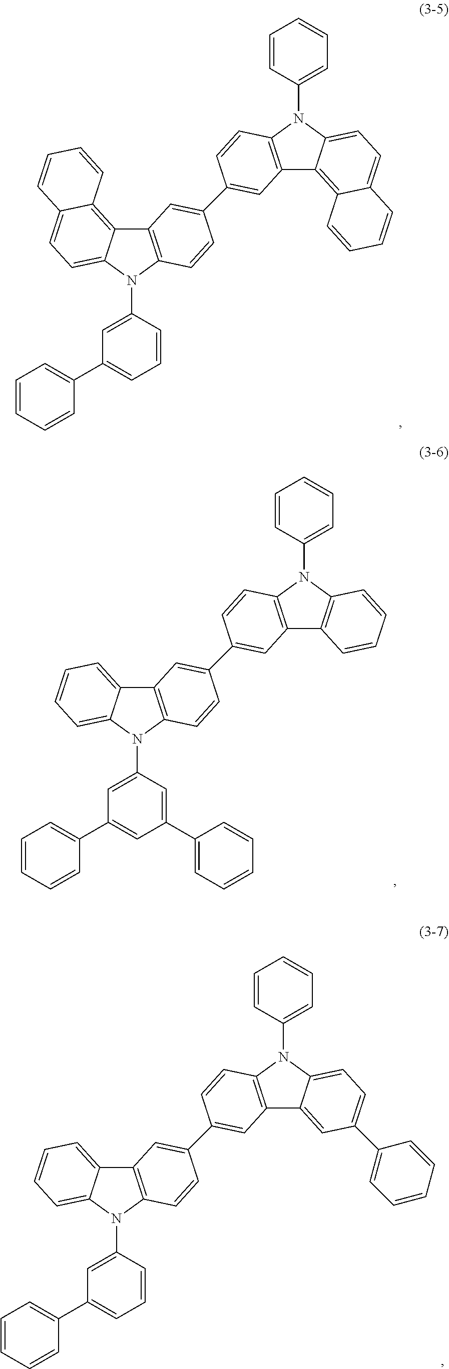

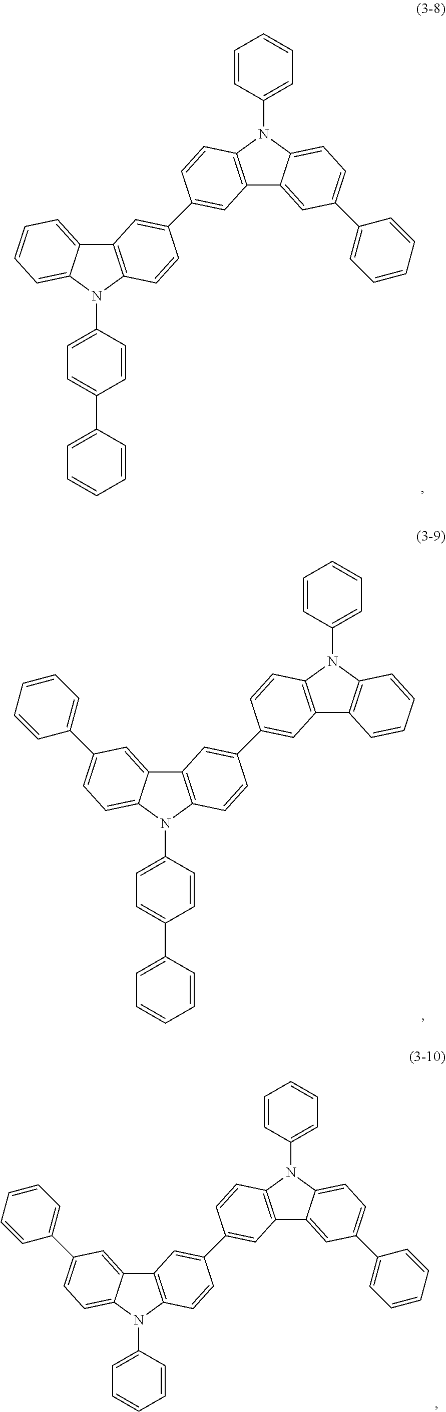

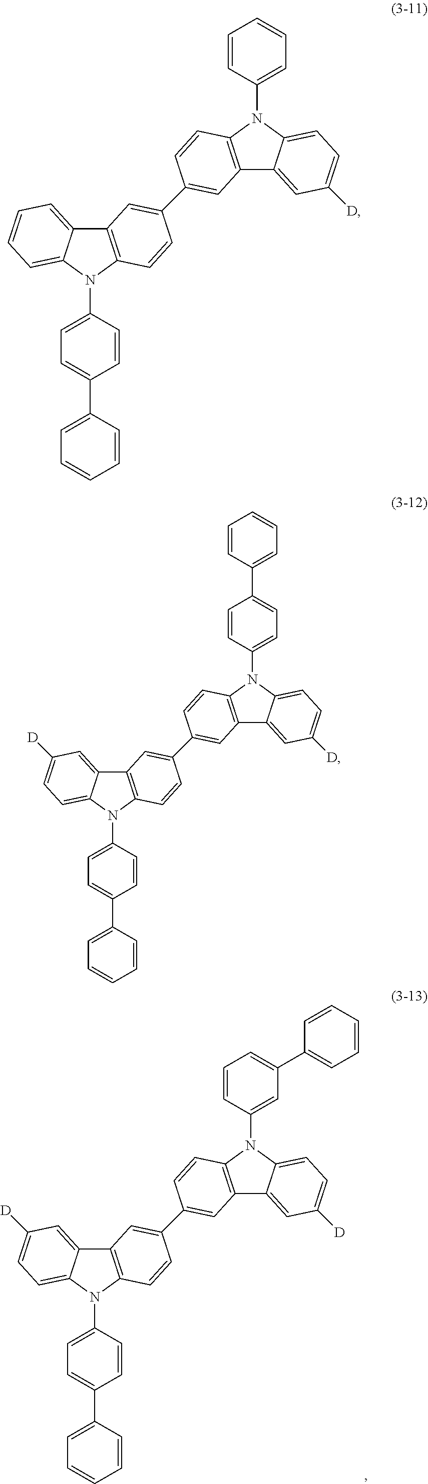

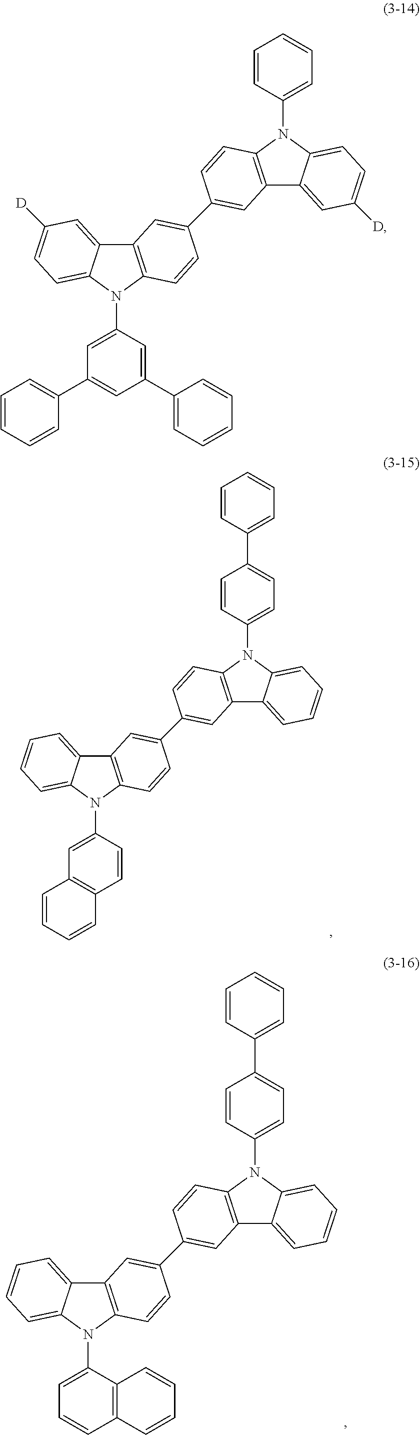

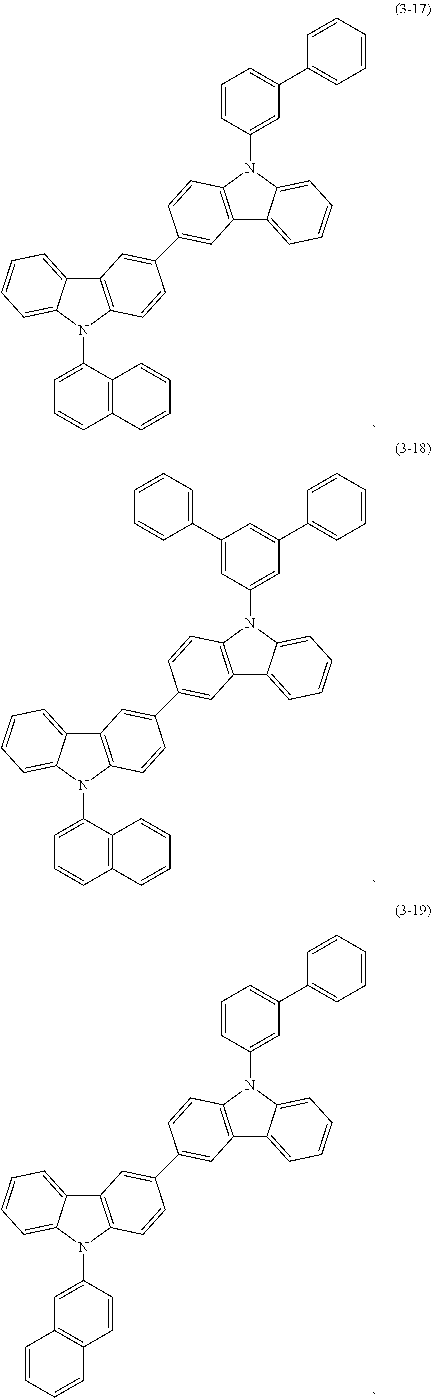

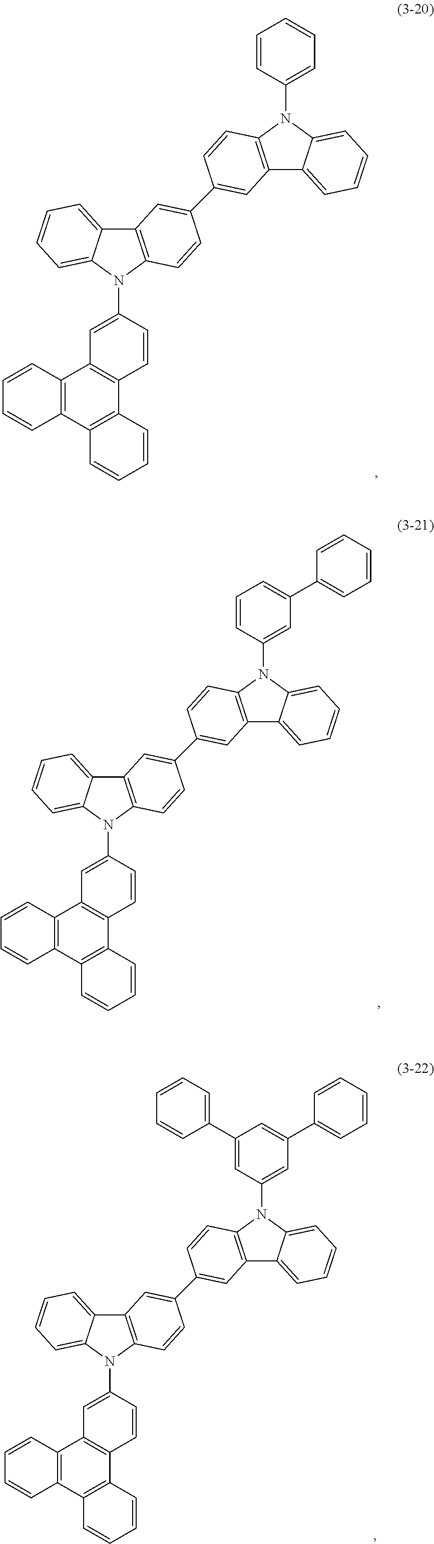

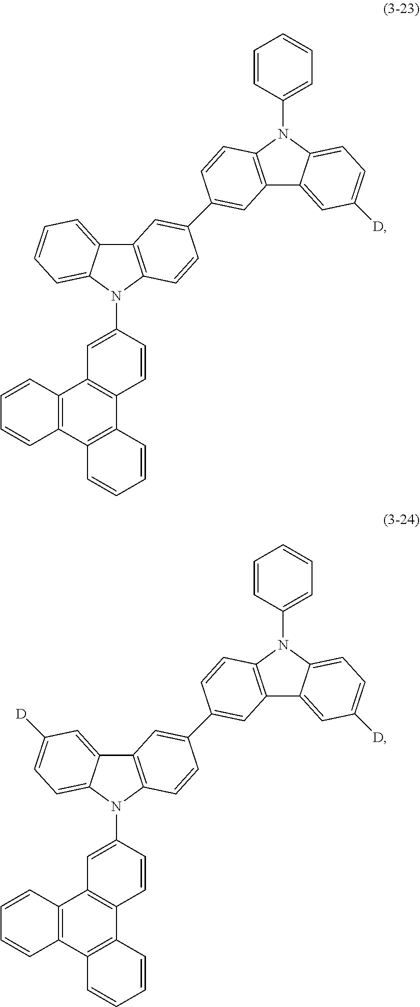

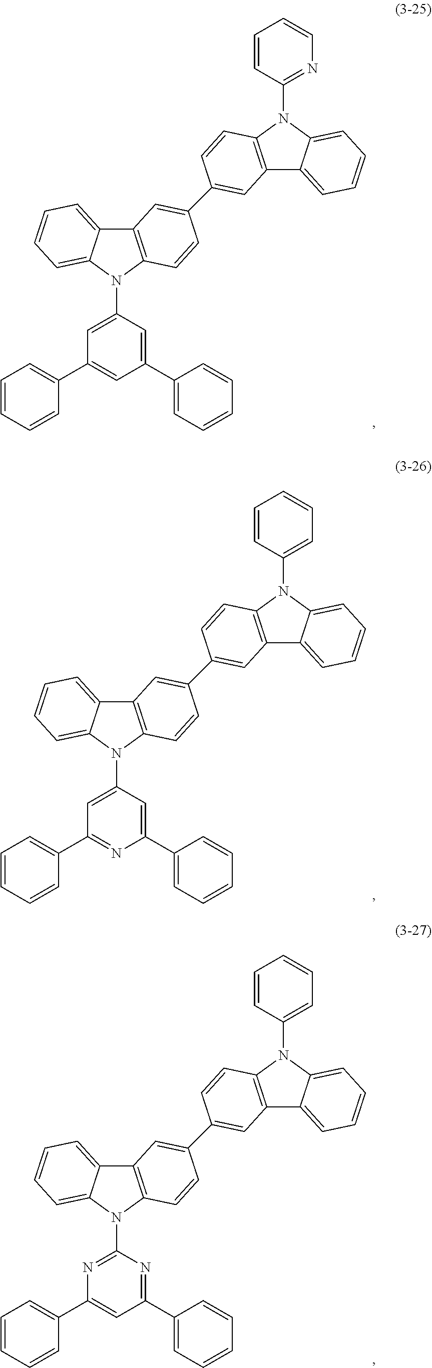

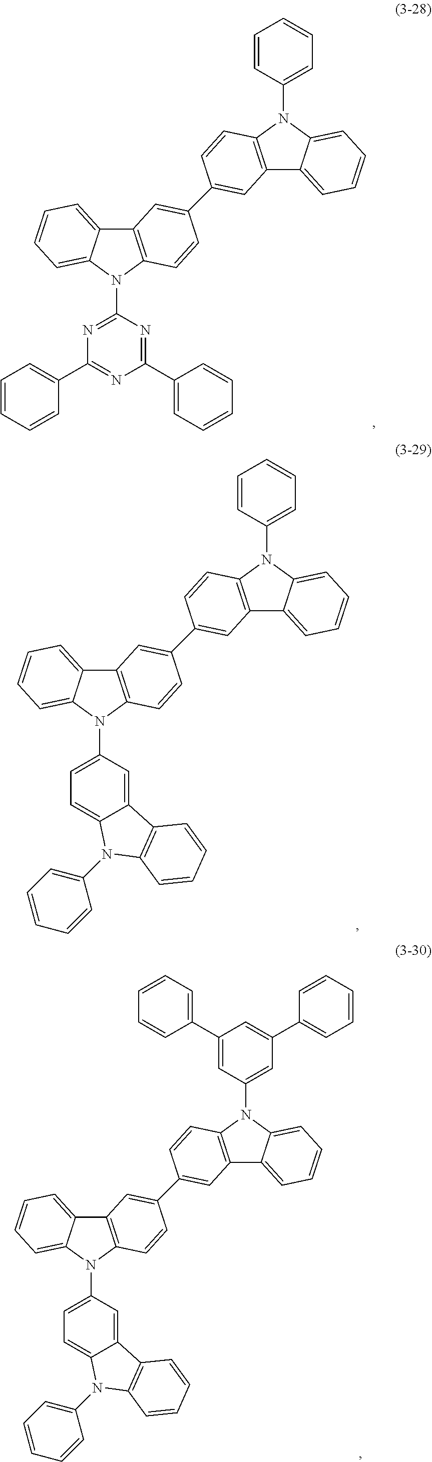

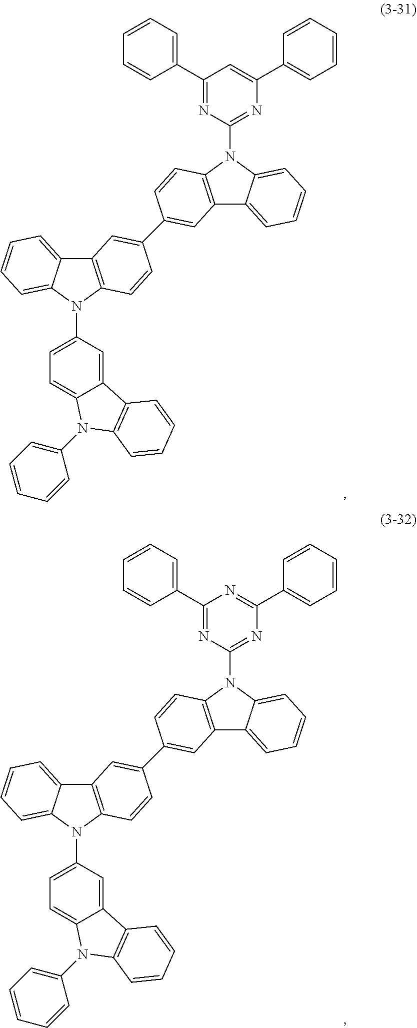

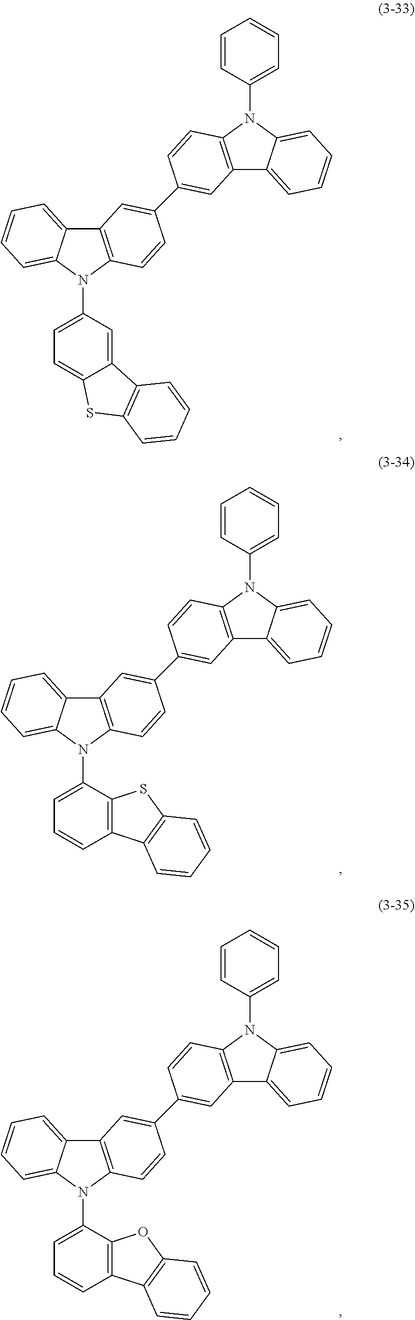

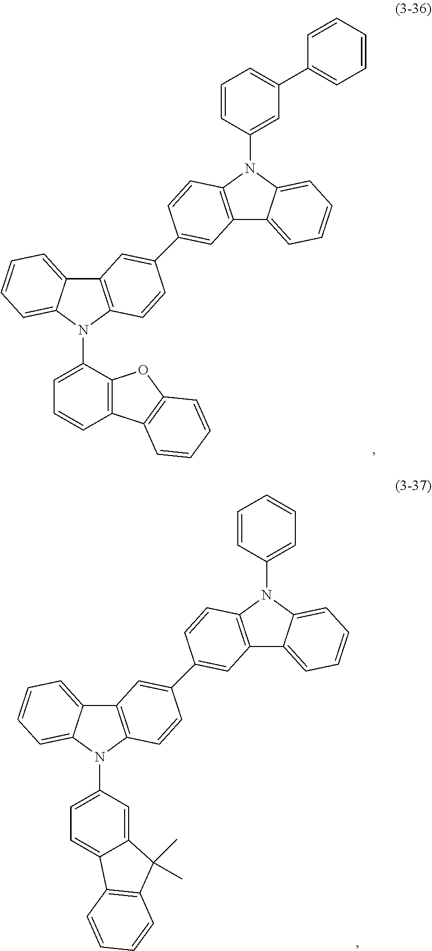

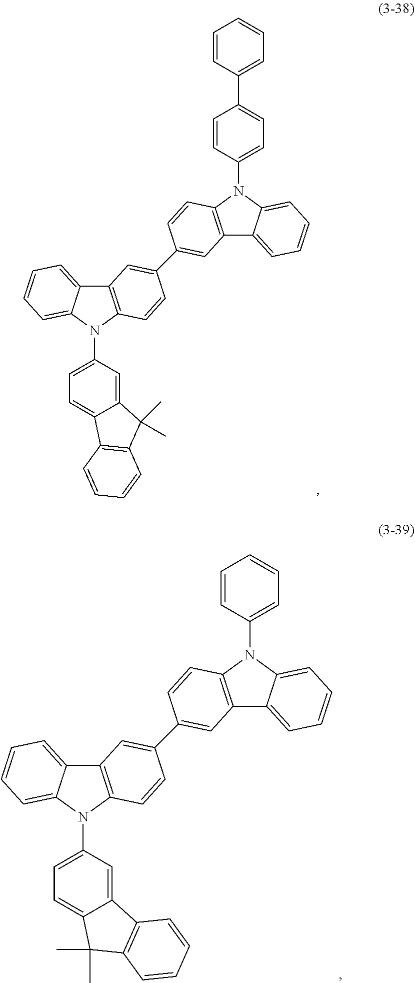

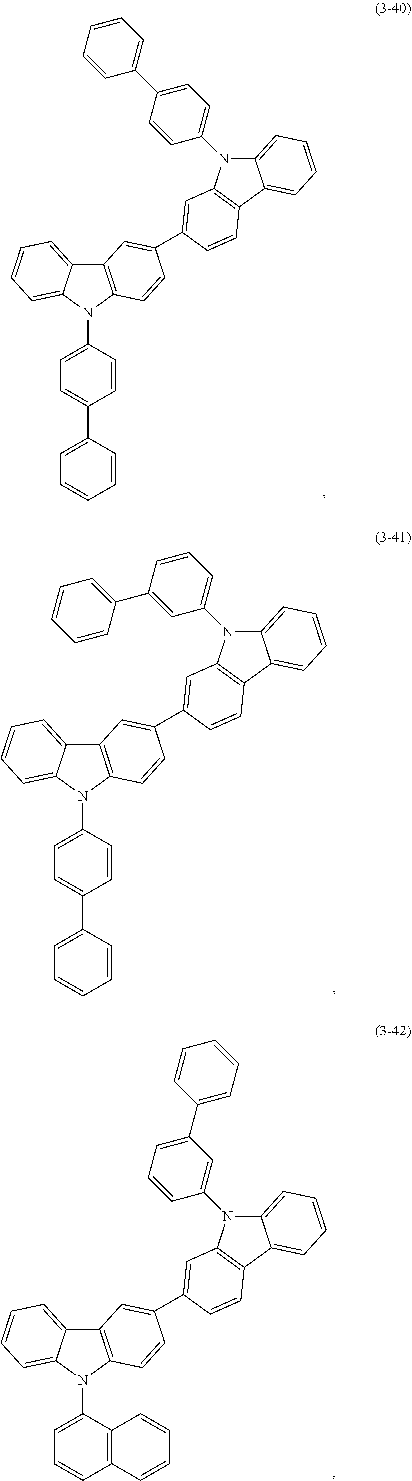

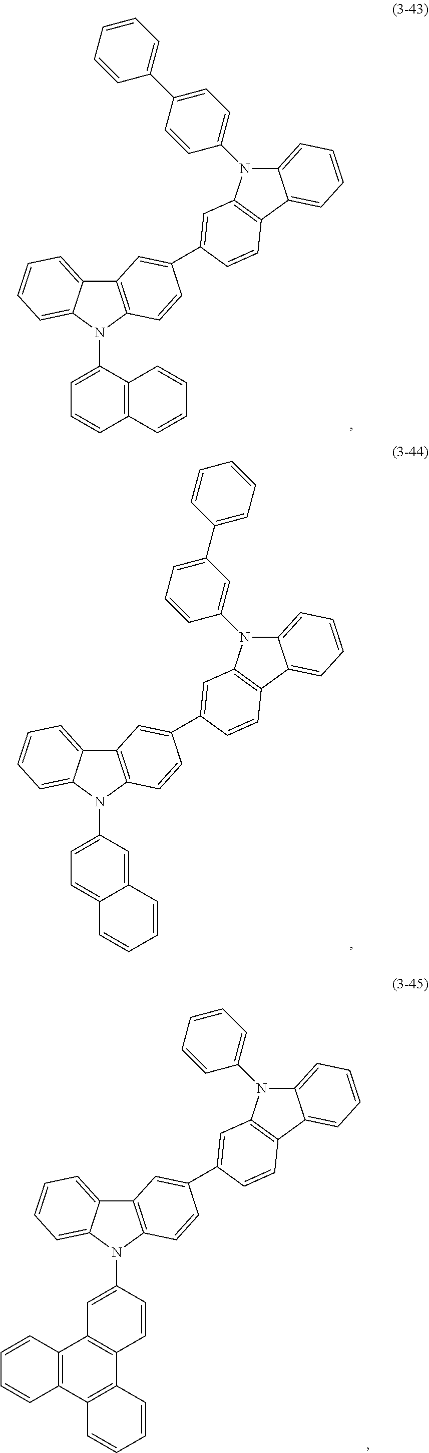

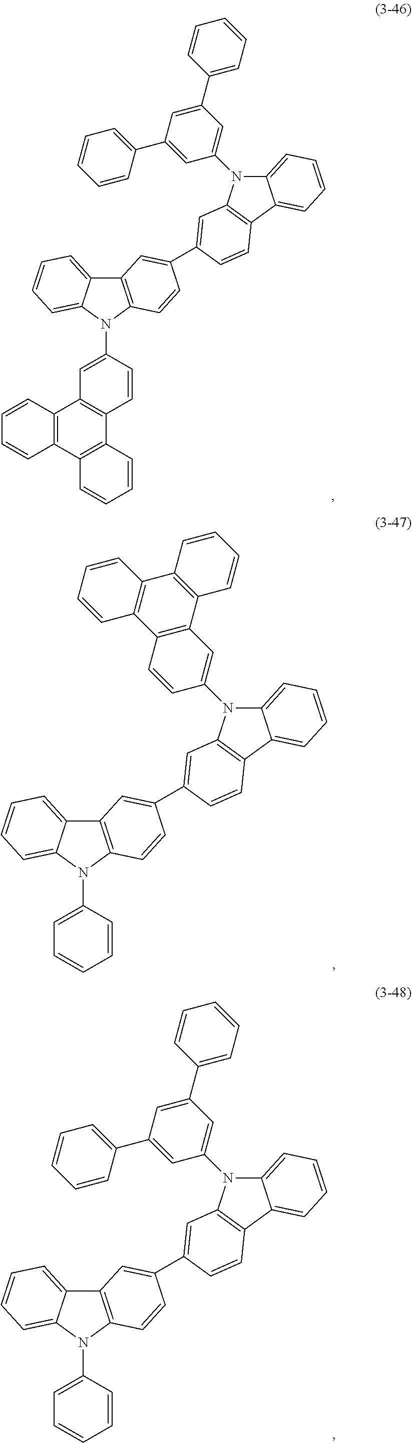

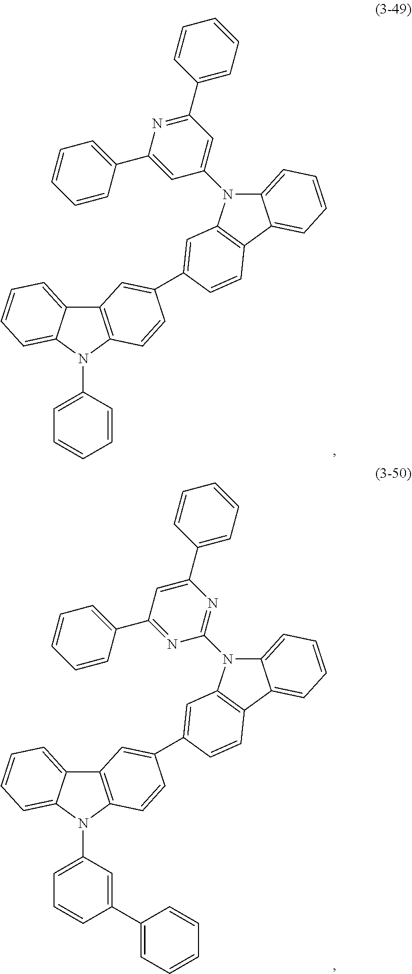

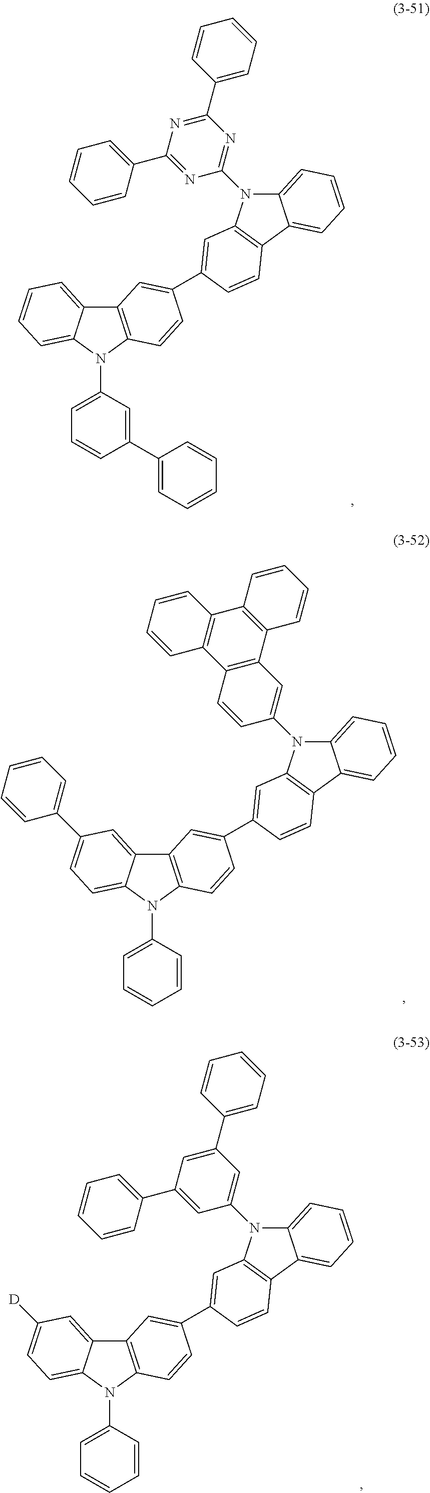

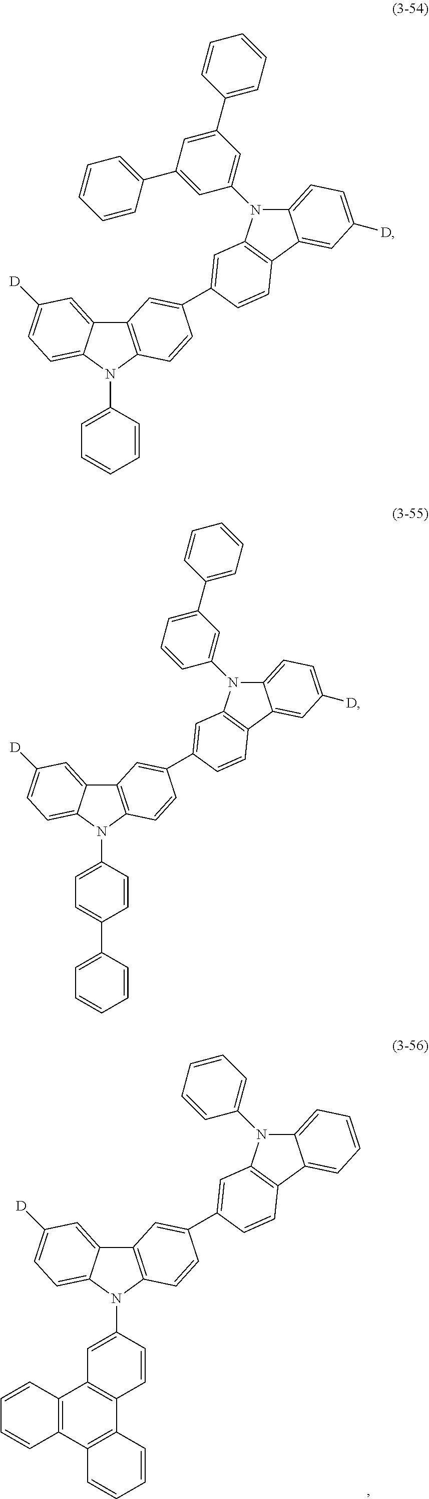

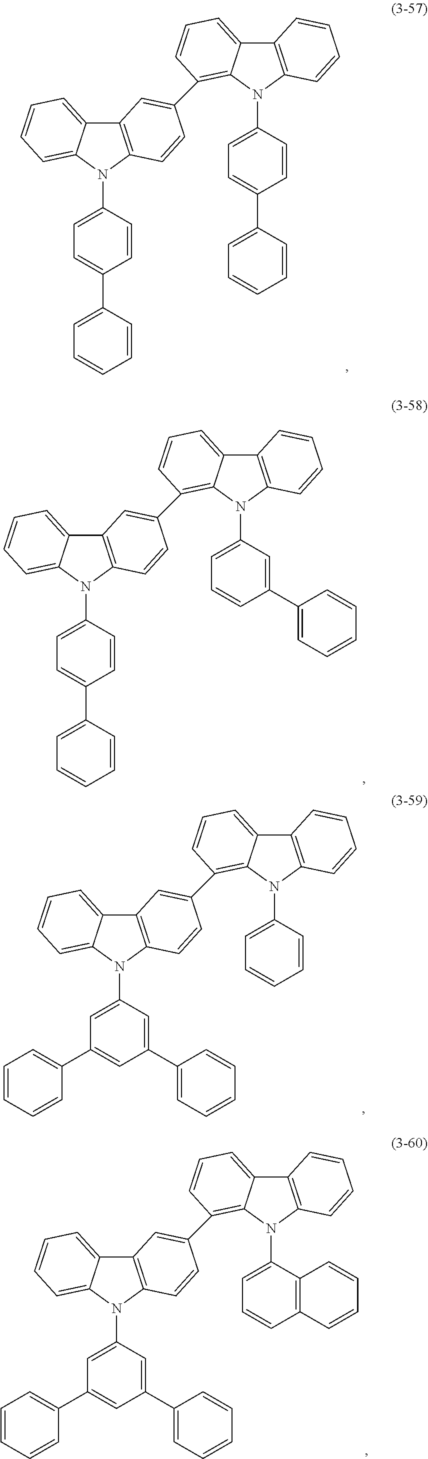

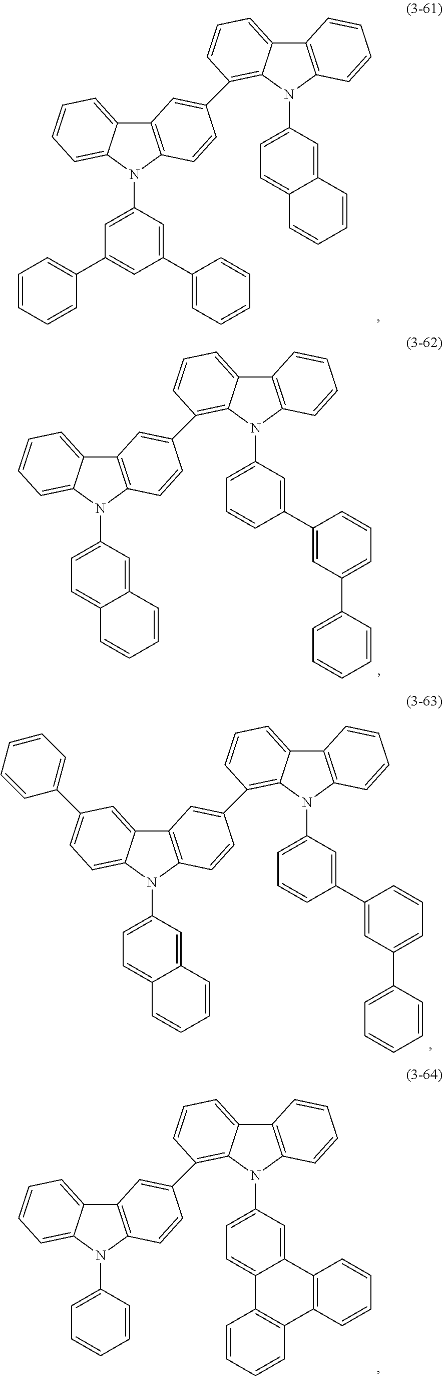

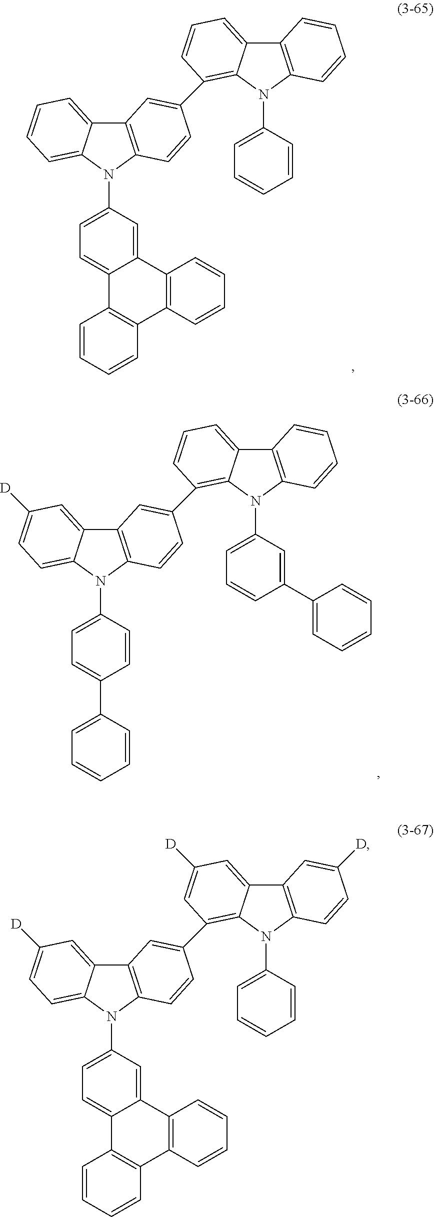

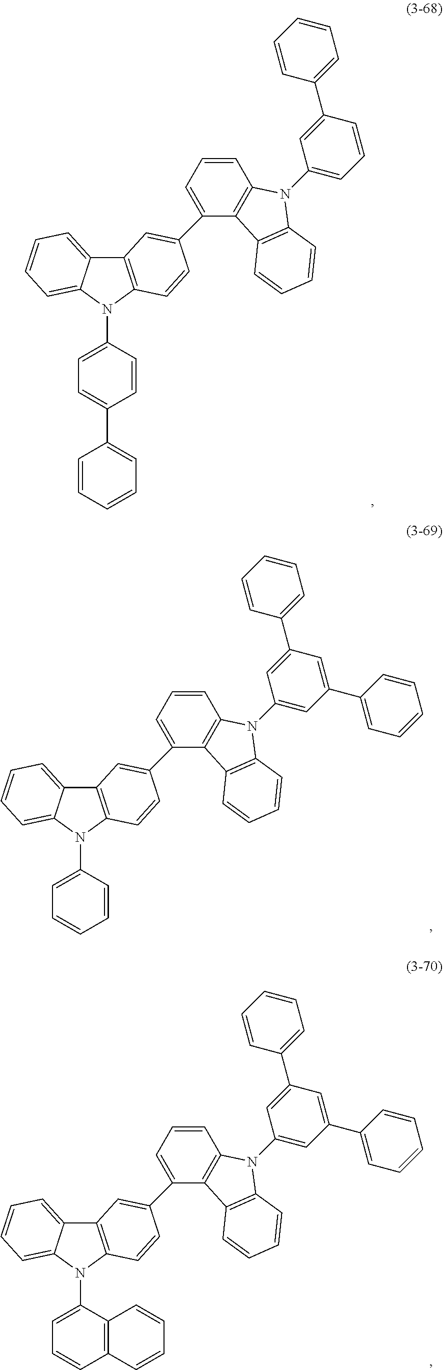

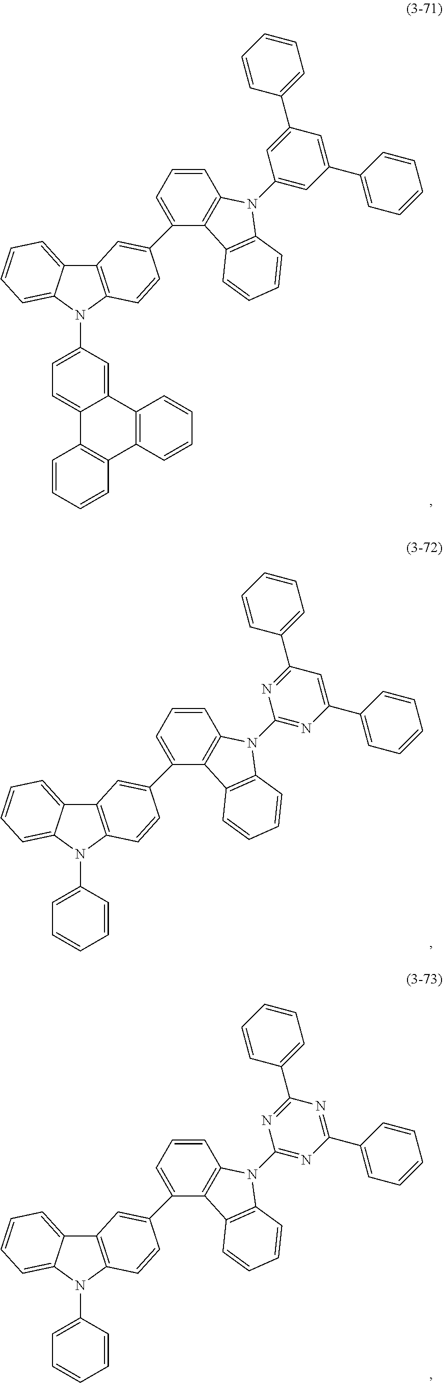

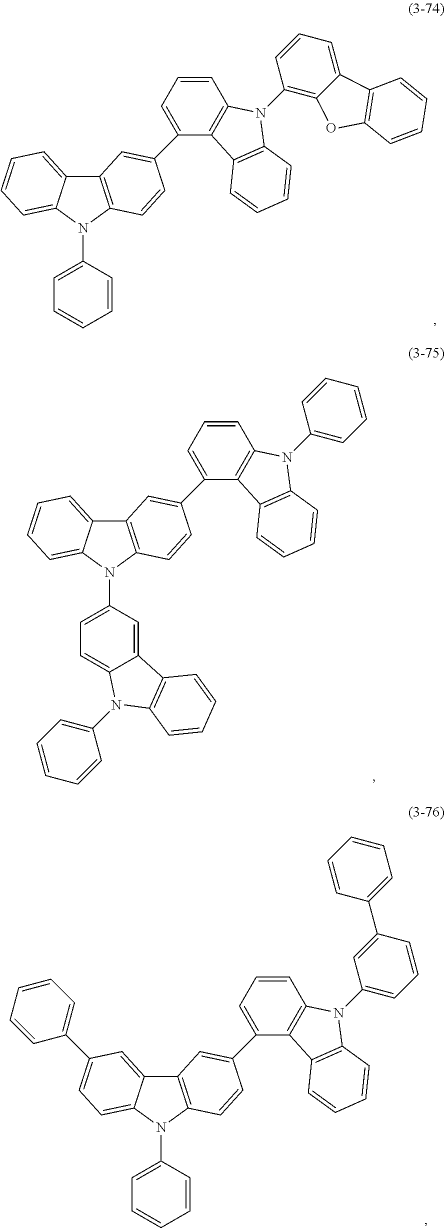

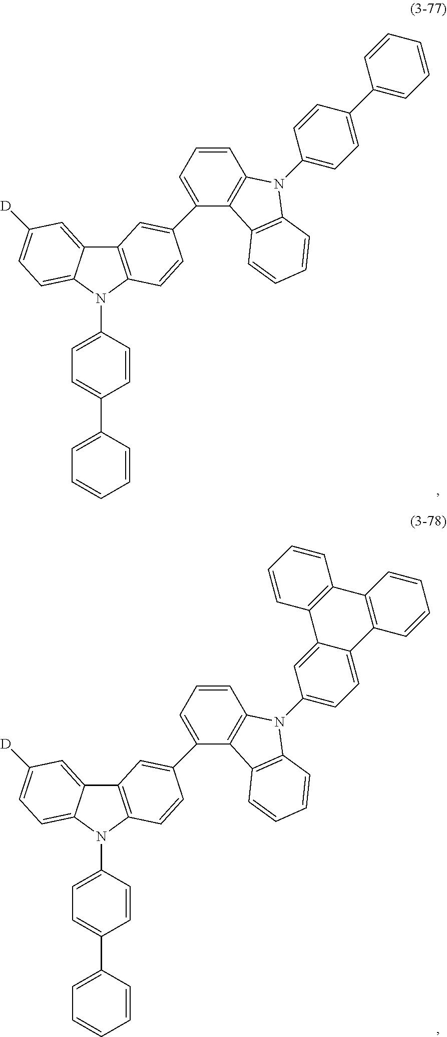

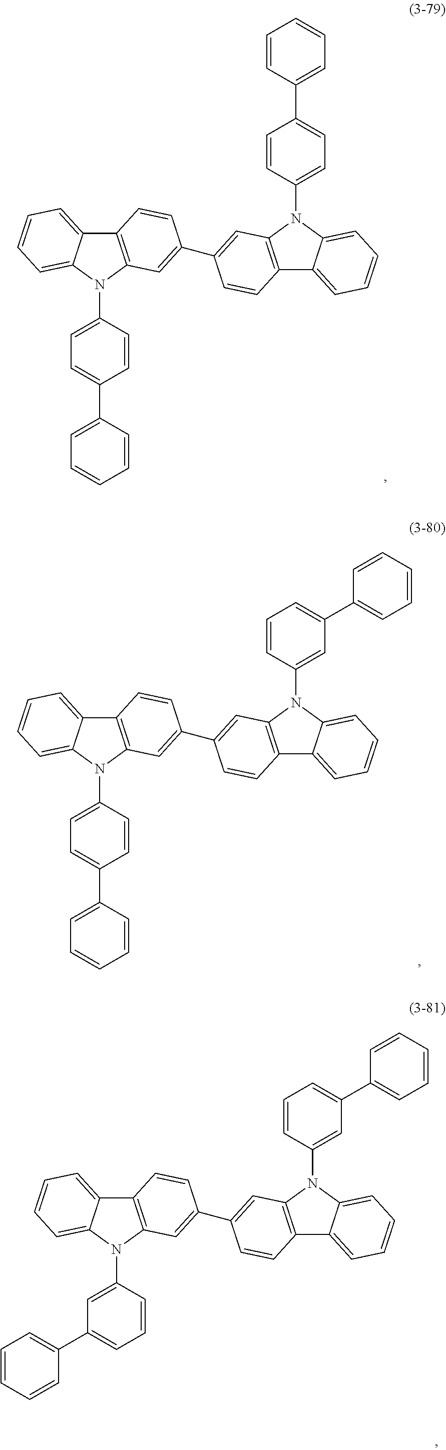

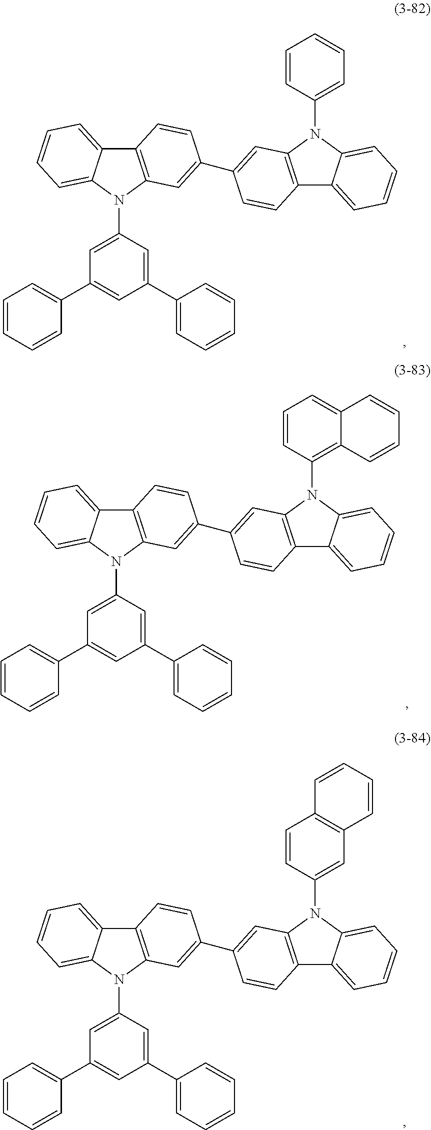

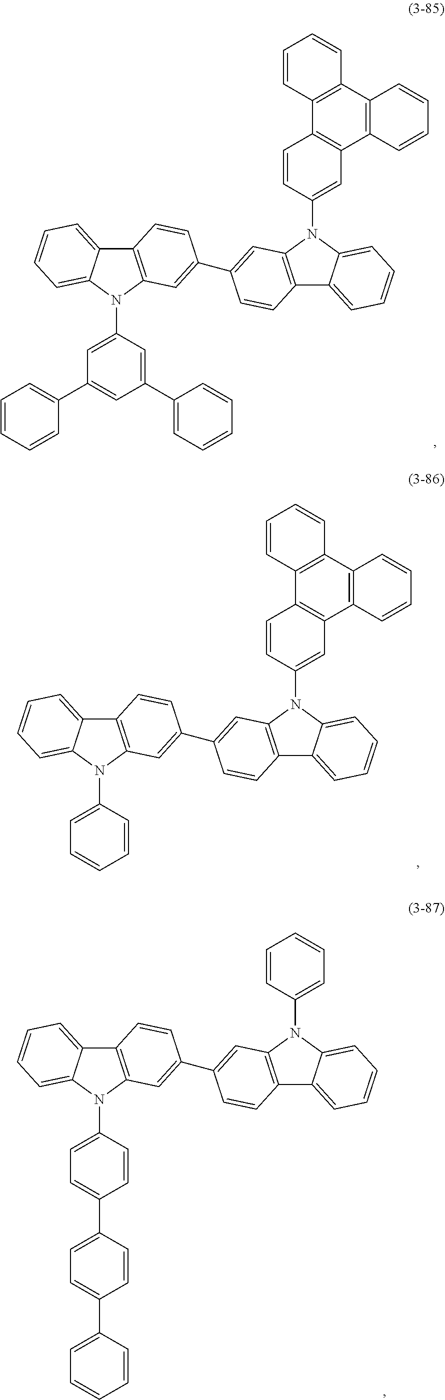

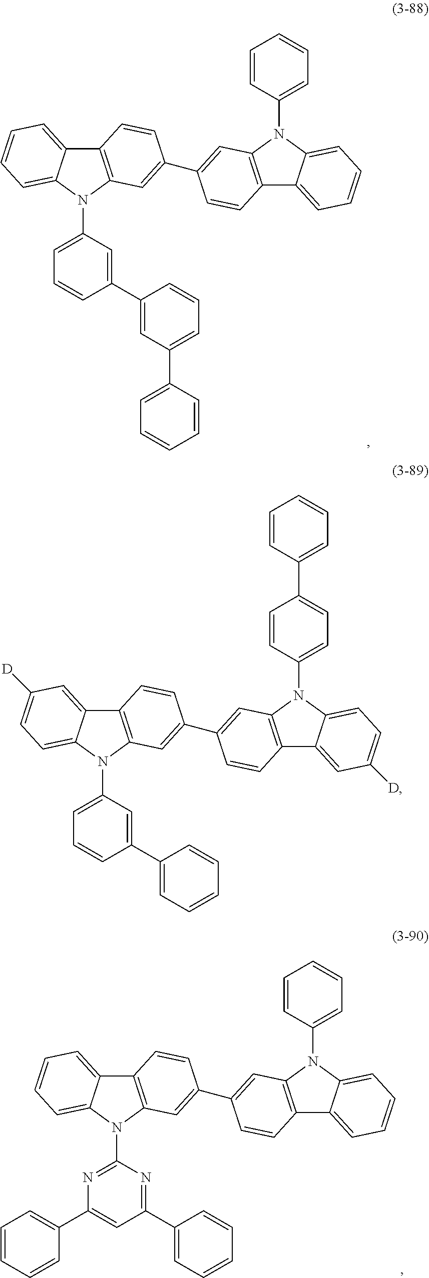

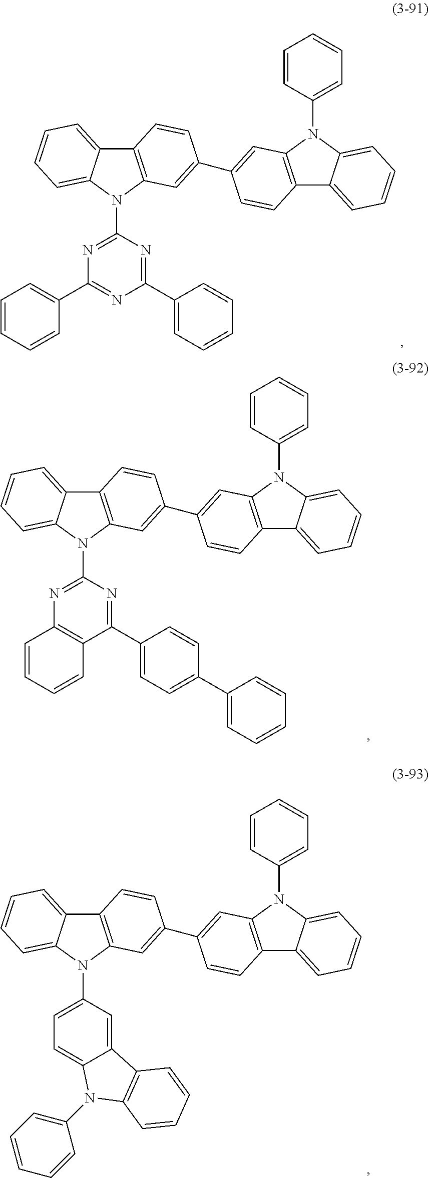

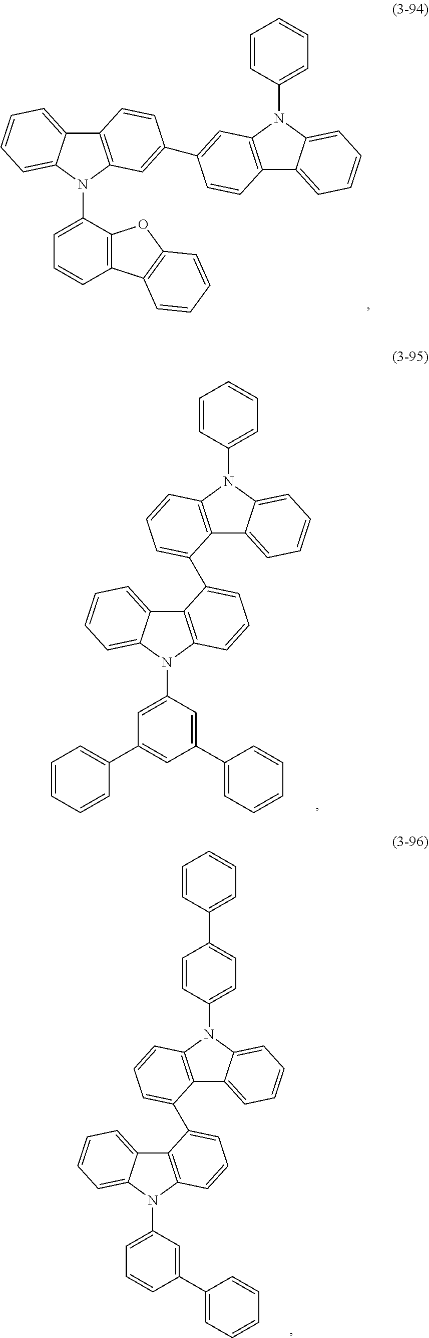

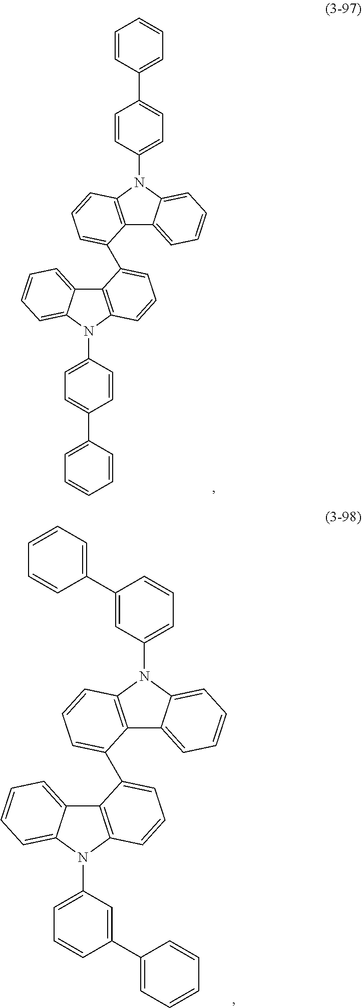

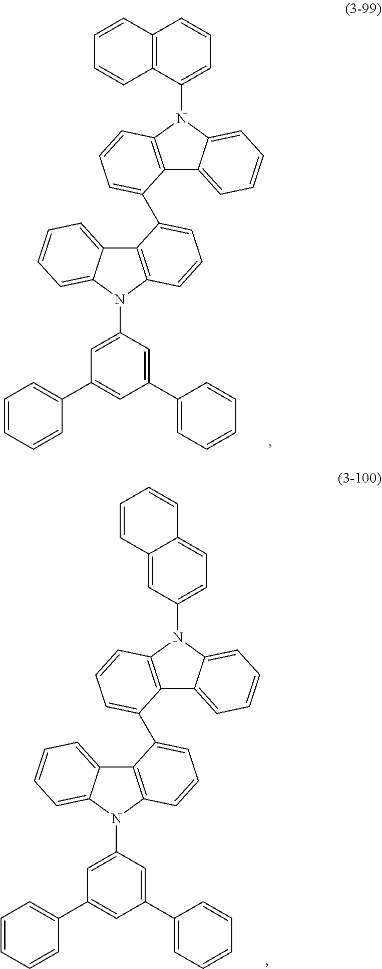

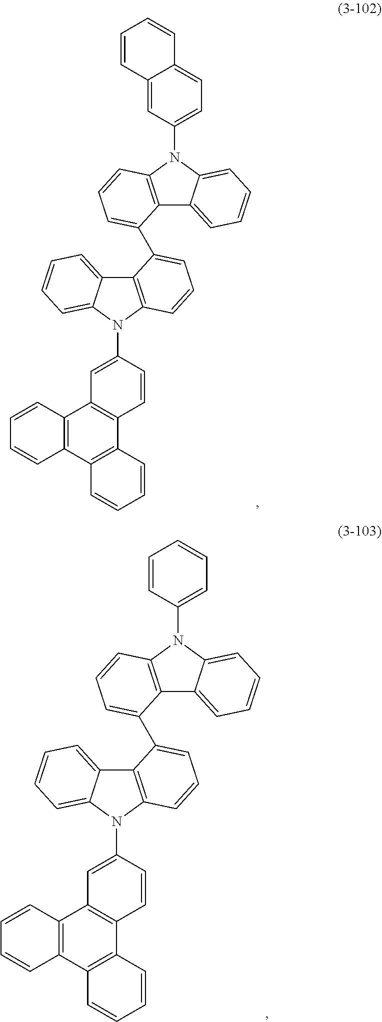

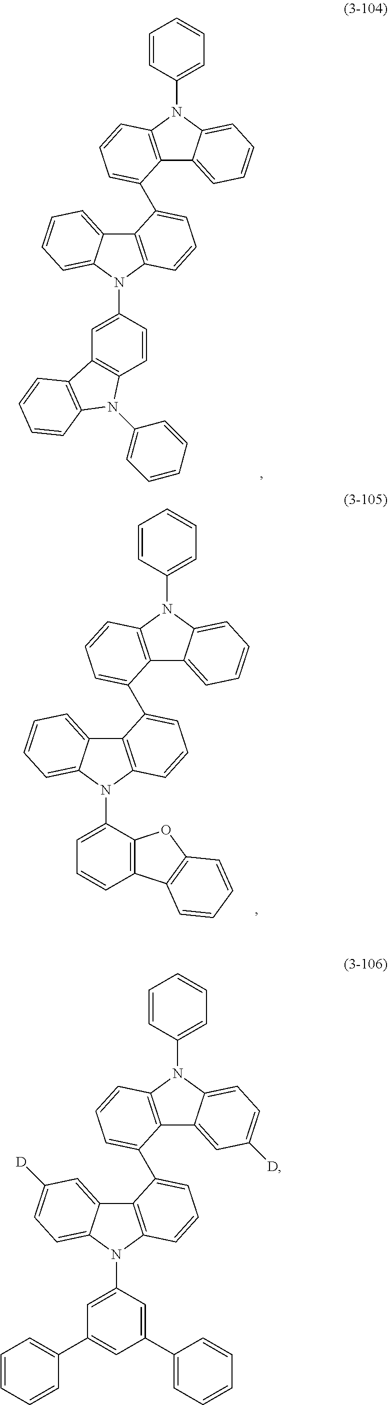

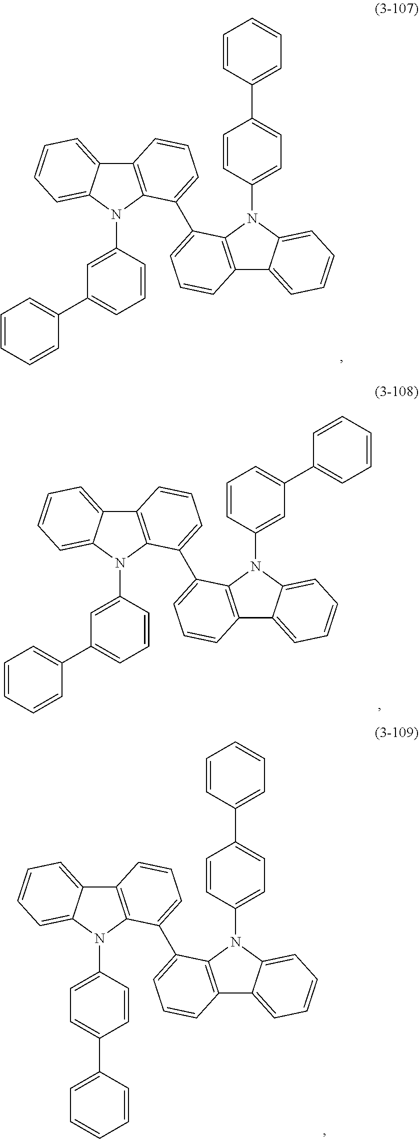

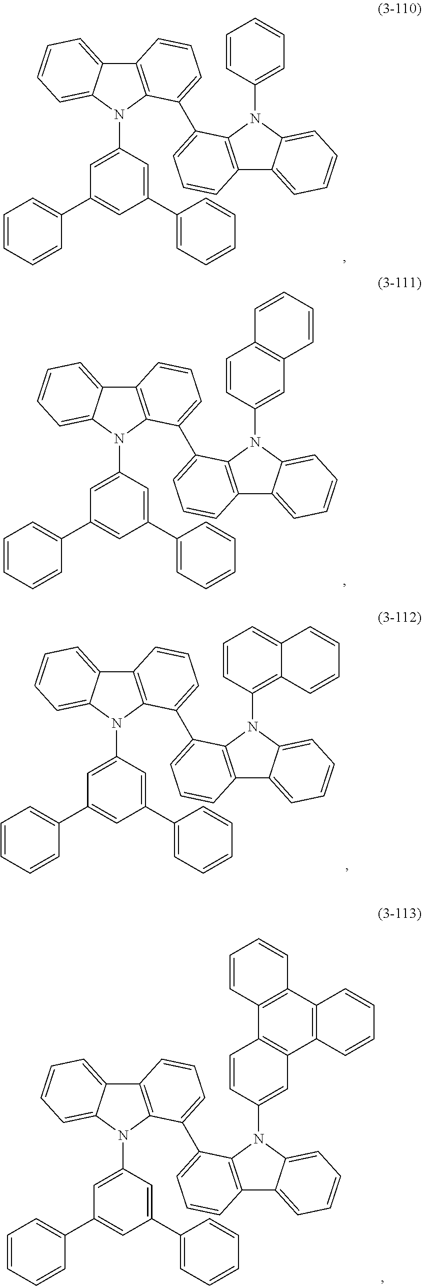

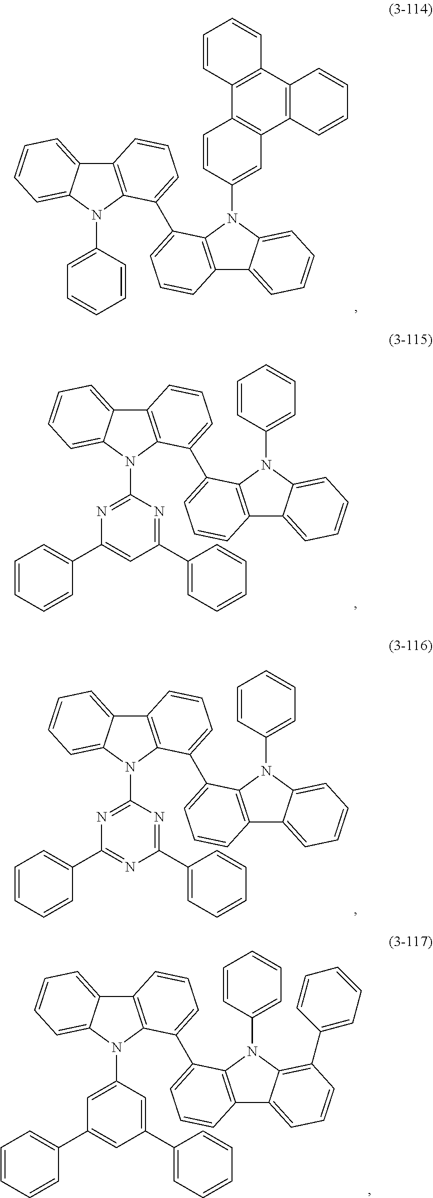

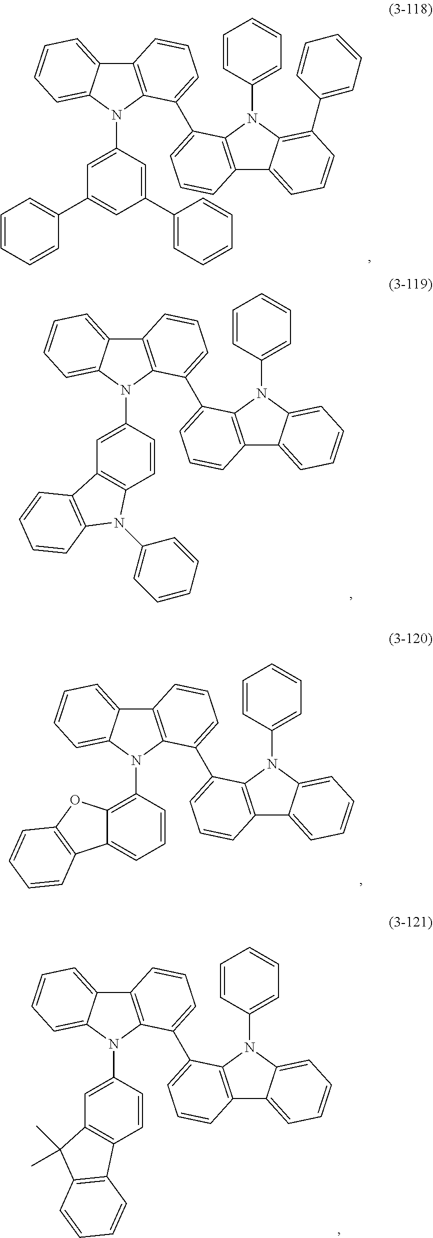

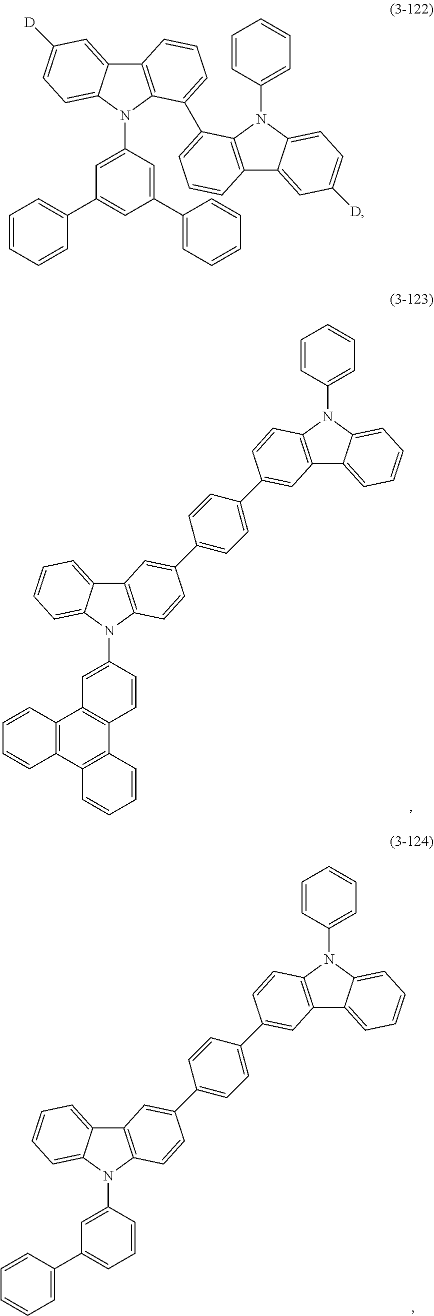

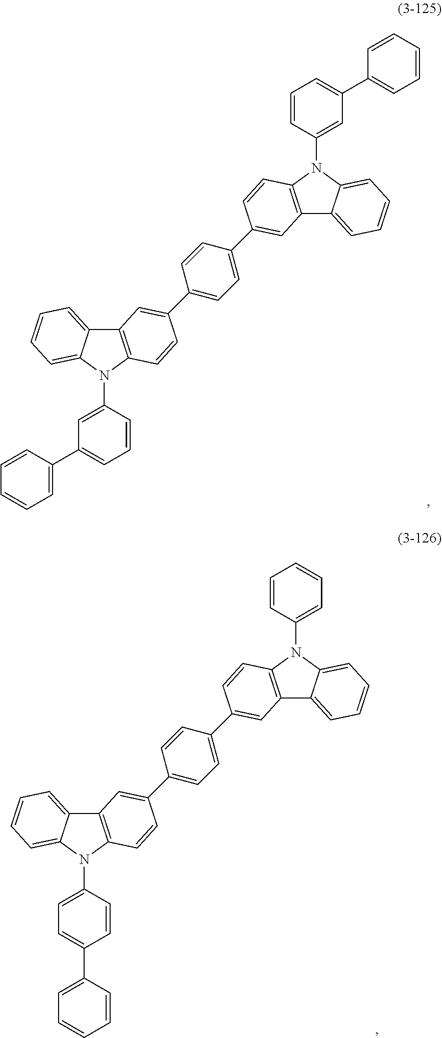

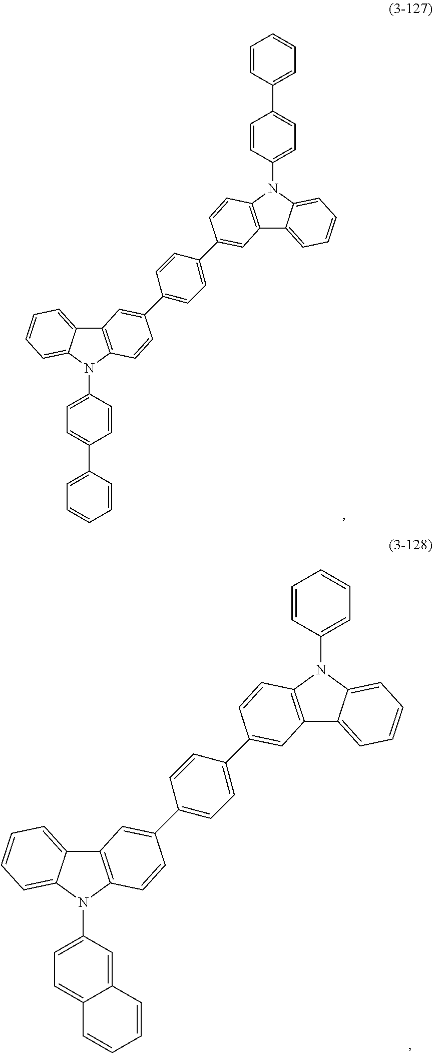

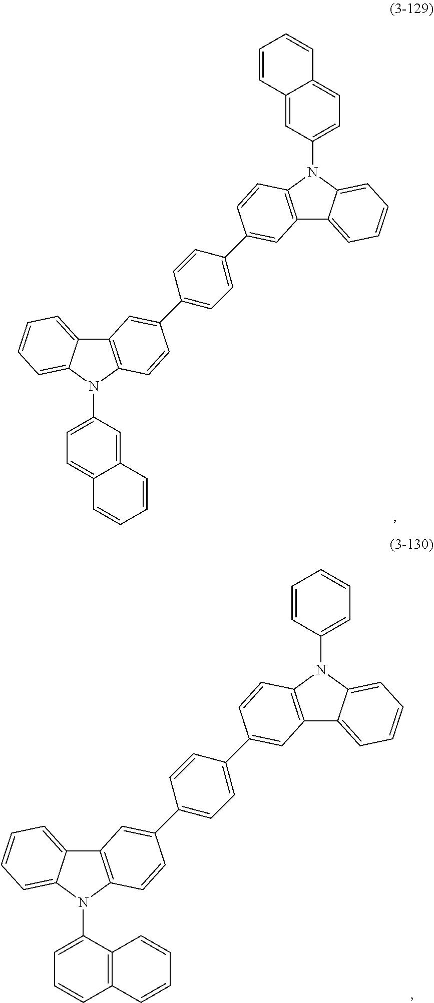

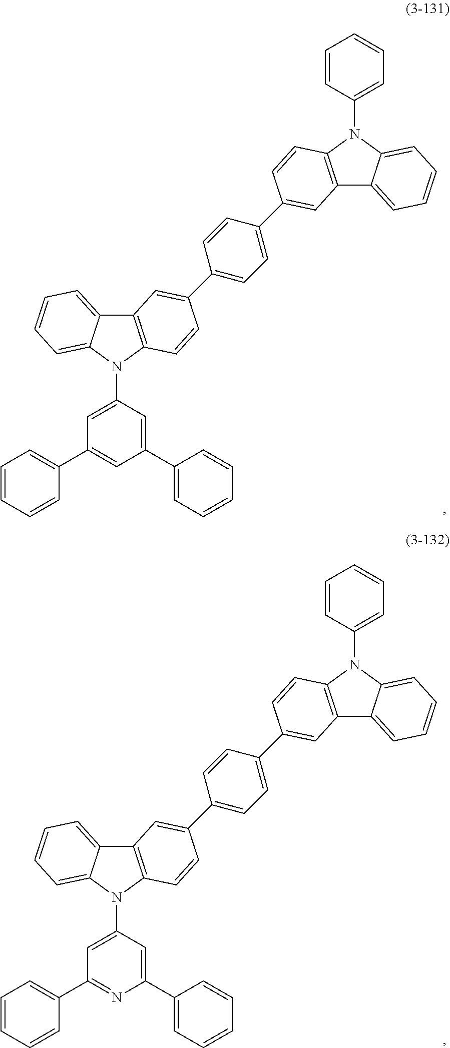

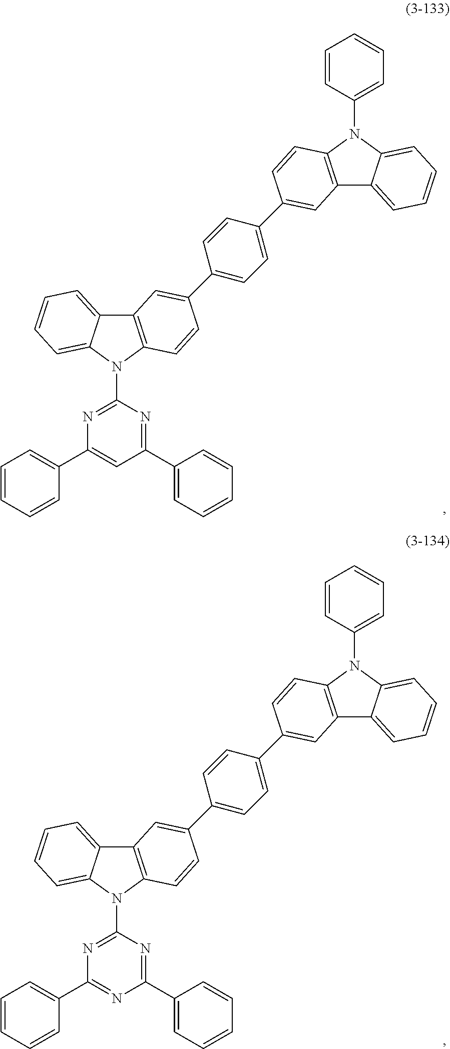

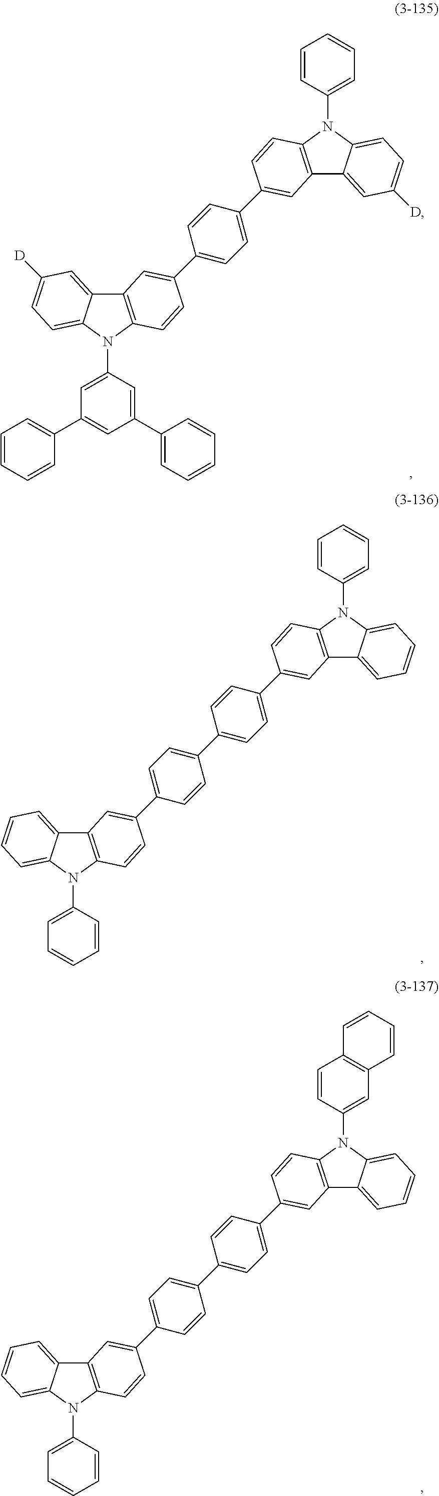

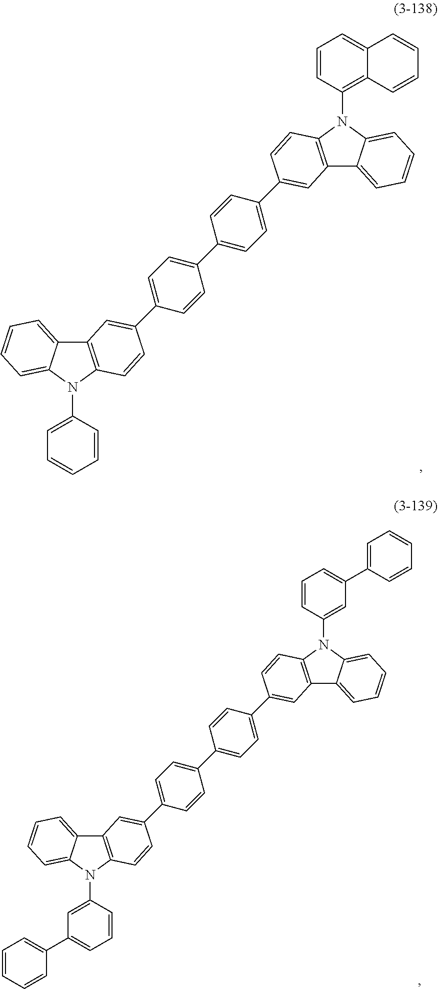

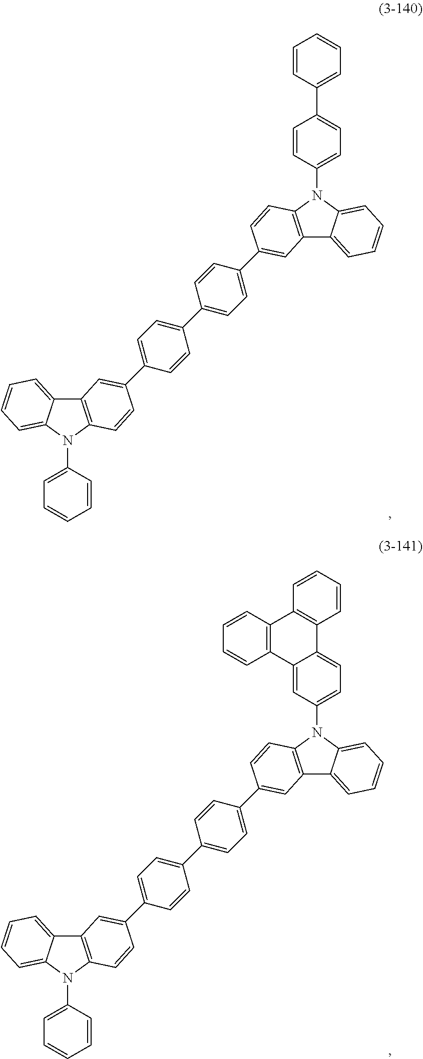

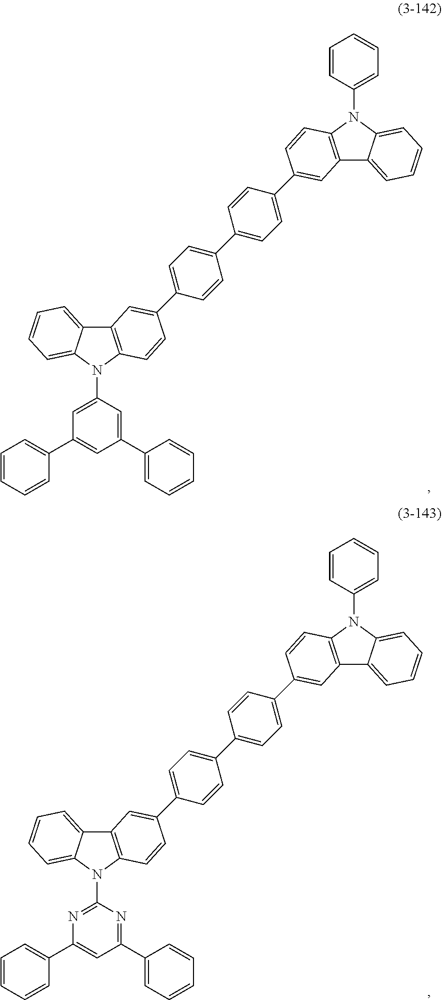

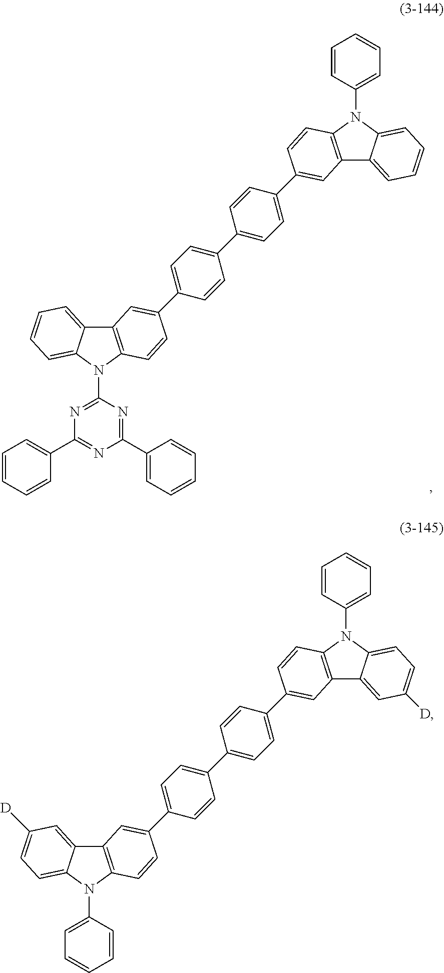

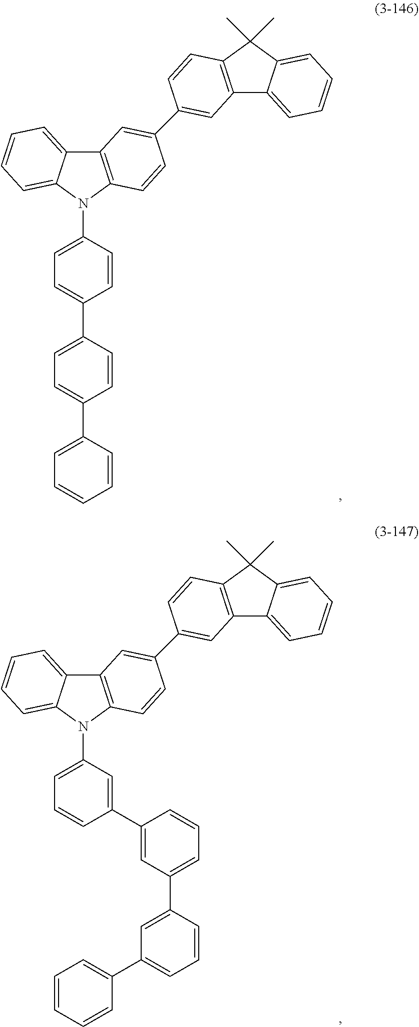

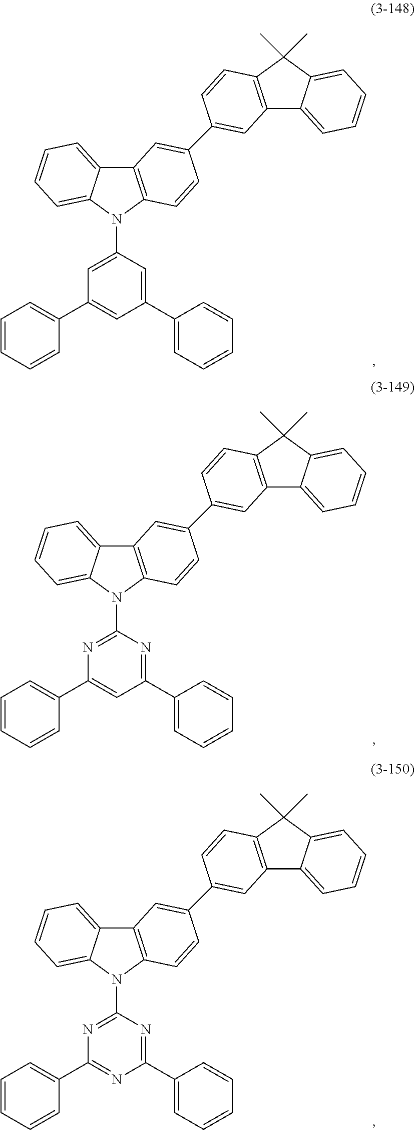

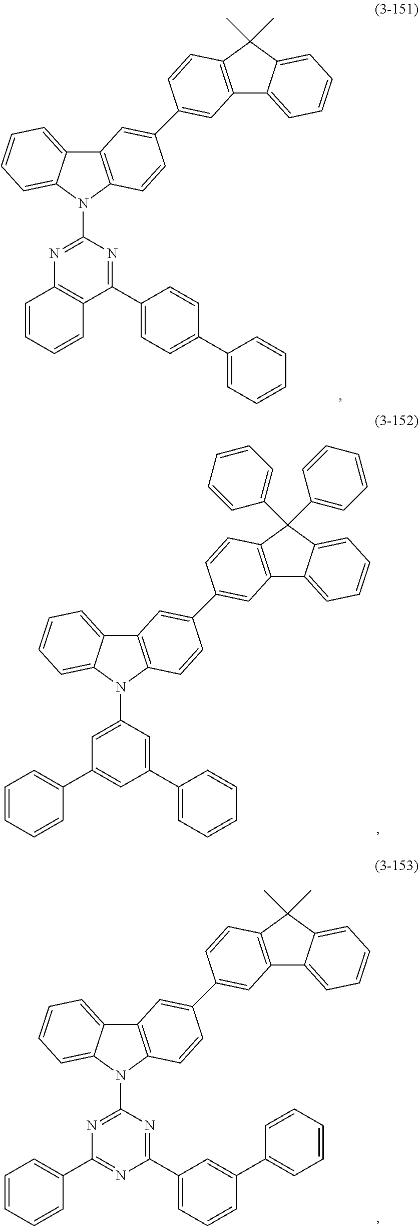

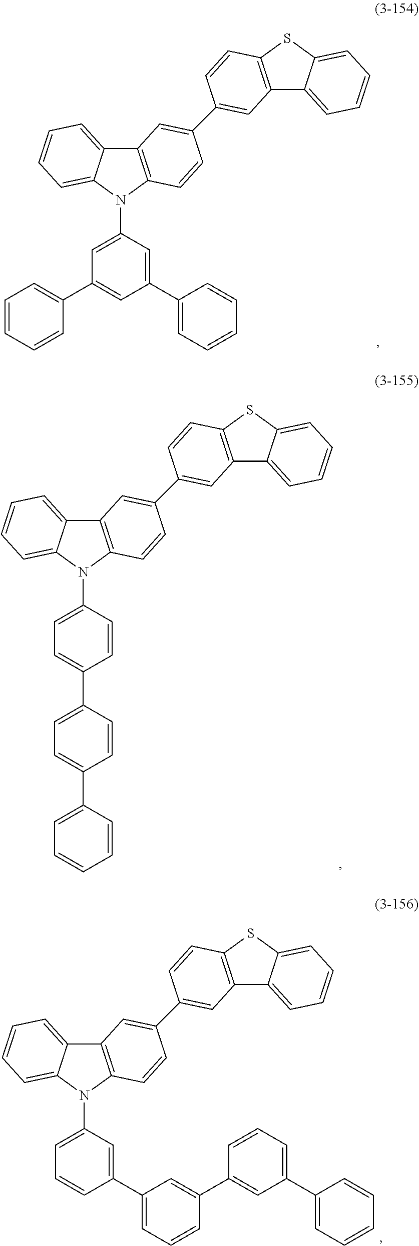

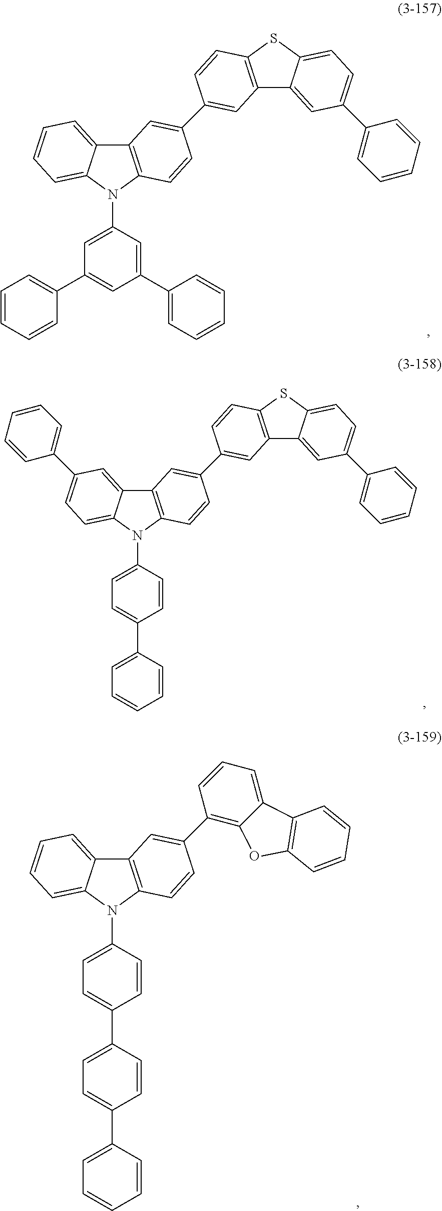

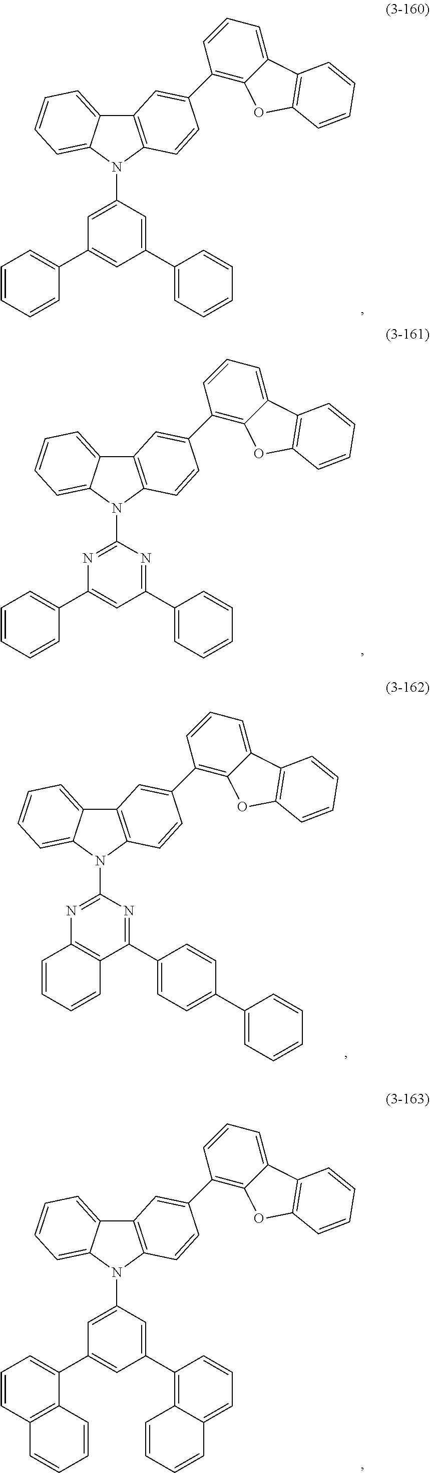

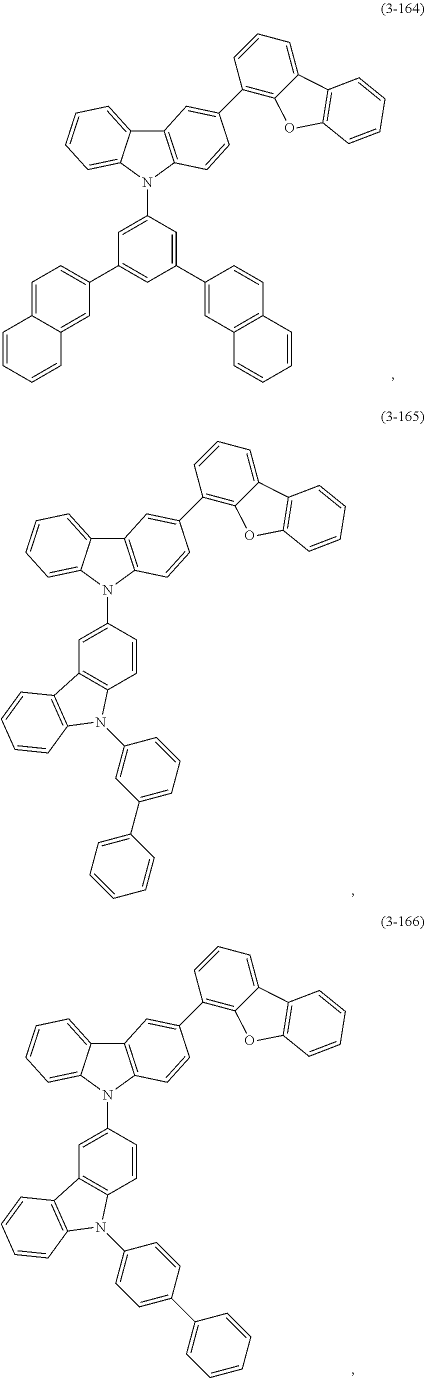

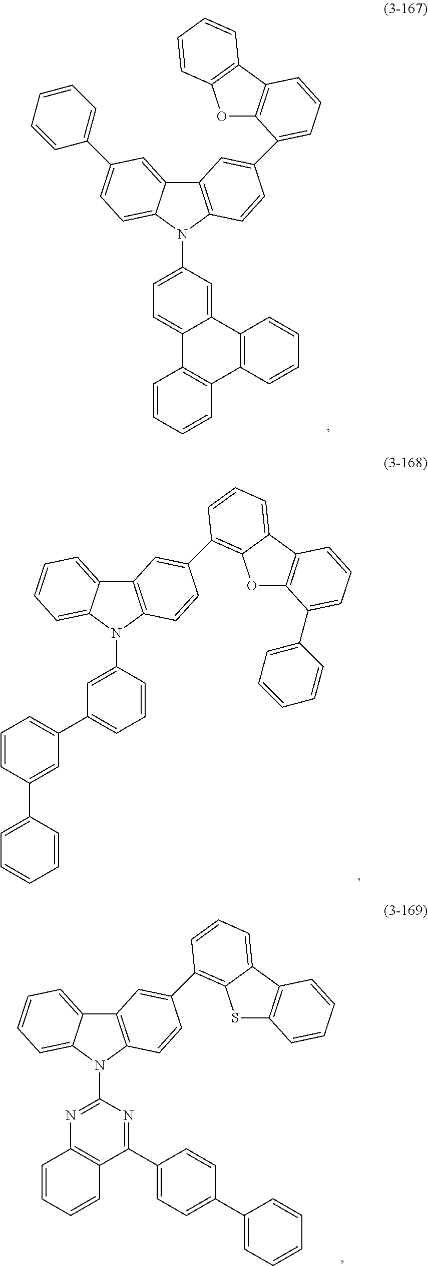

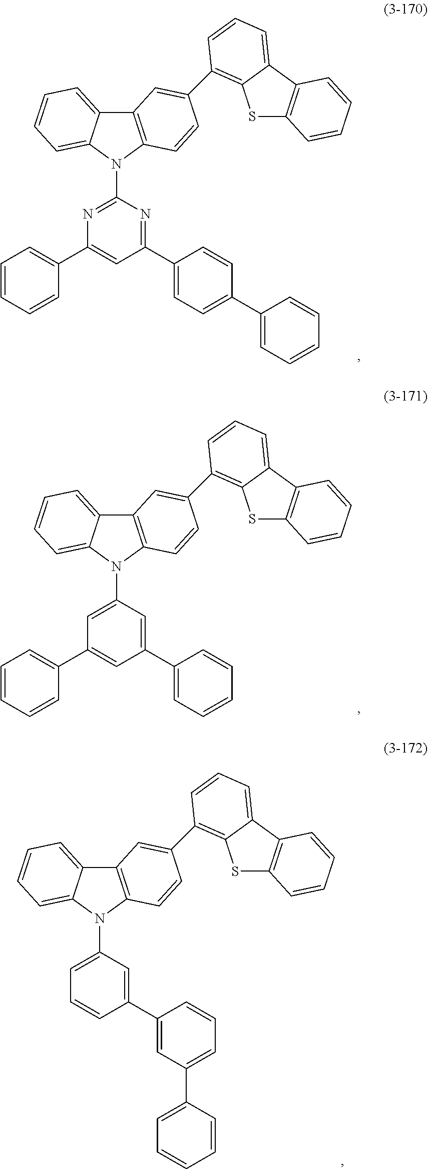

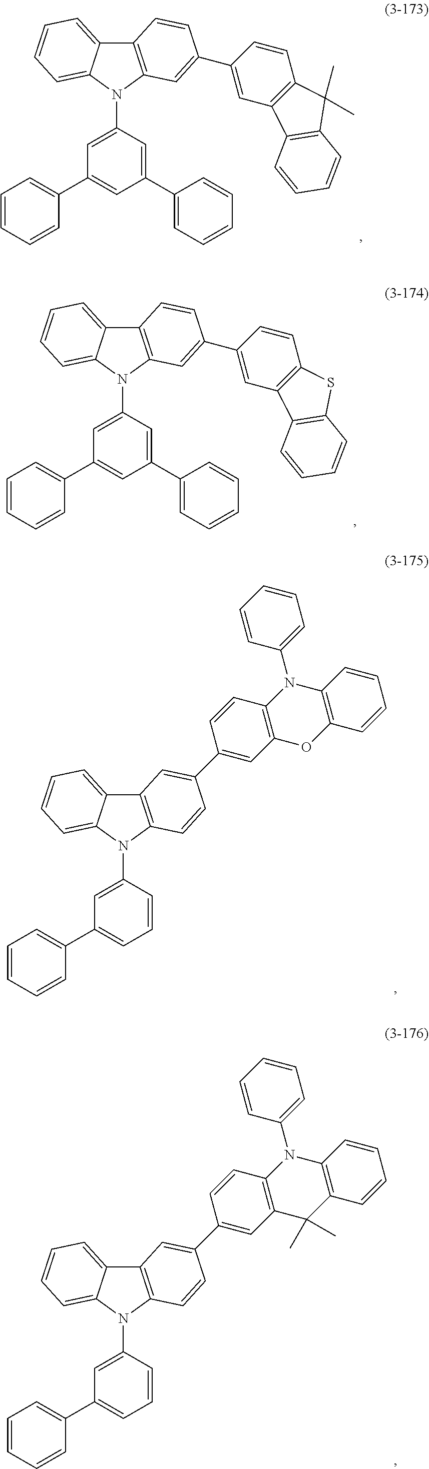

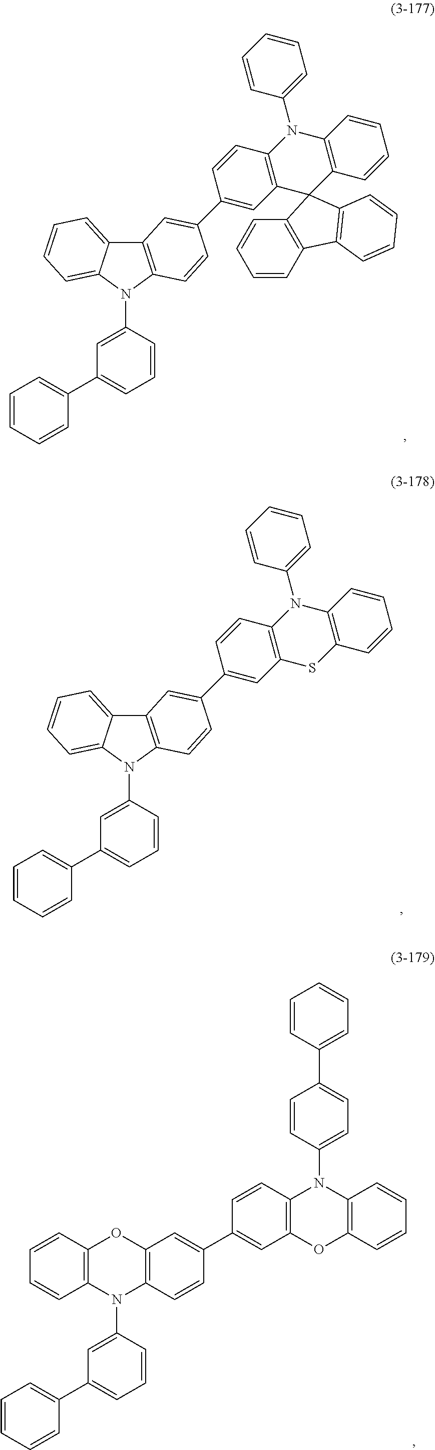

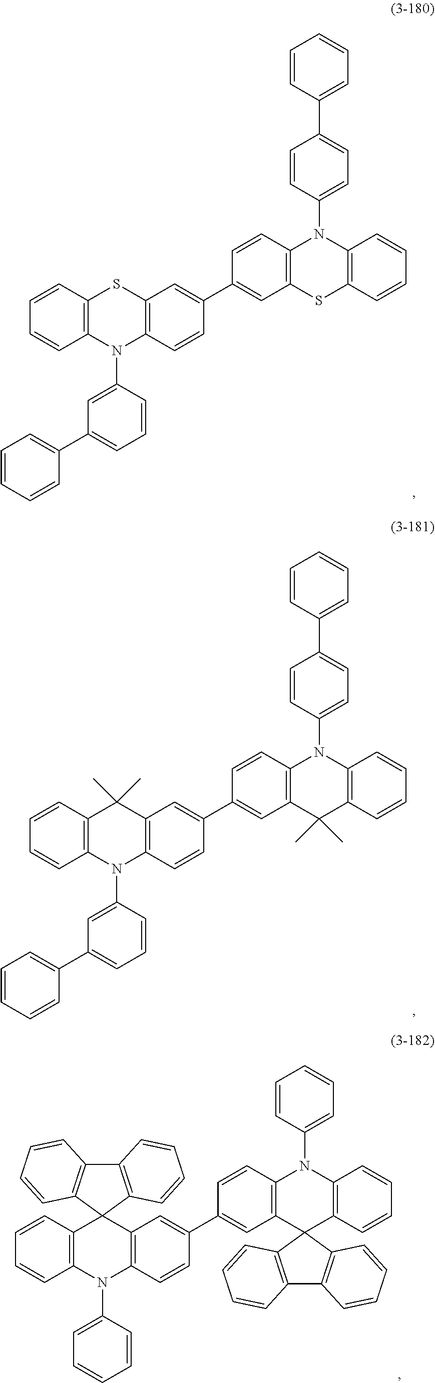

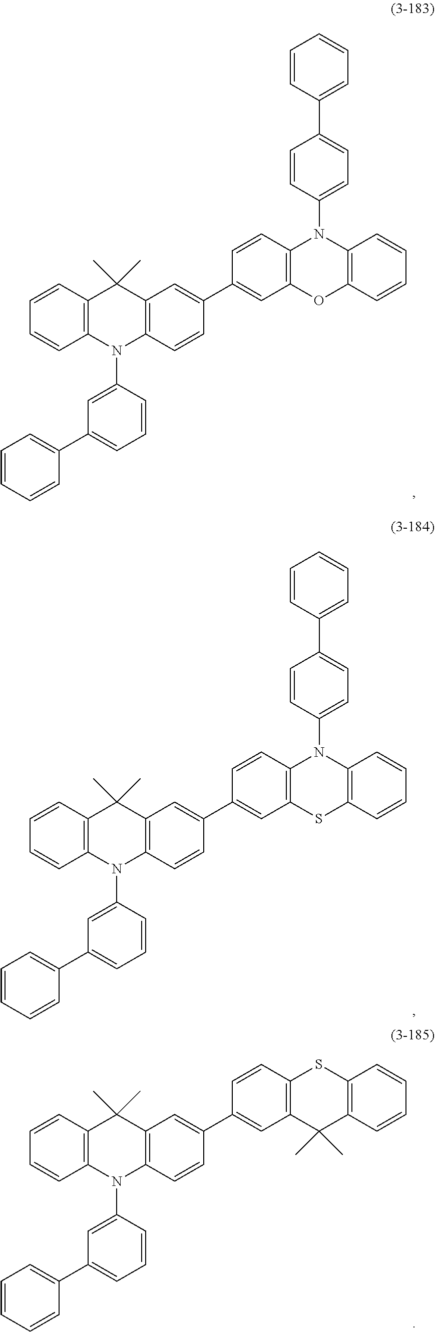

In an embodiment, the organic compound H2 is selected from one of the following structural formulas:

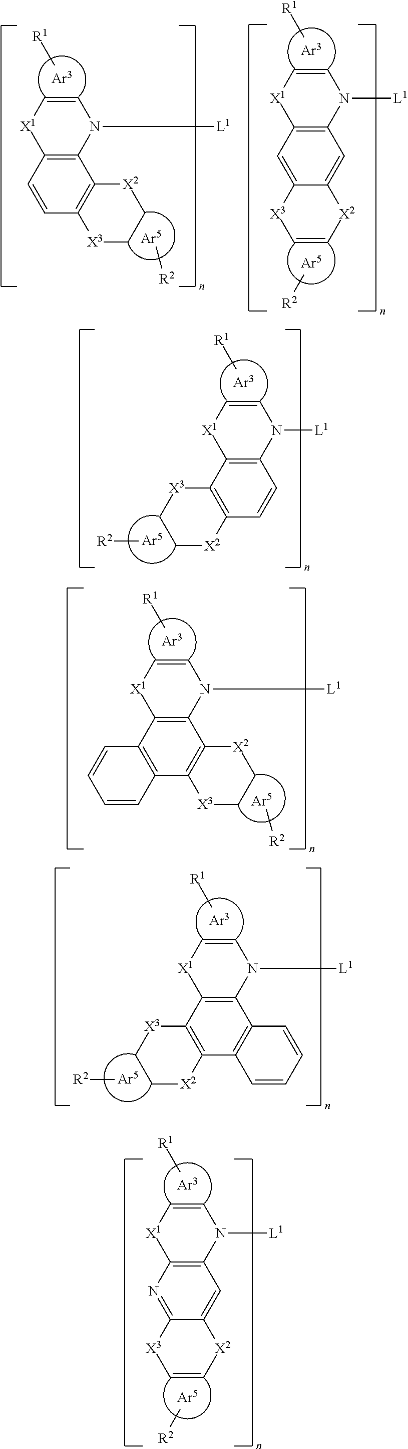

wherein, L¹ is selected from an aromatic group with a ring atom number of 5 to 60 or a heteroaromatic group with a ring atom number of 5 to 60; Ar³ and Ar⁵ are independently selected from an aromatic group with a ring atom number of 5 to 30 or a heteroaromatic group with a ring atom number of 5 to 30; X¹ is selected from a signal bond, N(R), C(R)₂, Si(R)₂, O, C═N(R), C═C(R)₂, P(R), P(═O)R, S, S═O or SO₂; X² and X³ are selected from a signal bond, N(R), C(R)₂, Si(R)₂, O, C═N(R), C═C(R)₂, P(R), P(═O)R, S, S═O or SO₂, X² and X³ are not signal bonds simultaneously; R¹, R² and R are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring; n is selected from 1, 2, 3 or 4.

In an embodiment, the organic compound H2 has a structure represented by the general formula (8):

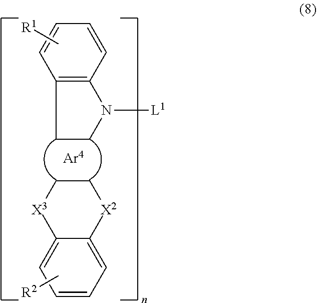

wherein, L¹ is selected from an aromatic group with a ring atom number of 5 to 60 or a heteroaromatic group with a ring atom number of 5 to 60; X² and X³ are selected from a signal bond, N(R), C(R)₂, Si(R)₂, O, C═N(R), C═C(R)₂, P(R), P(═O)R, S, S═O or SO₂, X² and X³ are not signal bonds simultaneously; R¹, R² and R are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring; n is selected from 1, 2, 3 or 4.

Specific examples of the compound represented by the general formula (4) are exemplified below, but not limited to:

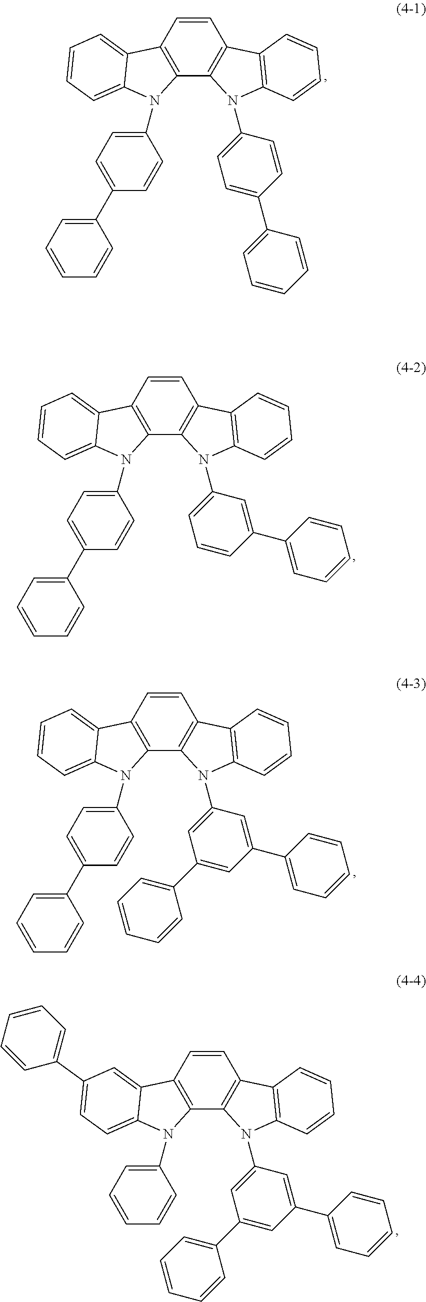

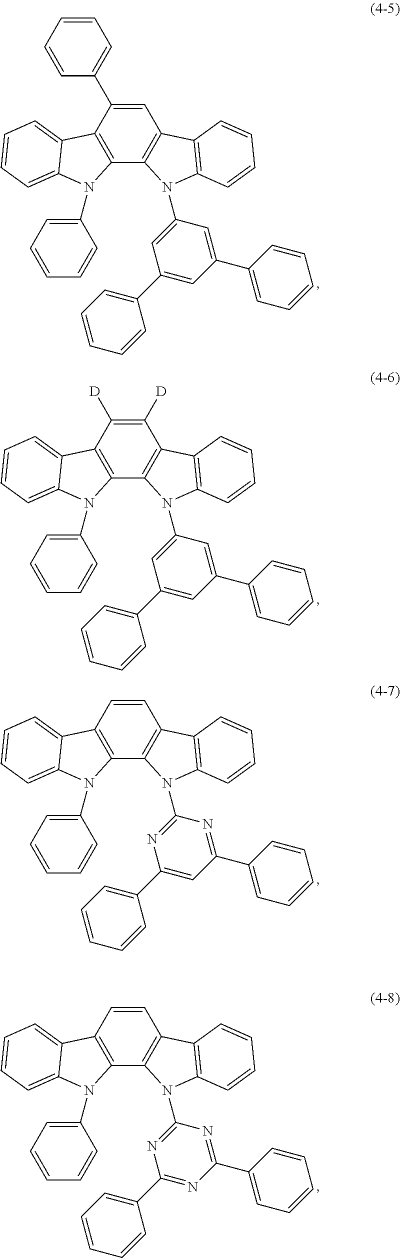

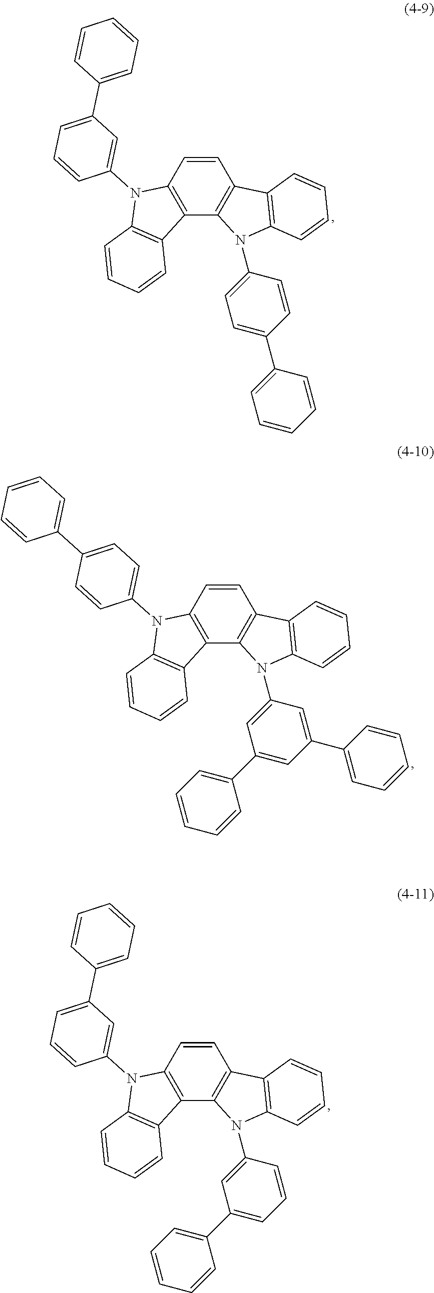

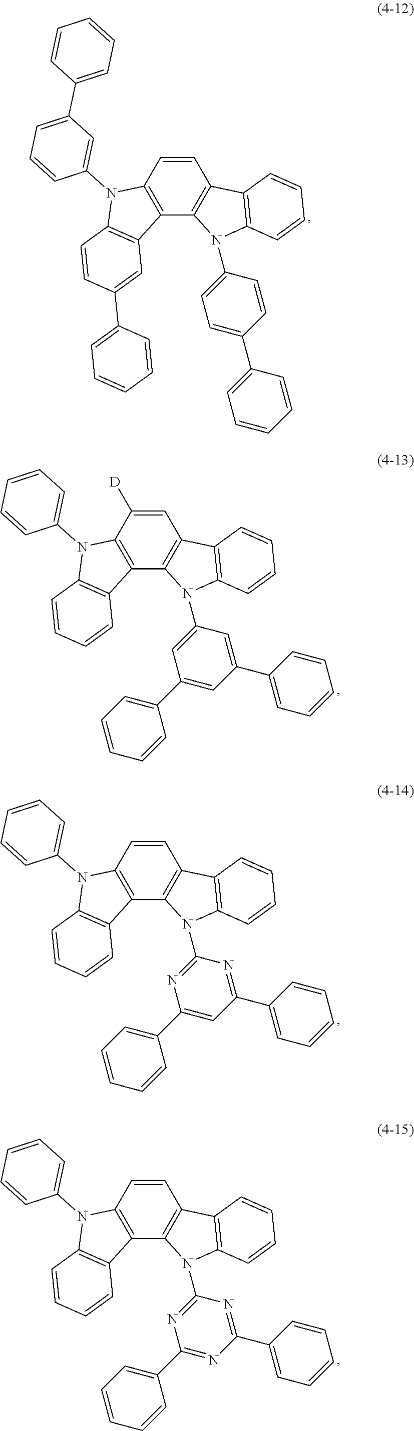

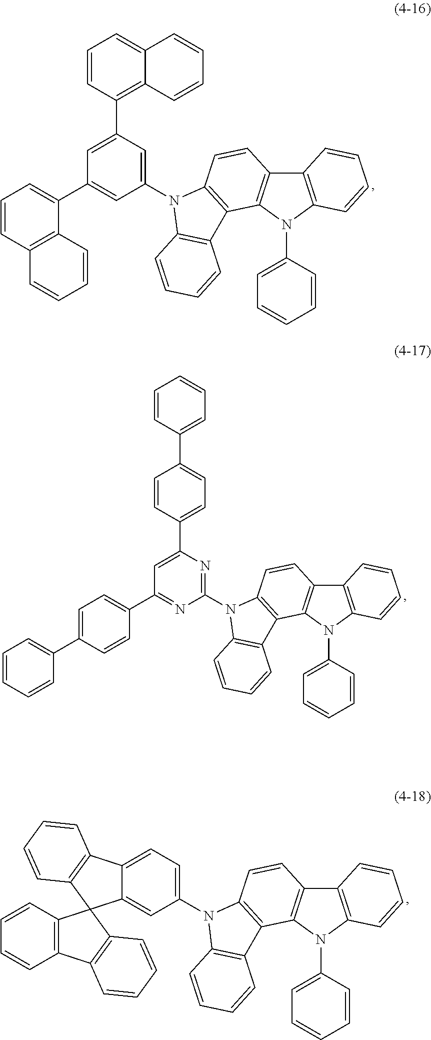

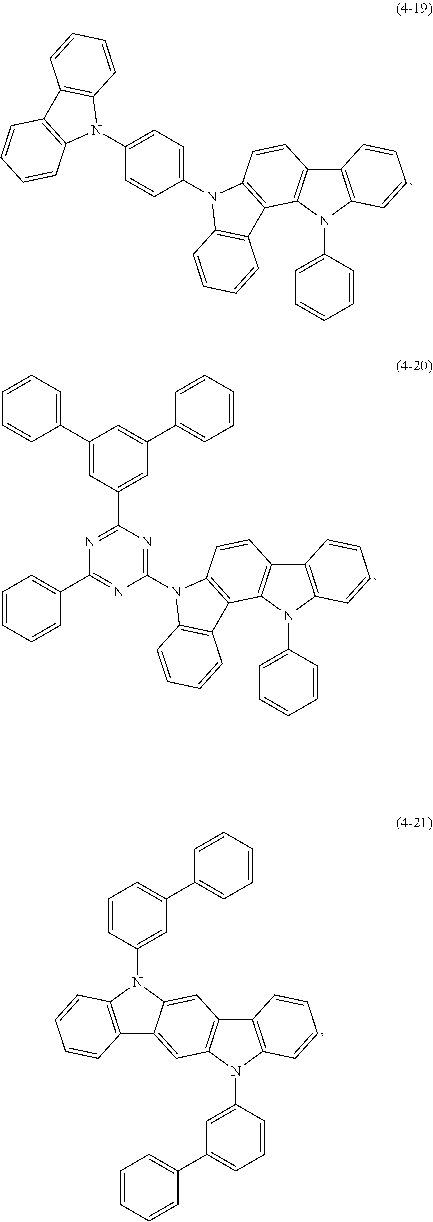

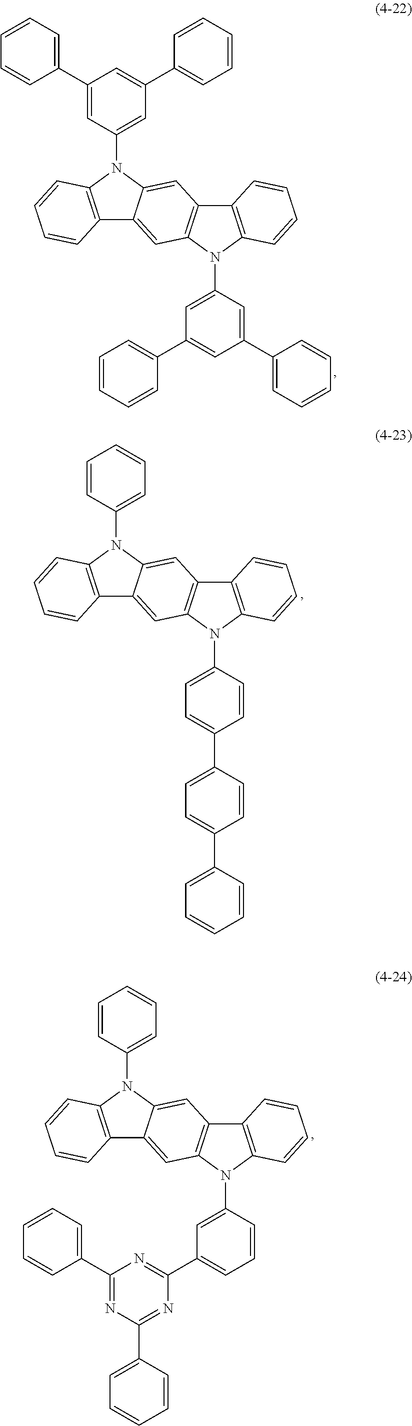

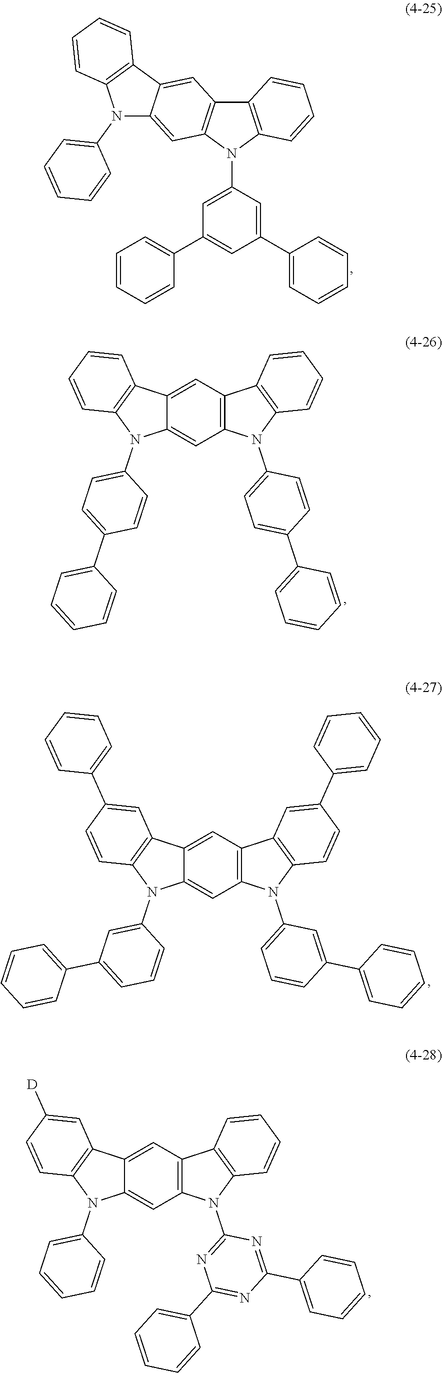

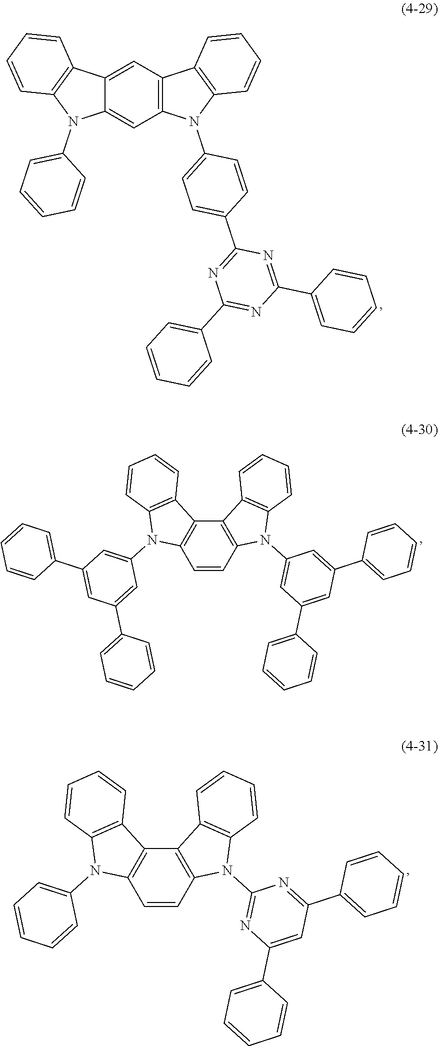

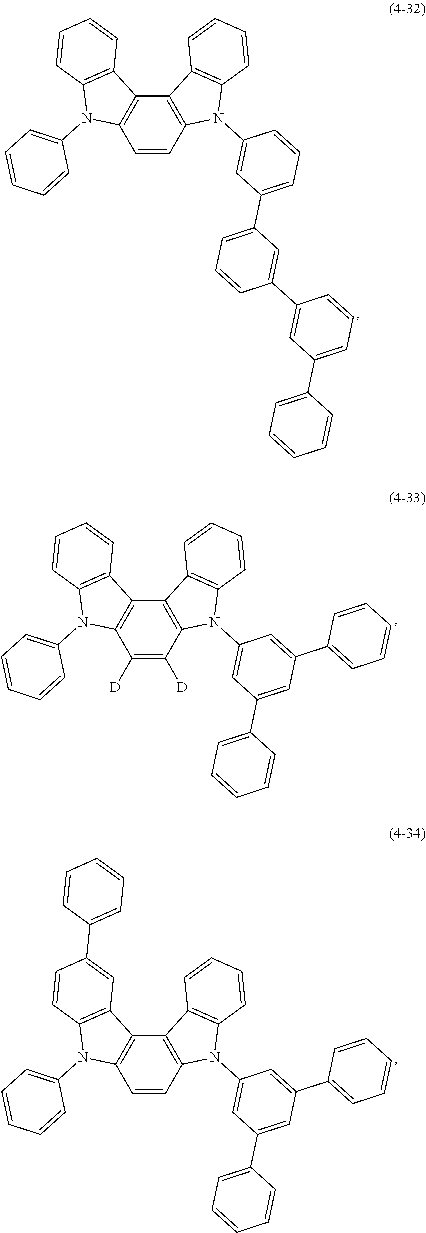

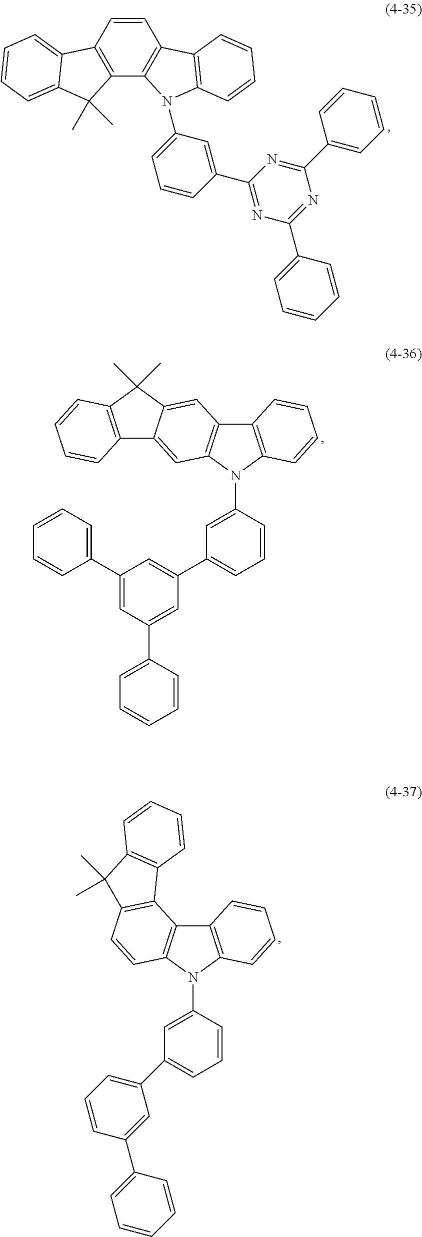

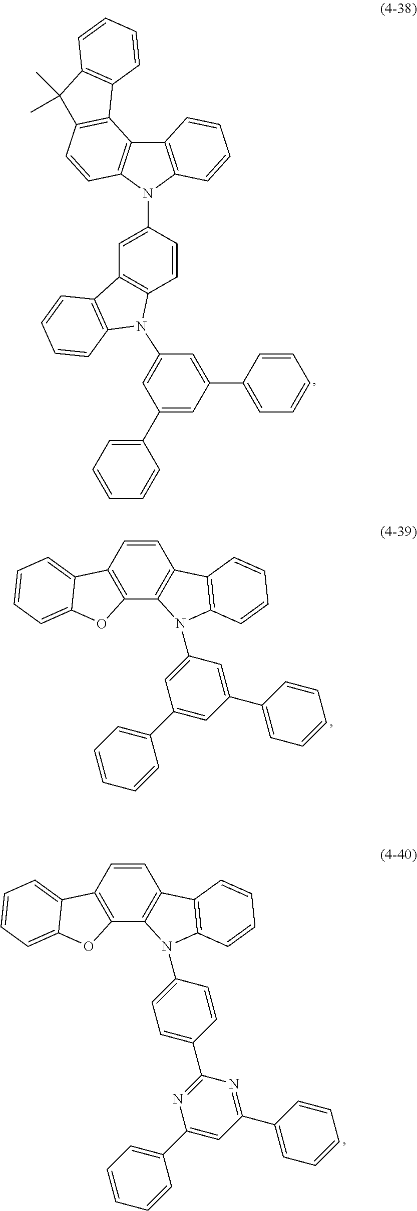

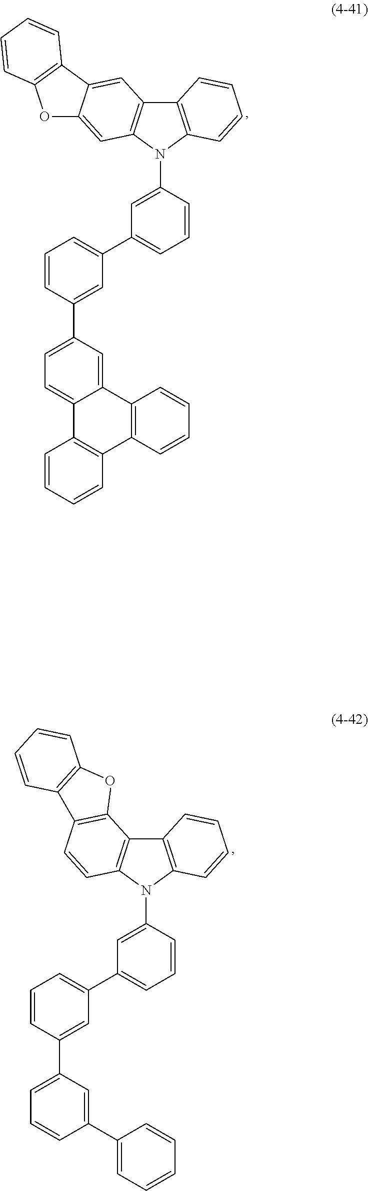

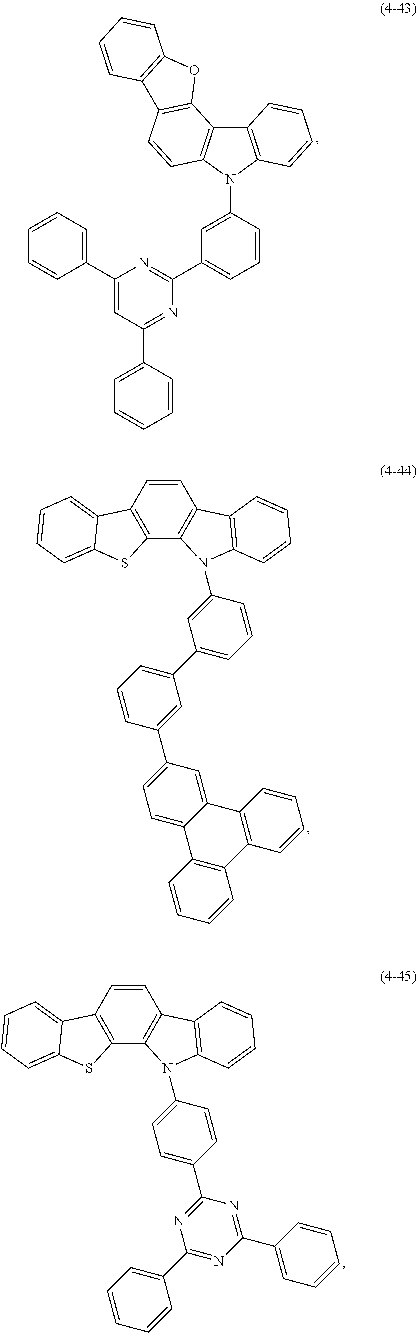

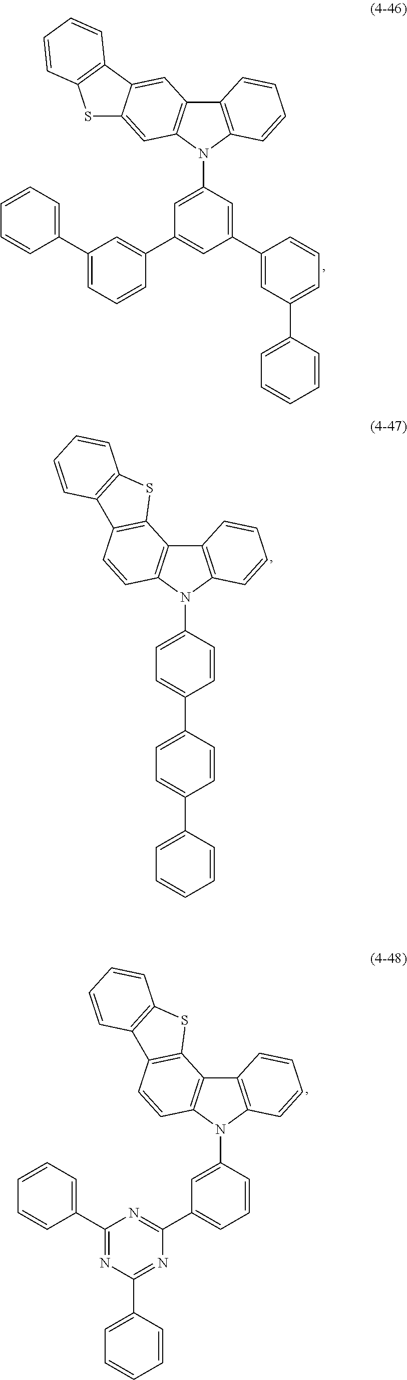

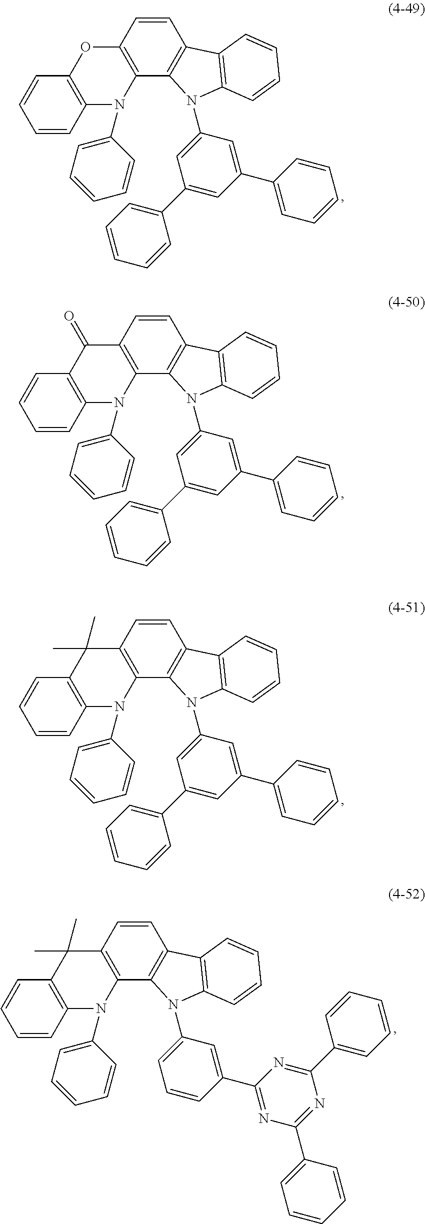

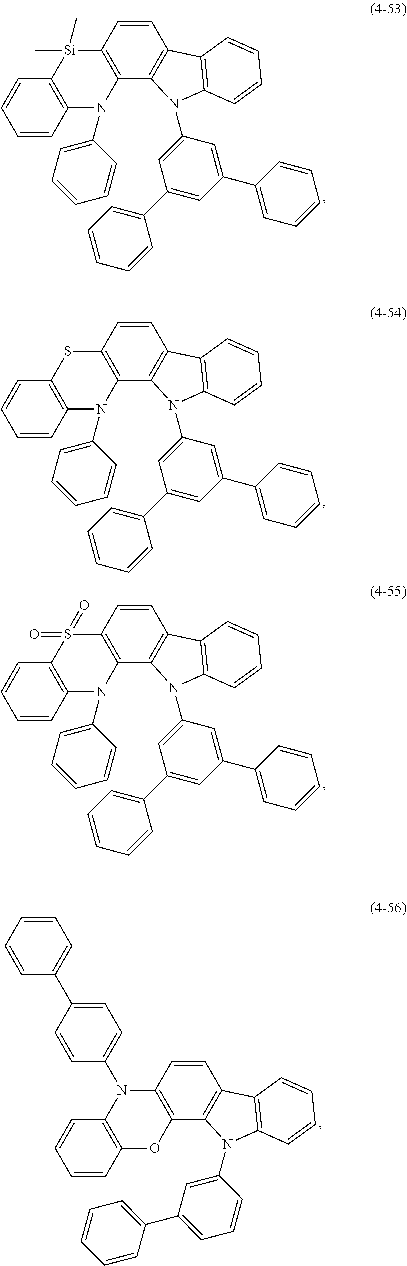

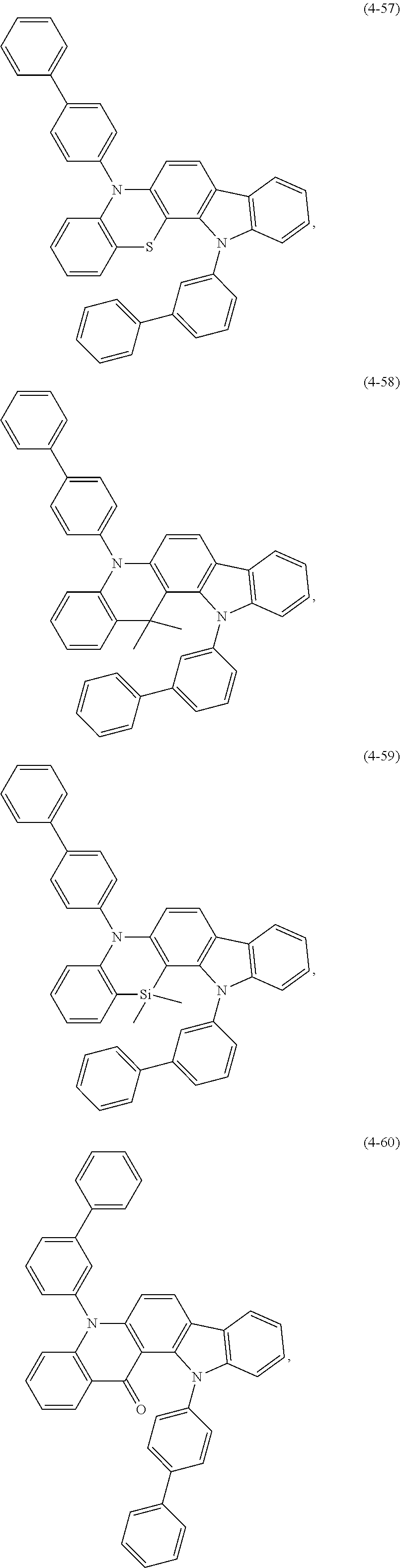

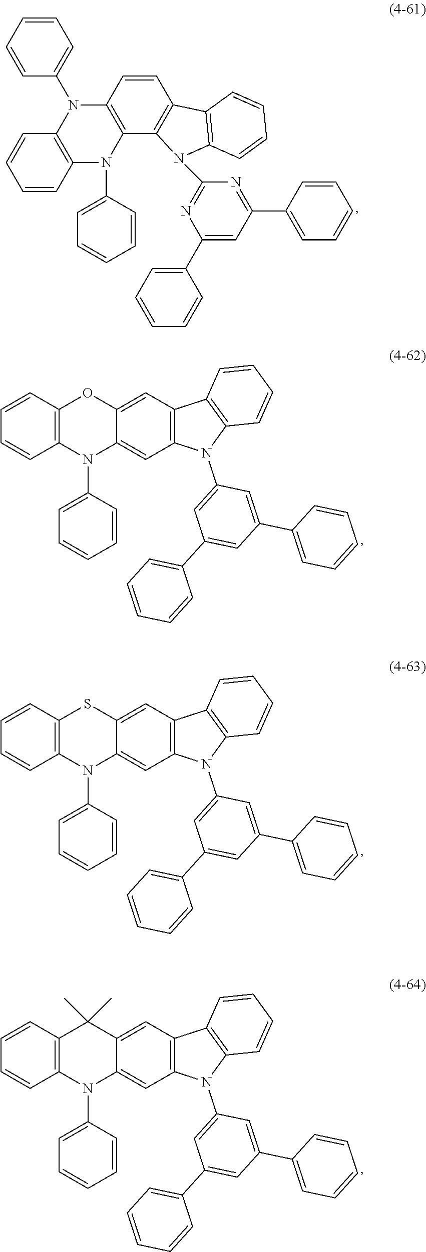

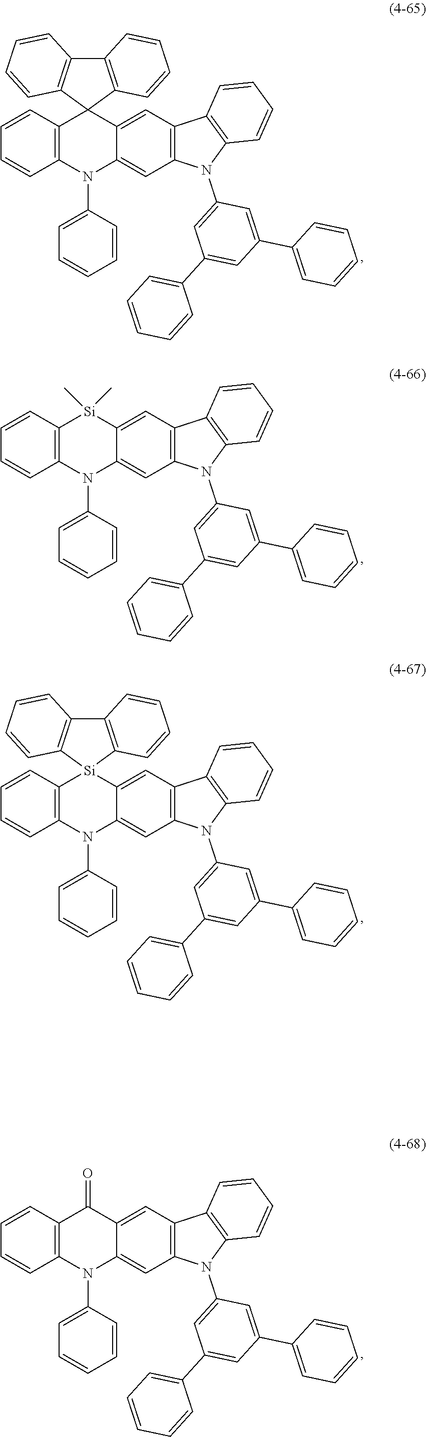

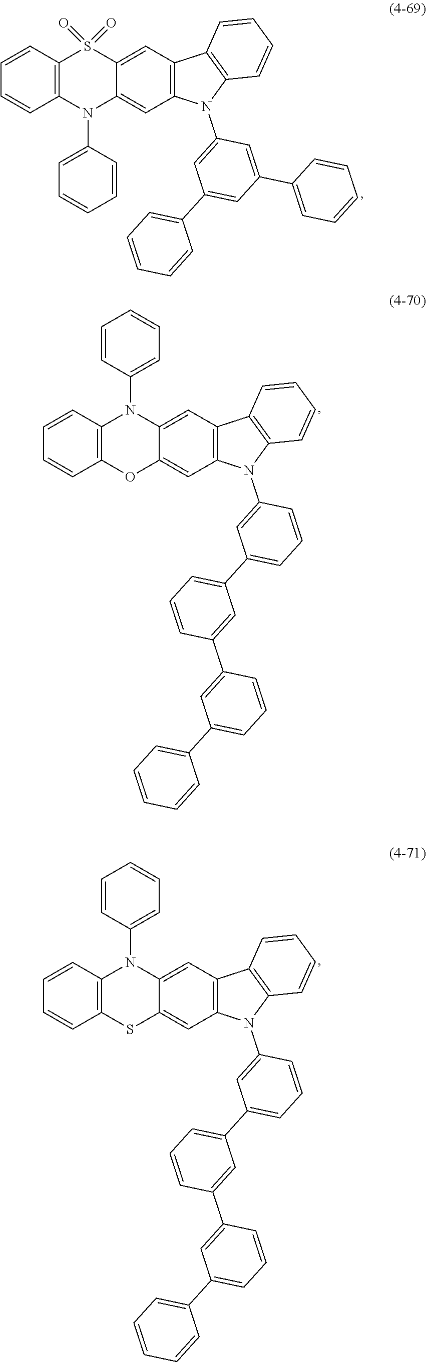

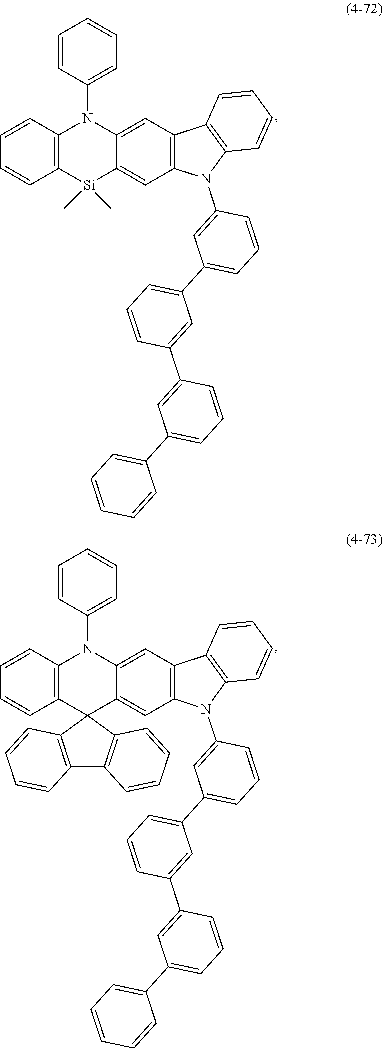

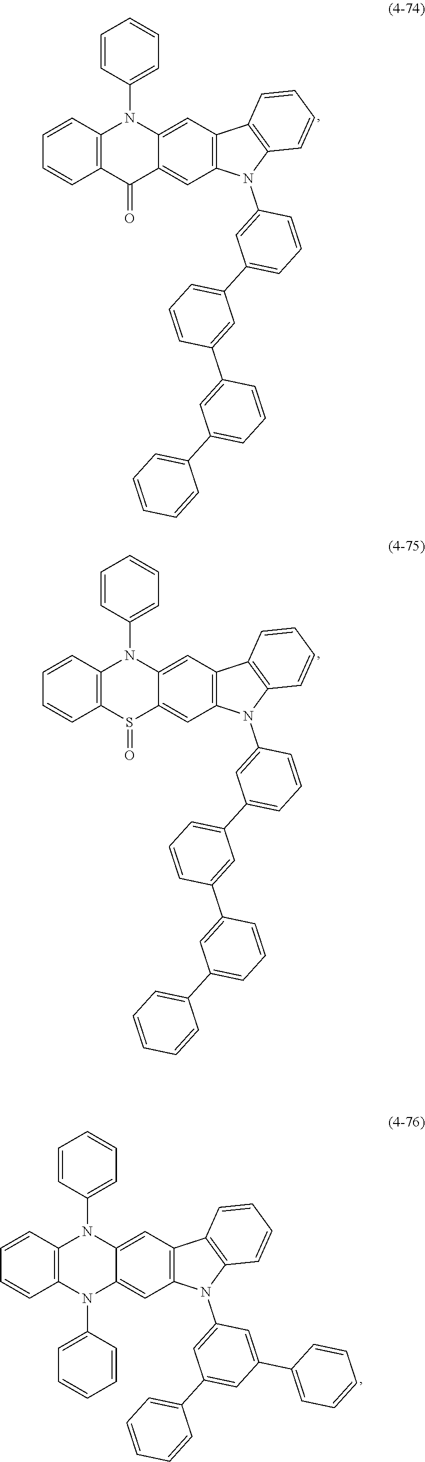

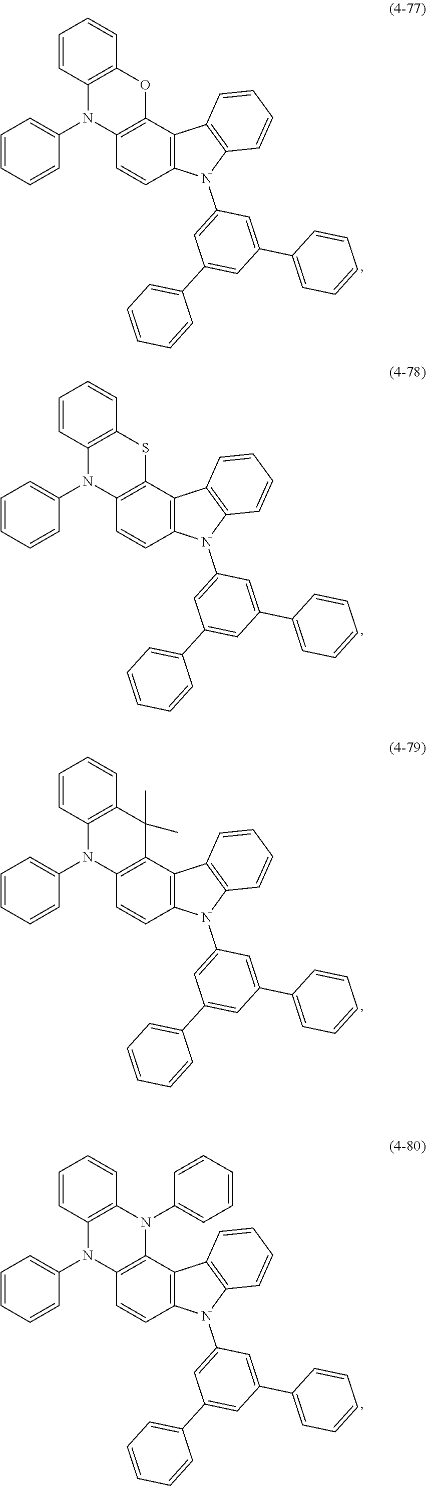

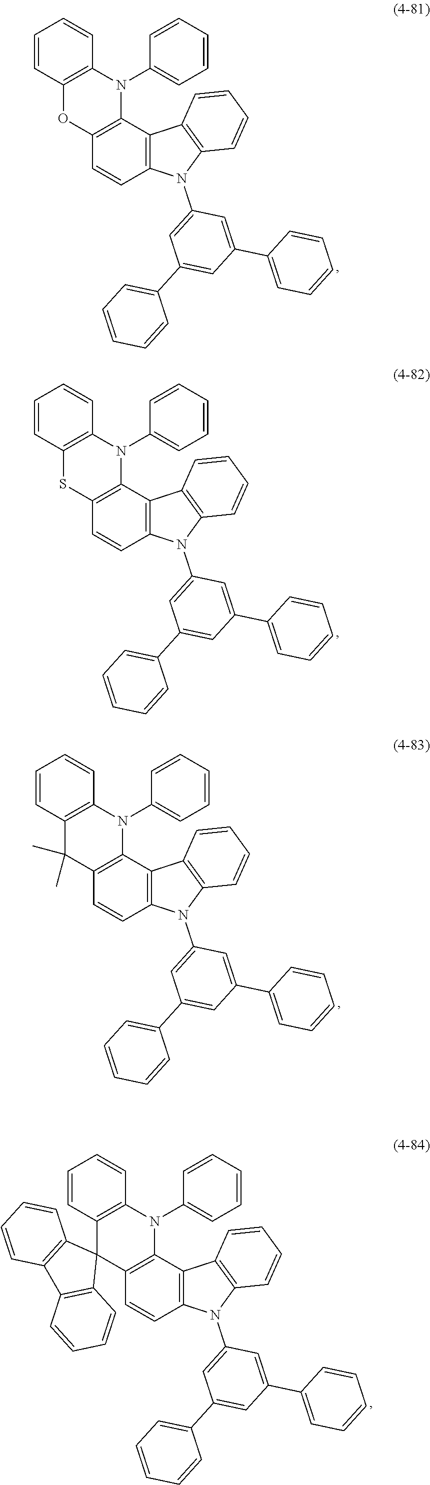

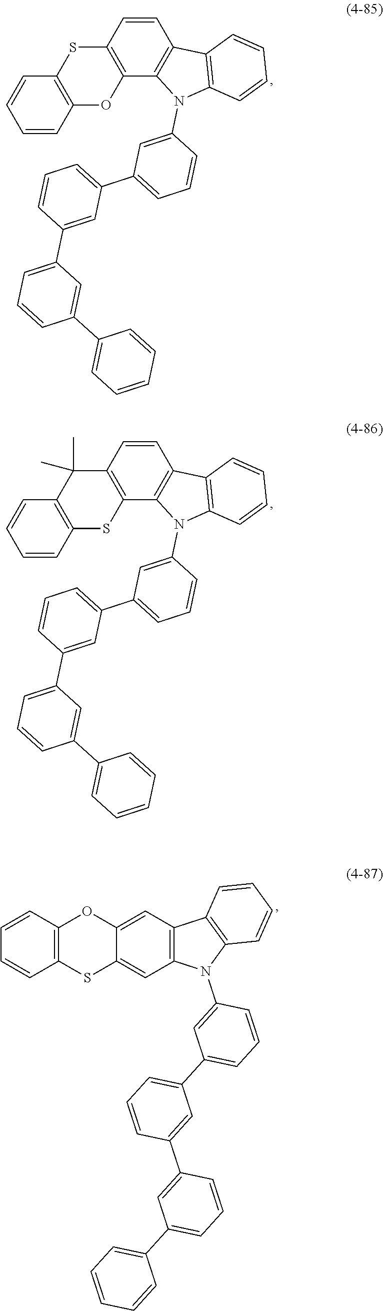

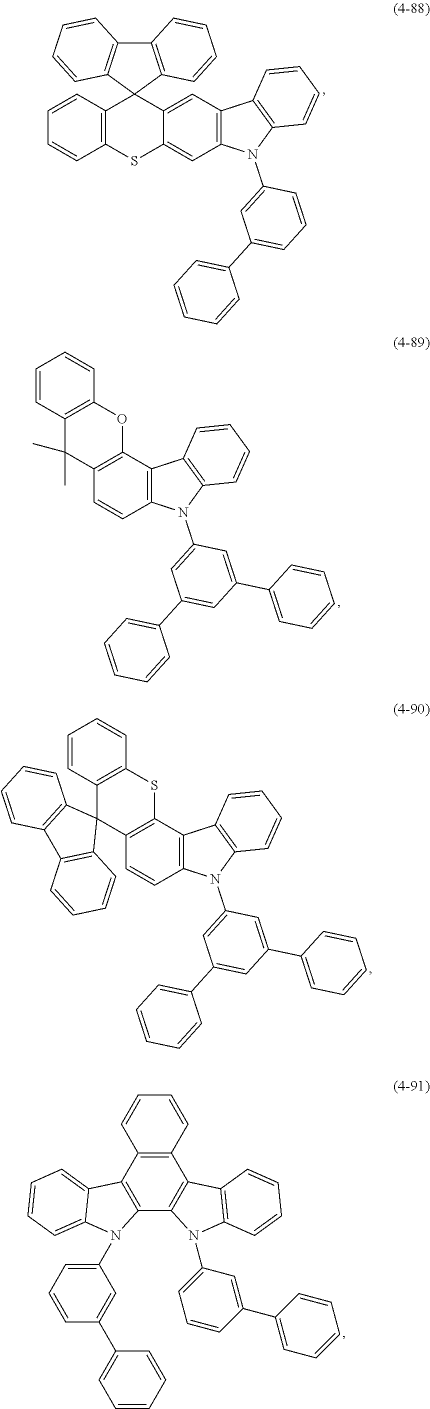

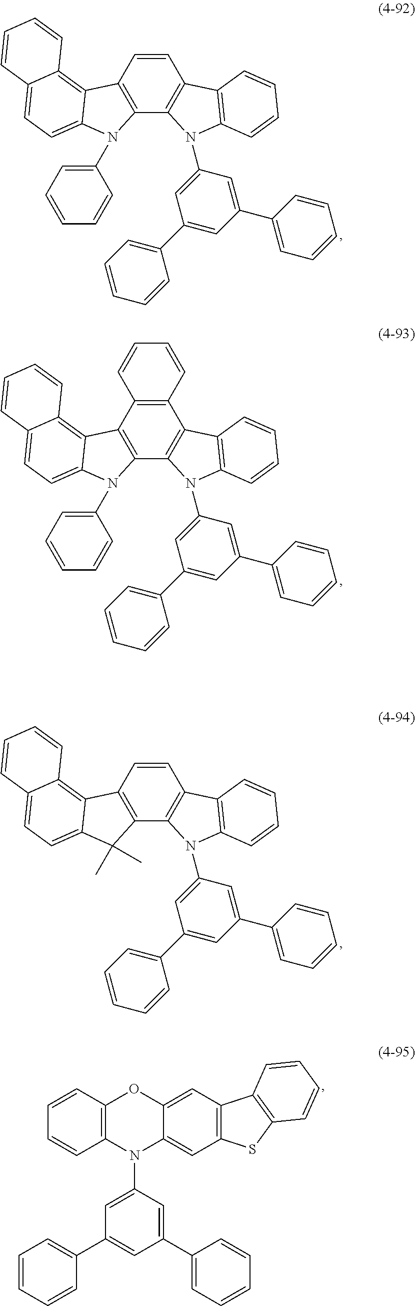

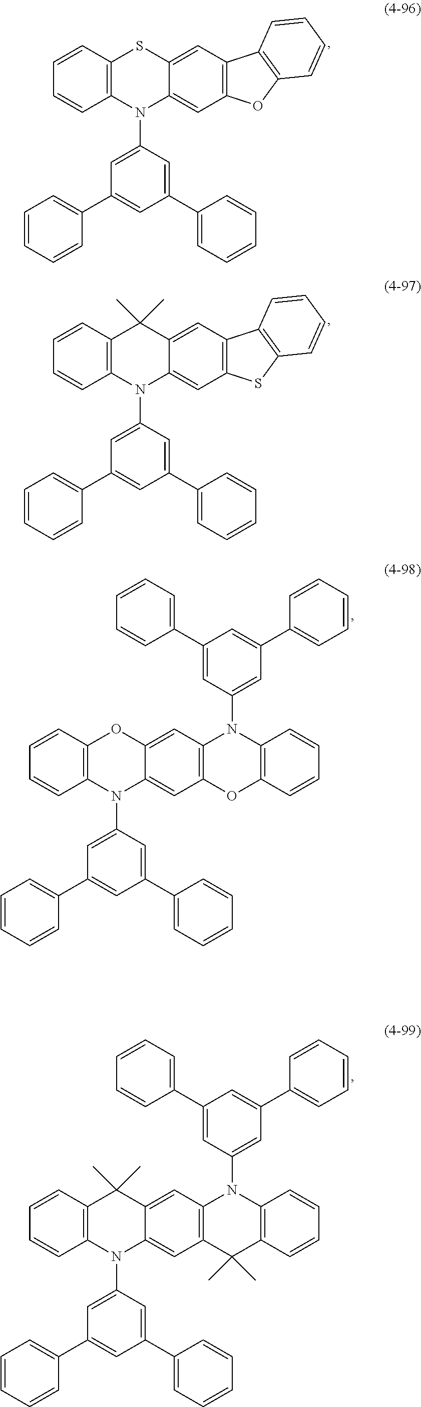

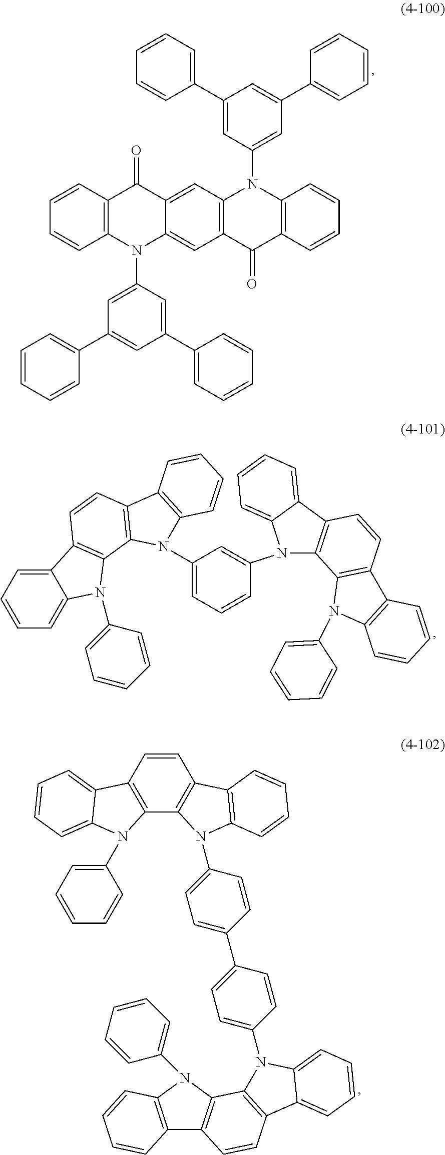

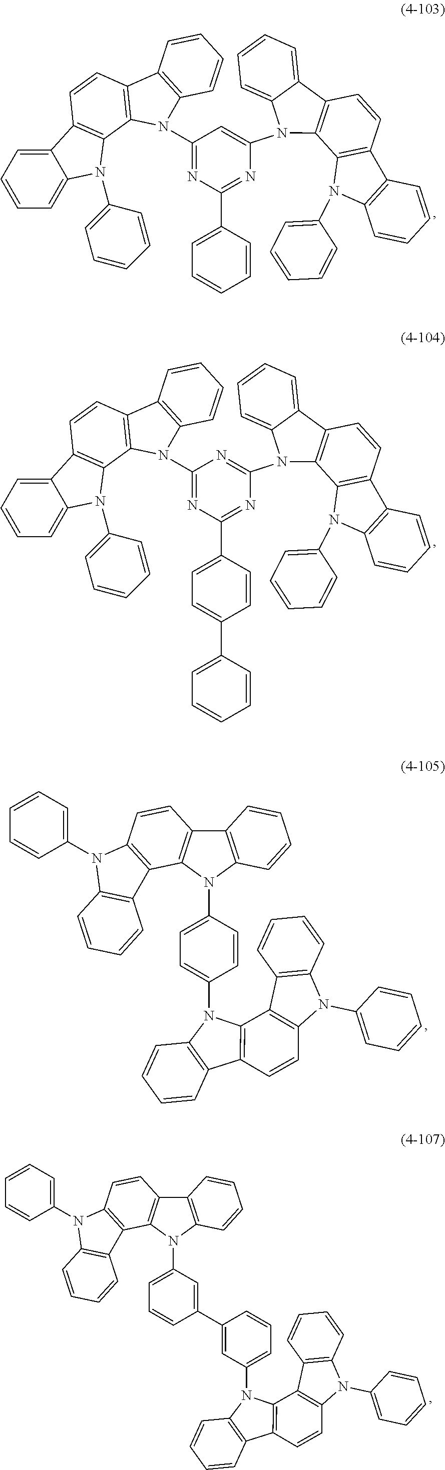

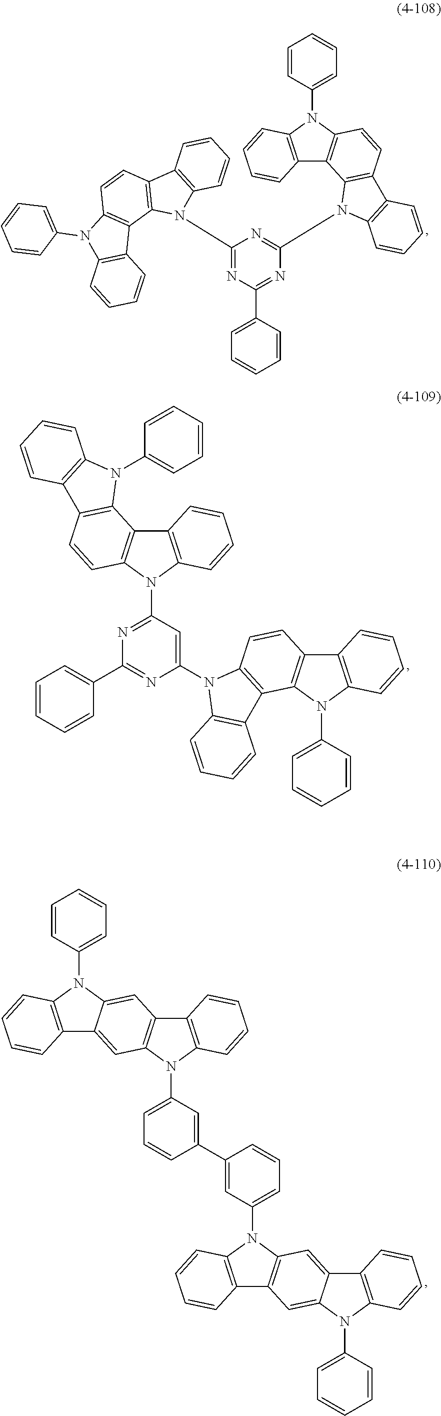

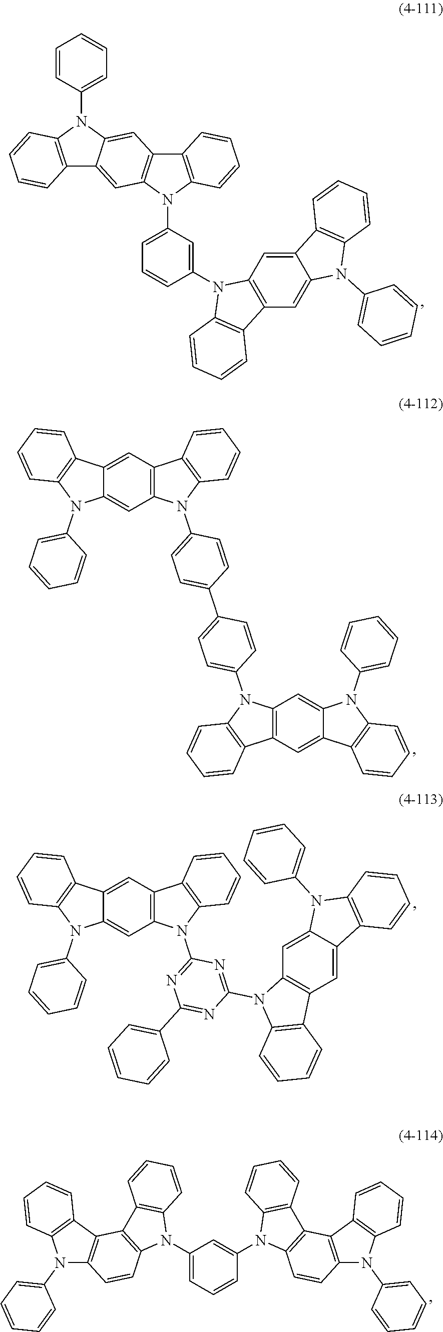

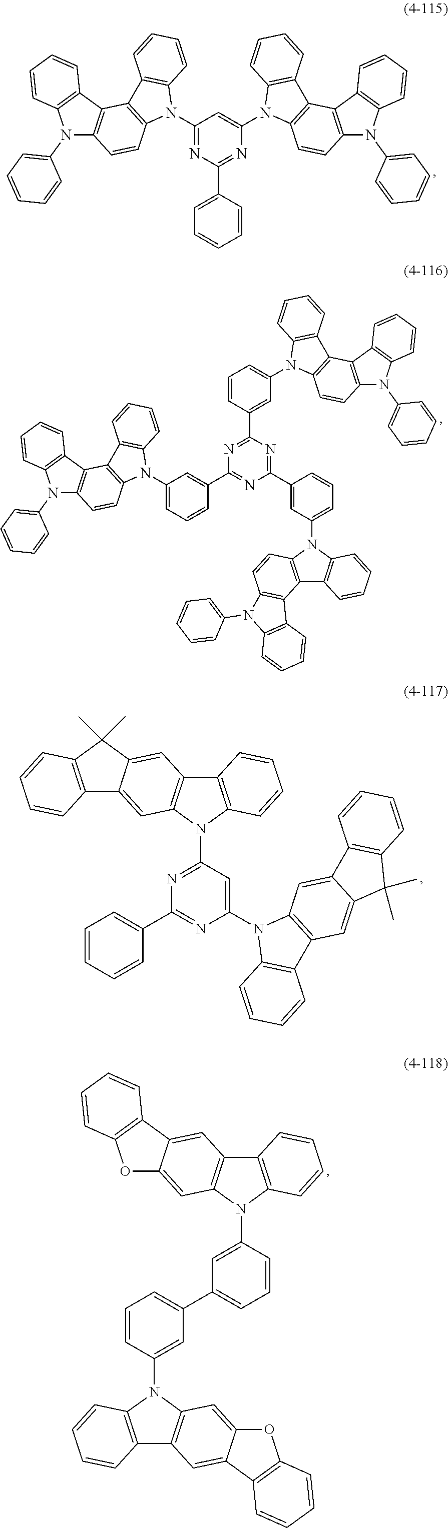

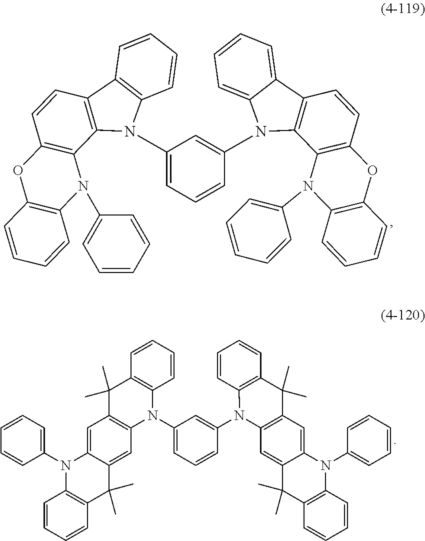

In an embodiment, the organic compound H2 is selected from one of the following structural formulas:

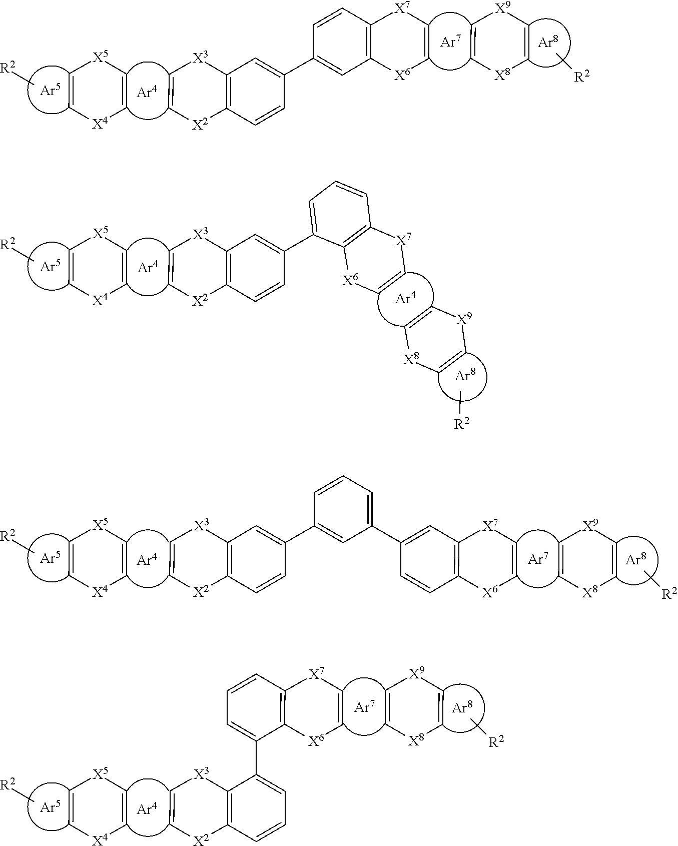

wherein, Ar⁴, Ar⁵, Ar⁷, Ar⁸, Ar⁷ and Ar⁸ are independently selected from an aromatic group with a ring atom number of 5 to 30 or a heteroaromatic group with a ring atom number of 5 to 30;

X², X³, X⁴, X⁵, X⁶, X⁷, X⁸ and X⁹ are independently selected from a single bond, N(R), C(R)₂, Si(R)₂, O, C═N(R), C═C(R)₂, P(R), P(═O)R, S, S═O or SO₂, and X² and X³ are not single bonds simultaneously, X⁴ and X⁵ are not both single bonds simultaneously, X⁶ and X⁷ are not both single bonds simultaneously, and X⁸ and X⁹ are not both single bonds simultaneously; R¹, R² and R are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring.

In an embodiment, the organic compound H2 has a structure represented by the general formula (9):

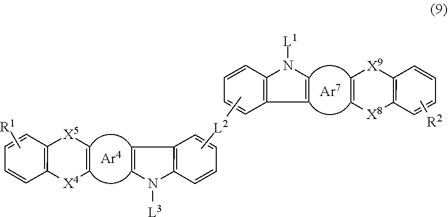

wherein, Ar⁴ and Ar⁷ are independently selected from an aromatic group with a ring atom number of 5 to 30 or a heteroaromatic group with a ring atom number of 5 to 30;

X⁴, X⁵, X⁸ and X⁹ are selected from a signal bond, N(R), C(R)₂, Si(R)₂, O, C═N(R), C═C(R)₂, P(R), P(═O)R, S, S═O or SO₂, X⁴ and X⁵ are not signal bonds simultaneously, and X⁸ and X⁹ are not signal bonds simultaneously; R¹, R² and R are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring.

Specific examples of the compound represented by the general formula (5) are exemplified below, but not limited to:

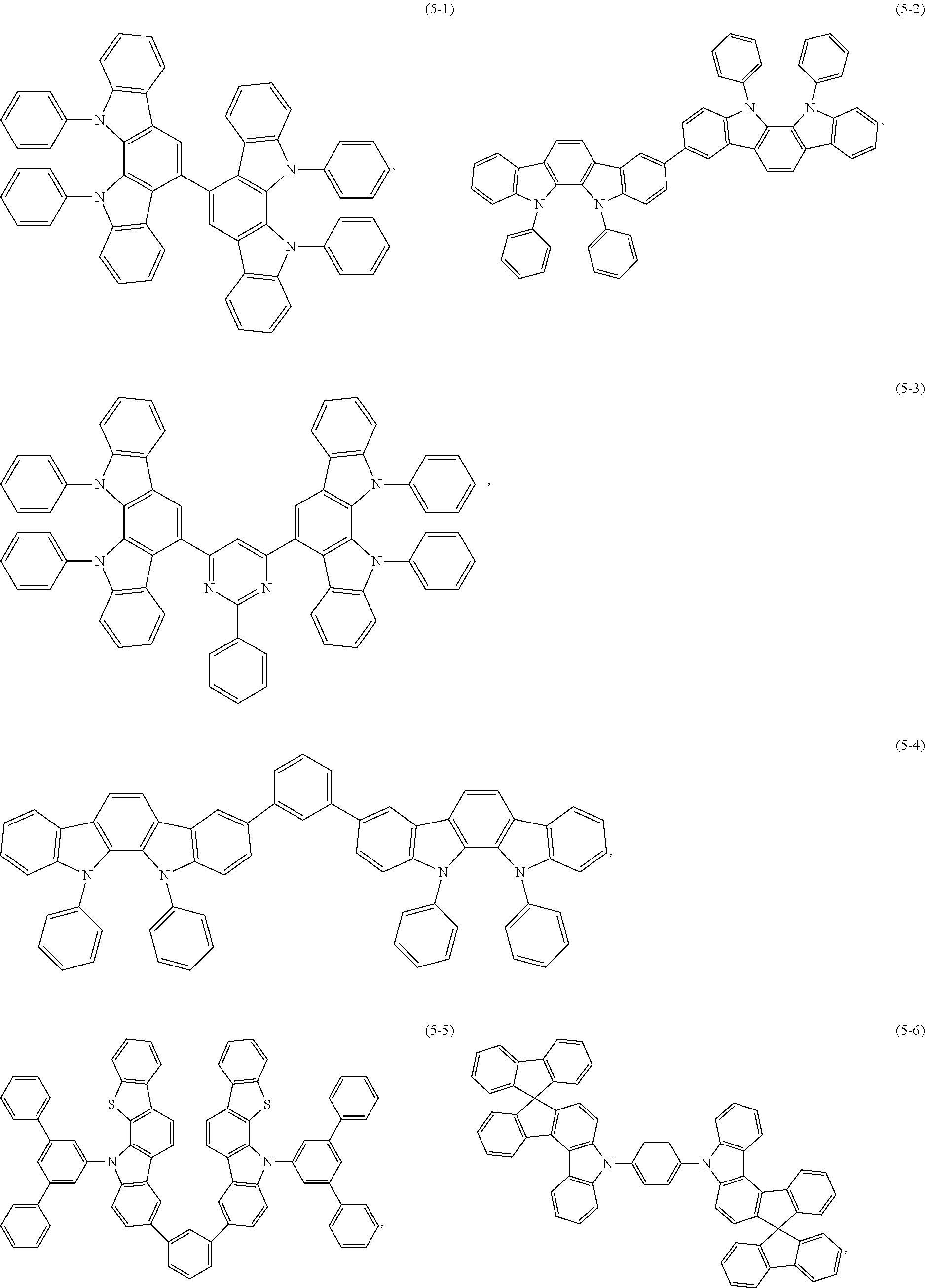

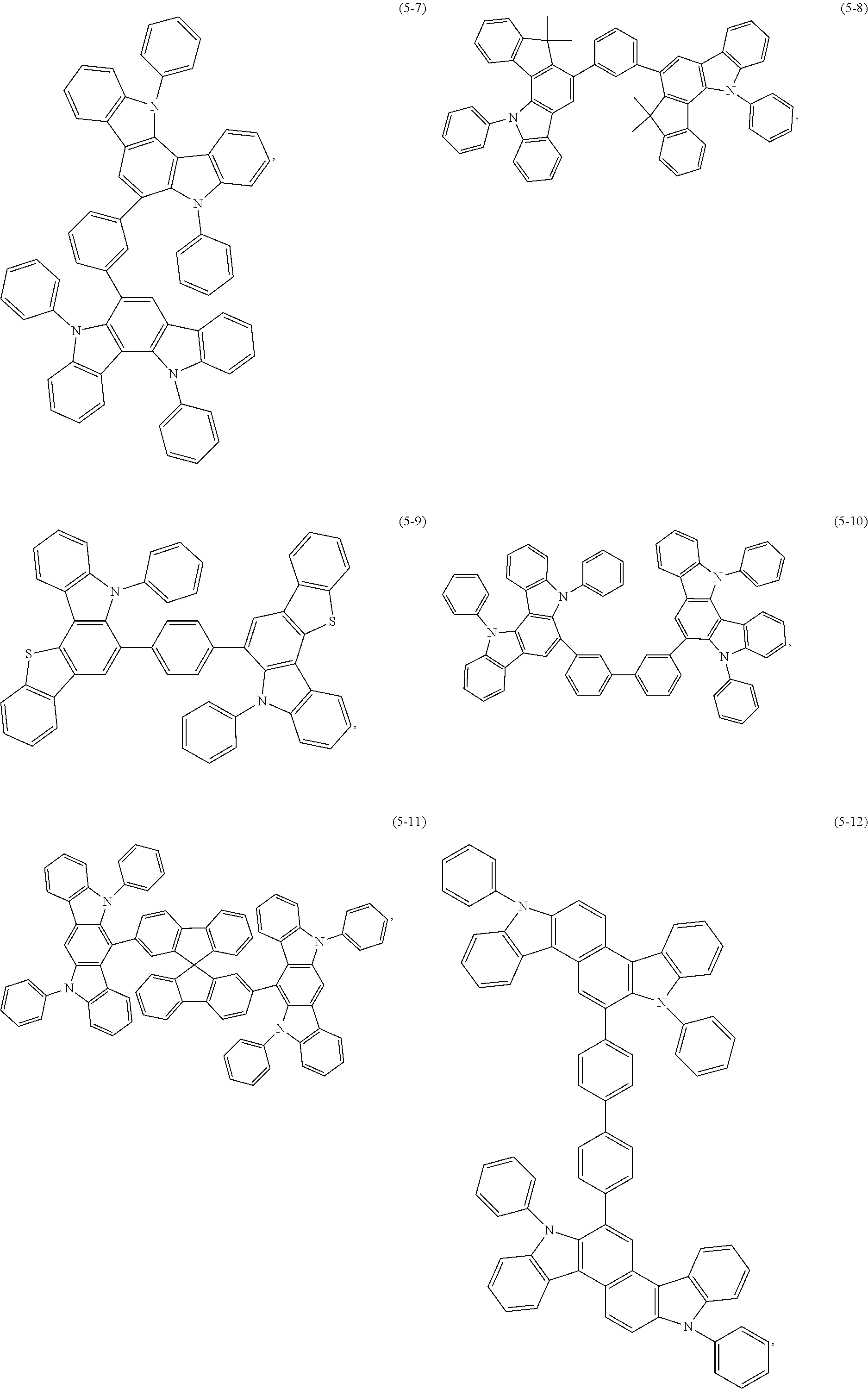

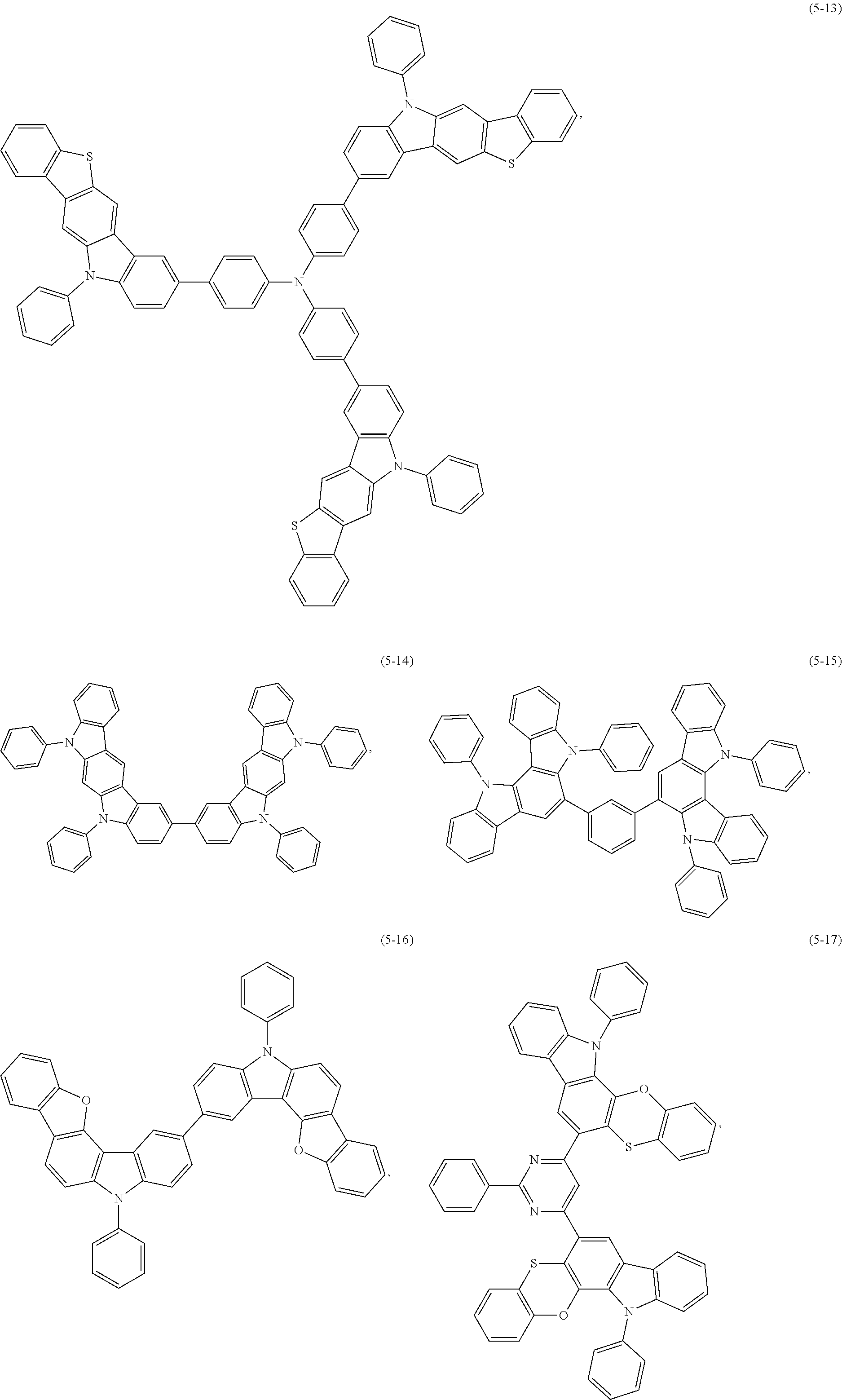

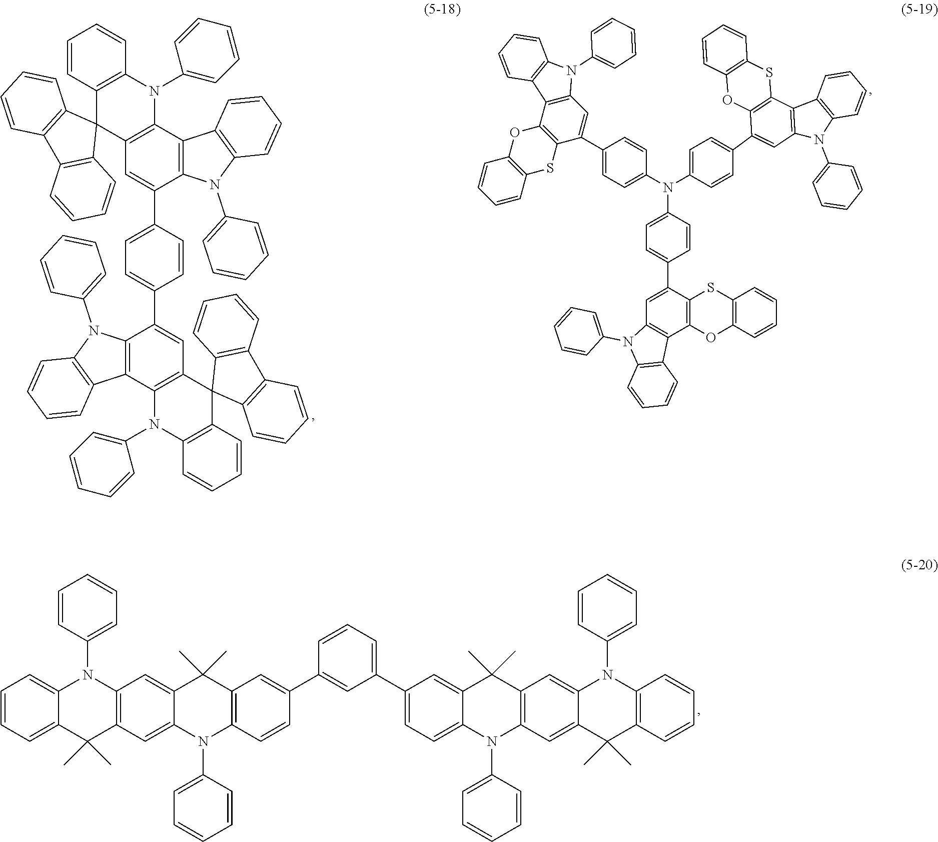

In an embodiment, since the organic compound H1 has electron transporting properties and the organic compound H2 has hole transporting properties, a type II semiconductor heterojunction can be formed between the organic compound H1 and the organic compound H2.

In an embodiment, the molar ratio of the organic compound H1 to the organic compound H2 is from 2:8 to 8:2. Further, the molar ratio of the organic compound H1 to the organic compound H2 is from 3:7 to 7:3. Still further, the molar ratio of the organic compound H1 to the organic compound H2 is from 4:6 to 6:4. Further, the molar ratio of the organic compound H1 to the organic compound H2 is from 4.5:5.5 to 5.5:4.5.

In an embodiment, the difference between the molecular weight of the organic compound H1 and the molecular weight of the organic compound H2 in the organic mixture is no greater than 100 g/mol, Further, the difference between the molecular weight of the organic compound H1 and the molecular weight of the organic compound H2 is no greater than 80 g/mol. Further, the difference between the molecular weight of the organic compound H1 and the molecular weight of the organic compound H2 is no greater than 70 g/mol. Further, the difference between the molecular weight of the organic compound H1 and the molecular weight of the organic compound H2 is no greater than 60 g/mol.

Further, the difference between the molecular weight of the organic compound H1 and the molecular weight of the organic compound H2 is no greater than 40 g/mol. Still further, the difference between the molecular weight of the organic compound H1 and the molecular weight of the organic compound H2 is no greater than 30 g/mol.

In an embodiment, in the organic mixture, the difference between the sublimation temperature of the organic compound H1 and that of the organic compound H2 is no greater than 50 K. Further, the difference between the sublimation temperature of the organic compound H1 and that of the organic compound H2 is no greater than 30 K. Further, the difference between the sublimation temperature of the organic compound H1 and that of the organic compound H2 is no greater than 20 K. Still further, the difference between the sublimation temperature of the organic compound H1 and that of the organic compound H2 is no greater than 10 K.

In an embodiment, the organic compound H1 and/or the organic compound H2 has a glass transition temperature of no lower than 100° C. Further, the organic compound H1 and/or the organic compound H2 has a glass transition temperature of no lower than 120° C. Further, the organic compound H1 and/or the organic compound H2 has a glass transition temperature of no lower than 140° C. Further, the organic compound H1 and/or the organic compound H2 has a glass transition temperature of no lower than 160° C. Further, the organic compound H1 and/or the organic compound H2 has a glass transition temperature of no lower than 180° C.

In an embodiment, the organic compound H1 and the organic compound H2 are small molecule materials, so that the organic mixture can be used for an evaporated OLED. In an embodiment, the molecular weight of the organic compound H1 is no greater than 1000 g/mol, and the molecular weight of the organic compound H2 is no greater than 1000 g/mol. Further, the molecular weight of the organic compound H1 is no greater than 900 g/mol, and the molecular weight of the organic compound H2 is no greater than 900 g/mol. Still further, the molecular weight of the organic compound H1 is no greater than 850 g/mol, and the molecular weight of the organic compound H2 is no greater than 850 g/mol. Still further, the molecular weight of the organic compound H1 is no greater than 800 g/mol, and the molecular weight of the organic compound H2 is no greater than 800 g/mol. Still further, the molecular weight of the organic compound H1 is no greater than 700 g/mol, and the molecular weight of the organic compound H2 is no greater than 700 g/mol.

It should be noted that, the term “small molecule” as defined herein refers to a molecule that is not a polymer, oligomer, dendrimer, or blend. In particular, there are no repeating structures in the small molecule. The molecular weight of the small molecule is no greater than 3000 g/mol, further no greater than 2000 g/mol, and still further no greater than 1500 g/mol.

Polymer includes homopolymer, copolymer, and block copolymer. In addition, in the present disclosure, the polymer also includes dendrimer. The synthesis and application of dendrimers are described in Dendrimers and Dendrons, Wiley-VCH Verlag GmbH & Co. KGaA, 2002, Ed. George R. Newkome, Charles N. Moorefield, Fritz Vogtle.

Conjugated polymer is a polymer whose backbone is primarily consisted of the sp2 hybrid orbital of C atoms. Famous examples are polyacetylene and poly (phenylene vinylene), the C atoms on the backbones of which may also be substituted by other non-C atoms, and which are still considered to be conjugated polymers when the sp2 hybridization on the backbones is interrupted by some natural defects. In addition, the conjugated polymer in the present disclosure may also comprise those which contained aryl amine, aryl phosphine and other heteroarmotics, organometallic complexes, and the like on the backbone thereof.

In an embodiment, the molecular weight of the organic compound H1 and/or the organic compound H2 is no smaller than 700 g/mol, the organic mixture therefore can be used in a printed OLED. Further, the molecular weight of the organic compound H1 and/or the organic compound H2 is no smaller than 900 g/mol. Further, the molecular weight of the organic compound H1 and/or the organic compound H2 is no smaller than 1000 g/mol. Further, the molecular weight of the organic compound H1 and/or the organic compound H2 is no smaller than 1100 g/mol.

In an embodiment, the solubility of the organic mixture in toluene at 25° C. is no less than 10 mg/ml. Further, the solubility of the organic mixture in toluene at 25° C. is no less than 15 mg/ml. Further, the solubility of the organic mixture in toluene at 25° C. is no less than 20 mg/ml.

In an embodiment, the organic mixture further comprises an organic functional material. The organic functional material is selected from the group consisting of a hole (also called electron hole) injection or transport material (HIM/HTM), a hole blocking material (HBM), an electron injection or transport material (EIM/ETM), an electron blocking material (EBM), an organic host material or an emitter.

In an embodiment, the emitter is selected from a singlet emitter (fluorescent emitter), a triplet emitter (phosphorescent emitter) or an organic thermally activated delayed fluorescent material (TADF material). Wherein, the organic thermally activated delayed fluorescent material may be a light-emitting organometallic complex. Various organic functional materials are described in detail, for example, in WO2010135519A1, US20090134784A1, and WO2011110277A1, the entire contents of which are hereby incorporated herein by reference. The organic functional material may be a small molecule material or a polymer material.

In an embodiment, the organic functional material is selected from an emitter, and the emitter has a weight percentage of 1 wt % to 30 wt %.

In an embodiment, the organic functional material is selected from a phosphorescent emitter. In this case, the organic mixture may be used as a host material, wherein the phosphorescent emitter has a weight percentage of no greater than 30 wt %. Further, the phosphorescent emitter has a weight percentage of no greater than 25 wt %. Further, the phosphorescent emitter has a weight percentage of no greater than 20 wt %.

In an embodiment, the organic functional material is selected from a fluorescent emitter. In this case, the organic mixture may be used as a fluorescent host material, wherein the fluorescent emitter has a weight percentage of no greater than 15 wt %. Further, the fluorescent emitter has a weight percentage of no greater than 10 wt %. Further, the fluorescent emitter has a weight percentage of no greater than 8 wt %.

In an embodiment, the organic functional material is selected from a phosphorescent emitter. A host material may be further included, and the host material, phosphorescent emitter and the organic mixture are mixed together. In this case, the organic mixture may be used as an auxiliary light-emitting material, and its weight ratio to the phosphorescent emitter is from 1:2 to 2:1. In other embodiments, the energy level of the exciplex of the organic mixture is higher than that of the phosphorescent emitter.

In an embodiment, the organic functional material is selected from a TADF material. The above organic mixture may be used as a TADF host material, wherein the TADF material has a weight percentage of no greater than 15%. Further, the TADF material has a weight percentage of no greater than 10%. Further, the TADF material has a weight percentage of no greater than 8%.

The singlet emitter, triplet emitter and TADF material are described in more detail below (but not limited thereto).

1. Singlet Emitter

Singlet emitter tends to have a longer conjugated it-electron system. To date, there have been many examples, such as, styrylamine and derivatives thereof disclosed in JP2913116B and WO2001021729A1, and indenofluorene and derivatives thereof disclosed in WO2008/006449 and WO2007/140847.

In an embodiment, the singlet emitter can be selected from one or more of the group consisting of mono-styrylamine, di-styrylamine, tri-styrylamine, tetra-styrylamine, styrene phosphine, styrene ether and arylamine.

A mono-styrylamine comprises an unsubstituted or substituted styryl group and at least one amine, particularly an aromatic amine. A di-styrylamine comprises two unsubstituted or substituted styryl groups and at least one amine, particularly an aromatic amine. A tri-styrylamine comprises three unsubstituted or substituted styryl groups and at least one amine, particularly an aromatic amine. A tetra-styrylamine comprises four unsubstituted or substituted styryl groups and at least one amine, particularly an aromatic amine. In an embodiment, styrene is stilbene, which may be further substituted. The definitions of the corresponding phosphines and ethers are similar to those of amines.

The aryl amine or aromatic amine comprises three unsubstituted or substituted aromatic cyclic or heterocyclic systems directly attached to nitrogen. At least one of these aromatic or heterocyclic ring systems is a fused ring system. Further, the fused ring system has at least 14 aromatic ring atoms. In an embodiment, aryl amine or aromatic amine may be selected from the group consisting of aromatic anthramine, aromatic anthradiamine, aromatic pyrene amine, aromatic pyrene diamine, aromatic chrysene amine and aromatic chrysene diamine. Aromatic anthracene amine refers to a compound in which a diarylamino group is directly attached to anthracene, particularly at position 9. Aromatic anthradiamine refers to a compound in which two diarylamino groups are directly attached to anthracene, particularly at positions 9,10. Aromatic pyrene amine, aromatic pyrene diamine, aromatic chrysene amine and aromatic chrysene diamine are similarly defined, wherein the diarylarylamino group is particularly attached to position 1 or 1 and 6 of pyrene.

In an embodiment, the singlet emitter is a singlet emitter based on vinylamine and arylamine. The singlet emitters can be found in the following patent documents: WO 2006/000388, WO 2006/058737, WO 2006/000389, WO 2007/065549, WO 2007/115610, U.S. Pat. No. 7,250,532 B2, DE 102005058557 A1, CN 1583691 A, JP 08053397 A, U.S. Pat. No. 6,251,531 B1, US 2006/210830 A, EP 1 957 606 A1 and US 2008/0113101 A1, the entirety of the patent documents listed above are hereby incorporated herein by reference. The singlet emitters based on distyrylbenzene and derivatives thereof may be found in U.S. Pat. No. 5,121,029.

In an embodiment, the singlet emitters may be selected from the group consisting of indenofluorene-amine and indenofluorene-diamine (see WO 2006/122630), benzoindenofluorene-amine or benzoindenofluorene-diamine (see WO 2008/006449), or dibenzoindenofluorene-amine or dibenzoindenofluorene-diamine (see WO2007/140847).

Other materials may be used as singlet emitters are polycyclic aromatic compounds, especially the derivatives of the following compounds: anthracenes such as 9,10-di(2-naphthylanthracene), naphthalene, tetraphenyl, oxyanthene, phenanthrene, perylene (such as 2,5,8,11-tetra-t-butylatedylene), indenoperylene, phenylenes (such as 4,4′-(bis (9-ethyl-3-carbazovinylene)-1,1′-biphenyl), periflanthene, decacyclene, coronene, fluorene, spirobifluorene, arylpyren (e.g., US20060222886), arylenevinylene (e.g., U.S. Pat. Nos. 5,121,029, 5,130,603), cyclopentadiene such as tetraphenylcyclopentadiene, rubrene, coumarine, rhodamine, quinacridone, pyrane such as 4 (dicyanoethylene)-6-(4-dimethyl aminostyryl-2-methyl)-4H-pyrane (DCM), thiapyran, bis (azinyl) imine-boron compounds (US 2007/0092753 A1), bis (azinyl) methene compounds, carbostyryl compounds, oxazone, benzoxazole, benzothiazole, benzimidazole and diketopyrrolopyrrole.

Examples of some singlet emitter materials may be found in the following patent documents: US 20070252517 A1, U.S. Pat. Nos. 4,769,292, 6,020,078, US 2007/0252517 A1 or US 2007/0252517 A1, the whole contents of which are incorporated herein by reference.

Examples of suitable singlet emitters are listed below:

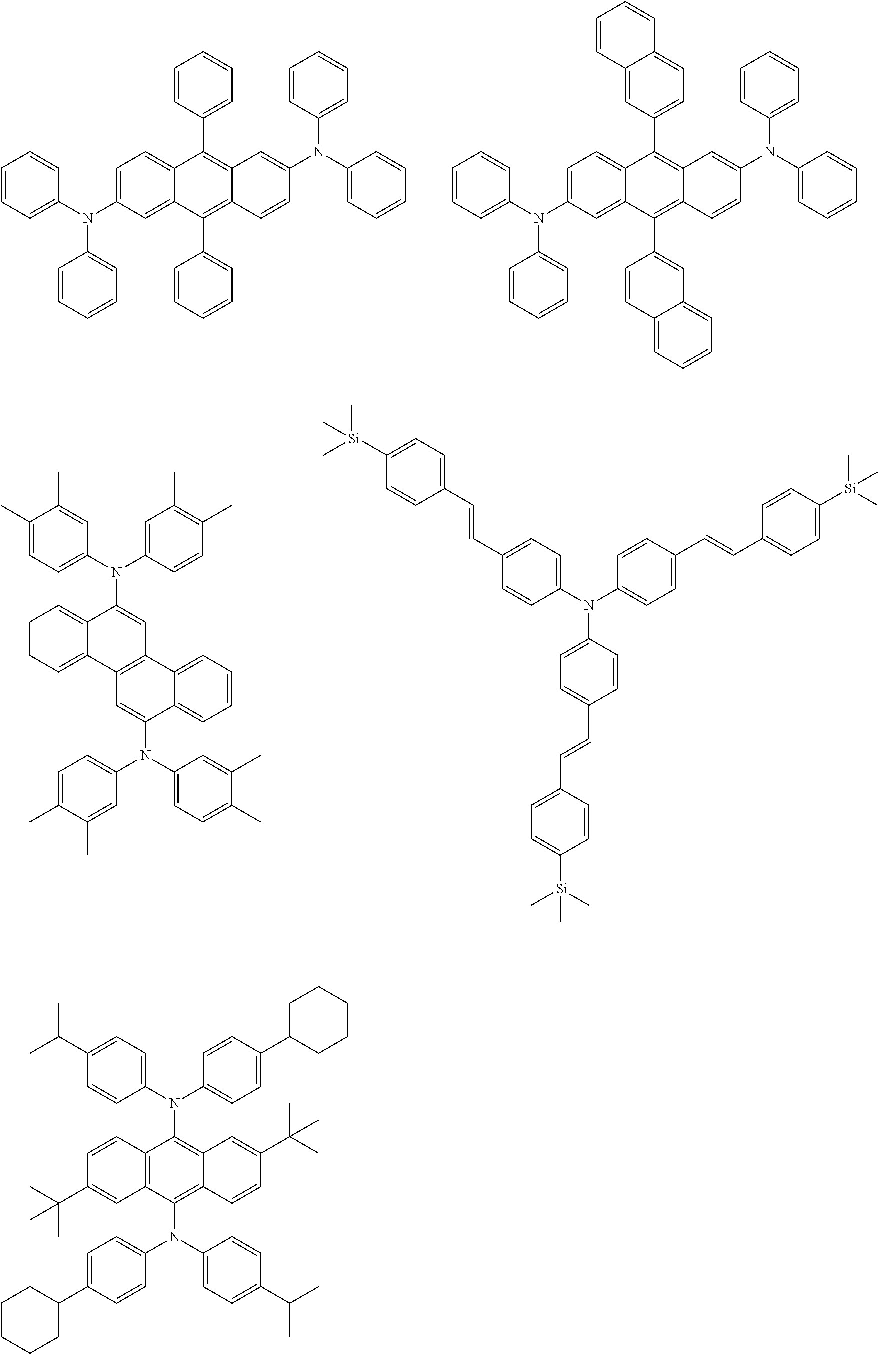

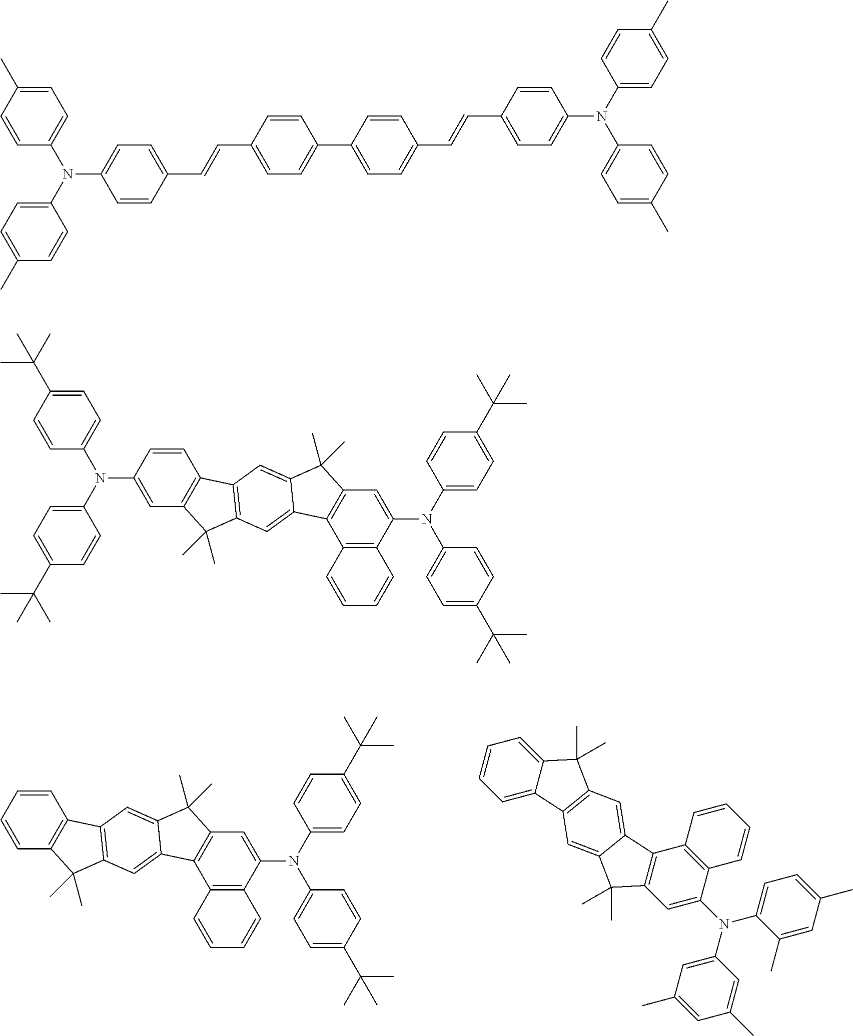

2. Thermally Activated Delayed Fluorescent Materials (TADF):

Traditional organic fluorescent materials can only emit light using 25% singlet excitonic luminescence formed by electrical excitation, and the devices have relatively low internal quantum efficiency (up to 25%). The phosphorescent material enhances the intersystem crossing due to the strong spin-orbit coupling of the heavy atom center, the singlet exciton and the triplet exciton luminescence formed by the electric excitation can be effectively utilized, so that the internal quantum efficiency of the device can reach 100%. However, the application of phosphor material in OLEDs is limited by the problems such as high cost, poor material stability and serious roll-off of the device efficiency, etc. Thermally-activated delayed fluorescent materials are the third generation of organic light-emitting materials developed after organic fluorescent materials and organic phosphorescent materials. This type of material generally has a small singlet-triplet energy level difference (ΔEst), and triplet excitons can be converted to singlet excitons by anti-intersystem crossing. Thus, singlet excitons and triplet excitons formed under electric excitation can be fully utilized. The device can achieve 100% internal quantum efficiency.

The TADF material needs to have a small singlet-triplet energy level difference, typically ΔEst<0.3 eV, further ΔEst<0.2 eV, still further ΔEst<0.1 eV, and even further ΔEst<0.05 eV. In an embodiment, TADF has good fluorescence quantum efficiency. Some TADF materials can be found in the following patent documents: CN103483332(A), TW201309696(A), TW201309778(A), TW201343874(A), TW201350558(A), US20120217869(A1), WO2013133359(A1), WO2013154064(A1), Adachi, et. al. Adv. Mater., 21, 2009, 4802, Adachi, et. al. Appl. Phys. Lett., 98, 2011, 083302, Adachi, et. al. Appl. Phys. Lett., 101, 2012, 093306, Adachi, et. al. Chem. Commun., 48, 2012, 11392, Adachi, et. al. Nature Photonics, 6, 2012, 253, Adachi, et. al. Nature, 492, 2012, 234, Adachi, et. al. J. Am. Chem. Soc, 134, 2012, 14706, Adachi, et. al. Angew. Chem. Int. Ed, 51, 2012, 11311, Adachi, et. al. Chem. Commun., 48, 2012, 9580, Adachi, et. al. Chem. Commun., 48, 2013, 10385, Adachi, et. al. Adv. Mater., 25, 2013, 3319, Adachi, et. al. Adv. Mater., 25, 2013, 3707, Adachi, et. al. Chem. Mater., 25, 2013, 3038, Adachi, et. al. Chem. Mater., 25, 2013, 3766, Adachi, et. al. J. Mater. Chem. C., 1, 2013, 4599, Adachi, et. al. J. Phys. Chem. A., 117, 2013, 5607, the contents of the above-listed patents or article documents are hereby incorporated by reference in their entirety.

Some examples of suitable TADF light-emitting materials are listed in the following table:

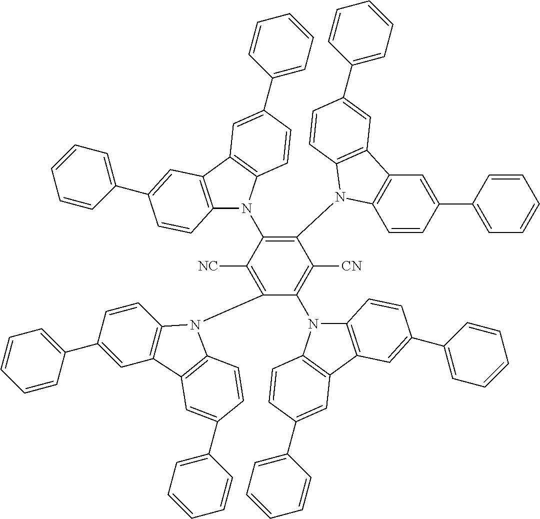 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

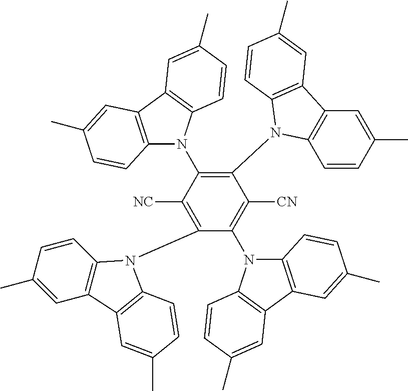

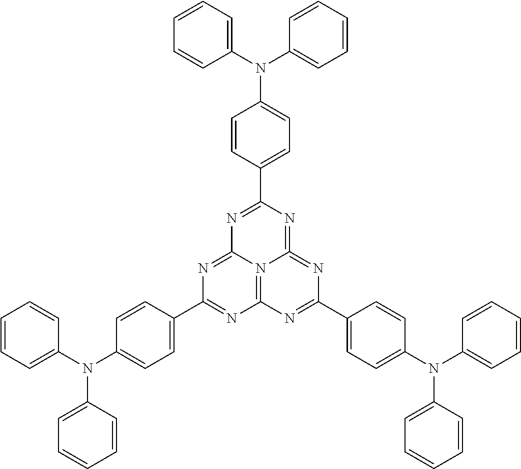

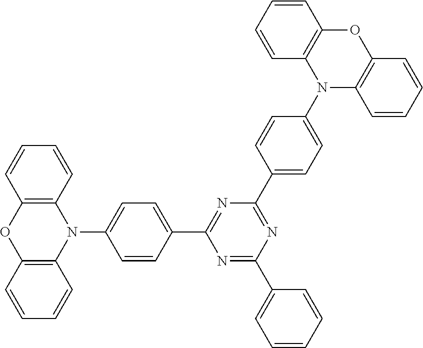 [SMILES: c1ccc(-c2nc(-c3ccc(N4c5ccccc5Oc5ccccc54)cc3)nc(-c3ccc(N4c5ccccc5Oc5ccccc54)cc3)n2)cc1]

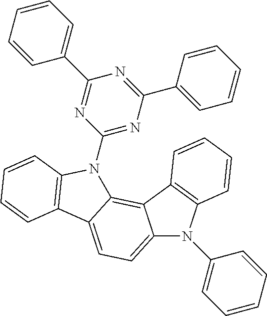 [SMILES: c1ccc(-c2nc(-c3ccccc3)nc(-n3c4ccccc4c4ccc5c(c6ccccc6n5-c5ccccc5)c43)n2)cc1]

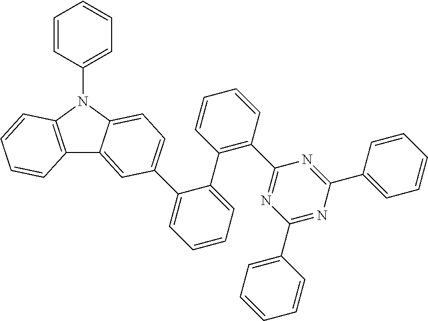 [SMILES: c1ccc(-c2nc(-c3ccccc3)nc(-c3ccccc3-c3ccccc3-c3ccc4c(c3)c3ccccc3n4-c3ccccc3)n2)cc1]

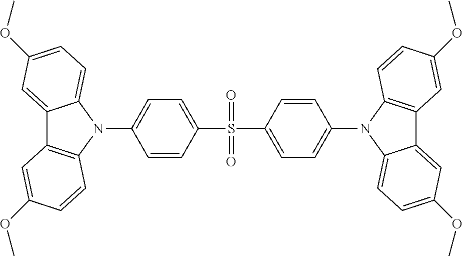 [SMILES: COc1ccc2c(c1)c1cc(OC)ccc1n2-c1ccc(S(=O)(=O)c2ccc(-n3c4ccc(OC)cc4c4cc(OC)ccc43)cc2)cc1]

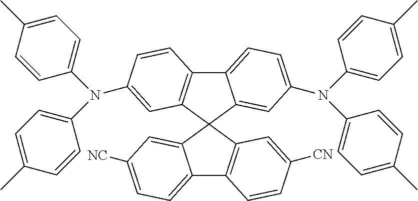

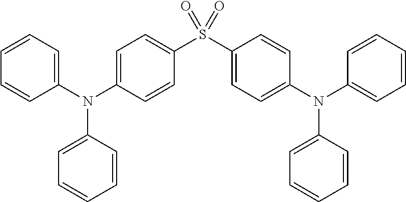 [SMILES: O=S(=O)(c1ccc(N(c2ccccc2)c2ccccc2)cc1)c1ccc(N(c2ccccc2)c2ccccc2)cc1]

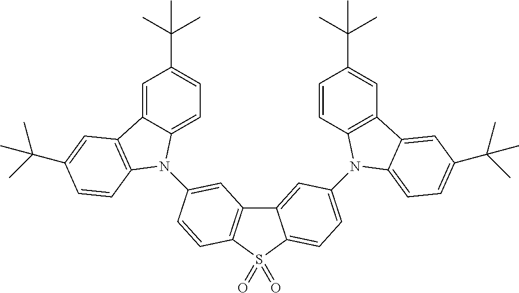 [SMILES: CC(C)(C)c1ccc2c(c1)c1cc(C(C)(C)C)ccc1n2-c1ccc2c(c1)-c1cc(-n3c4ccc(C(C)(C)C)cc4c4cc(C(C)(C)C)ccc43)ccc1S2(=O)=O]

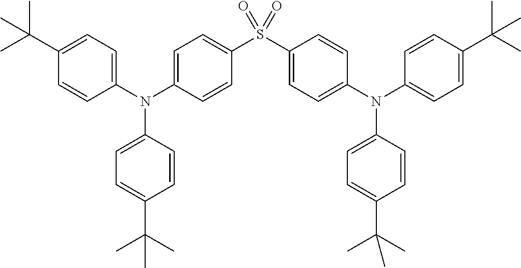 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

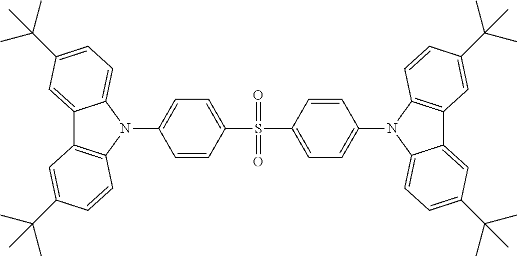 [SMILES: CC(C)(C)c1ccc2c(c1)c1cc(C(C)(C)C)ccc1n2-c1ccc(S(=O)(=O)c2ccc(-n3c4ccc(C(C)(C)C)cc4c4cc(C(C)(C)C)ccc43)cc2)cc1]

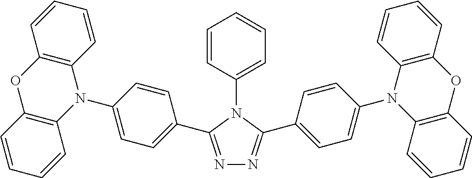 [SMILES: c1ccc(-n2c(-c3ccc(N4c5ccccc5Oc5ccccc54)cc3)nnc2-c2ccc(N3c4ccccc4Oc4ccccc43)cc2)cc1]

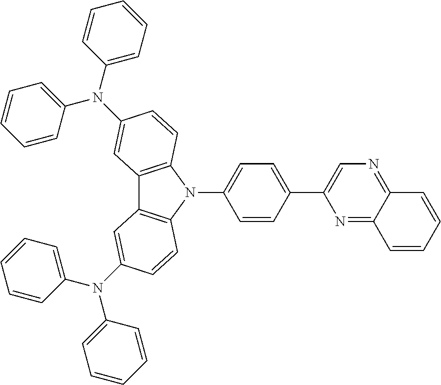 [SMILES: c1ccc(N(c2ccccc2)c2ccc3c(c2)c2cc(N(c4ccccc4)c4ccccc4)ccc2n3-c2ccc(-c3cnc4ccccc4n3)cc2)cc1]

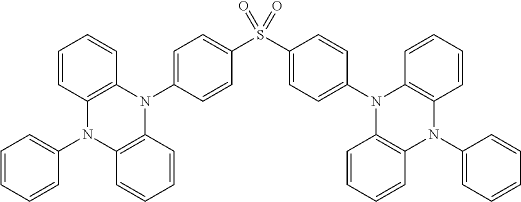 [SMILES: O=S(=O)(c1ccc(N2c3ccccc3N(c3ccccc3)c3ccccc32)cc1)c1ccc(N2c3ccccc3N(c3ccccc3)c3ccccc32)cc1]

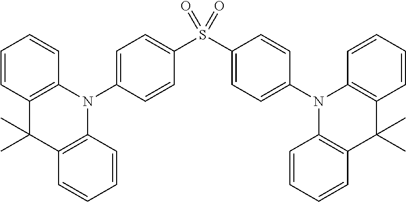

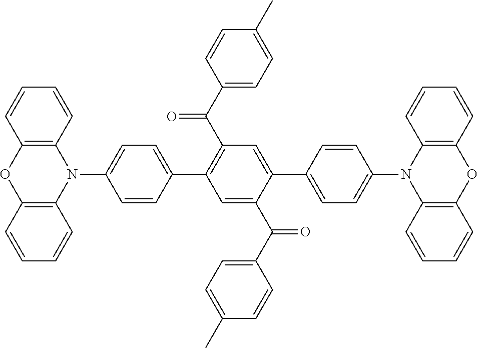 [SMILES: Cc1ccc(C(=O)c2cc(-c3ccc(N4c5ccccc5Oc5ccccc54)cc3)c(C(=O)c3ccc(C)cc3)cc2-c2ccc(N3c4ccccc4Oc4ccccc43)cc2)cc1]

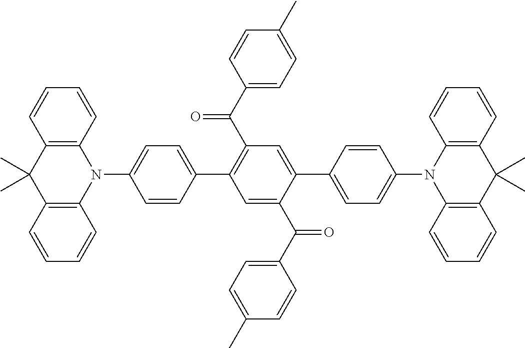

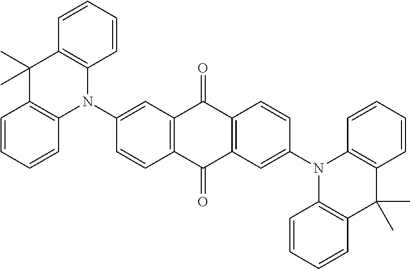 [SMILES: CC1(C)c2ccccc2N(c2ccc3c(c2)C(=O)c2ccc(N4c5ccccc5C(C)(C)c5ccccc54)cc2C3=O)c2ccccc21]

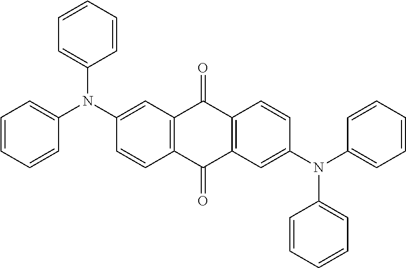 [SMILES: O=C1c2ccc(N(c3ccccc3)c3ccccc3)cc2C(=O)c2ccc(N(c3ccccc3)c3ccccc3)cc21]

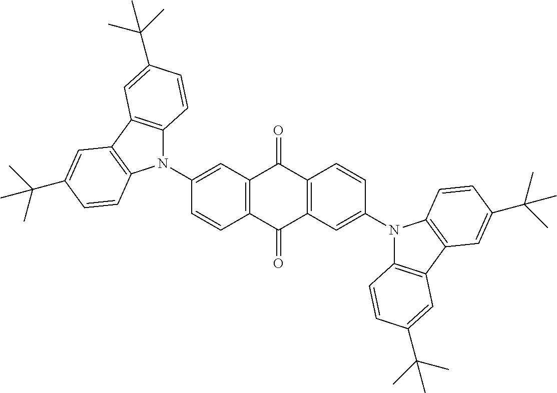 [SMILES: CC(C)(C)c1ccc2c(c1)c1cc(C(C)(C)C)ccc1n2-c1ccc2c(c1)C(=O)c1ccc(-n3c4ccc(C(C)(C)C)cc4c4cc(C(C)(C)C)ccc43)cc1C2=O]

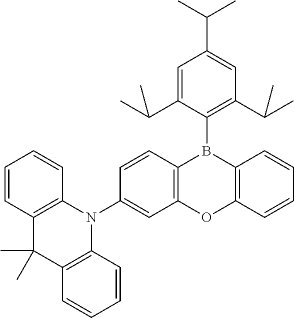 [SMILES: CC(C)c1cc(C(C)C)c(B2c3ccccc3Oc3cc(N4c5ccccc5C(C)(C)c5ccccc54)ccc32)c(C(C)C)c1]

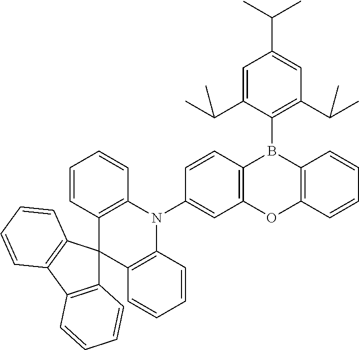 [SMILES: CC(C)c1cc(C(C)C)c(B2c3ccccc3Oc3cc(N4c5ccccc5C5(c6ccccc6-c6ccccc65)c5ccccc54)ccc32)c(C(C)C)c1]

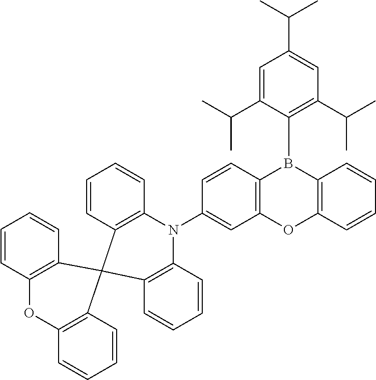 [SMILES: CC(C)c1cc(C(C)C)c(B2c3ccccc3Oc3cc(N4c5ccccc5C5(c6ccccc6Oc6ccccc65)c5ccccc54)ccc32)c(C(C)C)c1]

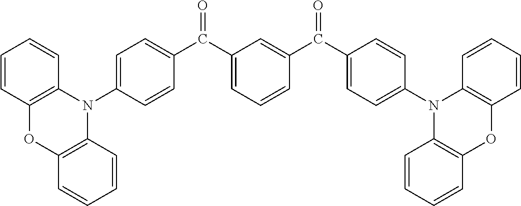 [SMILES: O=C(c1ccc(N2c3ccccc3Oc3ccccc32)cc1)c1cccc(C(=O)c2ccc(N3c4ccccc4Oc4ccccc43)cc2)c1]

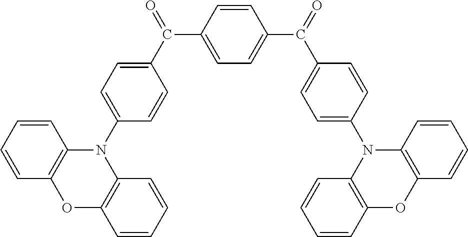 [SMILES: O=C(c1ccc(C(=O)c2ccc(N3c4ccccc4Oc4ccccc43)cc2)cc1)c1ccc(N2c3ccccc3Oc3ccccc32)cc1]

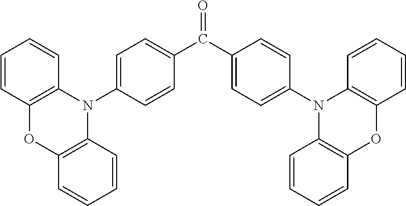 [SMILES: O=C(c1ccc(N2c3ccccc3Oc3ccccc32)cc1)c1ccc(N2c3ccccc3Oc3ccccc32)cc1]

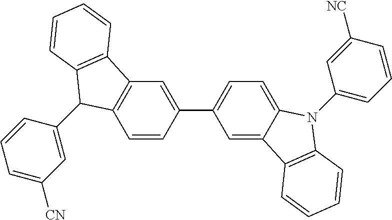 [SMILES: N#Cc1cccc(C2c3ccccc3-c3cc(-c4ccc5c(c4)c4ccccc4n5-c4cccc(C#N)c4)ccc32)c1]

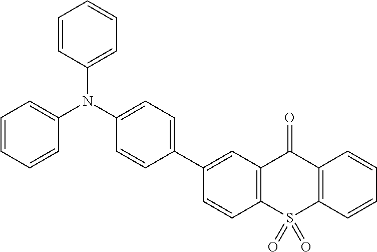 [SMILES: O=C1c2ccccc2S(=O)(=O)c2ccc(-c3ccc(N(c4ccccc4)c4ccccc4)cc3)cc21]

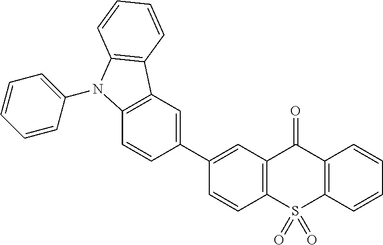 [SMILES: O=C1c2ccccc2S(=O)(=O)c2ccc(-c3ccc4c(c3)c3ccccc3n4-c3ccccc3)cc21]

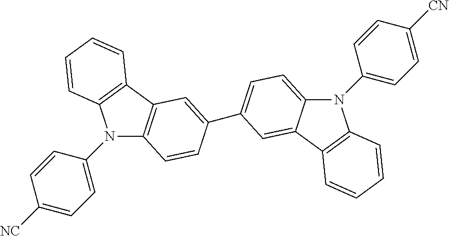 [SMILES: N#Cc1ccc(-n2c3ccccc3c3cc(-c4ccc5c(c4)c4ccccc4n5-c4ccc(C#N)cc4)ccc32)cc1]

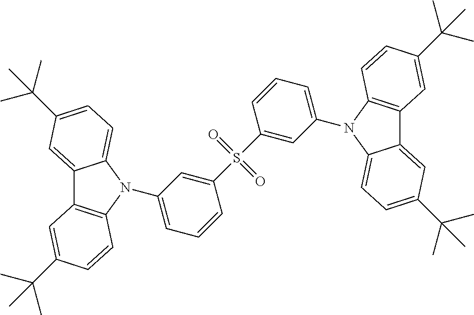 [SMILES: CC(C)(C)c1ccc2c(c1)c1cc(C(C)(C)C)ccc1n2-c1cccc(S(=O)(=O)c2cccc(-n3c4ccc(C(C)(C)C)cc4c4cc(C(C)(C)C)ccc43)c2)c1]

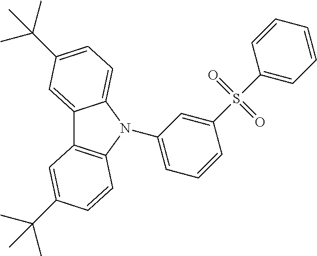 [SMILES: CC(C)(C)c1ccc2c(c1)c1cc(C(C)(C)C)ccc1n2-c1cccc(S(=O)(=O)c2ccccc2)c1]

3. Triplet Emitter

Triplet emitters are also called phosphorescent emitters. In an embodiment, the triplet emitter is a metal complex with general formula M(L)n; wherein, M is a metal atom, and each occurrence of L may be the same or different and is an organic ligand which is bonded or coordinated to the metal atom M through one or more positions; n is an integer greater than 1, particularly, n is selected from 1, 2, 3, 4, 5 or 6. In an embodiment, these metal complexes are attached to a polymer through one or more positions, particularly through organic ligands.

In an embodiment, the metal atom M is selected from a transitional metal element, a lanthanide element or an actinide element. Further, the metal atom M is selected from Ir, Pt, Pd, Au, Rh, Ru, Os, Sm, Eu, Gd, Tb, Dy, Re, Cu or Ag. Still further, the metal atom M is selected from Os, Ir, Ru, Rh, Re, Pd or Pt.

In an embodiment, the triplet emitter comprises chelating ligands, i.e. ligands, coordinated with the metal via at least two binding sites, and especially, the triplet emitter comprises two or three identical or different bidentate or multidentate ligands. The chelating ligands are helpful to improve the stability of the metal complexes.

The organic ligand may be selected from the group consisting of phenylpyridine derivatives, 7,8-benzoquinoline derivatives, 2-(2-thienyl)pyridine derivatives, 2-(1-naphthyl)pyridine derivatives or 2-phenylquinoline derivatives. All of these organic ligands may be substituted, for example, substituted by fluoromethyl or trifluoromethyl. The ancillary ligand may be selected from acetone acetate or picric acid.

In an embodiment, the metal complex used as a triplet emitter has the following general formula:

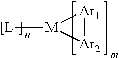

wherein, M is a metal and selected from a transitional metal element, a lanthanide element or an actinide element;

Ar₁ is a cyclic group, each occurrence of Ar₁ may be the same or different and comprises at least one donor atom (i.e., an atom having one lone pair of electrons, such as nitrogen or phosphorus) through which the cyclic group is coordinately coupled with metal; Ar₂ is a cyclic group, each occurrence of Ar₂ may be the same or different and comprises at least one carbon atom through which the cyclic group is coupled with metal; Ar₁ and Ar₂ are covalently bonded together, and each of them may carry one or more substituents, and they may be coupled together by substituents again; Each occurrence of L may be the same or different, and L is an auxiliary ligand, especially a bidentate chelating ligand, particularly a monoanionic bidentate chelating ligand; m is selected from 1, 2 or 3, further is 2 or 3, especially is 3; n is selected from 0, 1 or 2, further is 0 or 1, especially is 0.

Some examples of triplet emitter materials and applications thereof can be found in the following patent documents and references: WO 200070655, WO 200141512, WO 200202714, WO 200215645, EP 1191613, EP 1191612, EP 1191614, WO 2005033244, WO 2005019373, US 2005/0258742, WO 2009146770, WO 2010015307, WO 2010031485, WO 2010054731, WO 2010054728, WO 2010086089, WO 2010099852, WO 2010102709, US 20070087219 A1, US 20090061681 A1, US 20010053462 A1, Baldo, Thompson et al. Nature 403, (2000), 750-753, US 20090061681 A1, US 20090061681 A1, Adachi et al. Appl. Phys. Lett. 78 (2001), 1622-1624, J. Kido et al. Appl. Phys. Lett. 65 (1994), 2124, Kido et al. Chem. Lett. 657, 1990, US 2007/0252517 A1, Johnson et al., JACS 105, 1983, 1795, Wrighton, JACS 96, 1974, 998, Ma et al., Synth. Metals 94, 1998, 245, U.S. Pat. Nos. 6,824,895, 7,029,766, 6,835,469, 6,830,828, US 20010053462A1, WO 2007095118A1, US 2012004407A1, WO 2012007088A1, WO2012007087A1, WO 2012007086A1, US 2008027220A1, WO 2011157339A1, CN 102282150A, WO 2009118087A1. The entire contents of the above listed patent documents and literatures are hereby incorporated by reference.

Some suitable examples of triplet emitters are listed in the following table:

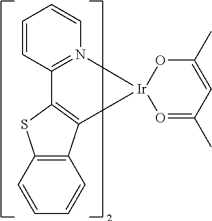

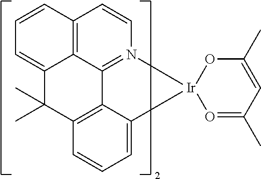

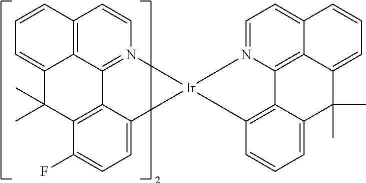

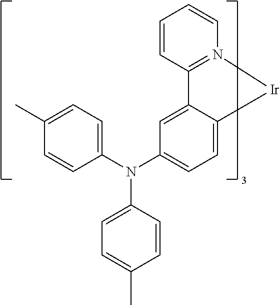

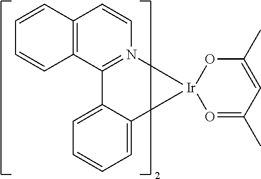

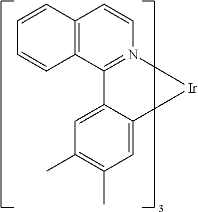

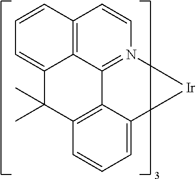

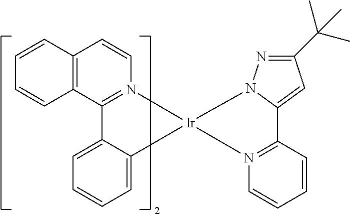

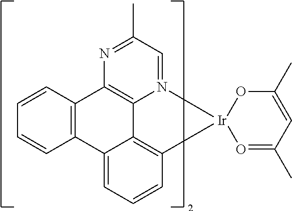

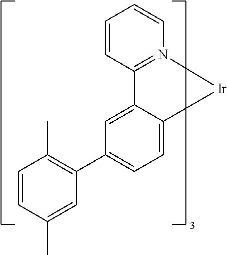

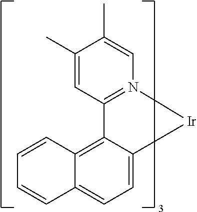

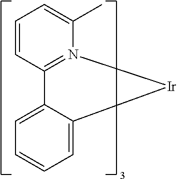

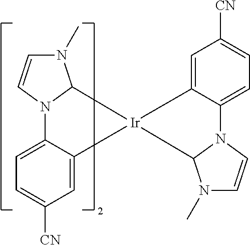

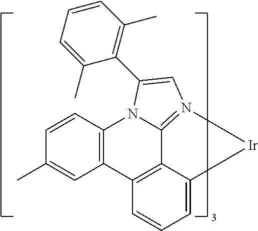

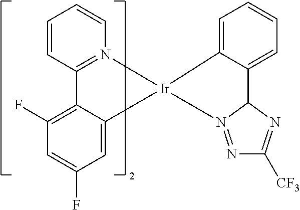

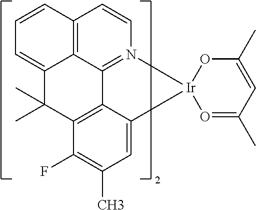

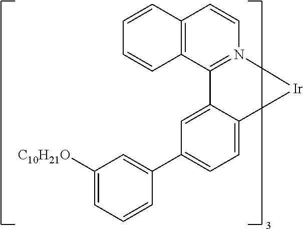

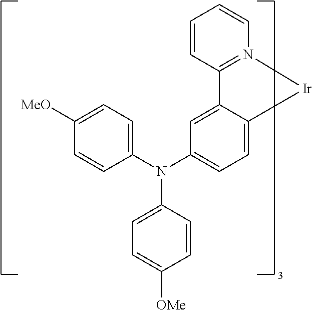

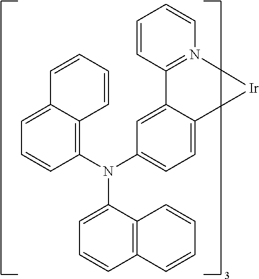

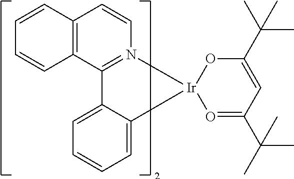

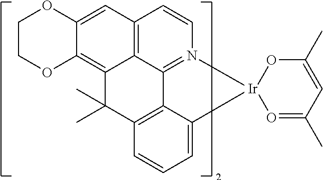

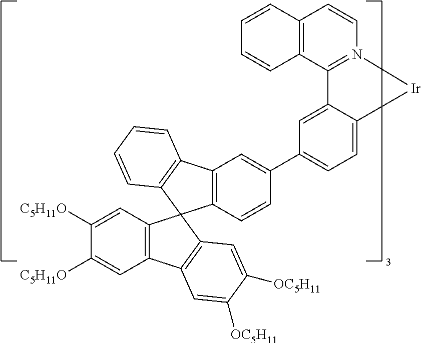

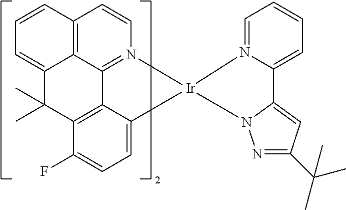

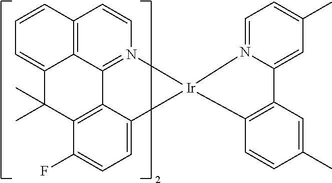

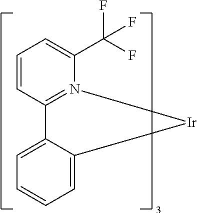

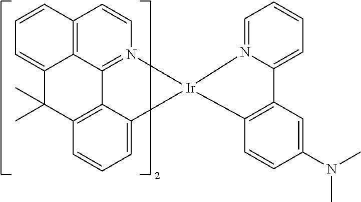

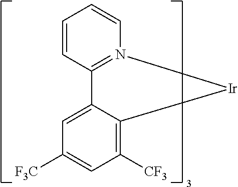

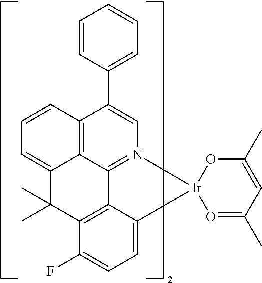

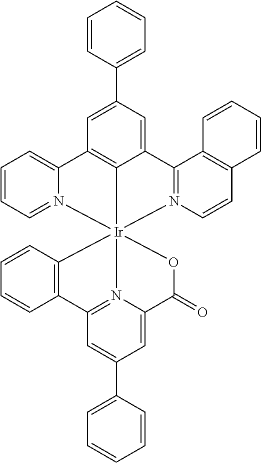

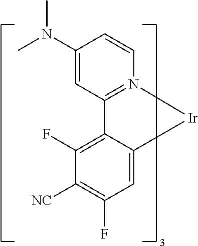

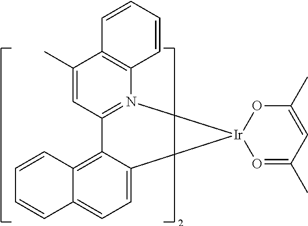

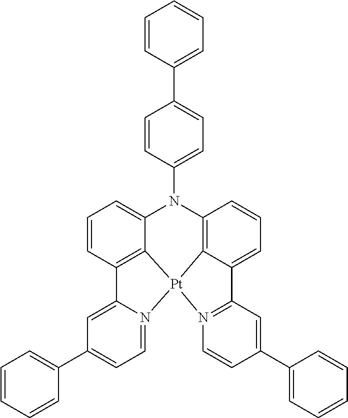

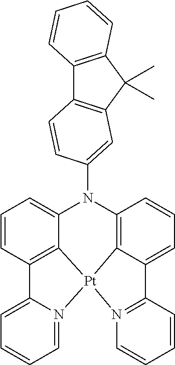

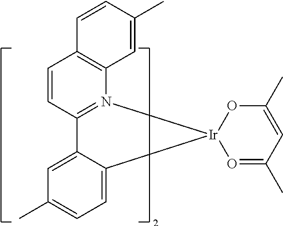

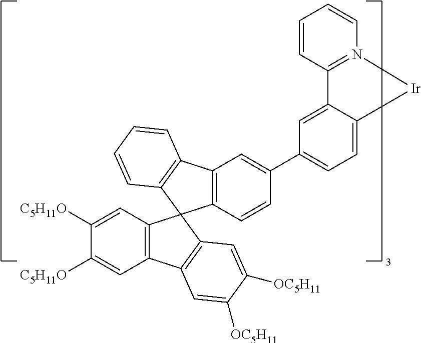

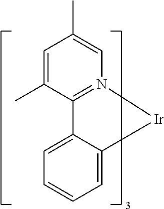

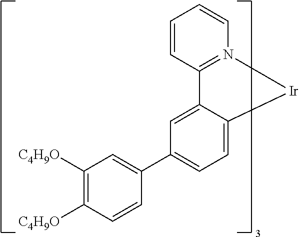

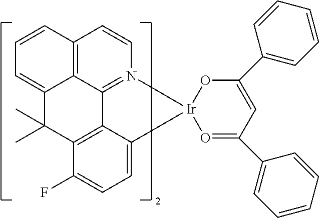

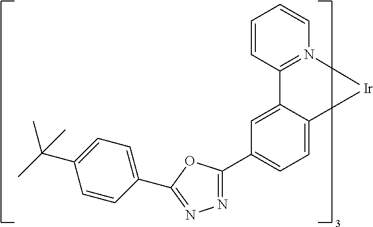

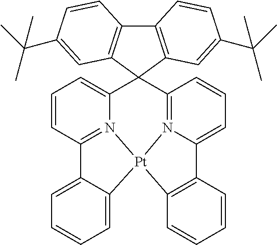

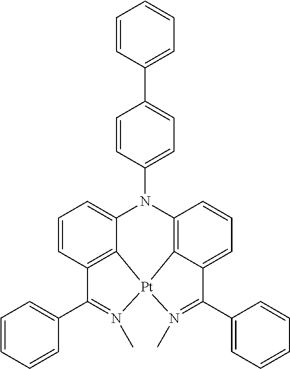

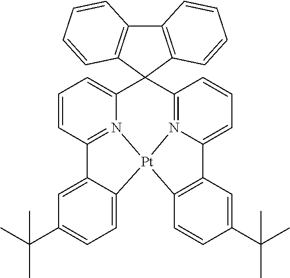

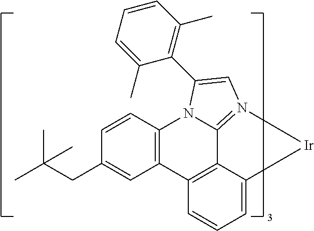

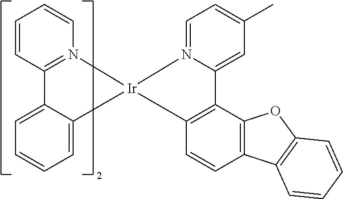

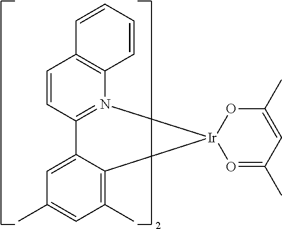

The formulation of an embodiment comprises the above organic mixture and an organic solvent. In this embodiment, the formulation is an ink. The viscosity and surface tension of ink are important parameters when the formulation is used in the printing process. The suitable surface tension parameters of ink are suitable for a particular substrate and a particular printing method.

In an embodiment, the surface tension of the ink at working temperature or at 25° C. is in the range of about 19 dyne/cm to 50 dyne/cm, further in the range of 22 dyne/cm to 35 dyne/cm, and still further in the range of 25 dyne/cm to 33 dyne/cm.

In an embodiment, the viscosity of the ink at working temperature or at 25° C. is in the range of about 1 cps to 100 cps, further in the range of 1 cps to 50 cps, still further in the range of 1.5 cps to 20 cps, and even further in the range of 4.0 cps to 20 cps. Therefore, the formulation is more suitable for inkjet printing.

The viscosity can be adjusted by different methods, such as by proper solvent selection and the concentration of functional materials in the ink. The ink comprising the metal organic compound or polymer can facilitate the adjustment of the printing ink in an appropriate range according to the printing method used. In general, the weight ratio of the functional material contained in the formulation is in the range of 0.3 wt % to 30 wt %, further in the range of 0.5 wt % to 20 wt %, still further in the range of 0.5 wt % to 15 wt %, even further in the range of 0.5 wt % to 10 wt %, and even further in the range of 1 wt % to 5 wt %.

In an embodiment, the organic solvent comprises a first solvent selected from aromatic and/or heteroaromatic based solvents. Further, the first solvent may be an aliphatic chain/ring substituted aromatic solvent, an aromatic ketone solvent, or an aromatic ether solvent.

Examples of the first solvent include, but are not limited to, aromatic or heteroaromatic based solvents: p-diisopropylbenzene, pentylbenzene, tetrahydronaphthalene, cyclohexyl benzene, chloronaphthalene, 1,4-dimethylnaphthalene, 3-isopropylbiphenyl, p-cymene, dipentylbenzene, tripentylbenzene, pentyltoluene, o-xylene, m-xylene, p-xylene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, 1-methoxynaphthalene, cyclohexylbenzene, dimethylnaphthalene, 3-isopropylbiphenyl, p-cymene, 1-methylnaphthalene, 1,2,4-trichlorob enzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine 4-isopropylbiphenyl, α,α-dichlorodiphenylmethane, 4-(3-phenylpropyl)pyridine, benzylbenzoate, 1,1-di(3,4-dimethylphenyl)ethane, 2-isopropylnaphthalene, dibenzylether, and the like; solvents based on ketones: 1-tetralone, 2-tetralone, 2-(phenylepoxy)tetralone, 6-(methoxyl)tetralone, acetophenone, phenylacetone, benzophenone, and derivatives thereof, such as 4-methylacetophenone, 3-methylacetophenone, 2-methylacetophenone, 4-methylphenyl acetone, 3-methylphenylacetone, 2-methylphenyl acetone, isophorone, 2,6,8-trimethyl-4-nonanone, fenchone, 2-nonanone, 3-nonanone, 5-nonanone, 2-demayone, 2,5-hexanedione, phorone, di-n-amyl ketone; aromatic ether solvents: 3-phenoxytoluene, butoxybenzene, benzylbutylbenzene, p-anisaldehyde dimethyl acetal, tetrahydro-2-phenoxy-2H-pyran, 1,2-dimethoxy 4-(1-propenyl)benzene, 1,4-benzodioxane, 1,3-dipropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-p-propenylanisole, 1,2-dimethoxybenzene, 1-methoxynaphthalene, diphenyl ether, 2-phenoxymethyl ether, 2-phenoxytetrahydrofuran, ethyl-2-naphthyl ether, pentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether; and ester solvents: alkyl octoate, alkyl sebacate, alkyl stearate, alkyl benzoate, alkyl phenylacetate, alkyl cinnamate, alkyl oxalate, alkyl maleate, alkyl lactone, alkyl oleate, and the like.

Further, the first solvent may also be selected from one or more of the group consisting of aliphatic ketones, such as 2-nonanone, 3-nonanone, 5-nonanone, 2-demayone, 2,5-hexanedione, 2,6,8-trimethyl-4-demayone, phorone, di-n-pentyl ketone, and the like; or aliphatic ethers, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethyl ether alcohol ethyl methyl ether, triethylene glycol butyl methyl ether, tripropylene glycol dimethyl ether, tetraethylene glycol dimethyl ether, and the like.

In an embodiment, the organic solvent further comprises a second solvent selected from one or more of the group consisting of methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxy toluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decalin and indene.

In an embodiment, the formulation may be a solution or a suspension, which depends on the compatibility of the organic mixture with the organic solvent.

In an embodiment, the weight percentage of the organic mixture in the formulation is 0.01 to 20 wt %, further 0.1 to 15 wt %, still further 0.2 to 10 wt %, and even further 0.25 to 5 wt %.

An embodiment relates to the application of the above formulation in the preparation of organic electronic devices, especially to the use of the formulation as a coating or printing ink in the preparation of organic electronic devices, and particularly by the preparation method of printing or coating.

The appropriate printing technology or coating technology includes, but is not limited to inkjet printing, nozzle printing, typography, screen printing, dip coating, spin coating, blade coating, roller printing, twist roller printing, lithography, flexography, rotary printing, spray coating, brush coating or transfer printing, or slot die coating, and the like. Especially are gravure printing, nozzle printing and inkjet printing. The formulation may further includes one or more components selected from the group consisting of a surfactant compound, a lubricant, a wetting agent, a dispersant, a hydrophobic agent and a binder, to adjust the viscosity and the film forming property and to improve the adhesion property. The detailed information relevant to the printing technology and requirements of the printing technology to the solution, such as solvent, concentration, and viscosity, may be referred to Handbook of Print Media: Technologies and Production Methods, Helmut Kipphan, ISBN 3-540-67326-1.

An embodiment relates to the application of the above organic mixture in the organic electronic devices. The organic electronic devices may be selected from the group consisting of an organic light-emitting diode (OLED), an organic photovoltaic cell (OPV), an organic light-emitting electrochemical cell (OLEEC), an organic field effect transistor (OFET), an organic light-emitting field effect transistor, an organic laser, an organic spintronic device, organic sensor and an organic plasmon emitting diode. In an embodiment, the organic electronic device is an OLED. Further, the organic mixture is applied in the light-emitting layer of the OLED device.

In an embodiment, the organic electronic device comprises a cathode, an anode and a functional layer located between the cathode and the anode, and the functional layer comprises the above organic mixture. Specifically, the organic electronic device includes at least a cathode, an anode and one functional layer located between the cathode and the anode, and the functional layer comprises at least one organic mixture as described above. The functional layer is selected from one or more of the group consisting of a hole injection layer, a hole transport layer, a hole blocking layer, an electron injection layer, an electron transport layer, an electron blocking layer and a light-emitting layer.

The organic electronic device may be selected from the group consisting of an organic light-emitting diode (OLED), an organic photovoltaic cell (OPV), an organic light-emitting electrochemical cell (OLEEC), an organic field effect transistor (OFET), an organic light-emitting field effect transistor, an organic laser, an organic spintronic device, an organic sensor and an organic plasmon emitting diode. In an embodiment, the organic electronic device is an organic electroluminescent device such as an OLED, an OLEEC or an organic light-emitting field effect transistor. Further, the organic light-emitting diode may be an evaporated organic light-emitting diode or a printed organic light-emitting diode.

In an embodiment, the light-emitting layer of the organic electroluminescent device comprises the above organic mixture.

In an embodiment, the organic electroluminescent device comprises a substrate, an anode, a light-emitting layer and a cathode which are sequentially stacked. Wherein, the layer number of the light-emitting layer is at least one layer.

The substrate may be opaque or transparent. The transparent substrate can be used to prepare a transparent light-emitting device, which may refers to Bulovic et al. Nature 1996, 380, p 29 and Gu et al. Appl. Phys. Lett. 1996, 68, p 2606. The substrate may be rigid or elastic. The substrate may be a plastic, a metal, a semiconductor wafer or a glass. Particularly, the substrate has a smooth surface. The substrate without any surface defects is the particular ideal selection. In an embodiment, the substrate is flexible and may be selected from a polymer thin film or a plastic which have a glass transition temperature T_{g} larger than 150° C., further larger than 200° C., still further larger than 250° C., even further larger than 300° C. The flexible substrate may be polyethylene terephthalate (PET) and polyethylene 2,6-naphthalate (PEN).

The anode may comprise a conductive metal, a metallic oxide, or a conductive polymer. The anode can inject holes easily into the hole injection layer (HIL), or the hole transport layer (HTL), or the light-emitting layer. In an embodiment, the absolute value of the difference between the work function of the anode and the HOMO energy level or the valence band energy level of the emitter in the light-emitting layer or of the p-type semiconductor material as the HIL or HTL or the electron blocking layer (EBL) is smaller than 0.5 eV, further smaller than 0.3 eV, still further smaller than 0.2 eV. Examples of the anode material include, but are not limited to Al, Cu, Au, Ag, Mg, Fe, Co, Ni, Mn, Pd, Pt, ITO, aluminum-doped zinc oxide (AZO), and the like. The anode material may also be other materials. The anode material may be deposited by any suitable technologies, such as the suitable physical vapor deposition method which includes radio frequency magnetron sputtering, vacuum thermal evaporation, electron beam, and the like. In other embodiments, the anode is patterned and structured. A patterned ITO conductive substrate may be purchased from market to prepare the organic electronic device according to the present embodiment.

The cathode may comprise a conductive metal or metal oxide. The cathode can inject electrons easily into the electron injection layer (EIL) or the electron transport layer (ETL), or directly injected into the light-emitting layer. In an embodiment, the absolute value of the difference between the work function of the cathode and the LUMO energy level or the valence band energy level of the emitter in the light-emitting layer or of the n type semiconductor material as the electron injection layer (EIL) or the electron transport layer (ETL) or the hole blocking layer (HBL) is smaller than 0.5 eV, further smaller than 0.3 eV, still further smaller than 0.2 eV. All materials capable of using as the cathode of the OLED may be used as the cathode material of the organic electronic device according to the present embodiment. Examples of the cathode material include, but are not limited to, Al, Au, Ag, Ca, Ba, Mg, LiF/Al, MgAg alloy, BaF2/Al, Cu, Fe, Co, Ni, Mn, Pd, Pt, ITO, and the like. The cathode material may be deposited by any suitable technologies, such as the suitable physical vapor deposition method which includes radio frequency magnetron sputtering, vacuum thermal evaporation, electron beam, etc.

The OLED may further comprise other functional layers such as a hole injection layer (HIL), a hole transport layer (HTL), an electron blocking layer (EBL), an electron injection layer (EIL), an electron transport layer (ETL) or a hole blocking layer (HBL). Materials which are suitable for use in these functional layers are described in detail above and in WO2010135519A1, US20090134784A1 and WO2011110277A1, the entire contents of which are hereby incorporated herein by reference.

In an embodiment, the method of preparing the organic electronic device includes the following step: depositing the organic mixture on a surface to form the functional layer. Specifically, the step includes: grinding and mixing the organic compound H1 and the organic compound H2; and then evaporating the ground and mixed organic compound H1 and organic compound H2 in an organic source, to form the functional layer. In addition, the step may also be: heating and melting the organic compound H1 and the organic compound H2 under vacuum to obtain a molten mixture; grinding the molten mixture after it is cooled to room temperature; and then evaporating the ground molten mixture in an organic source, to form the functional layer.

In an embodiment, the organic electronic device is an organic electroluminescent device, the functional layer of which is a light-emitting layer.

In another embodiment, the method of preparing the organic electronic device includes the following step: evaporating the organic compound H1 and the organic compound H2 in two sources under vacuum, respectively, to form the functional layer. It should be noted that the organic electronic device is an organic electroluminescent device, the functional layer of which is a light-emitting layer.

In an embodiment, the emission wavelength of the electroluminescent device is between 300 and 1000 nm, further between 350 and 900 nm, and still further between 400 and 800 nm.

In an embodiment, the above organic electronic device can be applied in electronic equipments. The electronic equipments are selected from display equipments, lighting equipments, light sources or sensors. Wherein, the organic electronic device may be an organic electroluminescent device.

An electronic equipment comprising the above organic electronic device is further provided.

Synthesis of the Organic Compound H1 (1-21)

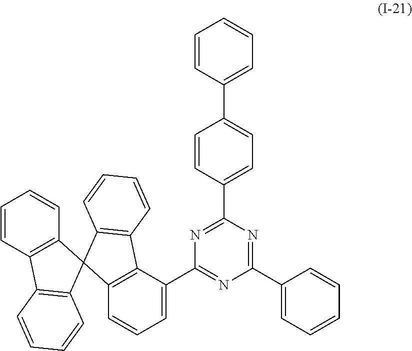 [SMILES: c1ccc(-c2ccc(-c3nc(-c4ccccc4)nc(-c4cccc5c4-c4ccccc4C54c5ccccc5-c5ccccc54)n3)cc2)cc1]

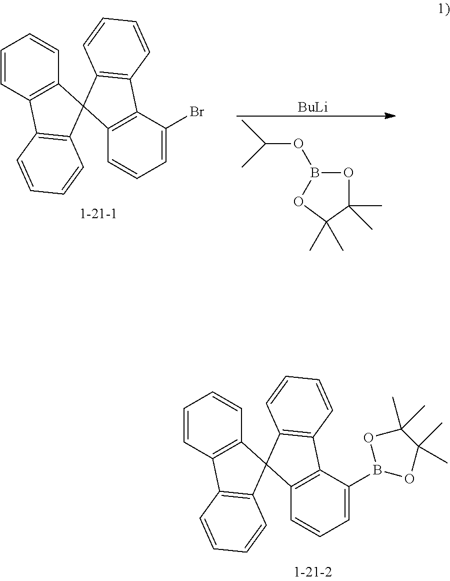

Compound (1-21-1) (31.6 g, 80 mmol) and 200 mL of anhydrous tetrahydrofuran were added to a 500 mL three-necked flask under nitrogen atmosphere, cooled to −78° C., and 85 mmol of n-butyllithium was slowly added dropwise, the mixture was reacted for 2 hours. Then 90 mmol of isopropoxyboronic acid pinacol ester was added one time to allow the reaction temperature to rise to room temperature naturally. The reaction was further performed for 12 hours and then quenched by addition of pure water. The reaction solution was rotary evaporated to remove most of the solvent, and then extracted with dichloromethane and washed with water for 3 times. The organic phase was collected, spin dried, and then recrystallized, with a yield of 90%.

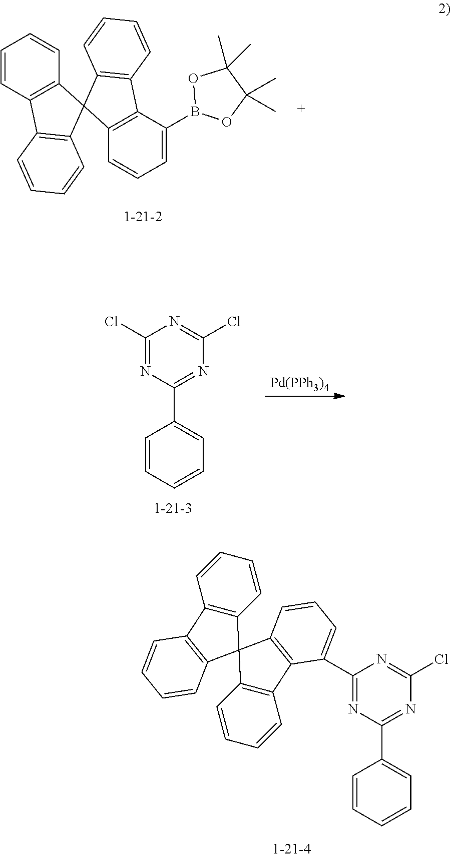 [SMILES: CC1(C)OB(c2cccc3c2-c2ccccc2C32c3ccccc3-c3ccccc32)OC1(C)C ; Clc1nc(Cl)nc(-c2ccccc2)n1 ; Clc1nc(-c2ccccc2)nc(-c2cccc3c2-c2ccccc2C32c3ccccc3-c3ccccc32)n1 ; "Pd(PPh3)4"]

Compound 1-21-2 (26.5 g, 60 mmol) and Compound 1-21-3 (13.6 g, 60 mmol), tetrakis(triphenylphosphine)palladium (3.45 g, 3 mmol), tetrabutylammonium bromide (2.6 g, 8 mmol), sodium hydroxide (3.2 g, 80 mmol), water (20 mL) and toluene (150 mL) were added to a 250 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 70%.

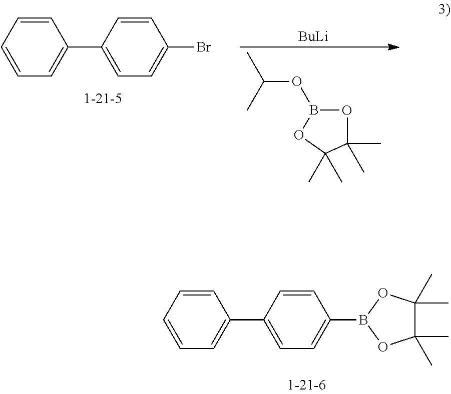

Compound (1-21-5) (7 g, 30 mmol) and 150 mL of anhydrous tetrahydrofuran were added to a 300 mL three-necked flask under nitrogen atmosphere, cooled to −78° C., and 35 mmol of n-butyllithium was slowly added dropwise, the mixture was reacted for 2 hours, then 40 mmol of isopropoxyboronic acid pinacol ester was added one time to allow the reaction temperature to rise to room temperature naturally. The reaction was further performed for 12 hours and then quenched by the addition of pure water. The reaction solution was rotary evaporated to remove most of the solvent, and then extracted with dichloromethane and washed with water for 3 times. The organic phase was collected, spin dried, and then recrystallized, with a yield of 90%.

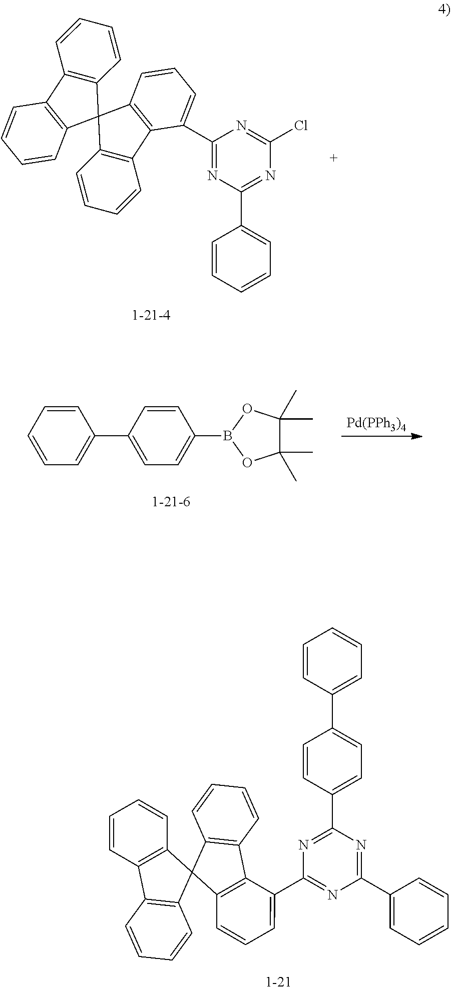 [SMILES: Clc1nc(-c2ccccc2)nc(-c2cccc3c2-c2ccccc2C32c3ccccc3-c3ccccc32)n1 ; CC1(C)OB(c2ccc(-c3ccccc3)cc2)OC1(C)C ; c1ccc(-c2ccc(-c3nc(-c4ccccc4)nc(-c4cccc5c4-c4ccccc4C54c5ccccc5-c5ccccc54)n3)cc2)cc1 ; "Pd(PPh3)4"]

Compound 1-21-4 (10.1 g, 20 mmol) and Compound 1-21-6 (5.6 g, 20 mmol), tetrakis(triphenylphosphine)palladium (1.15 g, 1 mmol), tetrabutylammonium bromide (1.3 g, 4 mmol), sodium hydroxide (1.6 g, 40 mmol), water (10 mL) and toluene (60 mL) were added to a 150 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography to obtain the compound, with a yield of 80%.

Synthesis of the Organic Compound H1 (1-22)

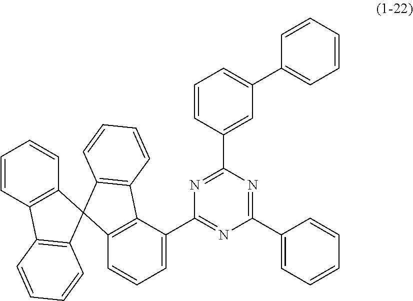 [SMILES: c1ccc(-c2cccc(-c3nc(-c4ccccc4)nc(-c4cccc5c4-c4ccccc4C54c5ccccc5-c5ccccc54)n3)c2)cc1]

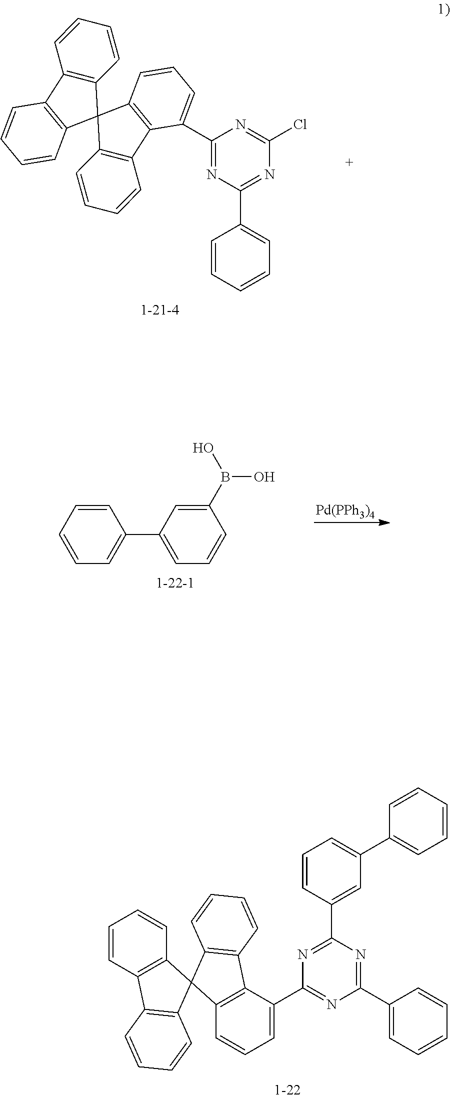 [SMILES: Clc1nc(-c2ccccc2)nc(-c2cccc3c2-c2ccccc2C32c3ccccc3-c3ccccc32)n1 ; OB(O)c1cccc(-c2ccccc2)c1 ; c1ccc(-c2cccc(-c3nc(-c4ccccc4)nc(-c4cccc5c4-c4ccccc4C54c5ccccc5-c5ccccc54)n3)c2)cc1 ; "Pd(PPh3)4"]

Compound 1-21-4 (10.1 g, 20 mmol) and Compound 1-22-1 (5.6 g, 20 mmol), tetrakis(triphenylphosphine)palladium (1.15 g, 1 mmol), tetrabutylammonium bromide (1.3 g, 4 mmol), sodium hydroxide (1.6 g, 40 mmol), water (10 mL) and toluene (60 mL) were added to a 150 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 80%.

Synthesis of the Organic Compound H2 (2-7)

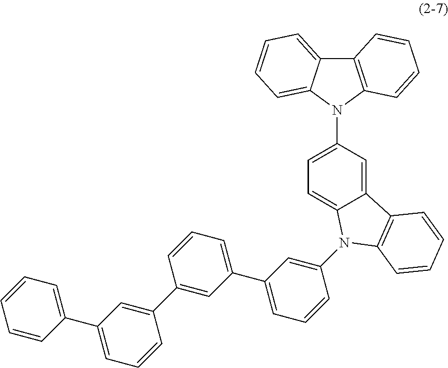 [SMILES: c1ccc(-c2cccc(-c3cccc(-c4cccc(-n5c6ccccc6c6cc(-n7c8ccccc8c8ccccc87)ccc65)c4)c3)c2)cc1]

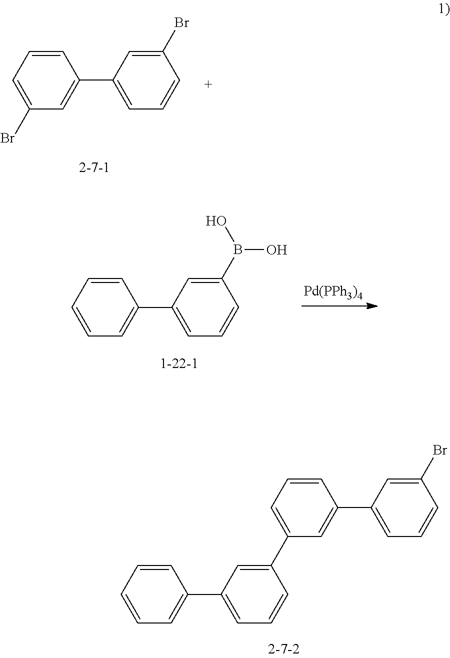 [SMILES: Brc1cccc(-c2cccc(Br)c2)c1 ; OB(O)c1cccc(-c2ccccc2)c1 ; Brc1cccc(-c2cccc(-c3cccc(-c4ccccc4)c3)c2)c1 ; "Pd(PPh3)4"]

Compound 2-7-1 (62.4 g, 200 mmol) and Compound 1-22-1 (56 g, 200 mmol), tetrakis(triphenylphosphine)palladium (11.5 g, 10 mmol), tetrabutylammonium bromide (13 g, 40 mmol), sodium hydroxide (16 g, 400 mmol), water (50 mL) and toluene (600 mL) were added to a 1500 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 70%.

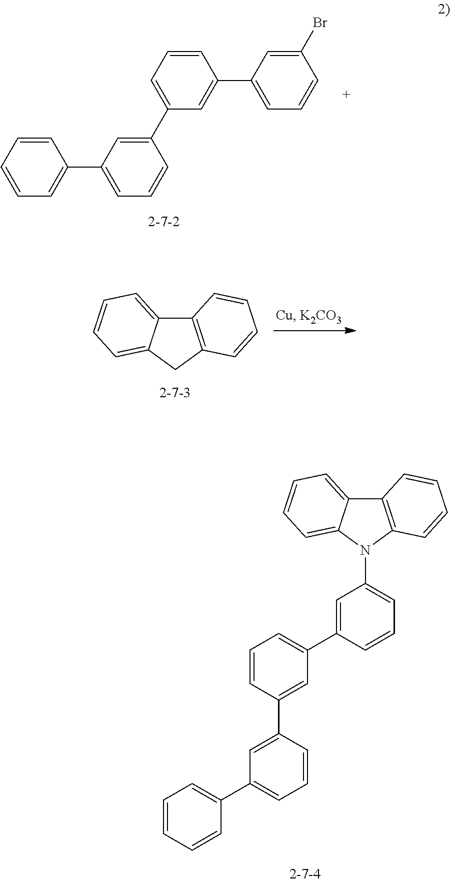

Compound (2-7-2) (38.5 g, 100 mmol) and Compound (2-7-3) (16.7 g, 100 mmol), copper powder (0.7 g, 10 mmol), potassium carbonate (13.8 g, 100 mmol) and 18-crown-6 (2.65 g, 5 mmol) and o-dichlorobenzene (400 mL) were added to a 1000 mL two-necked flask under nitrogen atmosphere, and the mixture was heated to 150° C. and reacted under stirring for 24 hours, and then the reaction was end. The reaction solution was distilled under reduced pressure to remove most of the solvent, and then dissolved with dichloromethane and washed with water for 3 times. The organic solution was collected, mixed with silica gel, and purified by column chromatography, with a yield of 80%.

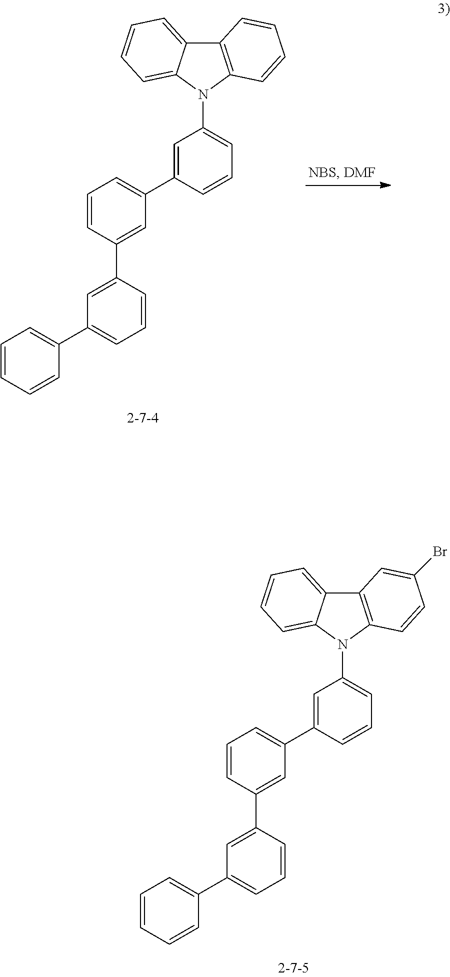 [SMILES: c1ccc(-c2cccc(-c3cccc(-c4cccc(-n5c6ccccc6c6ccccc65)c4)c3)c2)cc1 ; Brc1ccc2c(c1)c1ccccc1n2-c1cccc(-c2cccc(-c3cccc(-c4ccccc4)c3)c2)c1]

Compound 2-7-4 (28.3 g, 60 mmol) and 100 mL of N,N-dimethylformamide were added into a 250 mL single-necked flask, and 60 mmol of NBS N,N-dimethylformamide was added dropwise in an ice bath. The mixture was reacted under stirring for 12 hours in the dark, and then the reaction was ended. The reaction solution was poured into 500 mL of water, filtered with suction, and the filter residue was recrystallized, with a yield 85%. http://baike.sogou.com/lemma/ShowInnerLink.htm?lemmaId=600024&ss_c=ssc.citiao.link

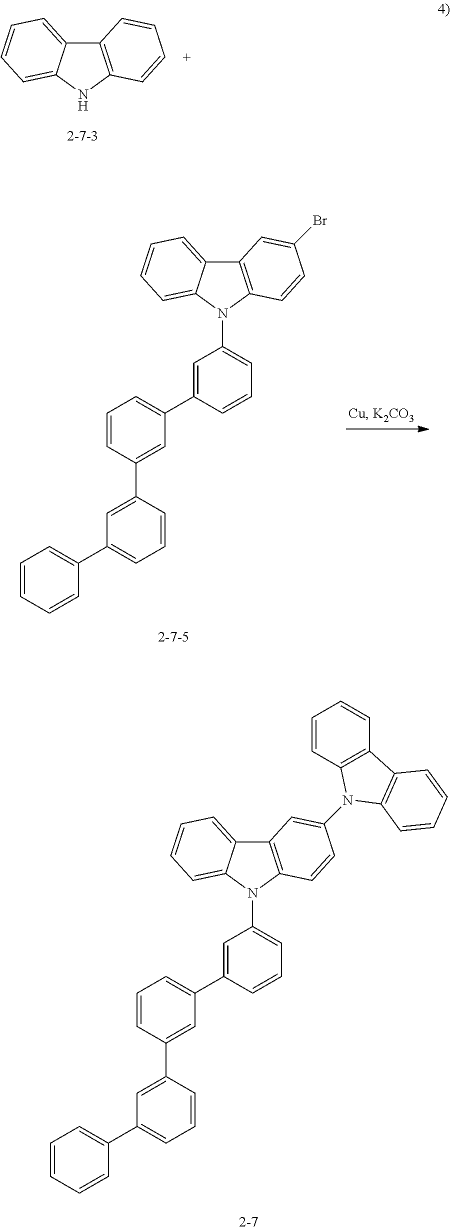 [SMILES: c1ccc2c(c1)[nH]c1ccccc12 ; Brc1ccc2c(c1)c1ccccc1n2-c1cccc(-c2cccc(-c3cccc(-c4ccccc4)c3)c2)c1 ; c1ccc(-c2cccc(-c3cccc(-c4cccc(-n5c6ccccc6c6cc(-n7c8ccccc8c8ccccc87)ccc65)c4)c3)c2)cc1]

Compound (2-7-3) (6.68 g, 40 mmol) and Compound (2-7-5) (18.9 g, 40 mmol), copper powder (0.26 g, 4 mmol), potassium carbonate (5.52 g, 40 mmol) and 18-crown-6 (1 g, 2 mmol) and o-dichlorobenzene (100 mL) were added to a 300 mL two-necked flask under nitrogen atmosphere, and the mixture was heated to 150° C. and reacted under stirring for 24 hours, and then the reaction was end. The reaction solution was distilled under reduced pressure to remove most of the solvent, and then dissolved with dichloromethane and washed with water for 3 times. The organic solution was collected, mixed with silica gel, and purified by column chromatography, with a yield of 75%.

Synthesis of the Organic Compound H2 (2-29)

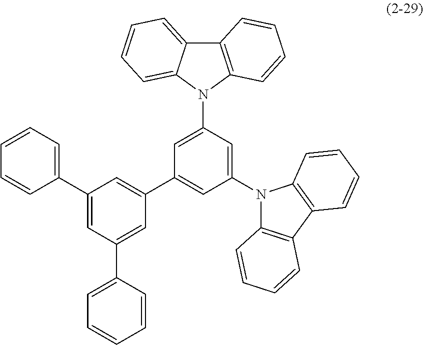 [SMILES: c1ccc(-c2cc(-c3ccccc3)cc(-c3cc(-n4c5ccccc5c5ccccc54)cc(-n4c5ccccc5c5ccccc54)c3)c2)cc1]

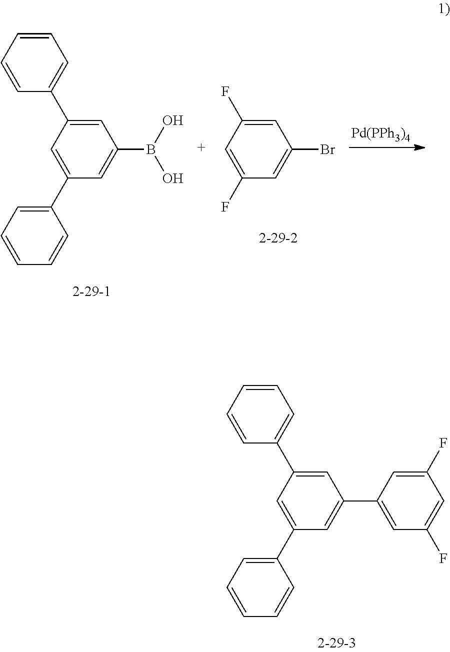 [SMILES: OB(O)c1cc(-c2ccccc2)cc(-c2ccccc2)c1 ; Fc1cc(F)cc(Br)c1 ; Fc1cc(F)cc(-c2cc(-c3ccccc3)cc(-c3ccccc3)c2)c1 ; "Pd(PPh3)4"]

Compound 2-29-1 (27.4 g, 100 mmol) and Compound 2-29-2 (19.2 g, 100 mmol), tetrakis(triphenylphosphine)palladium (5.8 g, 5 mmol), tetrabutylammonium bromide (6.5 g, 20 mmol), sodium hydroxide (8 g, 200 mmol), water (30 mL) and toluene (200 mL) were added to a 500 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 90%.

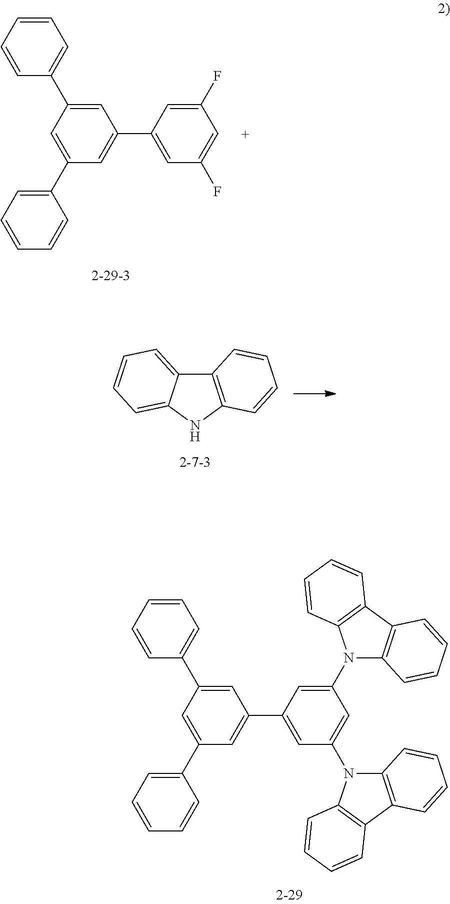 [SMILES: Fc1cc(F)cc(-c2cc(-c3ccccc3)cc(-c3ccccc3)c2)c1 ; c1ccc2c(c1)[nH]c1ccccc12 ; c1ccc(-c2cc(-c3ccccc3)cc(-c3cc(-n4c5ccccc5c5ccccc54)cc(-n4c5ccccc5c5ccccc54)c3)c2)cc1]

Compound 2-29-3 (16 g, 60 mmol), Compound 2-7-3 (20 g, 120 mmol) and potassium carbonate (27.6 g, 200 mmol) were mixed under nitrogen atmosphere, then 200 mL of N,N-dimethylformamide solvent was added. The mixture was reacted under stirring at 155° C. for 12 hours, cooled to room temperature, and extracted with dichloromethane. The organic solution was collected, mixed with silica gel, and then purified by column chromatography, with a yield of 80%.

Synthesis of the Organic Compound H2 (3-2)

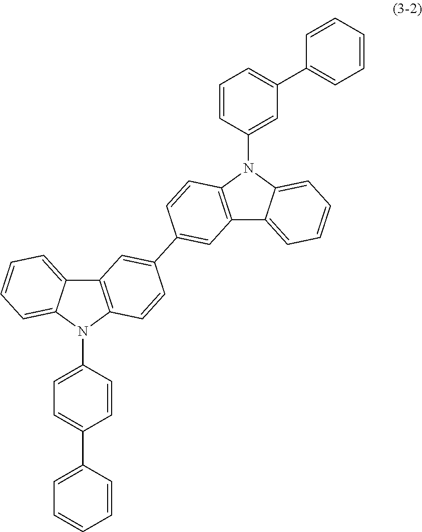 [SMILES: c1ccc(-c2ccc(-n3c4ccccc4c4cc(-c5ccc6c(c5)c5ccccc5n6-c5cccc(-c6ccccc6)c5)ccc43)cc2)cc1]

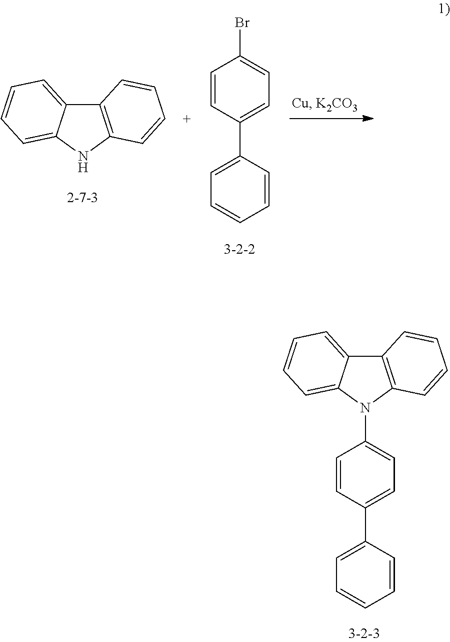 [SMILES: c1ccc2c(c1)[nH]c1ccccc12 ; Brc1ccc(-c2ccccc2)cc1 ; c1ccc(-c2ccc(-n3c4ccccc4c4ccccc43)cc2)cc1]

Compound (2-7-3) (16.7 g, 100 mmol) and Compound (3-2-2) (24.5 g, 105 mmol), copper powder (0.65 g, 10 mmol), potassium carbonate (13.8 g, 100 mmol) and 18-crown-6 (2.65 g, 5 mmol) and o-dichlorobenzene (200 mL) were added to a 500 mL two-necked flask under nitrogen atmosphere, and the mixture was heated to 150° C. and reacted under stirring for 24 hours, and then the reaction was end. The reaction solution was distilled under reduced pressure to remove most of the solvent, and then dissolved with dichloromethane and washed with water for 3 times. The organic solution was collected, mixed with silica gel, and purified by column chromatography, with a yield of 80%.

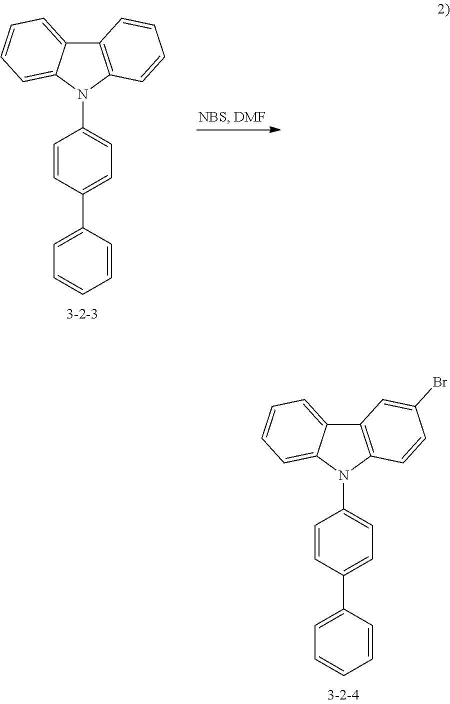 [SMILES: c1ccc(-c2ccc(-n3c4ccccc4c4ccccc43)cc2)cc1 ; Brc1ccc2c(c1)c1ccccc1n2-c1ccc(-c2ccccc2)cc1]

Compound 3-2-3 (19.1 g, 60 mmol) and 100 mL of N,N-dimethylformamide were added into a 250 mL single-necked flask, and 60 mmol of NBS N,N-dimethylformamide was added dropwise in an ice bath. The mixture was reacted under stirring for 12 hours in the dark, and then the reaction was ended. The reaction solution was poured into 500 mL of water, filtered with suction, and the filter residue was recrystallized, with a yield 90%. http://baike.sogou.com/lemma/ShowInnerLink.htm?lemmaId=600024&ss_c=ssc.citiao.link

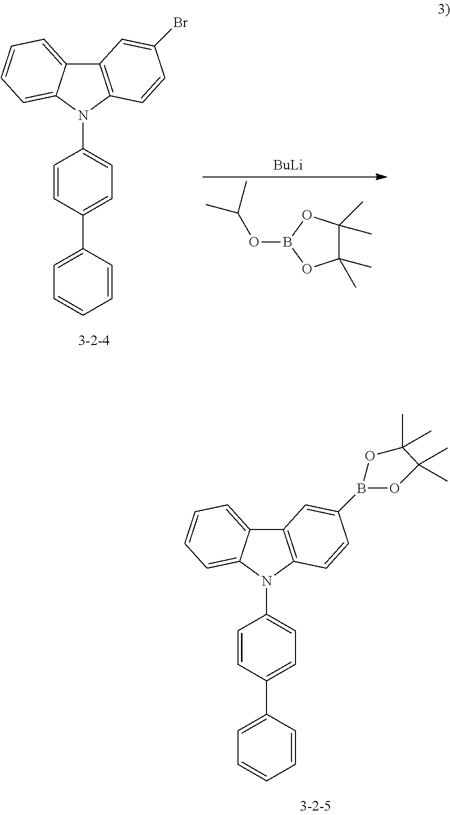

Compound (3-2-4) (15.9 g, 40 mmol) and 300 mL of anhydrous tetrahydrofuran were added to a 500 mL three-necked flask under nitrogen atmosphere, cooled to −78° C., and 50 mmol of n-butyllithium was slowly added dropwise, the mixture was reacted for 2 hours, then 55 mmol of isopropoxyboronic acid pinacol ester was added one time to allow the reaction temperature to rise to room temperature naturally. The reaction was further performed for 12 hours and then quenched by the addition of pure water. The reaction solution was rotary evaporated to remove most of the solvent, and then extracted with dichloromethane and washed with water for 3 times.

The organic phase was collected, spin dried, and then recrystallized, with a yield of 80%.

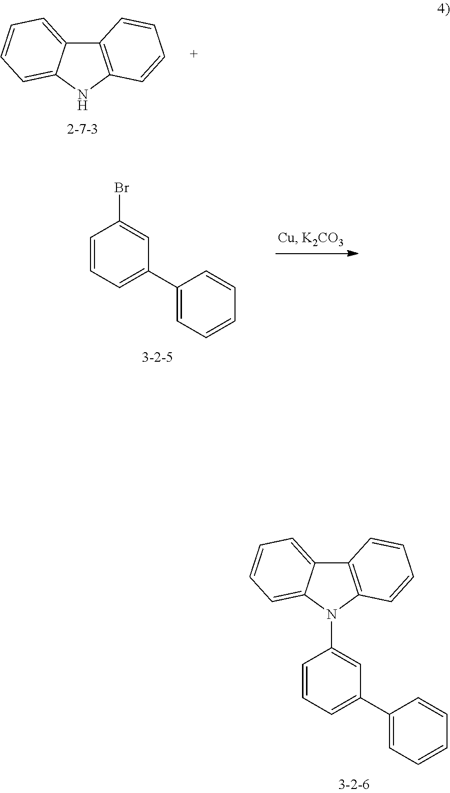 [SMILES: c1ccc2c(c1)[nH]c1ccccc12 ; Brc1cccc(-c2ccccc2)c1 ; c1ccc(-c2cccc(-n3c4ccccc4c4ccccc43)c2)cc1]

Compound (2-7-3) (16.7 g, 100 mmol) and Compound (3-2-5) (24.5 g, 105 mmol), copper powder (0.65 g, 10 mmol), potassium carbonate (13.8 g, 100 mmol) and 18-crown-6 (2.65 g, 5 mmol) and o-dichlorobenzene (200 mL) were added to a 500 mL two-necked flask under nitrogen atmosphere, and the mixture was heated to 150° C. and reacted under stirring for 24 hours, and then the reaction was end. The reaction solution was distilled under reduced pressure to remove most of the solvent, and then dissolved with dichloromethane and washed with water for 3 times. The organic solution was collected, mixed with silica gel, and purified by column chromatography, with a yield of 75%.

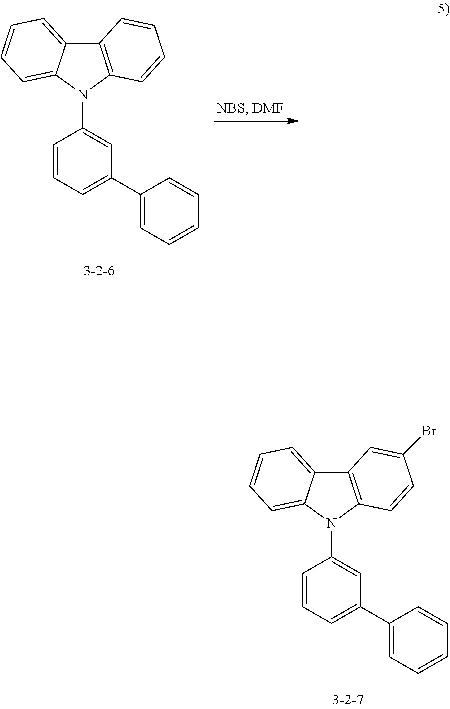 [SMILES: c1ccc(-c2cccc(-n3c4ccccc4c4ccccc43)c2)cc1 ; Brc1ccc2c(c1)c1ccccc1n2-c1cccc(-c2ccccc2)c1]

Compound 3-2-6 (19.1 g, 60 mmol) and 100 mL of N,N-dimethylformamide were added into a 250 mL single-necked flask, and 60 mmol of NBS N,N-dimethylformamide was added dropwise in an ice bath. The mixture was reacted under stirring for 12 hours in the dark, and then the reaction was ended. The reaction solution was poured into 500 mL of water, filtered with suction, and the filter residue was recrystallized, with a yield 88%. http://baike.sogou.com/lemma/ShowInnerLink.htm?lemmaId=600024&ss_c=ssc.citiao.link

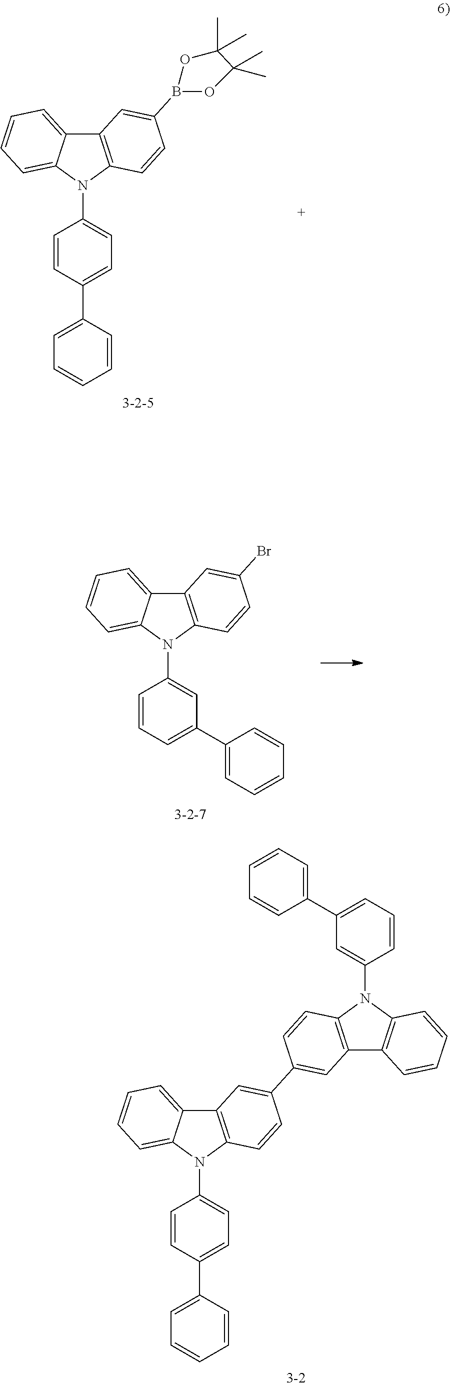 [SMILES: CC1(C)OB(c2ccc3c(c2)c2ccccc2n3-c2ccc(-c3ccccc3)cc2)OC1(C)C ; Brc1ccc2c(c1)c1ccccc1n2-c1cccc(-c2ccccc2)c1 ; c1ccc(-c2ccc(-n3c4ccccc4c4cc(-c5ccc6c(c5)c5ccccc5n6-c5cccc(-c6ccccc6)c5)ccc43)cc2)cc1]

Compound 3-2-5 (8.9 g, 20 mmol) and Compound 3-2-7 (8 g, 20 mmol), tetrakis(triphenylphosphine)palladium (1.15 g, 1 mmol), tetrabutylammonium bromide (2.6 g, 8 mmol), sodium hydroxide (3.2 g, 80 mmol), water (10 mL) and toluene (100 mL) were added to a 250 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 80%.

Synthesis of the Organic Compound H2 (3-20)

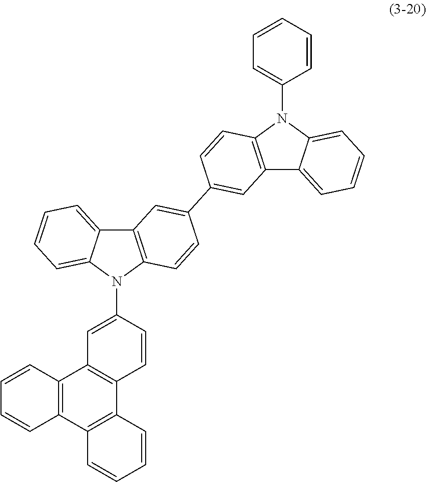 [SMILES: c1ccc(-n2c3ccccc3c3cc(-c4ccc5c(c4)c4ccccc4n5-c4ccc5c6ccccc6c6ccccc6c5c4)ccc32)cc1]

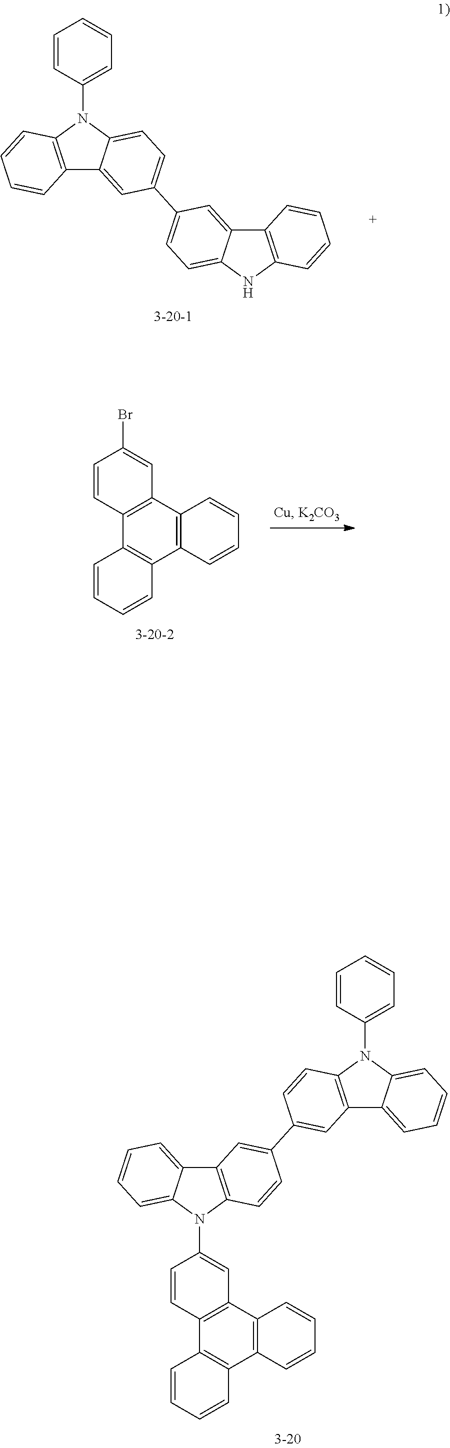 [SMILES: c1ccc(-n2c3ccccc3c3cc(-c4ccc5[nH]c6ccccc6c5c4)ccc32)cc1 ; Brc1ccc2c3ccccc3c3ccccc3c2c1 ; c1ccc(-n2c3ccccc3c3cc(-c4ccc5c(c4)c4ccccc4n5-c4ccc5c6ccccc6c6ccccc6c5c4)ccc32)cc1]

Compound (3-20-1) (24.5 g, 60 mmol) and Compound (3-20-2) (18.4 g, 60 mmol), copper powder (0.39 g, 6 mmol), potassium carbonate (8.28 g, 60 mmol) and 18-crown-6 (2.65 g, 5 mmol) and o-dichlorobenzene (150 mL) were added to a 300 mL two-necked flask under nitrogen atmosphere, and the mixture was heated to 150° C. and reacted under stirring for 24 hours, and then the reaction was end. The reaction solution was distilled under reduced pressure to remove most of the solvent, and then dissolved with dichloromethane and washed with water for 3 times. The organic solution was collected, mixed with silica gel, and purified by column chromatography, with a yield of 85%.

Synthesis of the Organic Compound H2 (4-10)

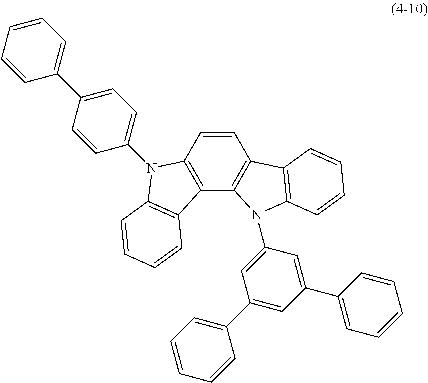 [SMILES: c1ccc(-c2ccc(-n3c4ccccc4c4c3ccc3c5ccccc5n(-c5cc(-c6ccccc6)cc(-c6ccccc6)c5)c34)cc2)cc1]

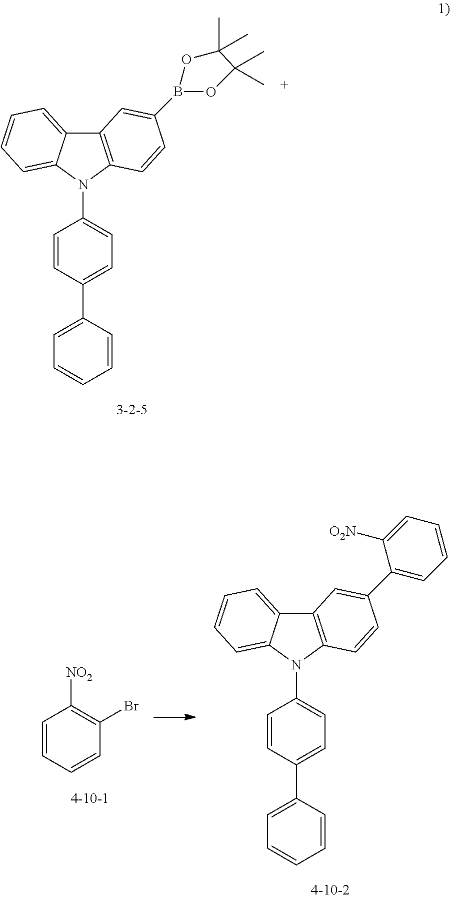 [SMILES: CC1(C)OB(c2ccc3c(c2)c2ccccc2n3-c2ccc(-c3ccccc3)cc2)OC1(C)C ; O=[N+]([O-])c1ccccc1Br ; O=[N+]([O-])c1ccccc1-c1ccc2c(c1)c1ccccc1n2-c1ccc(-c2ccccc2)cc1]

Compound 3-2-5 (26.7 g, 60 mmol) and Compound 4-10-1 (12.1 g, 60 mmol), tetrakis(triphenylphosphine)palladium (3.45 g, 3 mmol), tetrabutylammonium bromide (7.8 g, 24 mmol), sodium hydroxide (3.2 g, 80 mmol), water (20 mL) and toluene (120 mL) were added to a 250 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 80%.

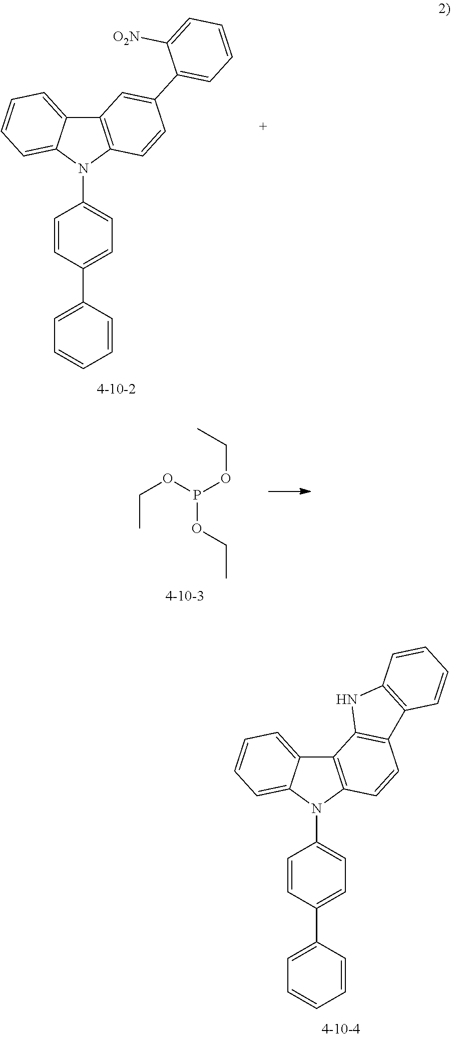

Compound 4-10-2 (17.6 g, 40 mmol) and triethylphosphine (10.1 g, 100 mmol) were added to a 150 mL two-necked flask under nitrogen atmosphere, and the mixture was heated to 190° C. and reacted under stirring for 12 hours, and then the reaction was ended. The reaction solution was distilled under reduced pressure to remove most of the solvent, and then dissolved with dichloromethane and washed with water for 3 times. The organic solution was collected, mixed with silica gel, and then purified by column chromatography, with a yield of 85%.

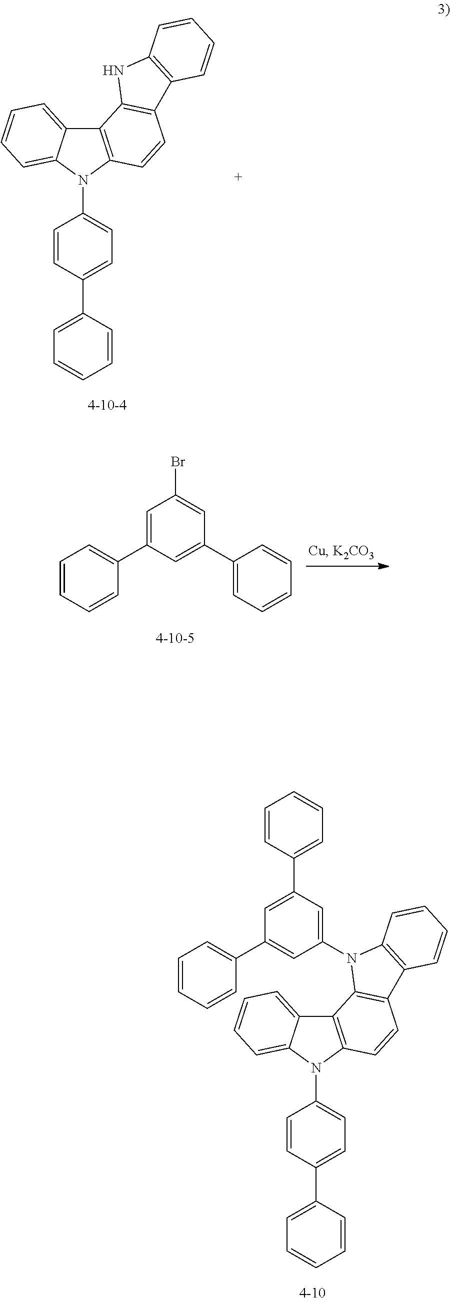 [SMILES: c1ccc(-c2ccc(-n3c4ccccc4c4c5[nH]c6ccccc6c5ccc43)cc2)cc1 ; Brc1cc(-c2ccccc2)cc(-c2ccccc2)c1 ; c1ccc(-c2ccc(-n3c4ccccc4c4c3ccc3c5ccccc5n(-c5cc(-c6ccccc6)cc(-c6ccccc6)c5)c34)cc2)cc1]

Compound (4-10-4) (8.2 g, 20 mmol) and Compound (4-10-5) (6.2 g, 20 mmol), copper powder (0.13 g, 2 mmol), potassium carbonate (2.8 g, 20 mmol) and 18-crown-6 (2.65 g, 5 mmol) and o-dichlorobenzene (80 mL) were added to a 150 mL two-necked flask under nitrogen atmosphere, and the mixture was heated to 150° C. and reacted under stirring for 24 hours, and then the reaction was end. The reaction solution was distilled under reduced pressure to remove most of the solvent, and then dissolved with dichloromethane and washed with water for 3 times. The organic solution was collected, mixed with silica gel, and purified by column chromatography, with a yield of 80%.

Synthesis of the Organic Compound H2 (5-2)

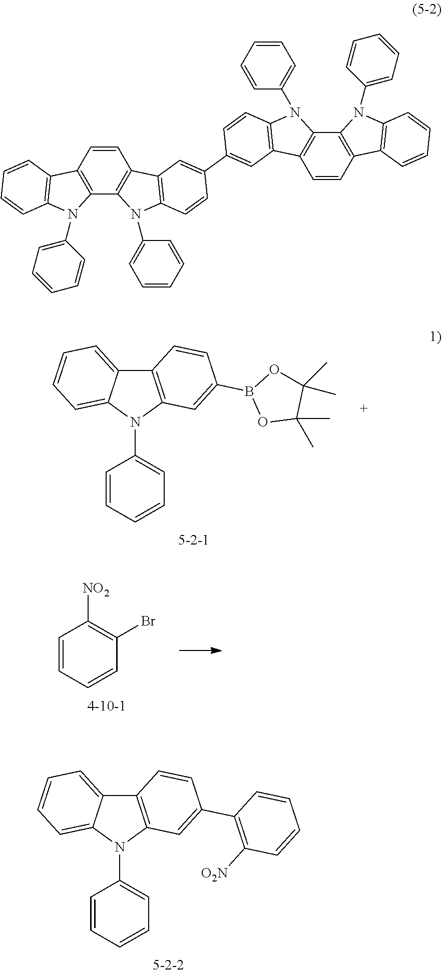 [SMILES: c1ccc(-n2c3ccccc3c3ccc4c5cc(-c6ccc7c(c6)c6ccc8c9ccccc9n(-c9ccccc9)c8c6n7-c6ccccc6)ccc5n(-c5ccccc5)c4c32)cc1 ; CC1(C)OB(c2ccc3c4ccccc4n(-c4ccccc4)c3c2)OC1(C)C ; O=[N+]([O-])c1ccccc1Br ; O=[N+]([O-])c1ccccc1-c1ccc2c3ccccc3n(-c3ccccc3)c2c1]

Compound 5-2-1 (36.9 g, 100 mmol) and Compound 4-10-1 (20.2 g, 100 mmol), tetrakis(triphenylphosphine)palladium (5.75 g, 5 mmol), tetrabutylammonium bromide (16.3 g, 50 mmol), sodium hydroxide (6 g, 150 mmol), water (20 mL) and toluene (120 mL) were added to a 250 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 80%.

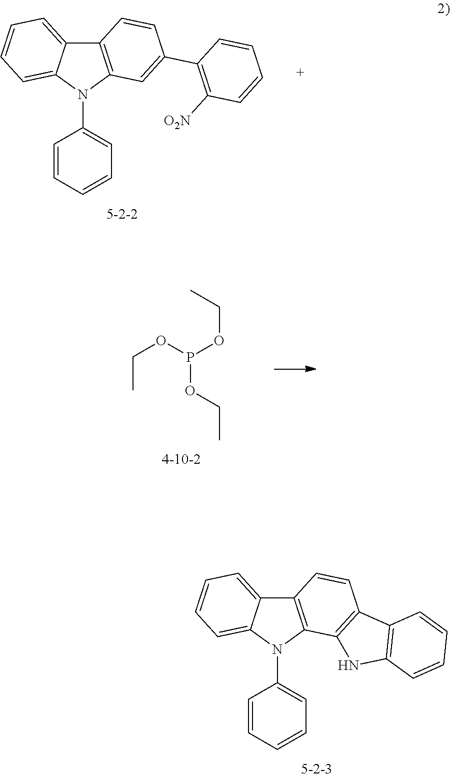

Compound 5-2-2 (21.8 g, 60 mmol) and triethylphosphine (10.1 g, 100 mmol) were added to a 150 mL two-necked flask under nitrogen atmosphere, and the mixture was heated to 190° C. and reacted under stirring for 12 hours, and then the reaction was ended. The reaction solution was distilled under reduced pressure to remove most of the solvent, and then dissolved with dichloromethane and washed with water for 3 times. The organic solution was collected, mixed with silica gel, and then purified by column chromatography, with a yield of 85%.

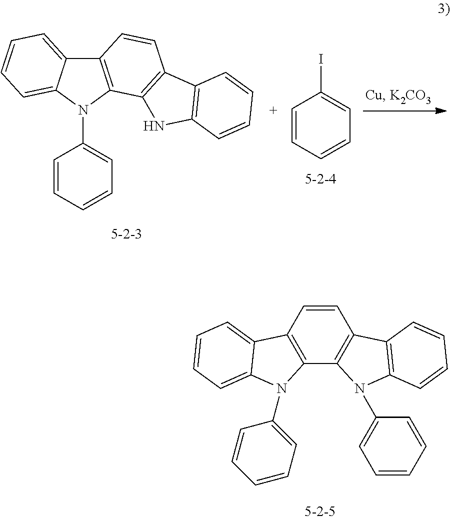

Compound (5-2-3) (10 g, 30 mmol) and Compound (5-2-4) (6.1 g, 30 mmol), copper powder (0.26 g, 4 mmol), potassium carbonate (5.6 g, 40 mmol) and 18-crown-6 (2.65 g, 5 mmol) and o-dichlorobenzene (80 mL) were added to a 150 mL two-necked flask under nitrogen atmosphere, and the mixture was heated to 150° C. and reacted under stirring for 24 hours, and then the reaction was end. The reaction solution was distilled under reduced pressure to remove most of the solvent, and then dissolved with dichloromethane and washed with water for 3 times. The organic solution was collected, mixed with silica gel, and purified by column chromatography, with a yield of 75%.

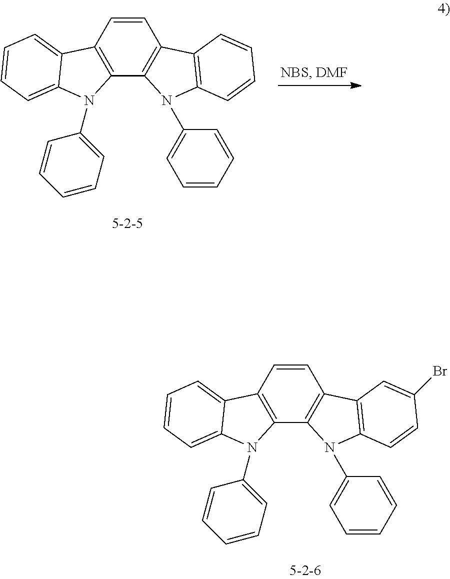 [SMILES: c1ccc(-n2c3ccccc3c3ccc4c5ccccc5n(-c5ccccc5)c4c32)cc1 ; Brc1ccc2c(c1)c1ccc3c4ccccc4n(-c4ccccc4)c3c1n2-c1ccccc1]

Compound 5-2-5 (8.2 g, 20 mmol) and 100 mL of N,N-dimethylformamide were added into a 250 mL single-necked flask, and 20 mmol of NBS N,N-dimethylformamide was added dropwise in an ice bath. The mixture was reacted under stirring for 12 hours in the dark, and then the reaction was ended. The reaction solution was poured into 500 mL of water, filtered with suction, and the filter residue was recrystallized, with a yield 88%.

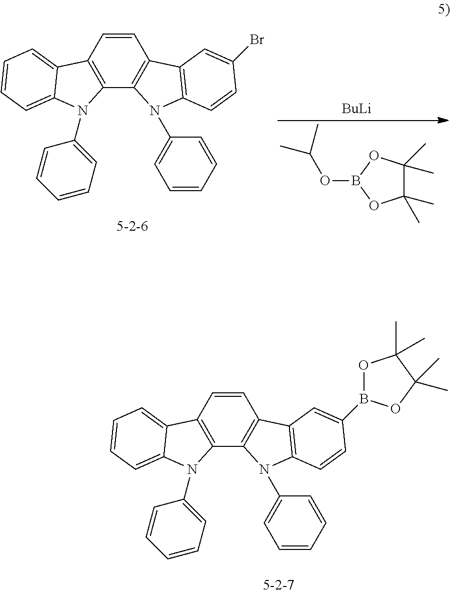

Compound (5-2-6) (4.9 g, 10 mmol) and 80 mL of anhydrous tetrahydrofuran were added to a 150 mL three-necked flask under nitrogen atmosphere, cooled to −78° C., and 50 mmol of n-butyllithium was slowly added dropwise, the mixture was reacted for 2 hours, then 12 mmol of isopropoxyboronic acid pinacol ester was added one time to allow the reaction temperature to rise to room temperature naturally. The reaction was further performed for 12 hours and then quenched by the addition of pure water. The reaction solution was rotary evaporated to remove most of the solvent, and then extracted with dichloromethane and washed with water for 3 times. The organic phase was collected, spin dried, and then recrystallized, with a yield of 80%.

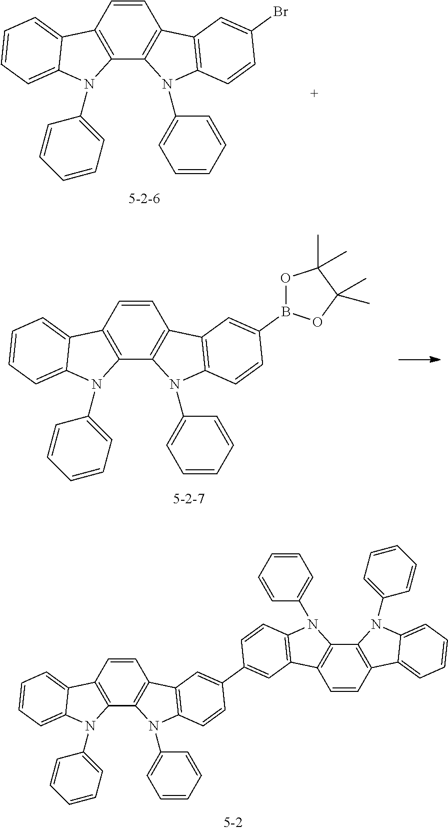 [SMILES: Brc1ccc2c(c1)c1ccc3c4ccccc4n(-c4ccccc4)c3c1n2-c1ccccc1 ; CC1(C)OB(c2ccc3c(c2)c2ccc4c5ccccc5n(-c5ccccc5)c4c2n3-c2ccccc2)OC1(C)C ; c1ccc(-n2c3ccccc3c3ccc4c5cc(-c6ccc7c(c6)c6ccc8c9ccccc9n(-c9ccccc9)c8c6n7-c6ccccc6)ccc5n(-c5ccccc5)c4c32)cc1]

Compound 5-2-6 (2.4 g, 5 mmol) and Compound 5-2-7 (2.7 g, 5 mmol), tetrakis(triphenylphosphine)palladium (1.15 g, 1 mmol), tetrabutylammonium bromide (1.6 g, 5 mmol), sodium hydroxide (0.6 g, 15 mmol), water (2 mL) and toluene (30 mL) were added to a 100 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 80%.

Energy Structure of Organic Compounds

The energy levels of organic materials can be obtained by quantum calculations, such as using TD-DFT (Time Dependent-Density Functional Theory) by Gaussian03W (Gaussian Inc.), and the specific simulation methods can be found in WO2011141110. Firstly, the molecular geometry is optimized by semi-empirical method “Ground State/Semi-empirical/Default Spin/AM1” (Charge 0/Spin Singlet), and then the energy structure of organic molecules is calculated by TD-DFT (time-density functional theory) “TD-SCF/DFT/Default Spin/B3PW91” and the basis set “6-31G (d)” (Charge 0/Spin Singlet). The HOMO and LUMO levels are calculated according to the following calibration formulas, S1 and T1 are used directly.

HOMO(eV)=((HOMO(G)×27.212)−0.9899)/1.1206

LUMO(eV)=((LUMO(G)×27.212)−2.0041)/1.385

wherein, HOMO(G) and LUMO(G) in the unit of Hartree are the direct calculation results of Gaussian 03W. The results were shown in Table 1:

TABLE 1

| | HOMO | (HOMO-(HOMO- | LUMO | | |
|---|---|---|---|---|---|
| Materials | [eV] | 1)) [eV] | [eV] | T1 [eV] | S1 [eV] |
| HATCN | −9.04 | 0 | −5.08 | 2.32 | 3.17 |
| SFNFB | −5.26 | 0.74 | −2.19 | 2.59 | 3.22 |
| (1-21) | −6.01 | 0.28 | −2.86 | 2.92 | 3.29 |
| (1-22) | −6.01 | 0.28 | −2.84 | 2.95 | 3.26 |
| (3-2) | −5.44 | 0.42 | −2.22 | 2.92 | 3.12 |
| (3-20) | −5.44 | 0.42 | −2.36 | 2.69 | 3.17 |
| Ir(p-ppy)₃ | −5.17 | 0.15 | −2.32 | 2.67 | 2.90 |
| NaTzF₂ | −6.19 | 0.02 | −2.82 | 2.55 | 3.52 |

| | | min((LUMO(H1)- | |
|---|---|---|---|
| Materials | | HOMO(H2), | |
| H1 | H2 | LUMO(H2)-HOMO(H1)) | min(E_{T}(H1), E_{T}(H2)) |
| (1-21) | (3-2) | 2.58 | 2.92 |
| (1-21) | (3-20) | 2.58 | 2.69 |
| (1-22) | (3-2) | 2.60 | 2.92 |
| (1-22) | (3-20) | 2.60 | 2.69 |

Preparation and Characterization of OLED Devices

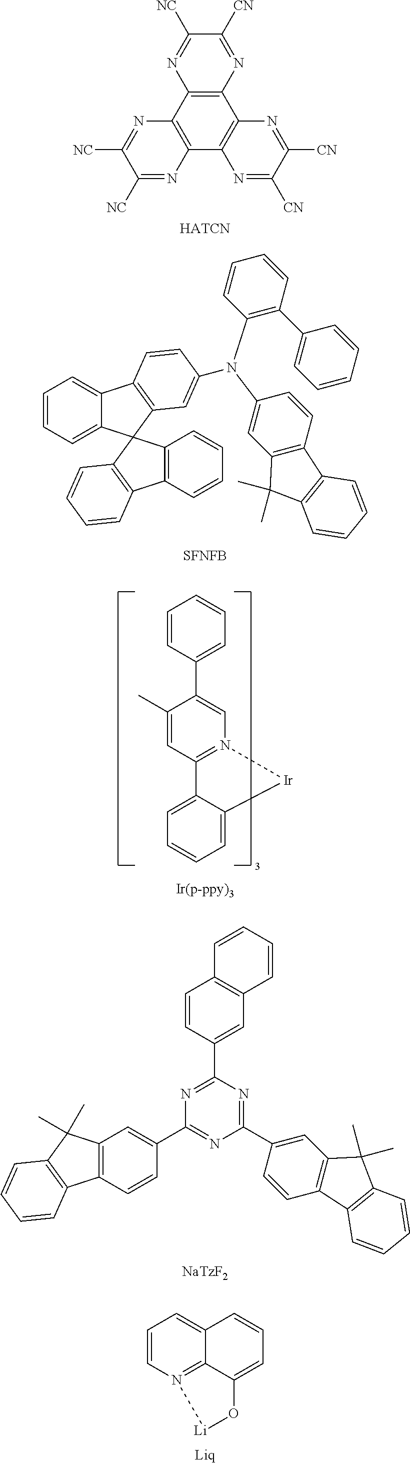

In the present embodiment, compounds (1-21) and (3-2), (1-21) and (3-20), (1-22) and (3-2), (1-22) and (3-20) with mass ratio of 1:1 were used as the host material, respectively, Ir(ppy)₃ (tris(2-phenylpyridine)iridium(III)) as the light-emitting material, HATCN as the hole injection material, SFNFB as the hole transport material, NaTzF₂ as the electron transport material, and Liq as the electron injection material, to prepare an electroluminescent device with a device structure of ITO/HATCN/HTL/host material: Ir(ppy)₃(10%)/NaTzF₂:Liq/Liq/Al.

The above materials such as HATCN, SFNFB, Ir(p-ppy)₃, NaTzF₂ and Liq are all commercially available, such as from Jilin OLED Material Tech Co., Ltd (www.jl-oled.com). The above materials such as HATCN, SFNFB, Ir(p-ppy)₃, NaTzF₂ and Liq can be obtained using synthesis methods which can be found in the references or patents of the art: J. Org. Chem., 1986, 51, 5241, WO2012034627, WO2010028151, US2013248830.

Preparation of OLED Devices

The structure of the OLED device is ITO/HATCN/SFNFB/host material: Ir(p-ppy)₃ (10%)/NaTzF₂:Liq/Liq/Al. The method of preparing the OLED device includes the following steps:

S1: Cleaning of ITO (Indium Tin Oxide) conductive glass substrate: cleaning the substrate with a variety of solvents (such as one or more of chloroform, acetone or isopropanol), and then treating with ultraviolet and ozone;

S2: HATCN (30 nm), SFNFB(50 nm), host material: 10% Ir(p-ppy)₃ (40 nm), NaTzF₂:Liq (30 nm), Liq (1 nm), Al (100 nm) were formed by thermal evaporation in high vacuum (1×10⁻⁶ mbar);

S3: Encapsulating: encapsulating the OLED device with UV-curable resin in a nitrogen glove box.

Wherein, the organic mixture is acted as the host material of the light-emitting layer, and the method of preparing the host material is as described above. Specifically, the following three ways are included:

(1) Vacuum co-evaporation, i.e., the organic compound H1 and the organic compound H2 were respectively placed in two different sources, and the doping ratio of the two host materials was controlled by controlling the respective evaporation rates.

(2) Simple blending, i.e., the organic compound H1 and the organic compound H2 were weighed according to a certain ratio, doped together, ground at room temperature, and the resulting mixture was placed in an organic source for evaporation.

(3) Organic alloy, i.e., the organic compound H1 and the organic compound H2 were weighed according to a certain ratio, doped together, heated and stirred until the mixture was melted under a vacuum lower than 10⁻³ torr. The mixture was cooled and then ground, and the resulting mixture was placed in an organic source for evaporation.

TABLE 2
Host materials in different OLED devices

| OLED | | Lifetimes of devices |
|---|---|---|
| devices | Host materials | T90 @ 1000 nits |
| OLED1 | (1-21):(3-2) = 1:1 Vacuum | 12 |
| | co-evaporation | |
| OLED2 | (1-21):(3-2) = 1:1 Simple blending | 16 |
| OLED3 | (1-21):(3-2) = 1:1 Organic alloy | 18 |
| OLED4 | (1-21):(3-20) = 1:1 Vacuum | 10 |
| | co-evaporation | |
| OLED5 | (1-21):(3-20) = 1:1 Simple | 14 |
| | blending | |
| OLED6 | (1-21):(3-20) = 1:1 Organic alloy | 16 |
| OLED7 | (1-22):(3-2) = 1:1 Vacuum | 18 |
| | co-evaporation | |
| OLED8 | (1-22):(3-2) = 1:1 Simple blending | 22 |
| OLED9 | (1-22):(3-2) = 1:1 Organic alloy | 25 |
| OLED10 | (1-22):(3-20) = 1:1 Vacuum | 15 |
| | co-evaporation | |
| OLED11 | (1-22):(3-20) = 1:1 Simple | 19 |
| | blending | |
| OLED12 | (1-22):(3-20) = 1:1 Organic alloy | 20 |
| RefOLED | mCP | 1 |

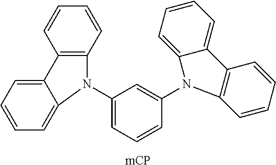

wherein, mCP was purchased from Jilin OLED Material Tech Co., Ltd.

The current-voltage (J-V) characteristics of each OLED device were characterized by characterization equipment while important parameters such as efficiency, lifetime and external quantum efficiency were recorded. The lifetimes of the organic mixture-based OLED devices were tested as shown in Table 2, wherein the lifetime data as shown are the lifetimes relative to the RefOLED device, and the light-emitting lifetimes of OLED3, OLED6, OLED9 and OLED12 are the highest among the same types of devices, wherein the lifetime of OLED9 device is 10 times or more that of RefOELD. It can be seen that the lifetimes of the OLED devices prepared by using the above organic compounds have been greatly improved

1. An organic mixture which comprises two organic compounds H1 and H2, the organic compound H1 is a spiro compound, and the organic compound H2 is a compound containing electron-donating group, wherein, min((LUMO(H1)−HOMO(H2)), (LUMO(H2)−HOMO(H1)))≤min (E_{T}(H1), E_{T}(H2))+0.1 eV; wherein, the LUMO(H1), HOMO(H1) and E_{T}(H1) respectively represent the lowest unoccupied molecular orbital energy level, highest occupied molecular orbital energy level and triplet excited state energy level of the organic compound H1, and the LUMO(H2), HOMO(H2) and E_{T}(H2) respectively represent the lowest unoccupied molecular orbital energy level, highest occupied molecular orbital energy level and triplet excited state energy level of the organic compound H2.

2. The organic mixture of claim 1, wherein, the structure of the organic compound H1 is represented by general formula (1): 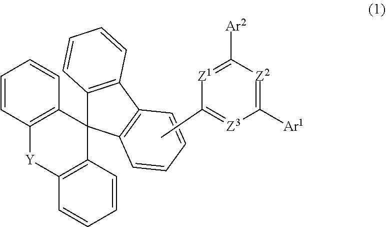
wherein, Z¹, Z² and Z³ are independently selected from N or C atoms, and at least one of Z¹, Z² and Z³ is N;
Y is selected from a signal bond, N(R), C(R)₂, Si(R)₂, O, C═N(R), C═C(R)₂, P(R), P(═O)R, S, S═O or SO₂; R is selected from the group consisting of H, D, F, CN, carbonyl, sulfonyl, alkoxy, alkyl with a carbon atom number of 1 to 30, cycloalkyl with a carbon atom number of 3 to 30, an aromatic group with a ring atom number of 5 to 60 and a heteroaromatic group with a ring atom number of 5 to 60;
Ar¹ and Ar² are independently selected from an aromatic group with a ring atom number of 5 to 60 or a heteroaromatic group with a ring atom number of 5 to 60.

3. The organic mixture of claim 2, wherein, Ar¹ and Ar² are independently selected from one of the following groups: 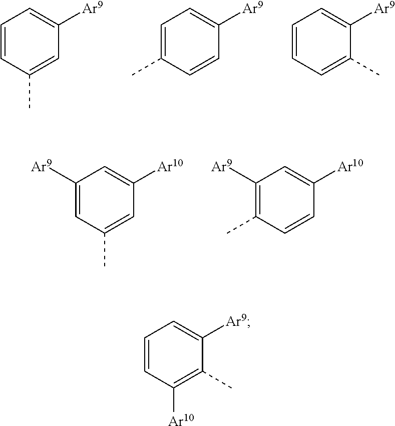
wherein, Ar⁹ and Ar¹⁰ are aromatic groups with a ring atom number of 5 to 48 or heteroaromatic groups with a ring atom number of 5 to 48.

4. The organic mixture of claim 2, wherein, the organic compound H1 is selected from one of compounds represented by the following structures: 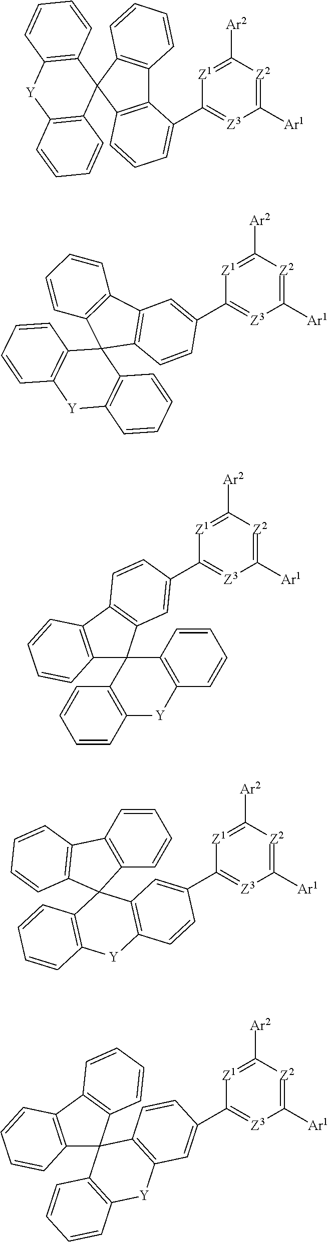 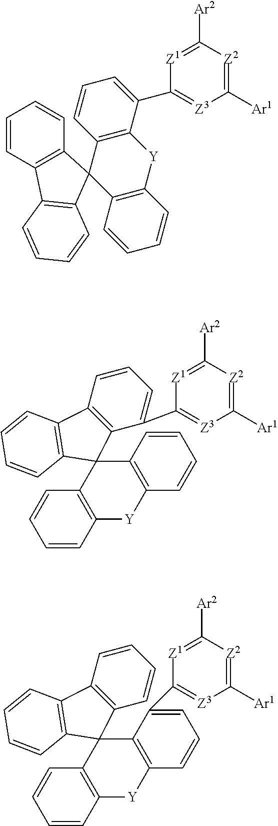
wherein Y has the same meaning as in the claim 2.

5. The organic mixture of claim 2, wherein, the organic compound H2 is a compound represented by one of the following general formulas (2) to (5): 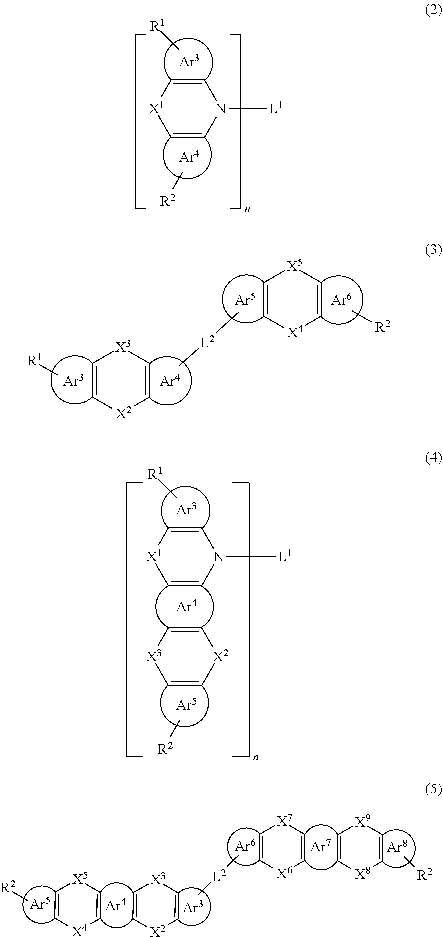
wherein, L¹ is selected from an aromatic group with a ring atom number of 5 to 60 or a heteroaromatic group with a ring atom number of 5 to 60;
L² is selected from a single bond, or an aromatic group with a ring atom number of 5 to 30 or a heteroaromatic group with a ring atom number of 5 to 30, and L² is coupled to any one of the carbon atoms on the ring;
Ar³, Ar⁴, Ar⁵, Ar⁶, Ar⁷ and Ar⁸ are independently selected from an aromatic group with a ring atom number of 5 to 30 or a heteroaromatic group with a ring atom number of 5 to 30;
X¹ is selected from a signal bond, N(R), C(R)₂, Si(R)₂, O, C═N(R), C═C(R)₂, P(R), P(═O)R, S, S═O or SO₂;
X², X³, X⁴, X⁵, X⁶, X⁷, X⁸ and X⁹ are independently selected from a signal bond, N(R), C(R)₂, Si(R)₂, O, C═N(R), C═C(R)2, P(R), P(═O)R, S, S═O or SO2, but X² and X³ are not single bonds simultaneously, X⁴ and X⁵ are not single bonds simultaneously, X⁶ and X⁷ are not single bonds simultaneously, and X⁸ and X⁹ are not single bonds simultaneously;
R¹, R² and R are independently selected from the group consisting of H, D, F, CN, alkenyl, alkynyl, a nitrile group, amino, nitro, acyl, alkoxy, carbonyl, sulfonyl, an alkyl with a carbon atom number of 1 to 30, a cycloalkyl with a carbon atom number of 3 to 30, an aromatic hydrocarbyl or an aromatic heterocyclic group with a ring atom number of 5 to 60; wherein, R¹ and R² are coupled to any one or more of carbon atoms on the fused ring;
n is 1, 2, 3 or 4.

6. The organic mixture of claim 5, wherein, the structure of the organic compound H2 is represented by one of formulas (6) to (9): 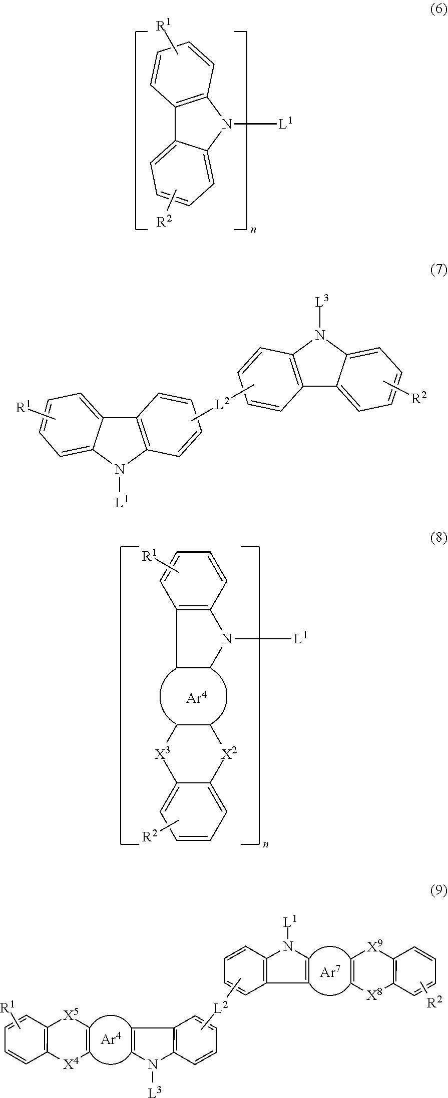
wherein, L³ is selected from a single bond, or an aromatic group with a ring atom number of 5 to 30 or a heteroaromatic group with a ring atom number of 5 to 30, and L² is coupled to any one of the carbon atoms on the ring.

7. The organic mixture of claim 65, wherein, Ar¹, Ar², Ar³, Ar⁴, Ar⁵, Ar⁶, Ar⁷ and Ar⁸ are independently selected from one of the following groups: 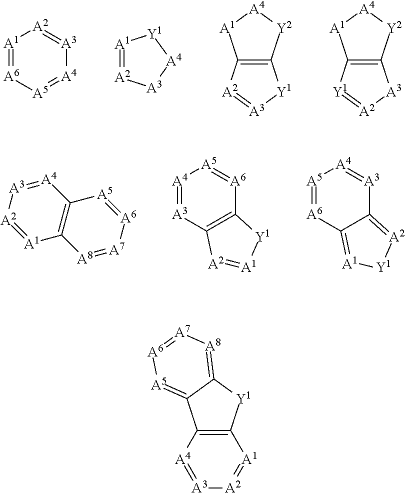
wherein, A¹, A², A³, A⁴, A⁵, A⁶, A⁷ and A⁸ are independently selected from CR³ or N;
Y¹ and Y² are independently selected from CR⁴R⁵, SiR⁴R⁵, NR³, C(═O), S or O;
R³, R⁴ and R⁵ are independently selected from the group consisting of H, D, a linear alkyl containing 1 to 20 C atoms, a linear alkoxy containing 1 to 20 C atoms, a linear thioalkoxy containing 1 to 20 C atoms, a branched or cyclic alkyl group containing 3 to 20 C atoms, a branched or cyclic alkoxy group containing 3 to 20 C atoms, a branched or cyclic thioalkoxy group containing 3 to 20 C atoms, a branched or cyclic silyl group containing 3 to 20 C atoms, a substituted ketone group containing 1 to 20 C atoms, an alkoxycarbonyl group containing 2 to 20 C atoms, an aryloxycarbonyl group containing 7 to 20 C atoms, cyano group, carbamoyl group, haloformyl group, formyl group, isocyano group, isocyanate group, thiocyanate group, isothiocyanate group, hydroxyl group, nitro group, CF₃ group, Cl, Br, F, a crosslinkable group, a substituted or unsubstituted aromatic ring system containing 5 to 40 ring atoms or substituted or unsubstituted heteroaromatic ring system containing 5 to 40 ring atoms, and a aryloxy group containing 5 to 40 ring atoms or heteroaryloxy group containing 5 to 40 ring atoms;
wherein, at least one of R³, R⁴ and R⁵ may form a monocyclic or polycyclic aliphatic or aromatic ring with the ring bonded to the groups, or at least two of R³, R⁴ and R⁵ form a monocyclic or polycyclic aliphatic or aromatic ring with each other.

8. The organic mixture of claim 7, wherein, Ar¹, Ar², Ar³, Ar⁴, Ar⁵, Ar⁶, Ar⁷, and Ar⁸ are independently are independently selected from one of the following structural groups: 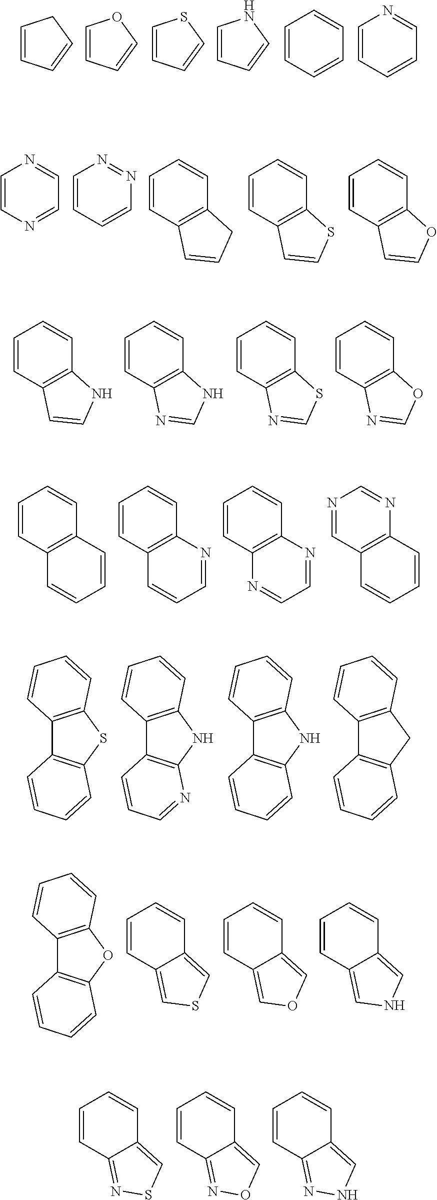
wherein, H on the ring of the structural group may be arbitrarily substituted.

9. The organic mixture of claim 8, wherein, the organic compound H2 is selected from one of compounds represented by the following structures:

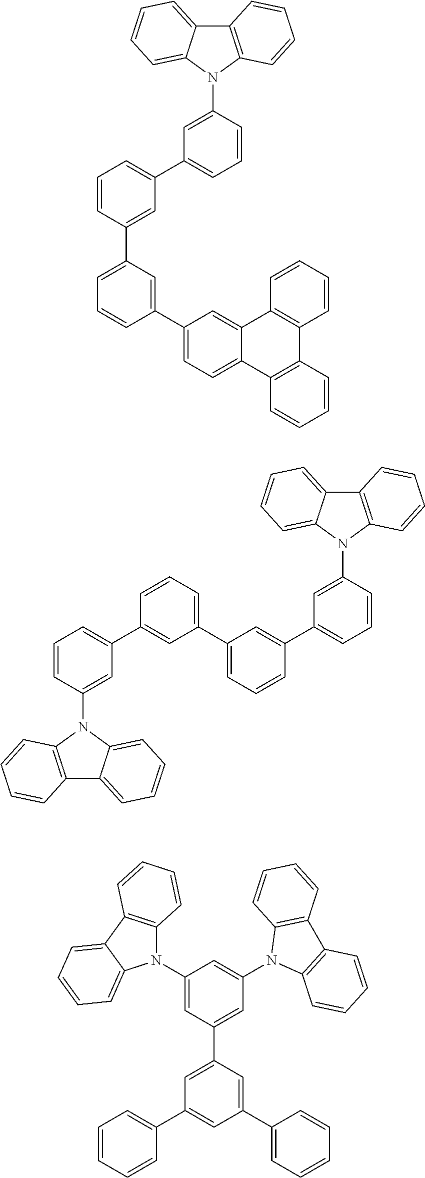

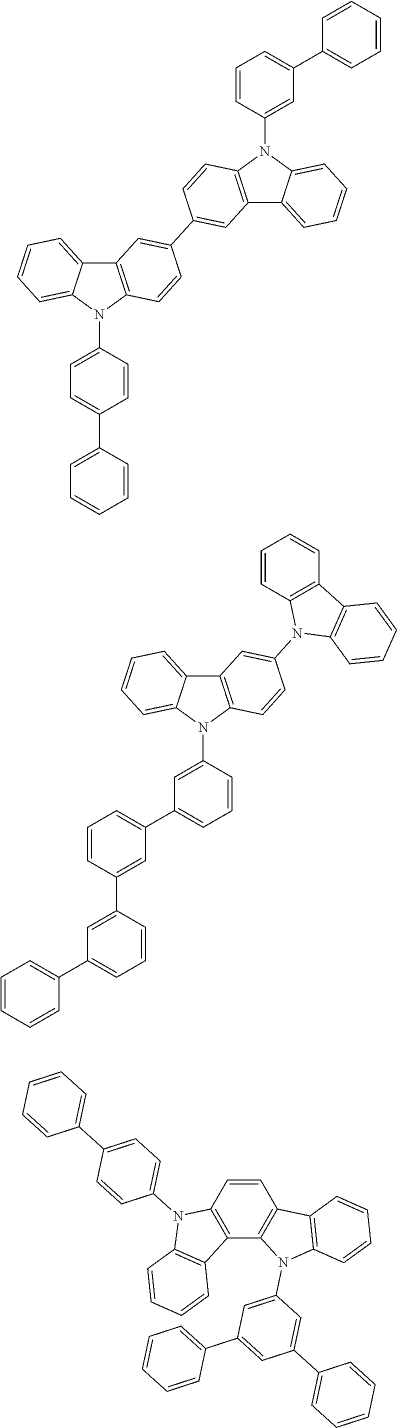 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-c3cccc(-c4cccc(-n5c6ccccc6c6cc(-n7c8ccccc8c8ccccc87)ccc65)c4)c3)c2)cc1 ; c1ccc(-c2ccc(-n3c4ccccc4c4c3ccc3c5ccccc5n(-c5cc(-c6ccccc6)cc(-c6ccccc6)c5)c34)cc2)cc1]

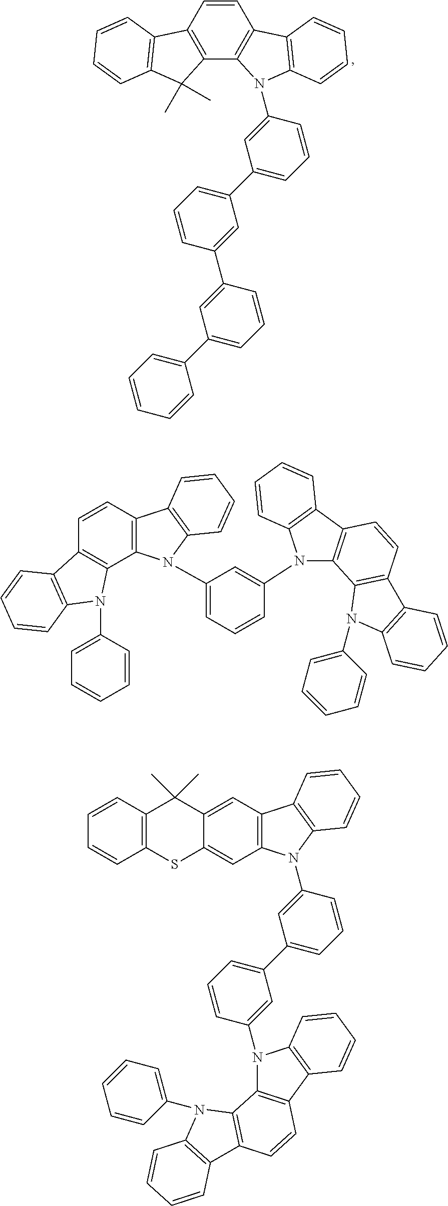 [SMILES: CC1(C)c2ccccc2-c2ccc3c4ccccc4n(-c4cccc(-c5cccc(-c6cccc(-c7ccccc7)c6)c5)c4)c3c21 ; c1ccc(-n2c3ccccc3c3ccc4c5ccccc5n(-c5cccc(-n6c7ccccc7c7ccc8c9ccccc9n(-c9ccccc9)c8c76)c5)c4c32)cc1 ; CC1(C)c2ccccc2Sc2cc3c(cc21)c1ccccc1n3-c1cccc(-c2cccc(-n3c4ccccc4c4ccc5c6ccccc6n(-c6ccccc6)c5c43)c2)c1]

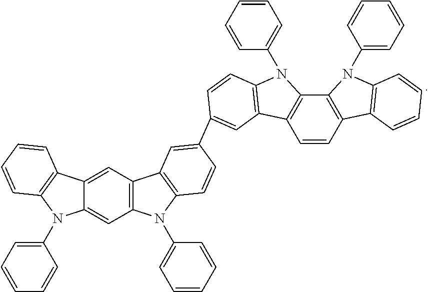 [SMILES: c1ccc(-n2c3ccccc3c3cc4c5cc(-c6ccc7c(c6)c6ccc8c9ccccc9n(-c9ccccc9)c8c6n7-c6ccccc6)ccc5n(-c5ccccc5)c4cc32)cc1]

10. The organic mixture of claim 1, wherein, a type II semiconductor heterojunction is formed between the organic compound H1 and the organic compound H2.

11. The organic mixture of claim 1, wherein, the organic compound H1 and/or the organic compound H2 satisfies (HOMO−(HOMO−1))≥0.2 eV, wherein, the HOMO refers to the highest occupied molecular orbital energy level of the organic compound H1 or the organic compound H2, and the (HOMO−1) refers to an occupied molecular orbital energy level of the organic compound H1 or the organic compound H2, which is one level lower than the highest occupied molecular orbital energy level of the organic compound H1 or the organic compound H2.

12. The organic mixture of claim 1, wherein, the difference between the molecular weight of the organic compound H1 and the molecular weight of the organic compound H2 is no greater than 100 g/mol.

13. The organic mixture of claim 1, wherein, the difference between the sublimation temperature of the organic compound H1 and the sublimation temperature of the organic compound H2 is no greater than 30 K.

14. The organic mixture of claim 1, wherein, the organic mixture further comprises an organic functional material selected from the group consisting of a hole injection material, a hole transport material, a hole blocking material, an electron injection material, an electron transport material, an electron blocking material and a light-emitting material.

15. The organic mixture of claim 14, wherein, the organic functional material is a light-emitting material, and the light-emitting material in the organic mixture has a weight percentage of 1 wt % to 30 wt %.

16. A formulation comprising comprises an organic solvent and the organic mixture of claim 1.

17. An organic electronic device comprising a cathode, an anode and a functional layer located between the cathode and the anode, the functional layer comprises the organic mixture of claim 1.

18. The organic electronic device of claim 17, wherein, the organic electronic device is an organic light emitting diode, an organic photovoltaic cell, an organic light-emitting electrochemical cell, an organic field effect transistor, an organic light-emitting field effect transistor, an organic sensor or an organic plasmon emitting diode.

19. (canceled)

20. (canceled)

21. The organic mixture of claim 1, wherein, the difference between the molecular weight of the organic compound H1 and the molecular weight of the organic compound H2 in the organic mixture is no greater than 40 g/mol.

22. The organic mixture of claim 1, wherein, min((LUMO(H1)−HOMO(H2)), (LUMO(H2)−HOMO(H1)))≤min (E_{T}(H1), E_{T}(H2))−0.1 eV.
